(19) United States
(12) Patent Application Publication
(10) Pub. No.: US 2015/0325798 A1
(43) Pub. Date: Nov. 12, 2015

(54) ORGANIC LIGHT-EMITTING DEVICES

(71) Applicant: SAMSUNG DISPLAY CO., LTD., Yongin-City (KR)

(72) Inventors: Hwan-Hee CHO, Yongin-City (KR); Mi-Kyung KIM, Yongin-City (KR); Jae-Yong LEE, Yongin-City (KR); Dong-Hyun KIM, Yongin-City (KR); Se-Hun KIM, Yongin-City (KR); Chang-Woong CHU, Yongin-City (KR)

(21) Appl. No.: 14/506,072

(22) Filed: Oct. 3, 2014

(30) Foreign Application Priority Data
May 12, 2014 (KR) 10-2014-0056570

(51) Int. Cl. H01L 51/00

(52) U.S. Cl. CPC H01L 51/0072; H01L 51/0067; H01L 51/0085; H01L 51/5012

(57) ABSTRACT

An organic light-emitting device including a first electrode; a second electrode facing the first electrode; and an emission layer between the first electrode and the second electrode, wherein the emission layer includes a triphenylene-based compound represented by Formula 2, below, and at least one heterocyclic compound selected from compounds represented by Formulae 1A, 1B, 1C, 1D, and 1E.

### CROSS-REFERENCE TO RELATED APPLICATION

Korean Patent Application No. 10-2014-0056570, filed on May 12, 2014, in the Korean Intellectual Property Office, and entitled: “Organic Light-Emitting Devices,” is incorporated by reference herein in its entirety.

### BACKGROUND

1. Field

One or more embodiments relate to an organic light-emitting device.

2. Description of the Related Art

Organic light-emitting devices are self-emission devices that have wide viewing angles, a high contrast ratio, short response times, and excellent brightness, driving voltage, and response speed characteristics, and produce full-color images.

An organic light-emitting device may have a structure in which a first electrode is formed on a substrate, and a hole transport region, an emission layer, an electron transport layer, and a second electrode are sequentially formed on the first electrode. Holes injected from the first electrode may move to the emission layer via the hole transport region and electrons injected from the second electrode may move to the emission layer via the electron transport region. Carriers (such as holes and electrons) may be recombined in the emission layer to produce excitons. These excitons may change from an excited state to a ground state, thereby generating light.

### SUMMARY

Embodiments are directed to an organic light-emitting device.

Additional aspects will be set forth in part in the description which follows and, in part, will be apparent from the description, or may be learned by practice of the presented embodiments.

According to one or more embodiments, provided is an organic light-emitting device including a first electrode, a second electrode disposed opposite to the first electrode; and an emission layer disposed between the first electrode and the second electrode, wherein

the emission layer includes one or more types of a heterocyclic compound selected from compounds represented by Formulae 1A, 1B, 1C, 1D, and 1E below and a triphenylene-based compound represented by Formula 2 below.

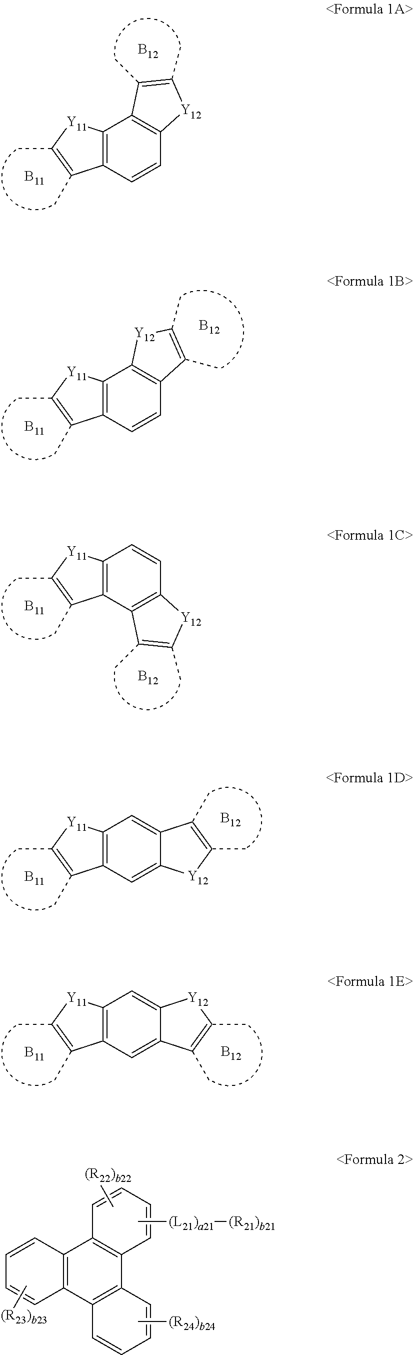

in Formulae 1A, 1B, 1C, 1D, 1E, and 2 above,

B₁₁ and B₁₂ may be each independently selected from a benzene group, a naphthalene group, an anthracene group, a pyridine group, a pyrimidine group, a quinoline group, an isoquinoline group, a 2,6-naphthyridine group, a 1,8-naphthyridine group, a 1,5-naphthyridine group, a 1,6-naphthyridine group, a 1,7-naphthyridine group, a 2,7-naphthyridine group, a quinoxaline group, a phthalazine group, and a quinazoline group; and

a benzene group, naphthalene group, an anthracene group, a pyridine group, a pyrimidine group, a quinoline group, an isoquinoline group, a 2,6-naphthyridine group(naphthyridine), a 1,8-naphthyridine group, a 1,5-naphthyridine group, a 1,6-naphthyridine group, a 1,7-naphthyridine group, a 2,7-naphthyridine group, a quinoxaline group, a phthalazine group, and a quinazoline group, each substituted with at least one selected from deuterium, —F, —Cl, —Br, —I, a C₁-C₆₀ alkyl group, a C₆-C₆₀ aryl group, a C₂-C₆₀ heteroaryl group, and —N(Q₁)(Q₂);

Y₁₁ is N-(L₁₁)ₐ₁₁-R₁₁;

Y₁₂ is N-(L₁₂)ₐ₁₂-R₁₂, a oxygen atom, a sulfur atom, C(R₁₃)(R₁₄), or Si(R₁₃)(R₁₄);

L₁₁, L₁₂ and L₂ may be each independently selected from a C₃-C₁₀ cycloalkylene group, a C₃-C₁₀ heterocycloalkylene group, a C₃-C₁₀ cycloalkenylene group, a C₃-C₁₀ heterocycloalkenylene group, a C₆-C₆₀ arylene group, a C₂-C₆₀ heteroarylene group, a divalent non-aromatic condensed polycyclic group, and a divalent non-aromatic hetero-condensed polycyclic group; and

a C₃-C₁₀ cycloalkylene group, a C₃-C₁₀ heterocycloalkylene group, a C₃-C₁₀ cycloalkenylene group, a C₃-C₁₀ heterocycloalkenylene group, a C₆-C₆₀ arylene group, a C₂-C₆₀ heteroarylene group, a divalent non-aromatic condensed polycyclic group, and a divalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group;

a11, a12, and a21 may be each independently selected from 0, 1, 2, 3, 4, and 5;

R₁₁ to R₁₄ and R₂₁ may be each independently selected from a substituted or unsubstituted C₃-C₁₀ cycloalkyl group, a substituted or unsubstituted C₃-C₁₀ heterocycloalkyl group, a substituted or unsubstituted C₃-C₁₀ cycloalkenyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, and a substituted or unsubstituted monovalent non-aromatic hetero-condensed polycyclic group;

at least one substituent of the substituted C₃-C₁₀ cycloalkyl group, the substituted C₃-C₁₀ heterocycloalkyl group, the substituted C₃-C₁₀ cycloalkenyl group, the substituted C₃-C₁₀ heterocycloalkenyl group, the substituted C₆-C₆₀ aryl group, the substituted C₂-C₆₀ heteroaryl group, the substituted monovalent non-aromatic condensed polycyclic group, and the substituted monovalent non-aromatic hetero-condensed polycyclic group may be selected from

deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₁₁)(Q₁₂), —Si(Q₁₃)(Q₁₄)(Q₁₅), and —B(Q₁₆)(Q₁₇);

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇);

R₂₂ to R₂₄, Q₁, Q₂, Q₁₁ to Q₁₇, Q₂₁ to Q₂₇, and Q₃₁ to Q₃₇ may be each independently selected from hydrogen, deuterium, a C₁-C₆₀ alkyl group, a C₆-C₆₀ aryl group, a C₂-C₆₀ heteroaryl group, a monovalent non-aromatic condensed polycyclic group, and a monovalent non-aromatic hetero-condensed polycyclic group;

b22 may be selected from 1, 2, and 3; and

b23 and b24 may be each independently selected from 1, 2, 3, and 4.

### BRIEF DESCRIPTION OF THE DRAWING

Features will be apparent to those of skill in the art by describing in detail exemplary embodiments with reference to the attached drawings in which:

FIG. 1 illustrates a schematic view of an organic light-emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

In the present specification, it is to be understood that the terms such as “including”, “having”, and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a layer, region, or component is referred to as being “formed on” another layer, region, or component, it can be directly or indirectly formed on the other layer, region, or component. That is, for example, intervening layers, regions, or components may be present.

As used herein, the expression “organic layer” refers to single and/or multiple layers between a first electrode and a second electrode in an organic light-emitting device. Materials included in the “organic layer” are not limited to organic materials.

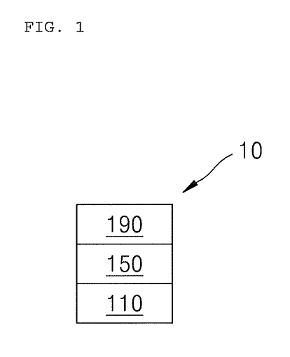

FIG. 1 illustrates a schematic cross-sectional view of an organic light-emitting device 10 according to an embodiment. The organic light-emitting device 10 may include a first electrode 110, an organic layer 150, and a second electrode 190.

Hereinafter, a structure and a method of manufacturing the organic light-emitting device 10 are described below with reference to FIG. 1.

A substrate may be additionally disposed under the first electrode 110 or on the second electrode 190 in FIG. 1. The substrate may be a glass substrate or a transparent plastic substrate with excellent mechanical strength, thermal stability, transparency, surface smoothness, ease of handling, and water resistance.

The first electrode 110 may be formed by, for example, depositing or sputtering a first electrode material on the substrate. When the first electrode 110 is an anode, a first electrode material may be selected from materials with a high work function to facilitate hole injection. The first electrode 110 may be a reflective electrode, a semi-transmission electrode, or a transmission electrode. The first electrode material may be a transparent material with high conductivity, and examples of such a material are indium tin oxide (ITO), indium zinc oxide (IZO), tin oxide (SnO₂), and zinc oxide (ZnO). To form the first electrode 110, which is a semi-transmission electrode or a reflective electrode, the first electrode material may be at least one selected from magnesium (Mg), aluminum (Al), aluminum-lithium (Al—Li), calcium (Ca), magnesium-indium (Mg—In), magnesium-silver (Mg—Ag), or the like.

The first electrode 110 may have a single-layered structure or a multi-layered structure including a plurality of layers. For example, the first electrode 110 may have a three-layered structure of ITO/Ag/ITO, but it is not limited thereto.

The organic layer 150 may be disposed on the first electrode 110. The organic layer 150 includes an emission layer.

The organic layer 150 may include a hole transport region disposed between the first electrode 110 and the emission layer and an electron transport region disposed between the emission layer and the second electrode 190.

The hole transport region may include at least one selected from a hole injection layer (HIL), a hole transport layer (HTL), a buffer layer, and an electron blocking layer EBL, and the electron transport region may include at least one selected from a hole-blocking layer (HBL), an electron transport layer (ETL), and an electron injection layer (EIL), but they are not limited thereto.

The hole transport region may include a single layer formed of a single material, a single layer formed of a plurality of different materials, or a multi-layered structure including a plurality of layers formed of a plurality of different materials.

For example, the hole transport region may have a single-layered structure formed of a plurality of different materials or a structure in which HIL/HTL, HIL/HTL/buffer layer, HIL/buffer layer, HTL/buffer layer, or HIL/HTL/EBL are sequentially layered on the first electrode 110, but it is not limited thereto.

When the hole transport region includes the HIL, the HIL may be formed on the first electrode 110 by using various methods, such as vacuum deposition, spin coating, casting, Langmuir—Blodgett (LB) deposition, inkjet printing, laser printing, and laser-induced thermal imaging (LITI).

When the HIL is formed by using vacuum deposition, vacuum deposition conditions may vary according to the compound that is used to form the HIL and the desired structure of the HIL to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec.

When the HIL is formed by using spin coating, the coating conditions may vary according to the compound that is used to form the HIL and the desired structure of the HIL to be formed. For example, the coating rate may be in the range of about 2000 rpm to about 5000 rpm, and a temperature at which a heat treatment is performed may be in the range of about 80° C. to about 200° C.

When the hole transport region includes the HTL, the HTL may be formed on the first electrode 110 or on the HIL by using various methods, such as vacuum deposition, spin coating, casting, LB deposition, inkjet printing, laser printing, and LITI. When the HTL is formed by vacuum deposition or spin coating, vacuum deposition conditions and coating conditions may be the same as the vacuum deposition conditions and the coating conditions of the HIL.

The hole transport region may include at least one selected from m-MTDATA, TDATA, 2-TNATA, NPB, β—NPB, TPD, Spiro-TPD, Spiro-NPB, α—NPB, TAPC, HMTPD, 4,4′,4″-tris(N-carbazolyl)triphenylamine(4,4′,4″-tris(N-carbazolyl)triphenylamine) (TCTA), polyaniline/dodecylbenzenesulfonic acid (Pani/DBSA), Poly(3,4-ethylenedioxythiophene)/Poly(4-styrenesulfonate) (PEDOT/PSS), polyaniline/camphor sulfonic acid (pani/CSA), or (polyaniline)/poly(4-styrenesulfonate) (PANI/PSS), a compound represented by Formula 201 below, and a compound represented by Formula 202 below.

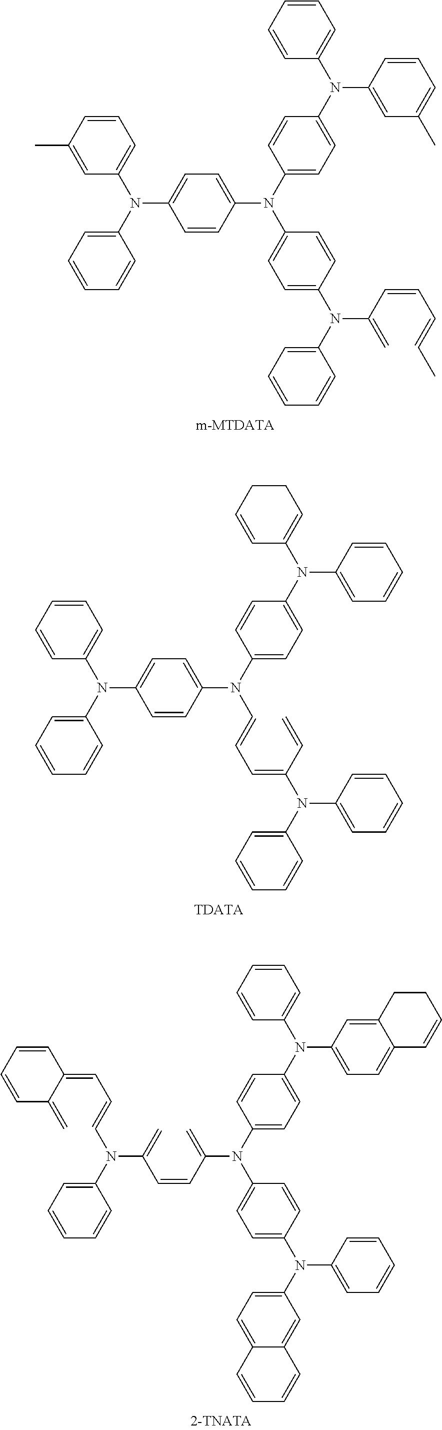 [SMILES: C=C(/C=C\C=C\C)N(c1ccccc1)c1ccc(N(c2ccc(N(c3ccccc3)c3cccc(C)c3)cc2)c2ccc(N(c3ccccc3)c3cccc(C)c3)cc2)cc1 ; C=C/C(=C\C=C\N(c1ccc(N(C2=CCCC=C2)c2ccccc2)cc1)c1ccc(N(c2ccccc2)c2ccccc2)cc1)N(c1ccccc1)c1ccccc1 ; "TDATA" ; C=C(/C=C\C(=C)N(c1ccc(N(c2ccccc2)c2ccc3c(c2)CCC=C3)cc1)c1ccc(N(c2ccccc2)c2ccc3ccccc3c2)cc1)N(/C=C/C=c1/ccccc1=C)c1ccccc1]

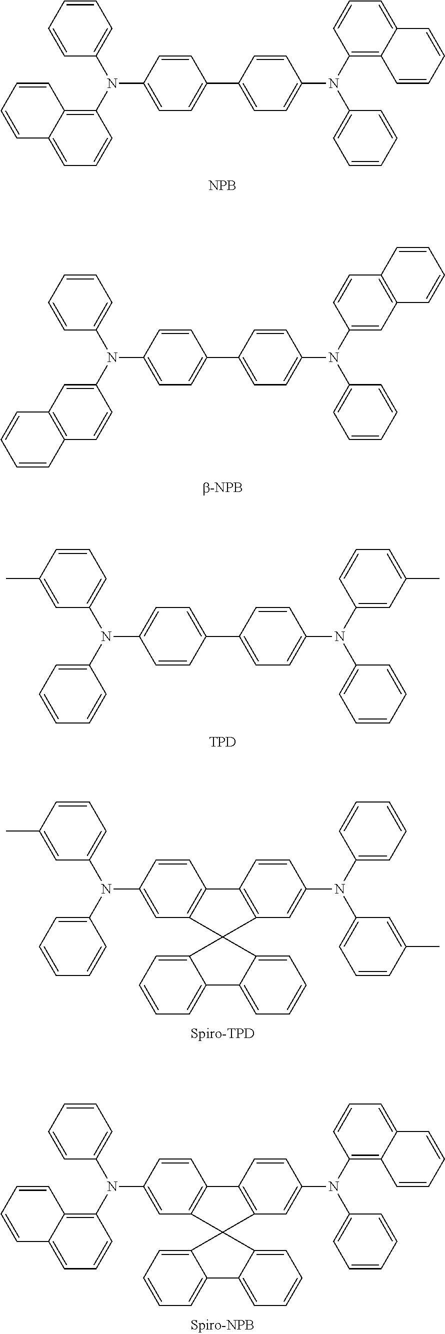

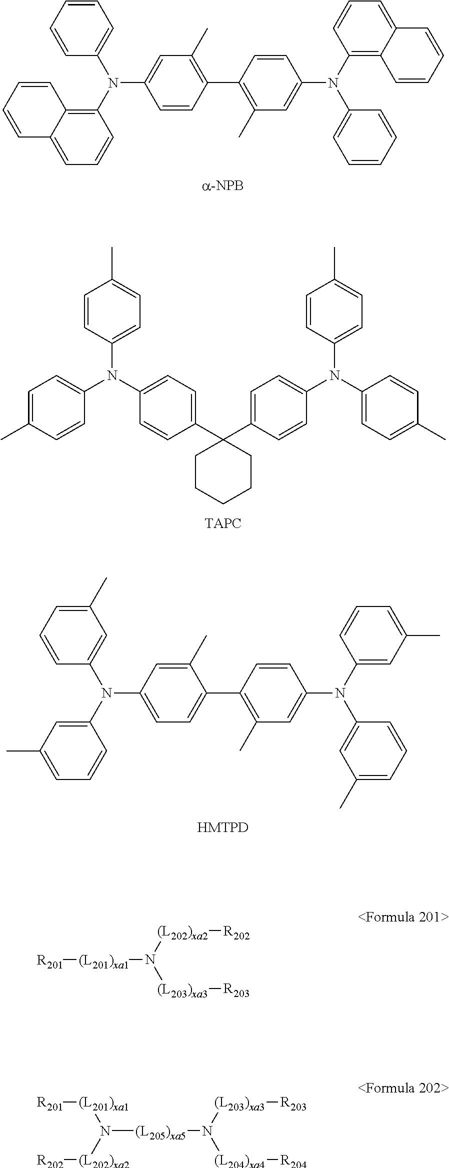

In Formulae 201 and 202,

descriptions of L₂₀₁ to L₂₀₅ may be each independently the same as the description for L₁₁ herein;

xa1 to xa4 may be each independently selected from 0, 1, 2, and 3;

xa5 may be selected from 1, 2, 3, 4, and 5; and

descriptions of R₂₀₁ to R₂₀₅ may be each independently the same as the description of R₂₁ herein.

For example, in Formulae 201 and 202 above,

L₂₀₁ to L₂₀₅ may be each independently selected from a phenylene group, a naphthylene group, a fluorenylene group, a spiro-fluorenylene group, a benzofluorene group, a dibenzofluorene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene, and a triazinylene group;

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene, and a triazinylene, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group, and a triazinyl group;

xa1 to xa4 may be each independently selected from 0, 1, or 2; and

xa5 may be selected from 1, 2, or 3; and

R₂₀₁ to R₂₀₅ may be each independently selected from a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, an azulenyl, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group.

The compound represented by Formula 201 may be represented by Formula 201A below.

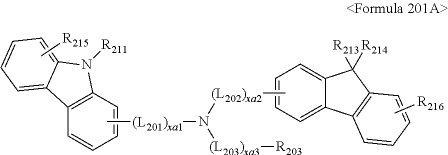

For example, the compound represented by Formula 201 may be represented by Formula 201A-1 below, but it is not limited thereto.

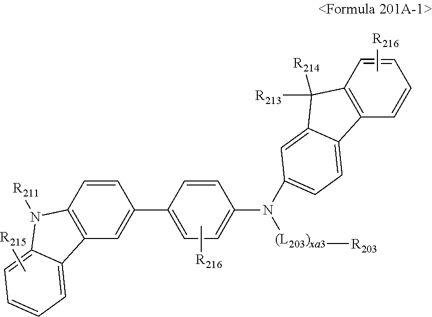

The compound represented by Formula 202 may be represented by Formula 202A below, but it is not limited thereto.

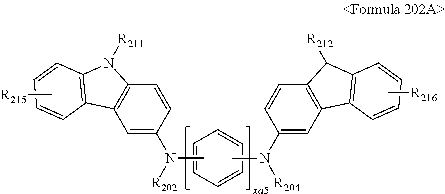

In Formulae 201A, 201A-1, and 202A, descriptions of L₂₀₁ to L₂₀₃, xa1 to xa3, xa5, and R₂₀₂ to R₂₀₄ may be as described herein, descriptions of R₂₁₁ may be as the description of R₂₀₃, and R₂₁₃ to R₂₁₆ may be each independently selected from hydrogen, deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, and a non-aromatic condensed polycyclic group.

For example, in Formulae 201A, 201A-1, and 202A,

L₂₀₁ to L₂₀₃ may be each independently selected from a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene, and a triazinylene group, and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene, and a triazinylene group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,

xa1 to xa3 may be each independently selected from 0 or 1;

R₂₀₃, R₂₁₁, and R₂₁₂ may be each independently selected from a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₃ and R₂₁₄ may be each independently selected from a C₁-C₂₀ alkyl group and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₅ and R₂₁₆ may be each independently selected from hydrogen, deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof,

a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

xa5 may be 1 or 2.

R₂₁₃ and R₂₁₄ in Formulae 201A and 201A-1 may bind to each other to form a saturated or an unsaturated ring.

The compound represented by Formula 201 and the compound represented by Formula 202 may include compounds HT1 to HT20, but they are not limited thereto.

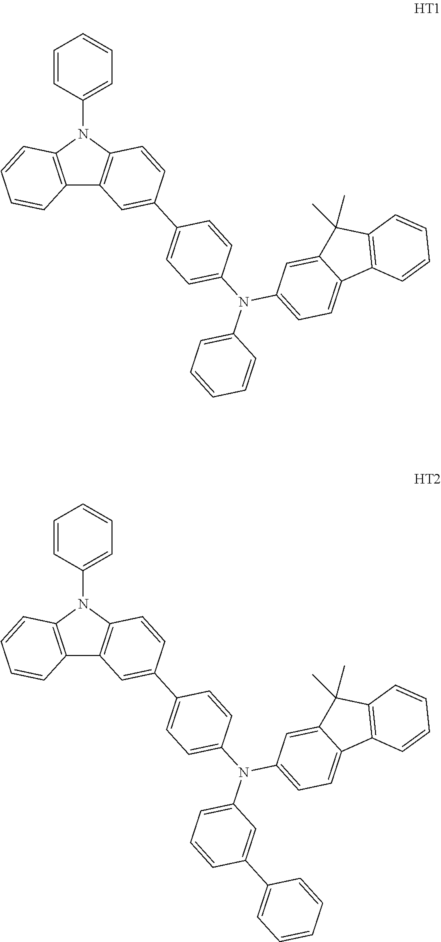 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21]

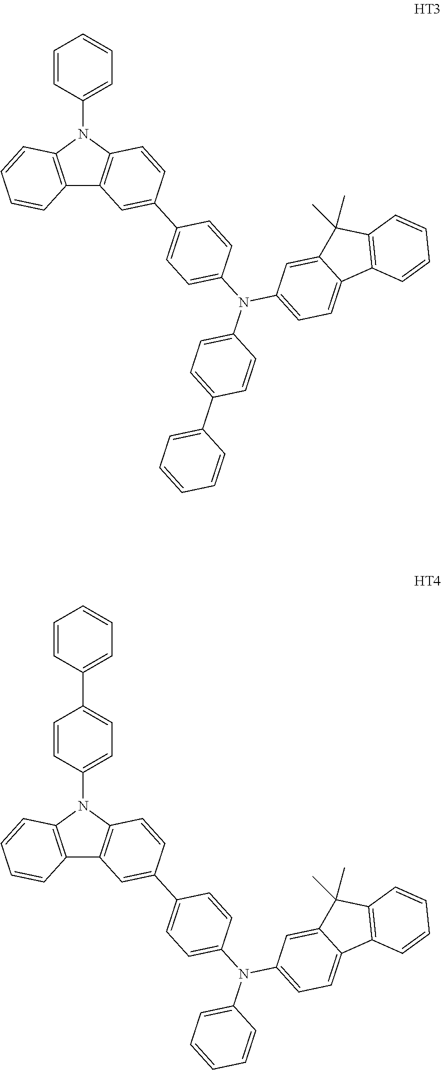 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

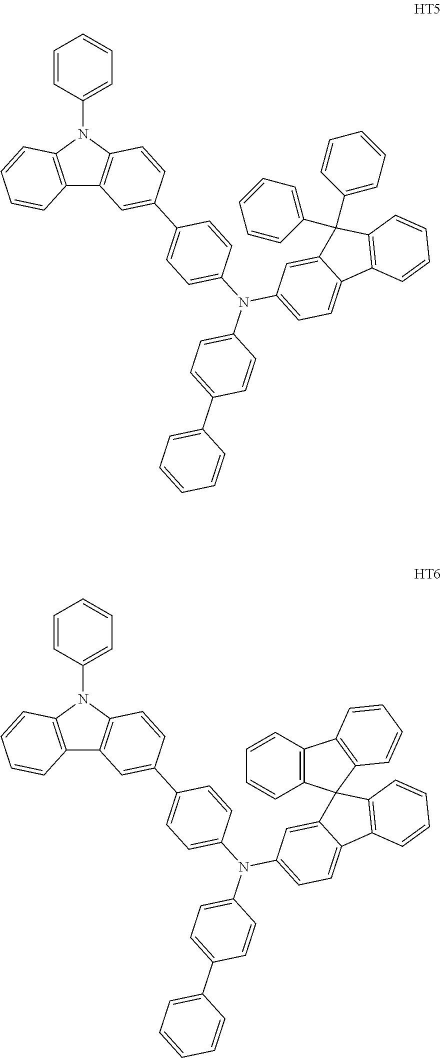 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

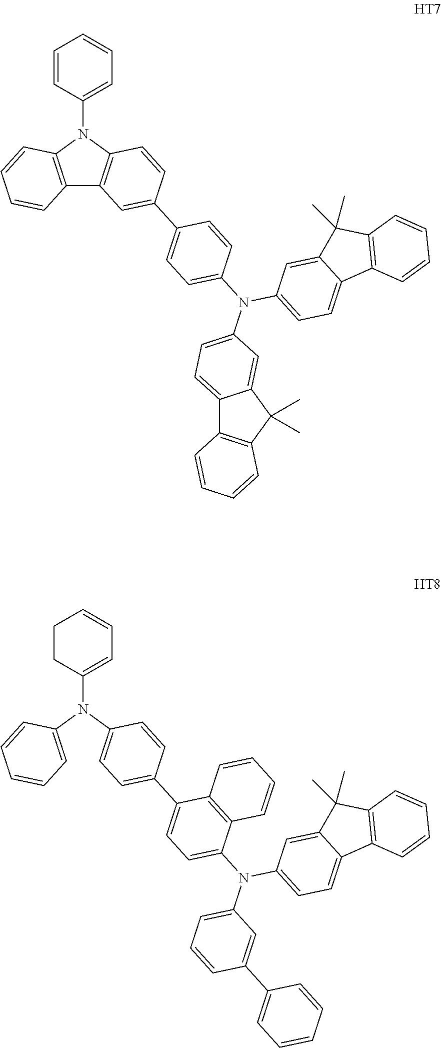 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc(N(C5=CC=CCC5)c5ccccc5)cc4)c4ccccc34)cc21]

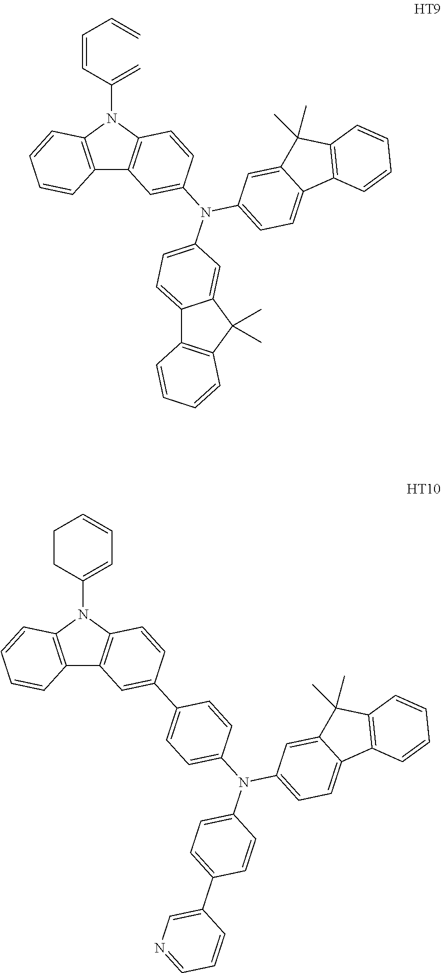 [SMILES: C=C/C=C\C(=C)n1c2ccccc2c2cc(N(c3ccc4c(c3)C(C)(C)c3ccccc3-4)c3ccc4c(c3)C(C)(C)c3ccccc3-4)ccc21 ; CC1(C)c2ccccc2-c2ccc(N(c3ccc(-c4cccnc4)cc3)c3ccc(-c4ccc5c(c4)c4ccccc4n5C4=CC=CCC4)cc3)cc21]

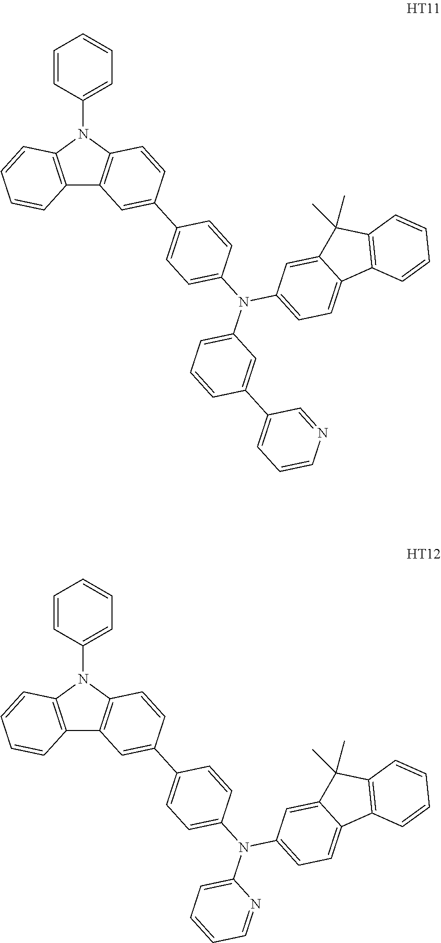 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

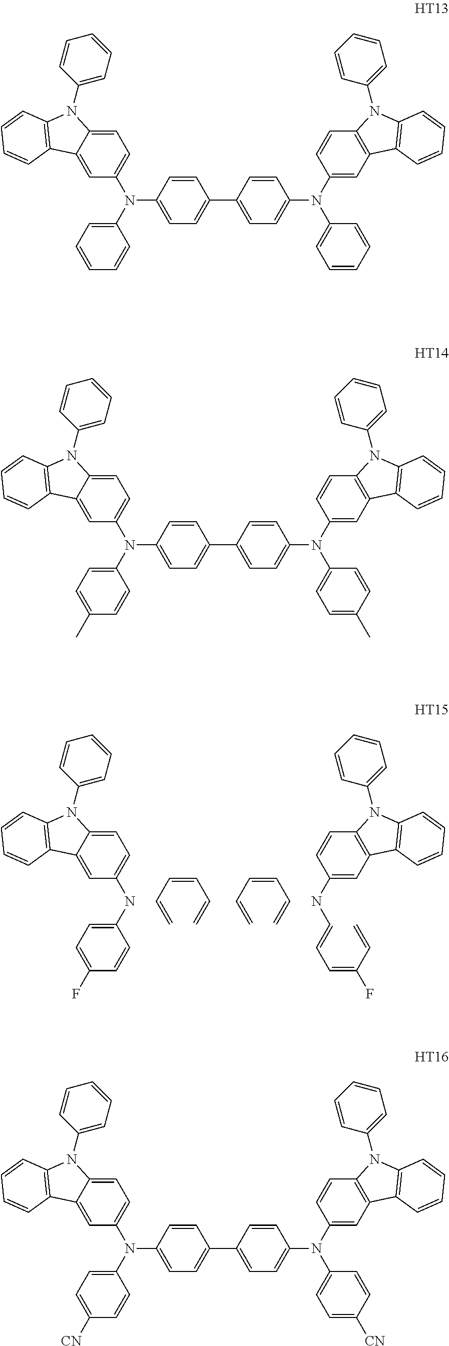

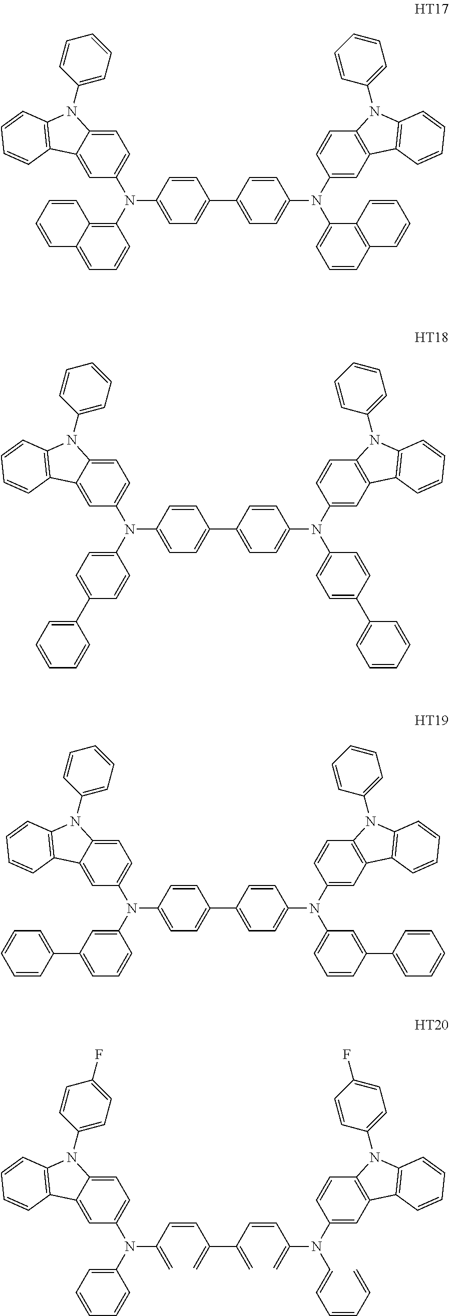

A thickness of the hole transport region may be about 100 Å to about 10000 Å, for example, about 100 Å to about 1000 Å. When the hole transport region includes both of the HIL and the HTL, a thickness of the HIL may be about 100 Å to about 10000 Å, for example, about 100 Å to about 1000 Å and a thickness of the HTL may be about 50 Å to about 2000 Å, for example, about 100 Å to about 1500 Å. When the thicknesses of the hole transport region, the HIL, and the HTL satisfy the ranges described above, satisfactory hole injection characteristics may be obtained without a substantial increase in a driving voltage.

The hole transport region may further include a charge-generating material, in addition to the material described above. The charge-generating material may be uniformly or disuniformly dispersed in the hole transport region.

The charge-generating material may be, for example, a p-dopant. The p-dopant may be selected from quinone derivatives, metal oxides, F-containing compounds, Cl-containing compounds, and CN-containing compounds, but it is not limited thereto. For example, non-limiting examples of the p-dopant are quinone derivatives, such as tetracyanoquinodimethane (TCNQ), and 2,3,5,6-tetrafluoro-tetracyano-1,4-benzoquinodimethane (F4-TCNQ); metal oxides such as tungsten oxides and molybdenym oxides; and a Compound HT-D1 below.

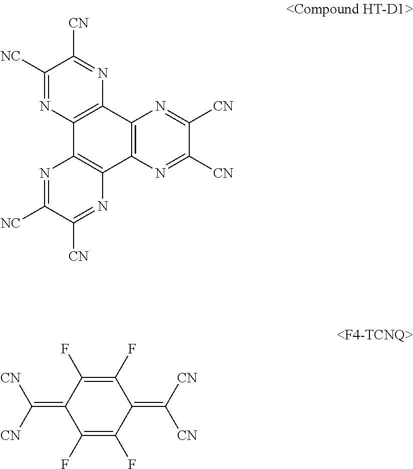

The hole transport region may include at least one selected from the buffer layer and the EBL, in addition to the HIL and the HTL. The buffer layer may compensate for an optical resonance distance of light according to a wavelength of the light emitted from the emission layer (EML), and thus may increase efficiency. The buffer layer may include any material that may be used in the hole transport region. The EBL may prevent injection of electrons from the electron transport region.

Then, the EML may be formed on the first electrode 110 or the hole transport region by vacuum deposition, spin coating, casting, LB deposition, inkjet printing, laser printing, LITI, or the like. When the EML is formed using vacuum deposition or spin coating, the deposition and coating conditions may be similar to those for the formation of the HIL.

When the organic light-emitting device 10 is a full color organic light-emitting device, the organic light-emitting device 10 may be patterned into red EML, green EML, and blue EML, according to different EMLs and individual sub-pixels. In an implementation, the EML may have a structure in which the red EML, the green EML, and the blue EML are layered or a structure in which a red light emission material, a green light emission material, and a blue light emission material are mixed without separation of layers and emit white light.

The EML may include at least one heterocyclic compound selected from compounds represented by Formulae 1A, 1B, 1C, 1D, and 1E, and may include a triphenylene-based compound represented by Formula 2:

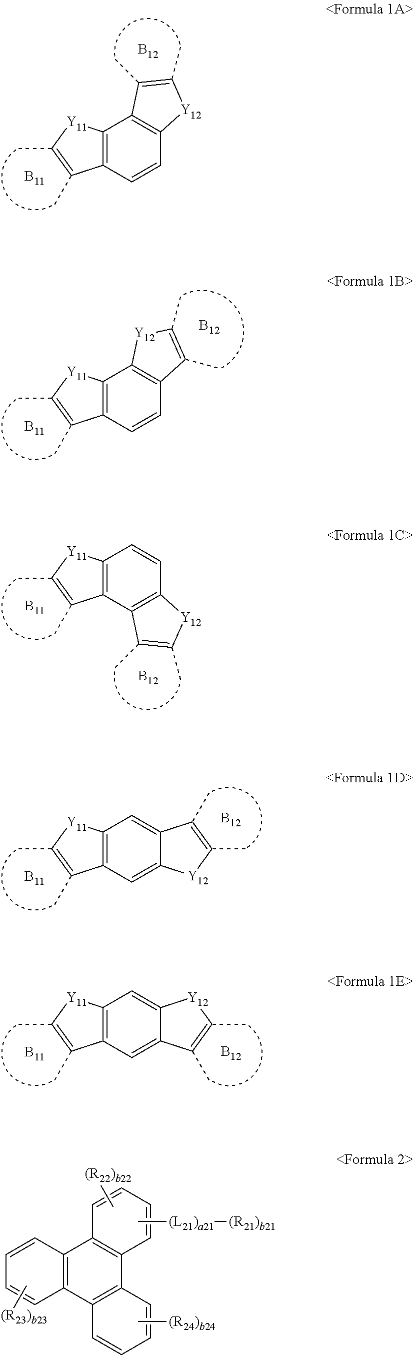

In Formulae 1A, 1B, 1C, 1D, and 1E, B₁₁ and B₁₂ may be each independently selected from a benzene group, a naphthalene group, an anthracene group, a pyridine group, a pyrimidine group, a quinoline group, an isoquinoline group, 2,6-naphthyridine group(naphthyridine), 1,8-naphthyridine group, 1,5-naphthyridine group, 1,6-naphthyridine group, 1,7-naphthyridine group, 2,7-naphthyridine group, a quinoxaline group, a phthalazine group, and a quinazoline group; and

a benzene group, a naphthalene group, an anthracene group, a pyridine group, a pyrimidine group, a quinoline group, an isoquinoline group, 2,6-naphthyridine group(naphthyridine), 1,8-naphthyridine group, 1,5-naphthyridine group, 1,6-naphthyridine group, 1,7-naphthyridine group, 2,7-naphthyridine group, a quinoxaline group, a phthalazine group, and a quinazoline group, each substituted with at least one selected from deuterium, —F, —Br, —I, a C₁-C₆₀ alkyl group, a C₆-C₆₀ aryl group, a C₂-C₆₀ heteroaryl group, and —N(Q₁)(Q₂); and

Q₁ and Q₂ may be each independently selected from hydrogen, deuterium, a C₁-C₆₀ alkyl group, a C₆-C₆₀ aryl group, a C₂-C₆₀ heteroaryl group, a monovalent non-aromatic condensed polycyclic group, and a monovalent non-aromatic hetero-condensed polycyclic group.

For example, in Formulae 1A, 1B, 1C, 1D, and 1E, B₁₁ and B₁₂ may be each independently selected from a benzene group, a naphthalene group, an anthracene group, a pyridine group, a pyrimidine group, a quinoline group, and an isoquinoline group; and

a benzene group, a naphthalene group, an anthracene group, a pyridine group, a pyrimidine group, a quinoline group, and an isoquinoline group, each substituted with at least one selected from deuterium, a methyl group, an ethyl group, a tert-butyl group, an octyl group, a phenyl group, a naphthyl group, a pyridyl group, a pyrimidyl group, and —N(Q₁)(Q₂);

Q₁ and Q₂ may be each independently selected from a phenyl group, a naphthyl group, an anthracenyl group, a triphenylenyl group, a phenanthrenyl group, a pyrenyl group, and a chrysenyl group; and

a phenyl group, a naphthyl group, an anthracenyl group, a triphenylenyl group, a phenanthrenyl group, a pyrenyl group, and a chrysenyl group, each substituted with at least one selected from a phenyl group, a naphthyl group, an anthracenyl group, a triphenylenyl group, a pyrenyl group, and a chrysenyl group, but they are not limited thereto.

In another embodiment, in Formulae 1A, 1B, 1C, 1D, and 1E, B₁₁ and B₁₂ may be each independently selected from a benzene group, a naphthalene group, a pyridine group, and a pyrimidine group; and

a benzene group, a naphthalene group, a pyridine group, and a pyrimidine group, each substituted with at least one selected from deuterium, a methyl group, an ethyl group, a phenyl group, a naphthyl group, a pyridyl group, a pyrimidyl group, and —N(Ph)₂, but they are not limited thereto.

In Formulae 1A, 1B, 1C, 1D, and 1E,

Y₁₁ may be N-(L₁₁)ₐ₁₁-R₁₁; and

Y₁₂ may be N-(L₁₂)ₐ₁₂-R₁₂, a oxygen atom, a sulfur atom, C(R₁₃)(R₁₄), or Si(R₁₃)(R₁₄).

For example, in Formulae 1A, 1B, 1C, 1D, and 1E,

Y₁₁ may be N-(L₁₁)ₐ₁₁-R₁₁;

Y₁₂ may be N-(L₁₂)ₐ₁₂-R₁₂, a oxygen atom, a sulfur atom, or C(R₁₃)(R₁₄), but they are not limited thereto.

In Formulae 1A, 1B, 1C, 1D, and 1E,

R₁₁ to R₁₄ may be each independently selected from a substituted or unsubstituted C₃-C₁₀ cycloalkyl group, a substituted or unsubstituted C₃-C₁₀ heterocycloalkyl group, a substituted or unsubstituted C₃-C₁₀ cycloalkenyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, and a substituted or unsubstituted monovalent non-aromatic hetero-condensed polycyclic group;

at least one substituent of the substituted C₃-C₁₀ cycloalkyl group, the substituted C₃-C₁₀ heterocycloalkyl group, the substituted C₃-C₁₀ cycloalkenyl group, the substituted C₃-C₁₀ heterocycloalkenyl group, the substituted C₆-C₆₀ aryl group, the substituted C₂-C₆₀ heteroaryl group, the substituted monovalent non-aromatic condensed polycyclic group, and the substituted monovalent non-aromatic hetero-condensed polycyclic group may be selected from

deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₁₁)(Q₁₂), —Si(Q₁₃)(Q₁₄)(Q₁₅), and —B(Q₁₆)(Q₁₇);

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇);

Q₁₁ to Q₁₇, Q₂₁ to Q₂₇, and Q₃₁ to Q₃₇ may be each independently selected from hydrogen, deuterium, a C₁-C₆₀ alkyl group, a C₆-C₆₀ aryl group, a C₂-C₆₀ heteroaryl group, a monovalent non-aromatic condensed polycyclic group, and a monovalent non-aromatic hetero-condensed polycyclic group.

For example, at least one of R₁₁ to R₁₄ in Formulae 1A, 1B, 1C, 1D, and 1E may be a group selected from a substituted or unsubstituted electron transporting-cyclic group including at least one N as a ring-forming atom, but it is not limited thereto.

In another embodiment, R₁₁ to R₁₄ in Formulae 1A, 1B, 1C, 1D, and 1E may be each independently selected from groups represented by Formulae H1 to H81.

In an implementation, at least one of R₁₁ to R₁₄ may be selected from groups represented by Formulae H1 to H28, H37 to H41, H68 to H76, and H80 below, but they are not limited thereto.

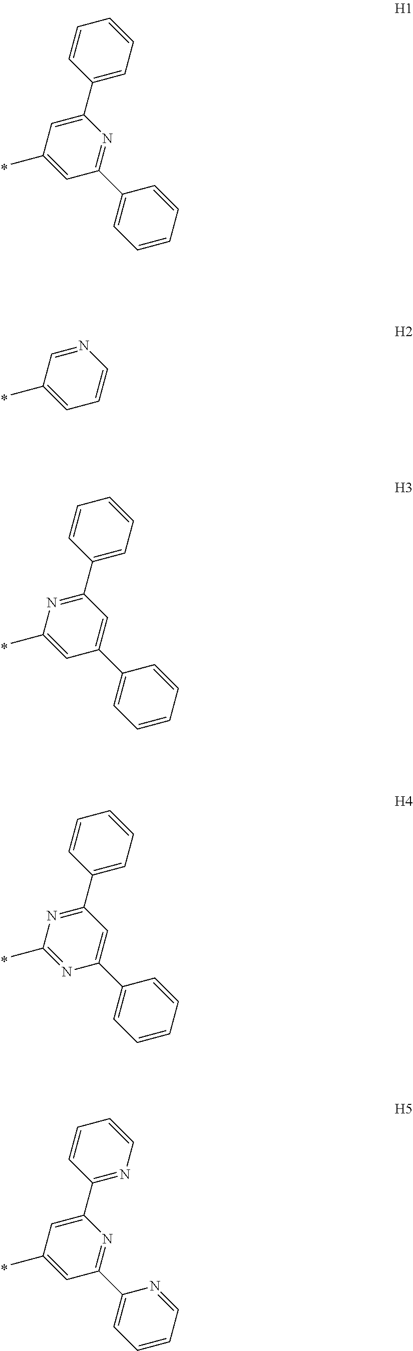

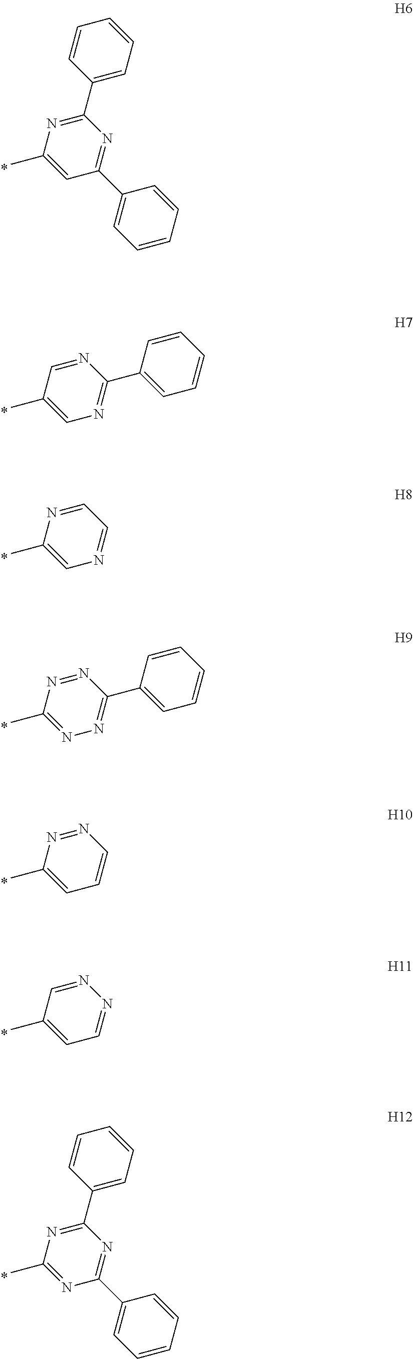

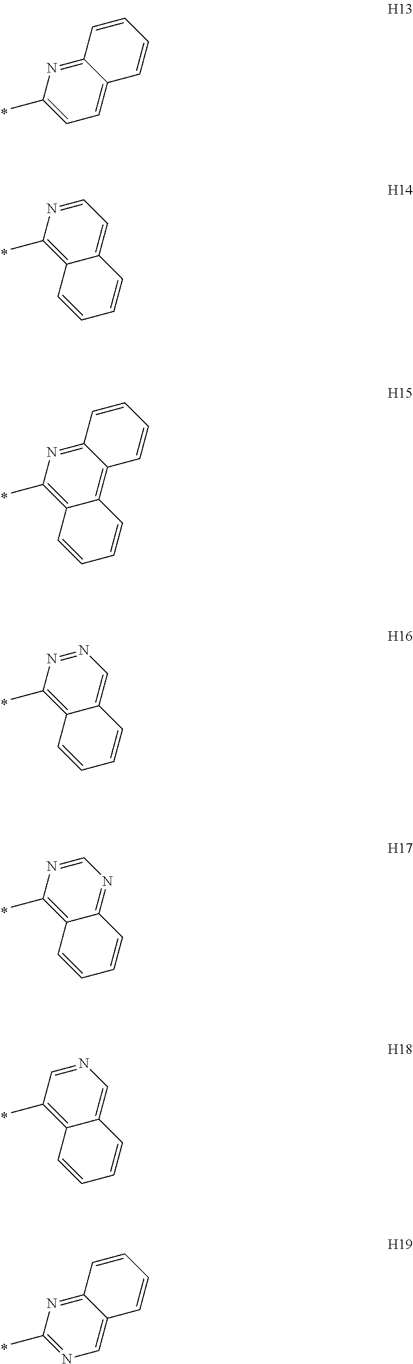

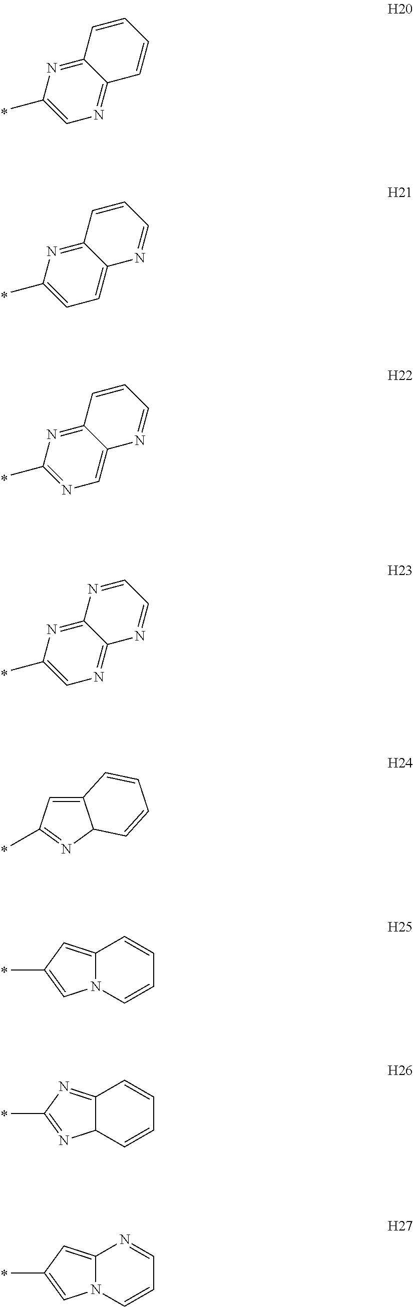

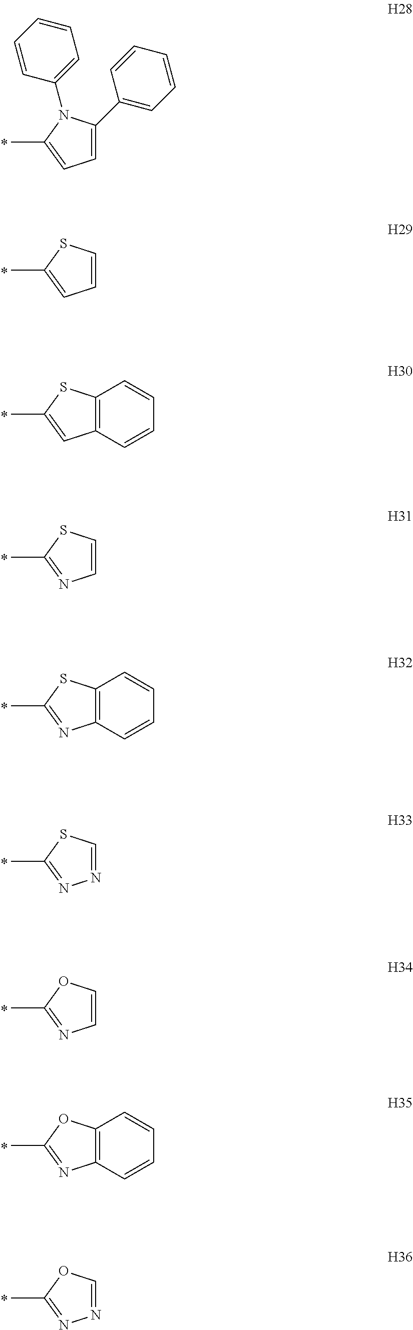

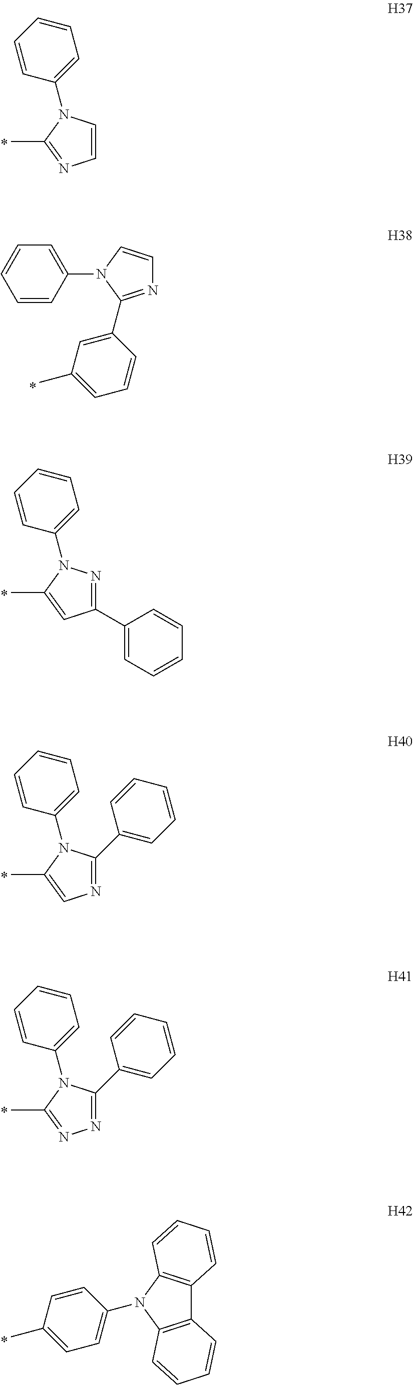 [SMILES: Cc1nccn1-c1ccccc1 ; Cc1cccc(-c2nccn2-c2ccccc2)c1 ; Cc1cc(-c2ccccc2)nn1-c1ccccc1 ; Cc1cnc(-c2ccccc2)n1-c1ccccc1 ; Cc1nnc(-c2ccccc2)n1-c1ccccc1 ; Cc1ccc(-n2c3ccccc3c3ccccc32)cc1]

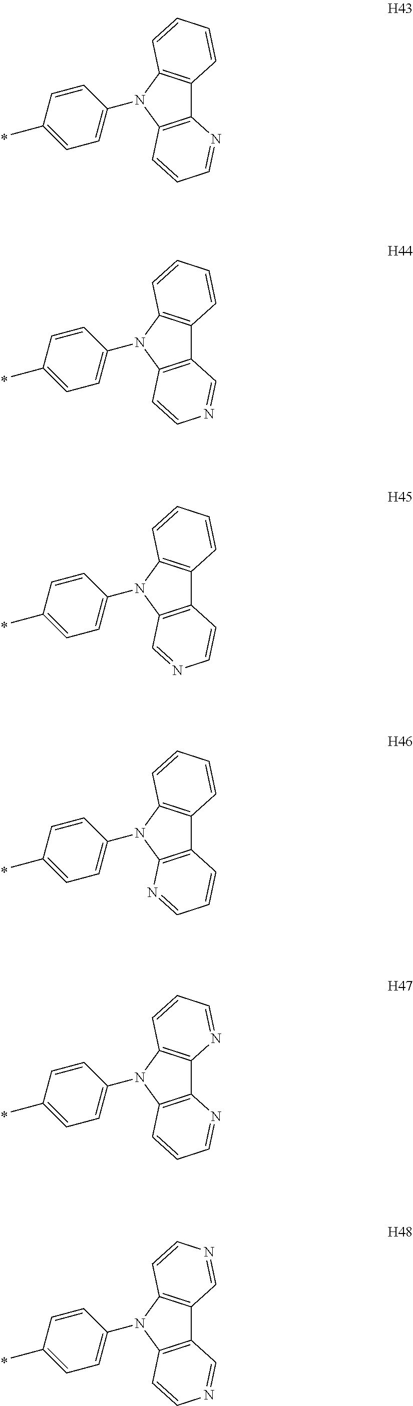 [SMILES: Cc1ccc(-n2c3ccccc3c3ncccc32)cc1 ; Cc1ccc(-n2c3ccccc3c3cnccc32)cc1 ; Cc1ccc(-n2c3ccccc3c3ccncc32)cc1 ; Cc1ccc(-n2c3ccccc3c3cccnc32)cc1 ; Cc1ccc(-n2c3cccnc3c3ncccc32)cc1 ; Cc1ccc(-n2c3ccncc3c3cnccc32)cc1]

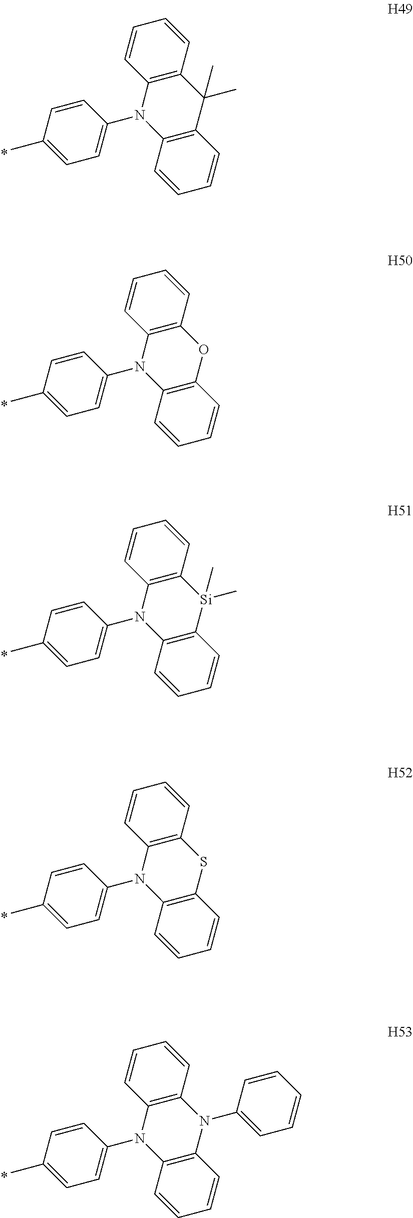

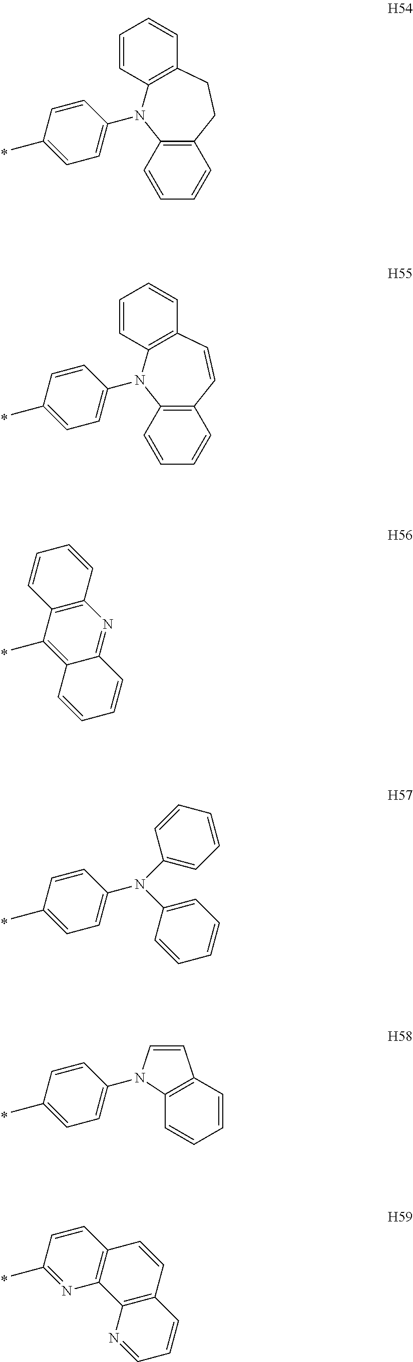 [SMILES: Cc1ccc(N2c3ccccc3CCc3ccccc32)cc1 ; Cc1ccc(N2c3ccccc3C=Cc3ccccc32)cc1 ; Cc1c2ccccc2nc2ccccc12 ; Cc1ccc(N(c2ccccc2)c2ccccc2)cc1 ; Cc1ccc(-n2ccc3ccccc32)cc1 ; Cc1ccc2ccc3cccnc3c2n1]

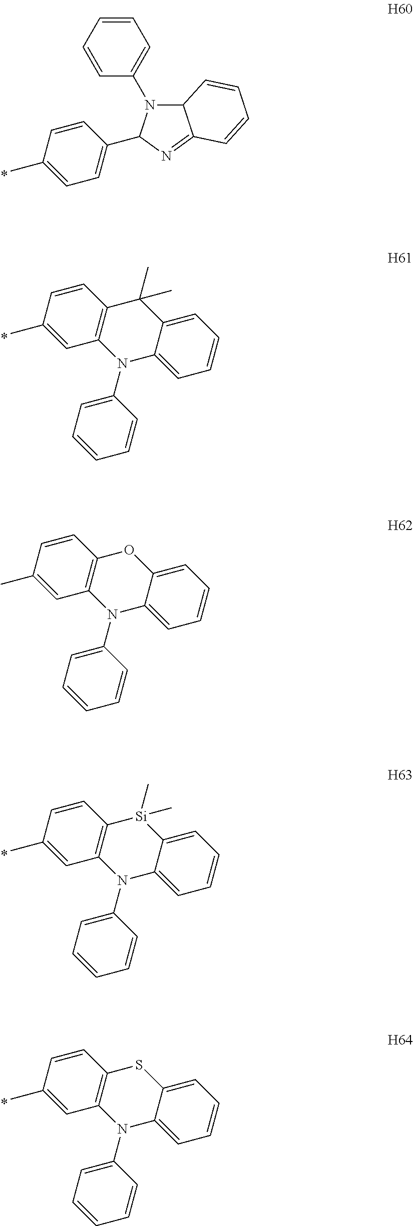 [SMILES: Cc1ccc(C2N=C3C=CC=CC3N2c2ccccc2)cc1 ; Cc1ccc2c(c1)N(c1ccccc1)c1ccccc1C2(C)C ; Cc1ccc2c(c1)N(c1ccccc1)c1ccccc1O2 ; Cc1ccc2c(c1)N(c1ccccc1)c1ccccc1[Si]2(C)C ; Cc1ccc2c(c1)N(c1ccccc1)c1ccccc1S2]

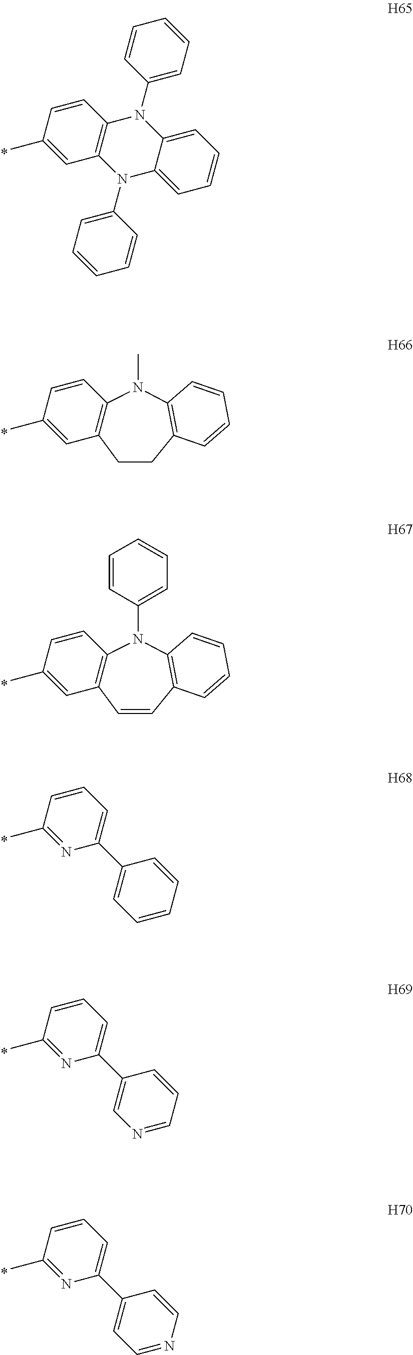 [SMILES: Cc1ccc2c(c1)N(c1ccccc1)c1ccccc1N2c1ccccc1 ; Cc1ccc2c(c1)CCc1ccccc1N2C ; Cc1ccc2c(c1)C=Cc1ccccc1N2c1ccccc1 ; Cc1cccc(-c2ccccc2)n1 ; Cc1cccc(-c2cccnc2)n1 ; Cc1cccc(-c2ccncc2)n1]

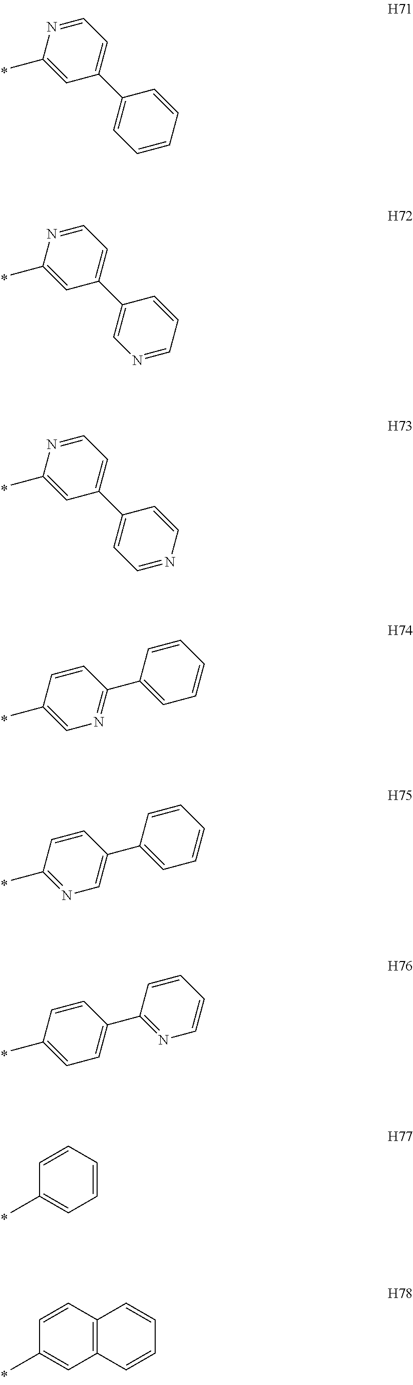

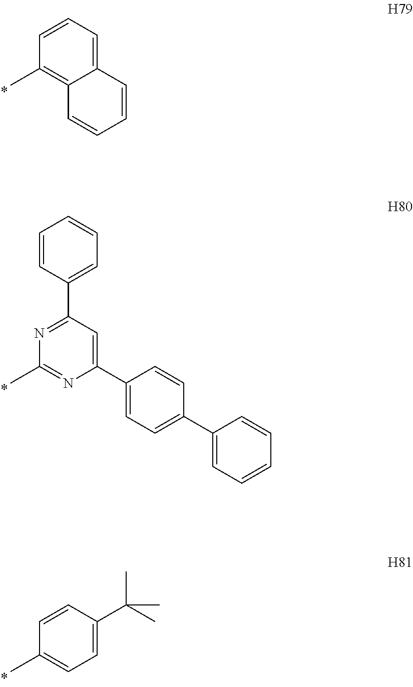 [SMILES: Cc1cccc2ccccc12 ; Cc1nc(-c2ccccc2)cc(-c2ccc(-c3ccccc3)cc2)n1 ; Cc1ccc(C(C)(C)C)cc1]

In Formulae H1 to H81, * is a binding site to a neighboring atom.

In Formulae 1A, 1B, 1C, 1D, 1E, and 2, L₁₁, L₁₂, and L₂₁ may be each independently selected from a C₃-C₁₀ cycloalkylene group, a C₃-C₁₀ heterocycloalkylene group, a C₃-C₁₀ cycloalkenylene group, a C₃-C₁₀ heterocycloalkenylene group, a C₆-C₆₀ arylene group, a C₂-C₆₀ heteroarylene group, a divalent non-aromatic condensed polycyclic group, and a divalent non-aromatic hetero-condensed polycyclic group; and

a C₃-C₁₀ cycloalkylene group, a C₃-C₁₀ heterocycloalkylene group, a C₃-C₁₀ cycloalkenylene group, a C₃-C₁₀ heterocycloalkenylene group, a C₆-C₆₀ arylene group, a C₂-C₆₀ heteroarylene group, a divalent non-aromatic condensed polycyclic group, and a divalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group.

For example, in Formulae 1A, 1B, 1C, 1D, 1E, and 2, L₁₁, L₁₂, and L₂₁ may be each independently selected from a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thienylene group, a furanylene group, a silolylene group, an imidazolylene group, a pyrazolylene group, a thiazolylene group, an isothiazolylene group, an oxazolylene group, an isooxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothienylene group, a benzosilolylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, and a dibenzosilolylene(dibenzosilolylene); and

a phenylene group, a pentalenylene, an indenylene, a naphthylene group, an azulenylene, a heptalenylene, an indacenylene, an acenaphthylene group, a fluorenylene group, a spiro-fluorenylene group, a benzofluorenylene group, a dibenzofluorenylene group, a phenalenylene, a phenanthrenylene group, an anthracenylene group, a fluoranthenylene, a triphenylenylene, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thienylene group, a furanylene group, a silolylene group, an imidazolylene group, a pyrazolylene group, a thiazolylene group, an isothiazolylene group, an oxazolylene group, an isooxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothienylene group, a benzosilolylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, and a dibenzosilolylene group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thienyl group, a furanyl group, a silolyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothienyl group, a benzosilolyl group, an isobenzothiazolyl group, a benzooxazolyl group, an isobenzooxazolyl group, a triazolyl group, tetrazole group, an oxadiazolyl group, a triazinyl group, a dibenzofuranyl group, a dibenzothienyl group, a benzocarbazolyl group, a dibenzocarbazolyl group, and a dibenzosilolyl group.

In another embodiment, in Formulae 1A, 1B, 1C, 1D, 1E, and 2, L₁₁, L₁₂, and L₂₁ may be each independently a group selected from groups represented by Formulae 3-1 to 3-30, but they are not limited thereto.

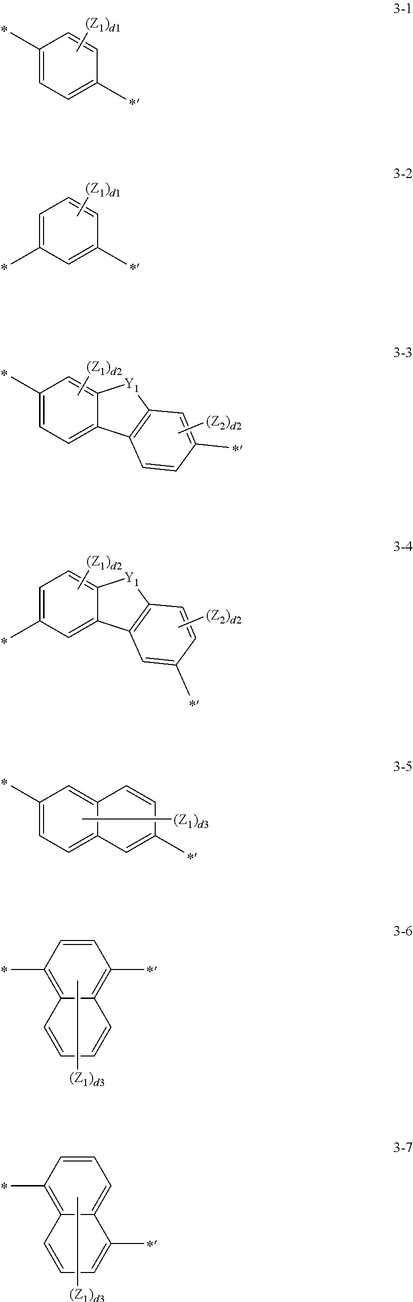

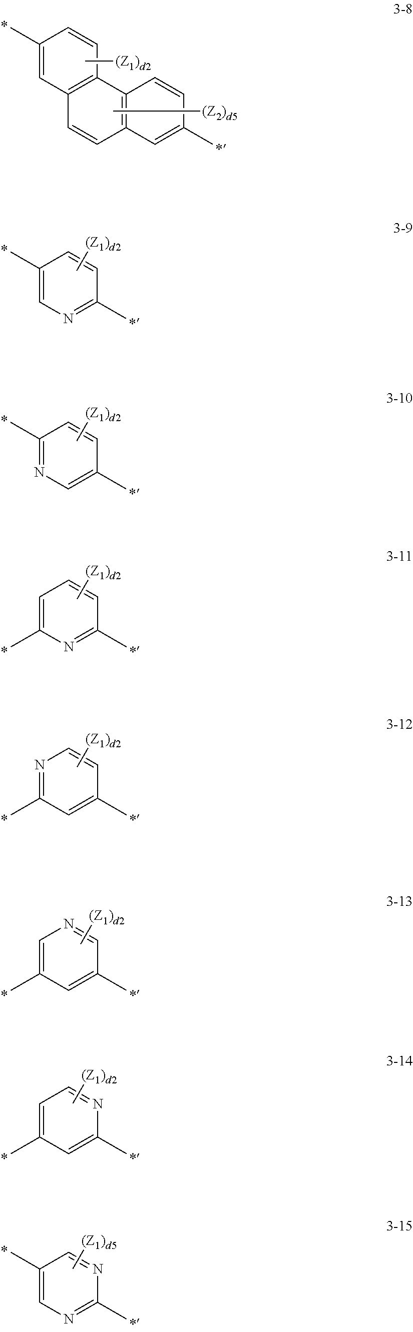

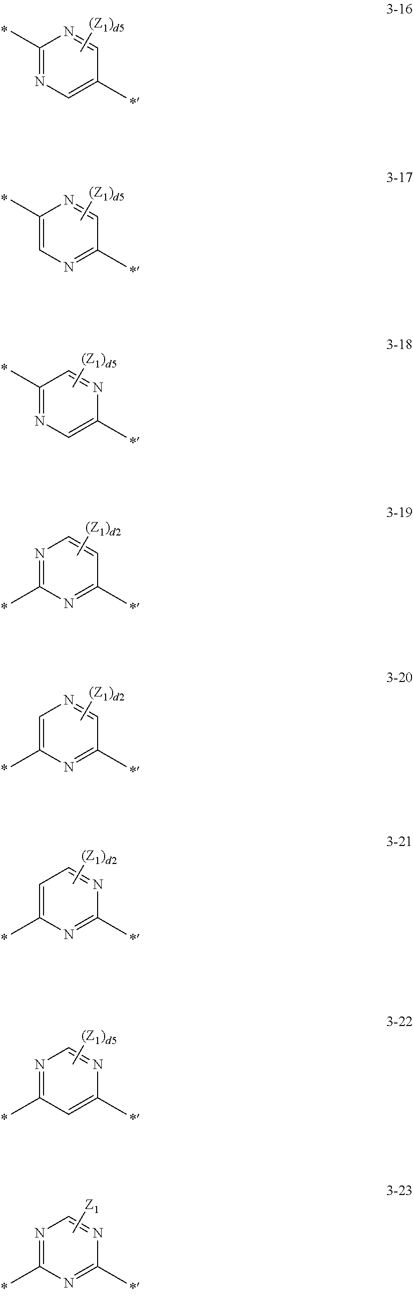

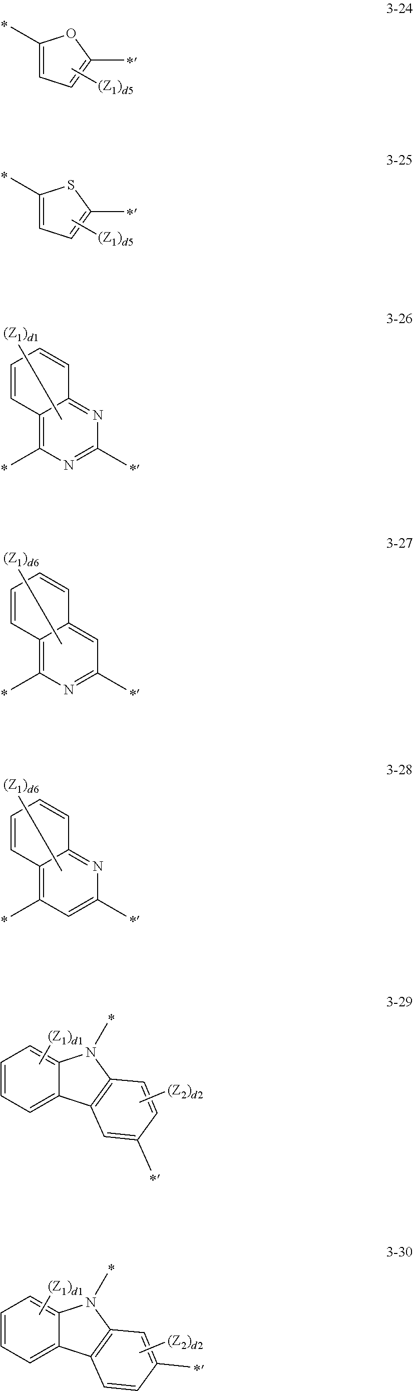

In Formulae 3-1 to 3-30,

Y₁ may be O, S, C(Z₃)(Z₄), N(Z₅), or Si(Z₆)(Z₇);

Z₁ to Z₇ may be each independently selected from hydrogen, deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,

d1 may be an integer of 1 to 4;

d2 may be an integer of 1 to 3;

d3 may be an integer of 1 to 6;

d4 may be an integer of 1 to 8;

d5 may be 1 or 2; and

d6 may be an integer of 1 to 5. * and *′ may be binding sites to neighboring atoms.

In another embodiment, in Formulae 1A, 1B, 1C, 1D, 1E, and 2, L₁₁, L₁₂, and L₂₁ may be each independently selected from groups represented by Formulae 4-1 to 4-21, but they are not limited thereto.

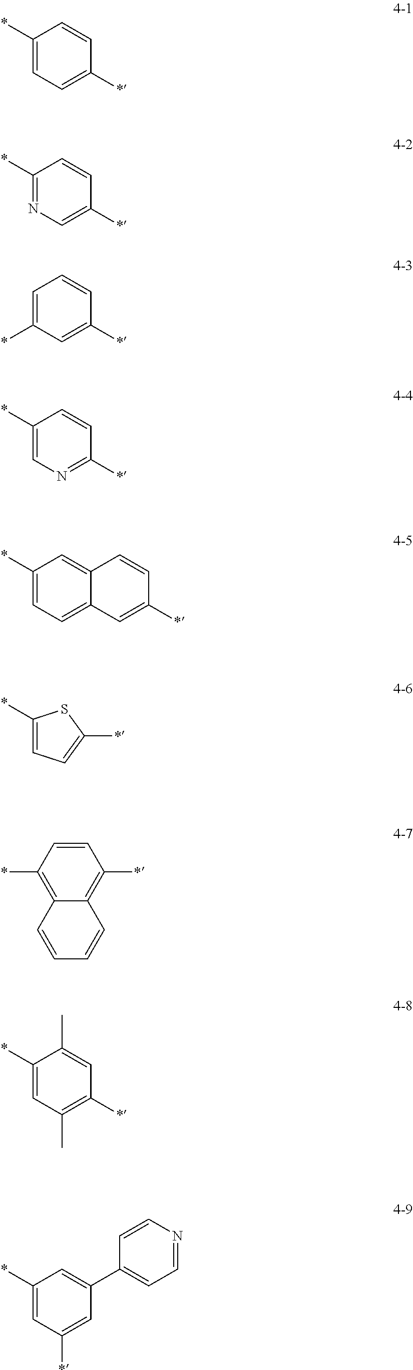

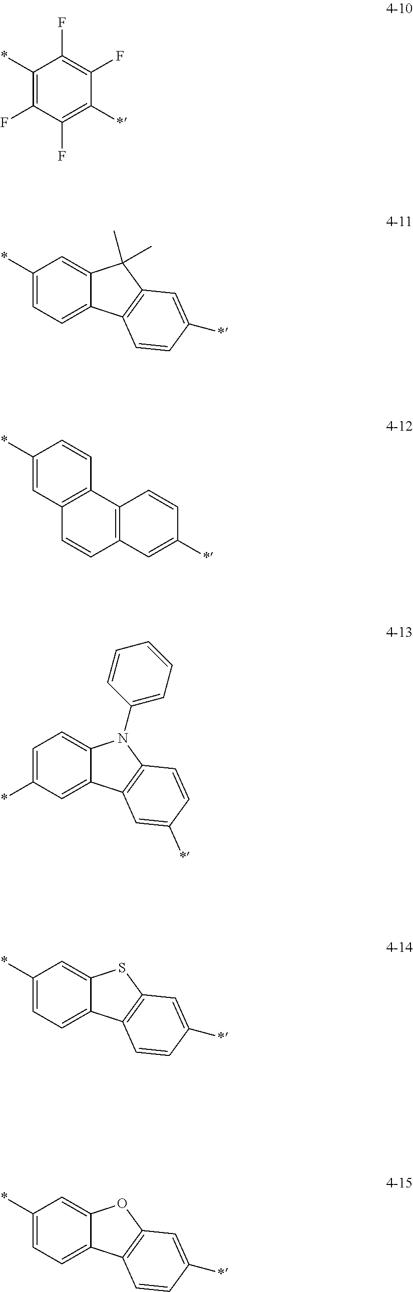

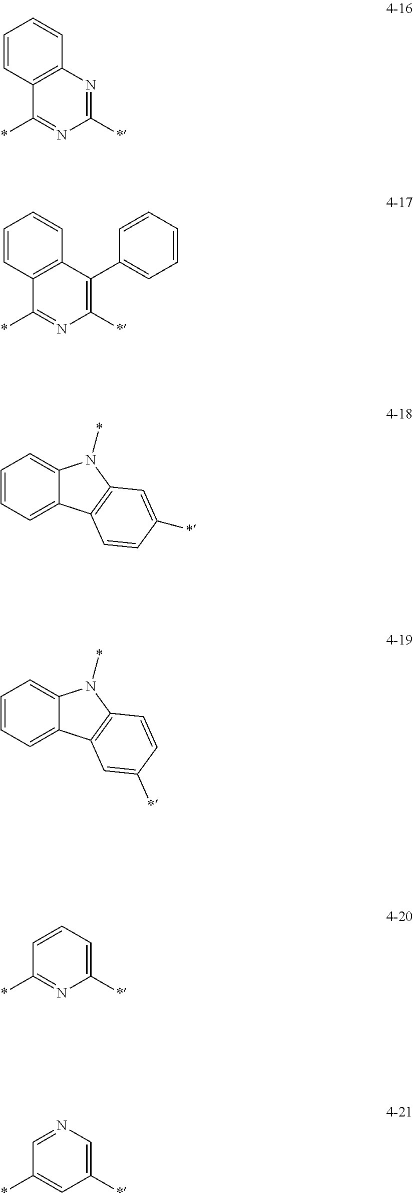

In Formulae 4-1 to 4-21, * and *′ may be binding sites to neighboring atoms.

In Formulae 1A, 1B, 1C, 1D, and 1E, a11 represents the number of L₁₁s and may be selected from 0, 1, 2, 3, 4, and 5. For example, a11 in Formulae 1A, 1B, 1C, 1D, and 1E may be 0 or 1, but it is not limited thereto. When a11 is an integer of 2 or greater, a plurality of L₁₁s may be the same or different. When a11 is 0, (L₁₁)ₐ₁₁ represents a direct bonding.

In Formulae 1A, 1B, 1C, 1D, and 1E, a12 represents the number of L₁₂s and may be selected from 0, 1, 2, 3, 4, and 5. For example, in Formulae 1A, 1B, 1C, 1D, and 1E, a12 may be 0 or 1, but it is not limited thereto. When a12 is an integer of 2 or greater, a plurality of L₁₂s may be the same or different. When a12 is 0, (L₁₁)ₐ₁₁ represents a direct bonding.

In Formula 2, a21 represents the number of L₂₁s, the L₂₁ may be selected from 0, 1, 2, 3, 4, and 5. For example, in Formula 2, a21 may be 1, but it is not limited thereto. When a21 is an integer of 2 or greater, a plurality of L₂₁s may be the same or different. When a21 is 0, (L₂₁)ₐ₂₁ represents a direct bonding.

In Formula 2, R₂₁ may be selected from a substituted or unsubstituted C₃-C₁₀ cycloalkyl group, a substituted or unsubstituted C₃-C₁₀ heterocycloalkyl group, a substituted or unsubstituted C₃-C₁₀ cycloalkenyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, and a substituted or unsubstituted monovalent non-aromatic hetero-condensed polycyclic group;

at least one substituent of the substituted C₃-C₁₀ cycloalkyl group, the substituted C₃-C₁₀ heterocycloalkyl group, the substituted C₃-C₁₀ cycloalkenyl group, the substituted C₃-C₁₀ heterocycloalkenyl group, the substituted C₆-C₆₀ aryl group, the substituted C₂-C₆₀ heteroaryl group, the substituted monovalent non-aromatic condensed polycyclic group, and the substituted monovalent non-aromatic hetero-condensed polycyclic group may be selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₁₁)(Q₁₂), —Si(Q₁₃)(Q₁₄)(Q₁₅), and —B(Q₁₆)(Q₁₇);

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇);

Q₁₁ to Q₁₇, Q₂₁ to Q₂₇ and Q₃₁ to Q₃₇ may be each independently selected from hydrogen, deuterium, a C₁-C₆₀ alkyl group, a C₆-C₆₀ aryl group, a C₂-C₆₀ heteroaryl group, a monovalent non-aromatic condensed polycyclic group, and a monovalent non-aromatic hetero-condensed polycyclic group.

In an implementation, in Formula 2, R₂₁ may exclude, e.g., may not be or may not include, a substituted or unsubstituted electron transporting-cyclic group including at least one N as a ring-forming atom, but it is not limited thereto.

For example, in Formula 2, R₂₁ may be selected from a phenyl group, a naphthyl group, a fluorenyl group, a spiro-fluorenyl group, a phenanthrenyl group, an anthracenyl group, a fluoranthenyl group, a triphenylenyl group, a pyrenyl group, a chrysenyl group, a carbazolyl group, a furanyl group, a thienyl group, a thianthrenyl group, a phnoxathiinyl group, and an oxanthrenyl group; and

a phenyl group, a naphthyl group, a fluorenyl group, a spiro-fluorenyl group, a phenanthrenyl group, an anthracenyl group, a fluoranthenyl group, a triphenylenyl group, a pyrenyl group, a chrysenyl group, a carbazolyl group, a furanyl, a thienyl, a thianthrenyl group, a phnoxathiinyl group, and an oxanthrenyl group, each substituted with at least one selected from deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, phosphoric acid or a salt thereof, a C₁-C₂₀ alkyl group, a C₁-C₂₀ alkoxy group, a phenyl group, a naphthyl group, a fluorenyl group, a spiro-fluorenyl group, a phenanthrenyl group, an anthracenyl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinylene group, a carbazolyl group, a triazinyl group, and —Si(Q₃₃)(Q₃₄)(Q₃₅);

Q₃₃ to Q₃₅ may be each independently selected from a C₁-C₂₀ alkyl group, a phenyl group, and a naphthyl group, but they are not limited thereto.

In another embodiment, in Formula 2, R₂₁ may be selected from groups represented by Formulae 13-1 to 13-13 below, but it is not limited thereto.

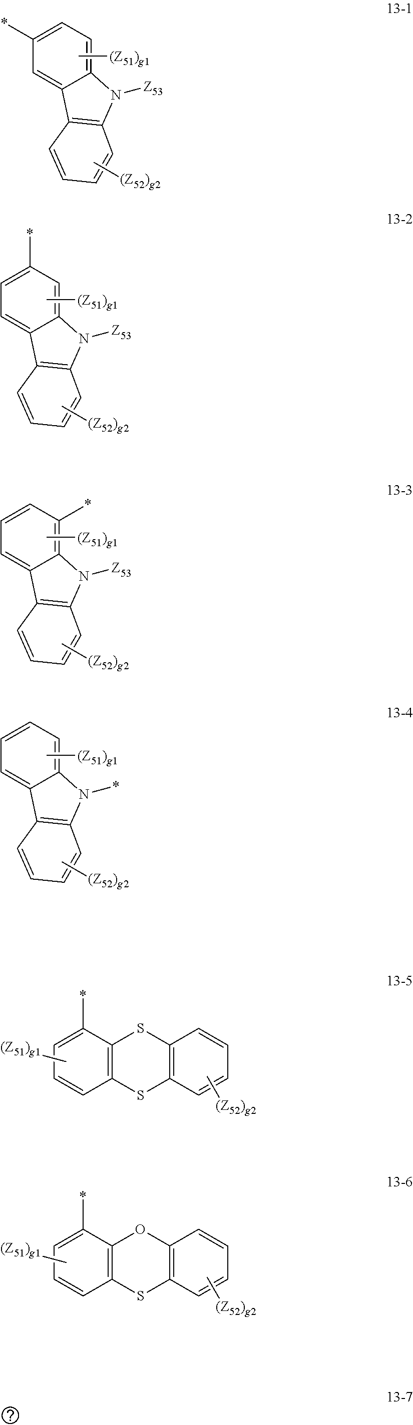

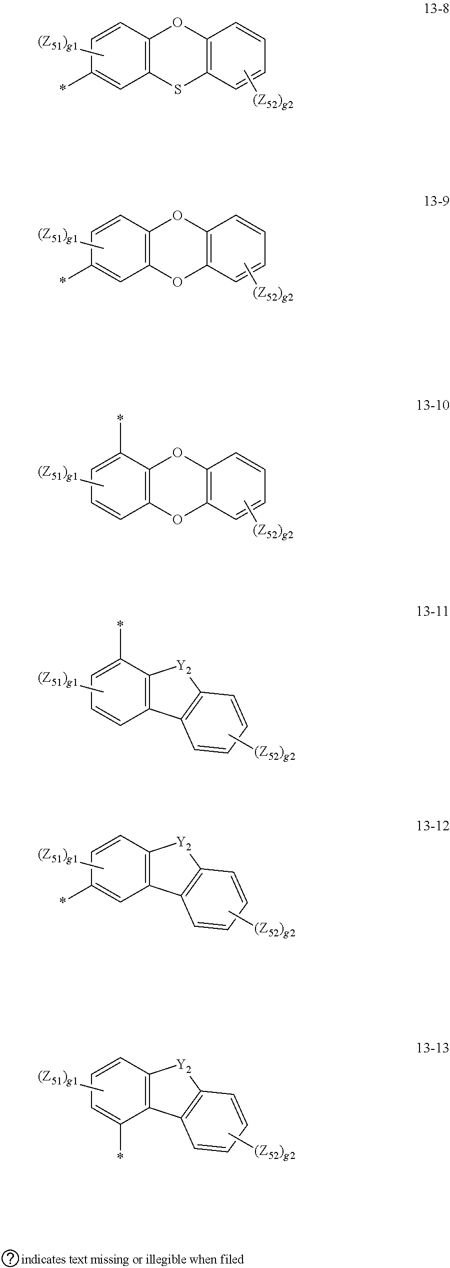

In Formulae 13-1 to 13-13,

Y₂ may be an oxygen atom or a sulfur atom;

Z₅₁ to Z₅₃ may be each independently selected from hydrogen, deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, and phosphoric acid or a salt thereof, a C₁-C₂₀ alkyl group, a C₂-C₂₀ alkenyl group, a C₂-C₂₀ alkynyl group, a C₁-C₂₀ alkoxy group, a phenyl group, a naphthyl group, an anthryl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a quinoxalinyl group, a quinazolinyl group, a cinnolinyl group, a quinazolinyl group, and —Si(Q₃₃)(Q₃₄)(Q₃₅);

Q₃₃ to Q₃₅ may be each independently selected from a C₁-C₂₀ alkyl group, a phenyl group, and a naphthyl group;

g1 may be an integer from 1 to 3; and

g2 may be an integer from 1 to 4. * may be a binding site to a neighboring atom.

In another embodiment, in Formula 2, R₂₁ may be selected from groups represented by Formulae 14-1 to 14-13, but it is not limited thereto.

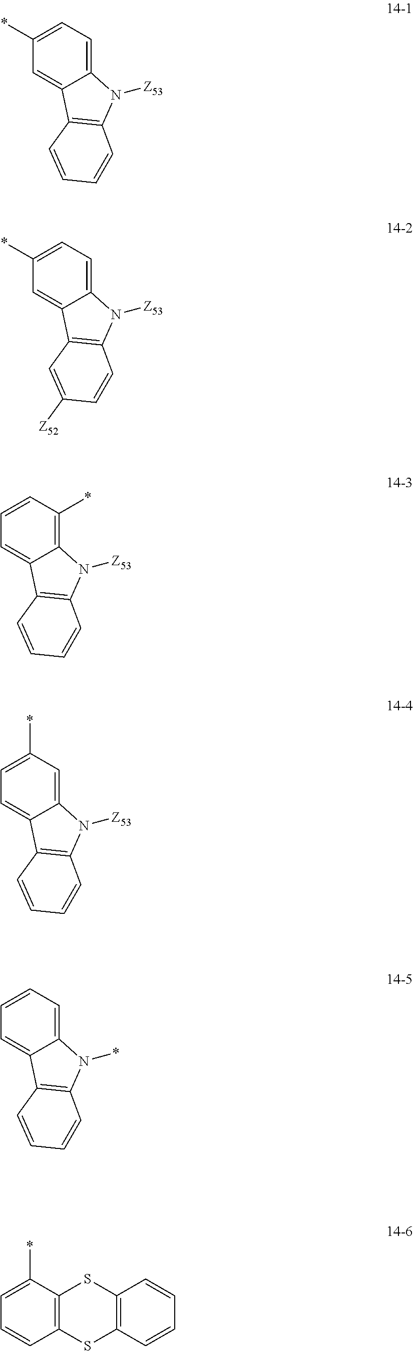

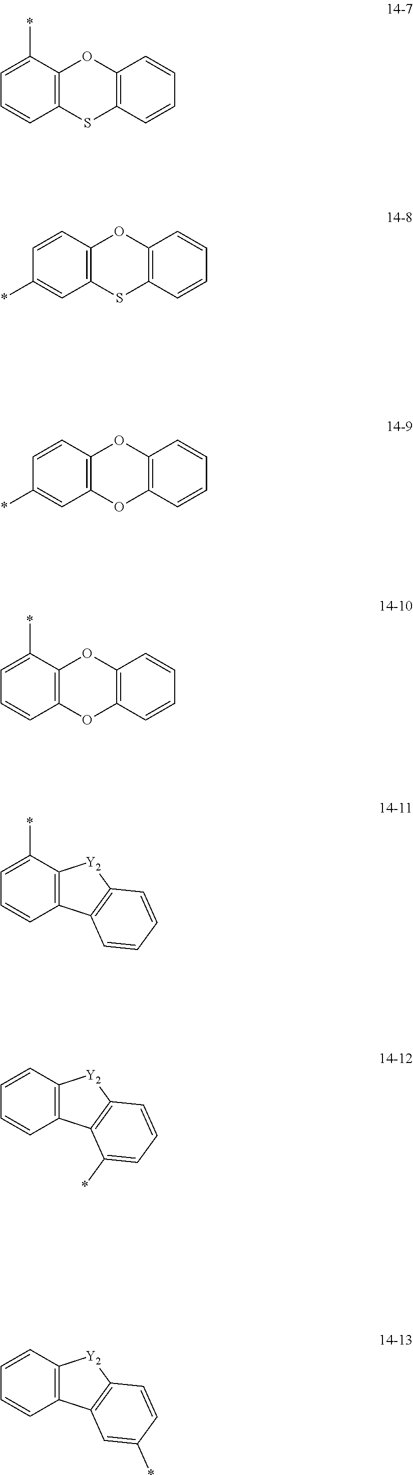

In Formulae 14-1 to 14-13,

Y₂ may be a oxygen atom or a sulfur atom;

Z₅₃ may be selected from hydrogen, deuterium, —F, —Cl, —Br, —I, a cyano group, a nitro group, a phenyl group, a naphthyl group, an anthryl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a quinoxalinyl group, a quinazolinyl group, a cinnolinyl group, a quinazolinyl group, and —Si(Q₃₃)(Q₃₄)(Q₃₅); and

Q₃₃ to Q₃₅ may be each independently selected from a C₁-C₂₀ alkyl group, a phenyl group, and a naphthyl group. * may be a binding site to a neighboring atom

In Formula 2, R₂₂ to R₂₄ may be each independently selected from hydrogen, deuterium, a C₁-C₆₀ alkyl group, a C₆-C₆₀ aryl group, a C₂-C₆₀ heteroaryl group, a monovalent non-aromatic condensed polycyclic group, and a monovalent non-aromatic hetero-condensed polycyclic group.

For example, in Formula 2, R₂₂ to R₂₄ may be hydrogen, but they are not limited thereto.

In Formula 2, b22 represents the number of R₂₂s, and may be selected from 1, 2, and 3.

In Formula 2, b23 represents the number of R₂₃s, and may be selected from 1, 2, 3, and 4.

In Formula 2, b24 represents the number of R₂₄s, and may be selected from 1, 2, 3, and 4.

In an embodiment, the triphenylene-based compound represented by Formula 2 may be selected from Formulae 2A and 2B, but they are not limited thereto.

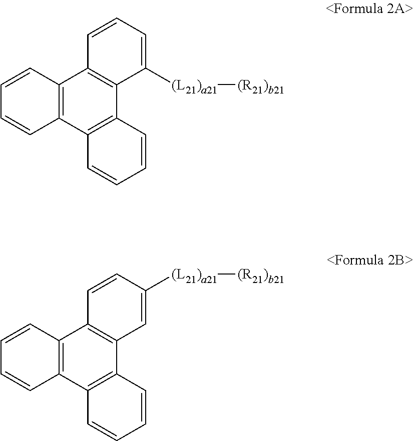

In Formulae 2A and 2B,

L₂₁, a21, R₂₁, and b21 are as described above, e.g., with respect to Formula 2.

In an implementation, the heterocyclic compound (e.g., represented by one of Formulae 1A to 1E) may be selected from Compounds 100 to 238. In an implementation, the triphenylene-based compound (e.g., represented by Formula 2) may be selected from Compounds 201A to 242A, but they are not limited thereto.

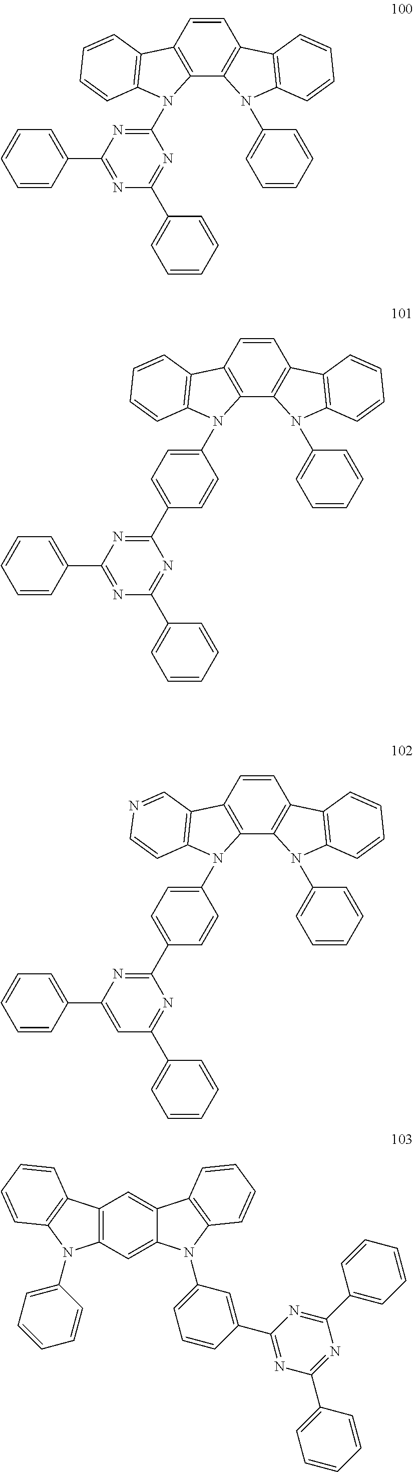 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-c3ccc(-n4c5ccccc5c5ccc6c7ccccc7n(-c7ccccc7)c6c54)cc3)n2)cc1 ; c1ccc(-c2cc(-c3ccccc3)nc(-c3ccc(-n4c5ccncc5c5ccc6c7ccccc7n(-c7ccccc7)c6c54)cc3)n2)cc1 ; c1ccc(-c2nc(-c3ccccc3)nc(-c3cccc(-n4c5ccccc5c5cc6c7ccccc7n(-c7ccccc7)c6cc54)c3)n2)cc1]

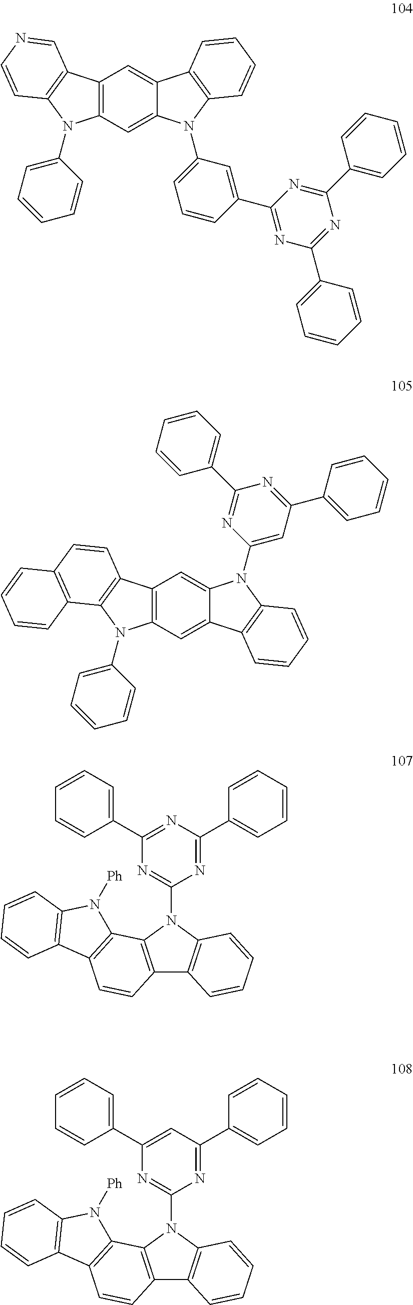

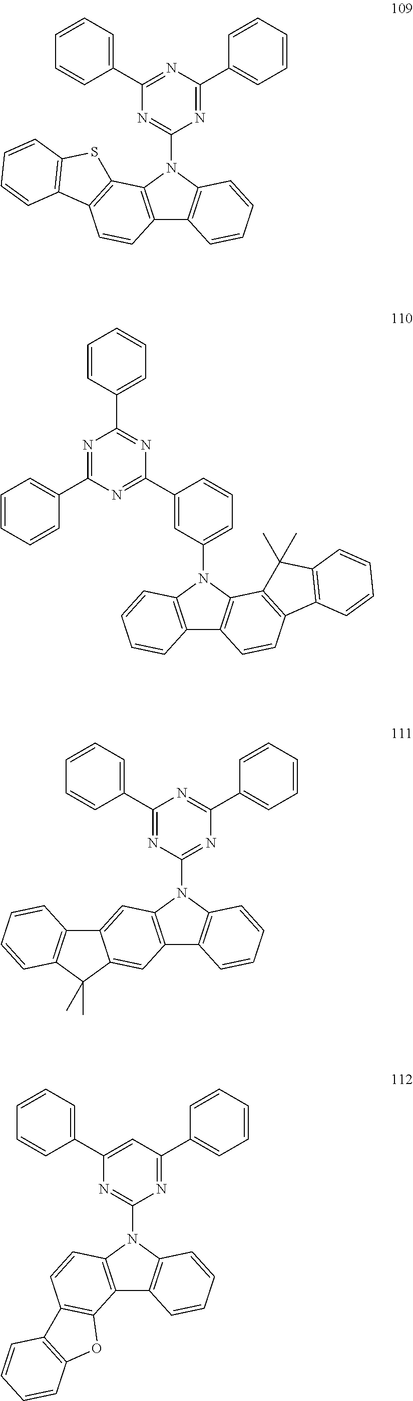 [SMILES: c1ccc(-c2nc(-c3ccccc3)nc(-n3c4ccccc4c4ccc5c6ccccc6sc5c43)n2)cc1 ; CC1(C)c2ccccc2-c2ccc3c4ccccc4n(-c4cccc(-c5nc(-c6ccccc6)nc(-c6ccccc6)n5)c4)c3c21 ; CC1(C)c2ccccc2-c2cc3c(cc21)c1ccccc1n3-c1nc(-c2ccccc2)nc(-c2ccccc2)n1 ; c1ccc(-c2cc(-c3ccccc3)nc(-n3c4ccccc4c4c5oc6ccccc6c5ccc43)n2)cc1]

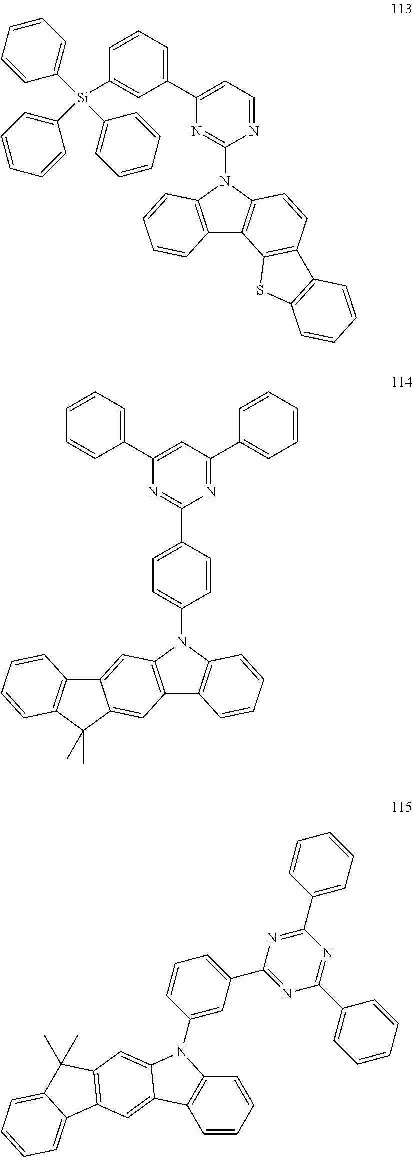 [SMILES: c1ccc([Si](c2ccccc2)(c2ccccc2)c2cccc(-c3ccnc(-n4c5ccccc5c5c6sc7ccccc7c6ccc54)n3)c2)cc1 ; CC1(C)c2ccccc2-c2cc3c(cc21)c1ccccc1n3-c1ccc(-c2nc(-c3ccccc3)cc(-c3ccccc3)n2)cc1 ; CC1(C)c2ccccc2-c2cc3c4ccccc4n(-c4cccc(-c5nc(-c6ccccc6)nc(-c6ccccc6)n5)c4)c3cc21]

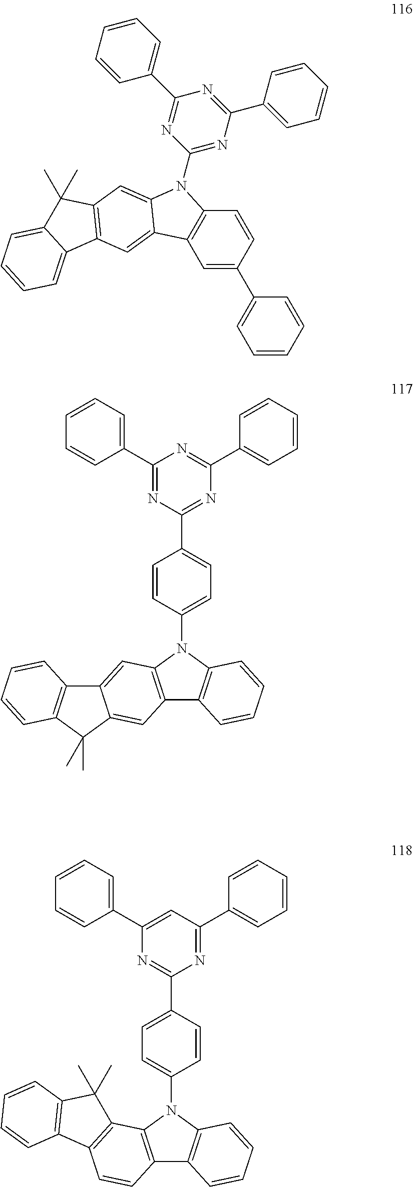

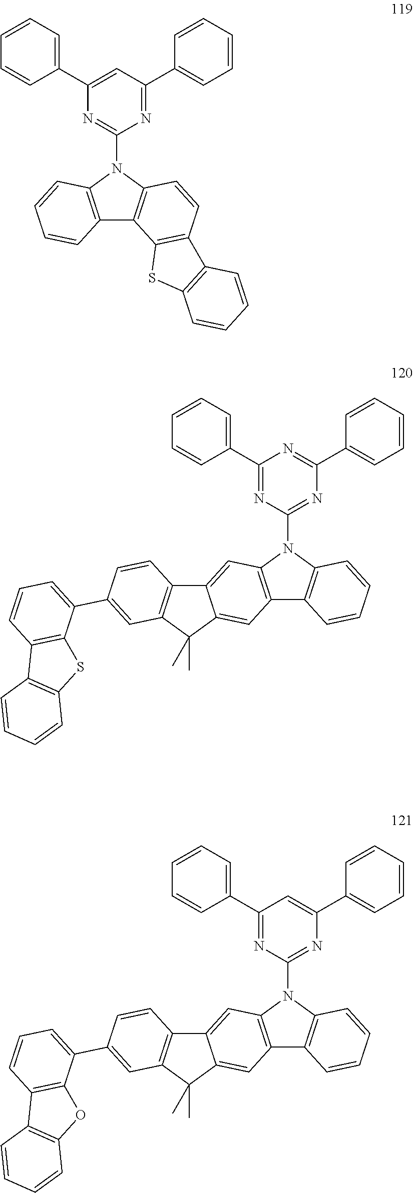 [SMILES: c1ccc(-c2cc(-c3ccccc3)nc(-n3c4ccccc4c4c5sc6ccccc6c5ccc43)n2)cc1 ; CC1(C)c2cc(-c3cccc4c3sc3ccccc34)ccc2-c2cc3c(cc21)c1ccccc1n3-c1nc(-c2ccccc2)nc(-c2ccccc2)n1 ; CC1(C)c2cc(-c3cccc4c3oc3ccccc34)ccc2-c2cc3c(cc21)c1ccccc1n3-c1nc(-c2ccccc2)cc(-c2ccccc2)n1]

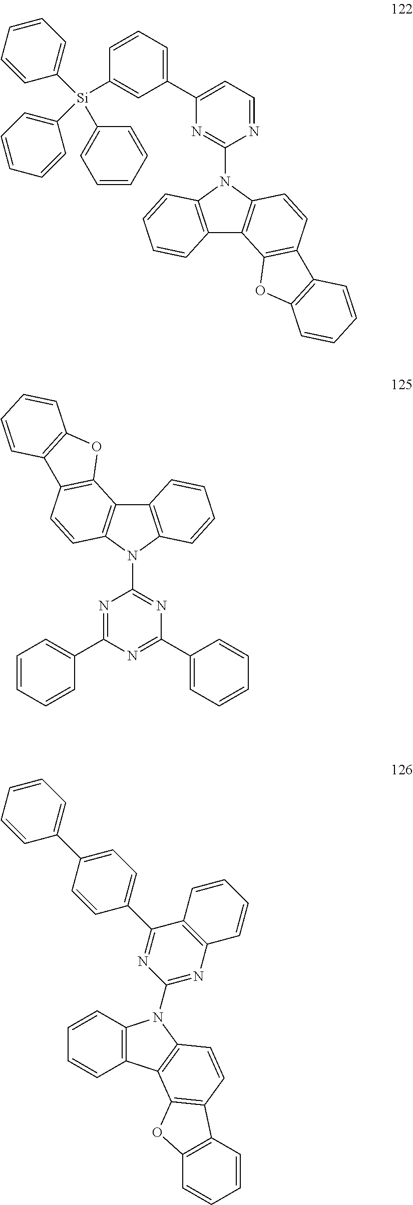 [SMILES: c1ccc([Si](c2ccccc2)(c2ccccc2)c2cccc(-c3ccnc(-n4c5ccccc5c5c6oc7ccccc7c6ccc54)n3)c2)cc1 ; c1ccc(-c2nc(-c3ccccc3)nc(-n3c4ccccc4c4c5oc6ccccc6c5ccc43)n2)cc1 ; c1ccc(-c2ccc(-c3nc(-n4c5ccccc5c5c6oc7ccccc7c6ccc54)nc4ccccc34)cc2)cc1]

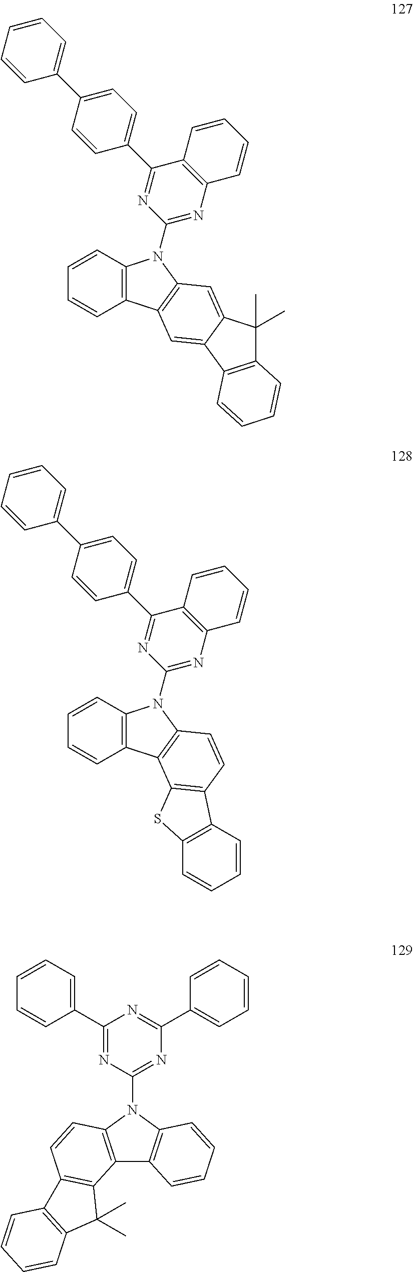 [SMILES: CC1(C)c2ccccc2-c2cc3c4ccccc4n(-c4nc(-c5ccc(-c6ccccc6)cc5)c5ccccc5n4)c3cc21 ; c1ccc(-c2ccc(-c3nc(-n4c5ccccc5c5c6sc7ccccc7c6ccc54)nc4ccccc34)cc2)cc1 ; CC1(C)c2ccccc2-c2ccc3c(c21)c1ccccc1n3-c1nc(-c2ccccc2)nc(-c2ccccc2)n1]

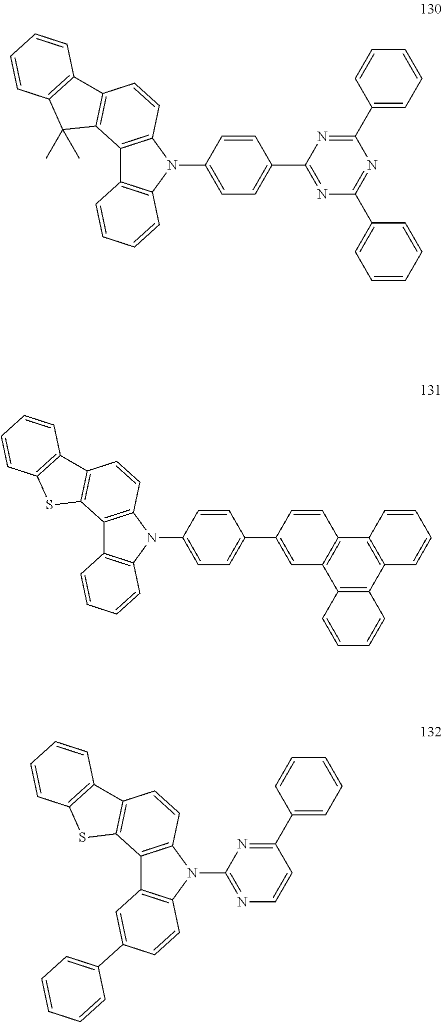 [SMILES: CC1(C)c2ccccc2-c2ccc3c(c21)c1ccccc1n3-c1ccc(-c2nc(-c3ccccc3)nc(-c3ccccc3)n2)cc1 ; c1ccc2c(c1)sc1c2ccc2c1c1ccccc1n2-c1ccc(-c2ccc3c4ccccc4c4ccccc4c3c2)cc1 ; c1ccc(-c2ccc3c(c2)c2c4sc5ccccc5c4ccc2n3-c2nccc(-c3ccccc3)n2)cc1]

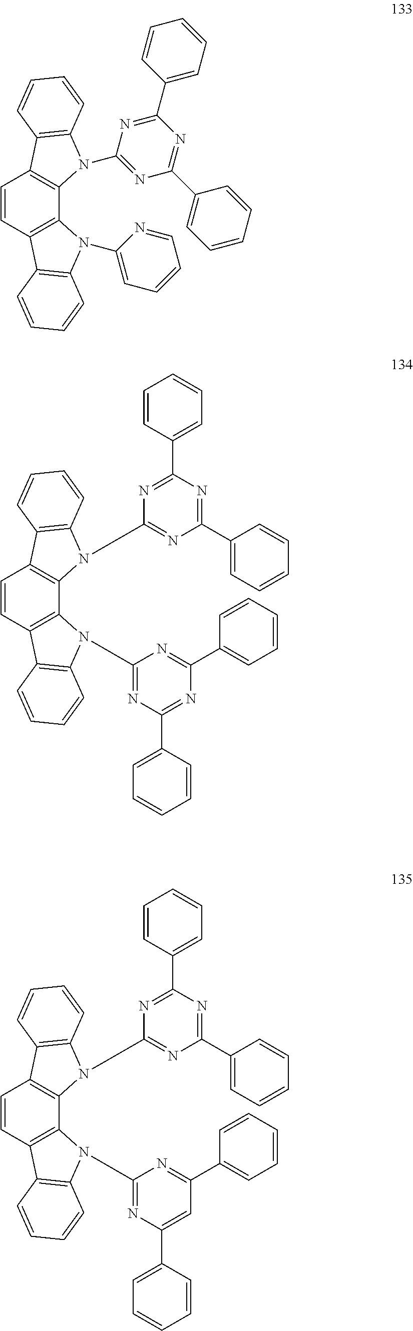 [SMILES: c1ccc(-c2nc(-c3ccccc3)nc(-n3c4ccccc4c4ccc5c6ccccc6n(-c6ccccn6)c5c43)n2)cc1 ; c1ccc(-c2nc(-c3ccccc3)nc(-n3c4ccccc4c4ccc5c6ccccc6n(-c6nc(-c7ccccc7)nc(-c7ccccc7)n6)c5c43)n2)cc1 ; c1ccc(-c2cc(-c3ccccc3)nc(-n3c4ccccc4c4ccc5c6ccccc6n(-c6nc(-c7ccccc7)nc(-c7ccccc7)n6)c5c43)n2)cc1]

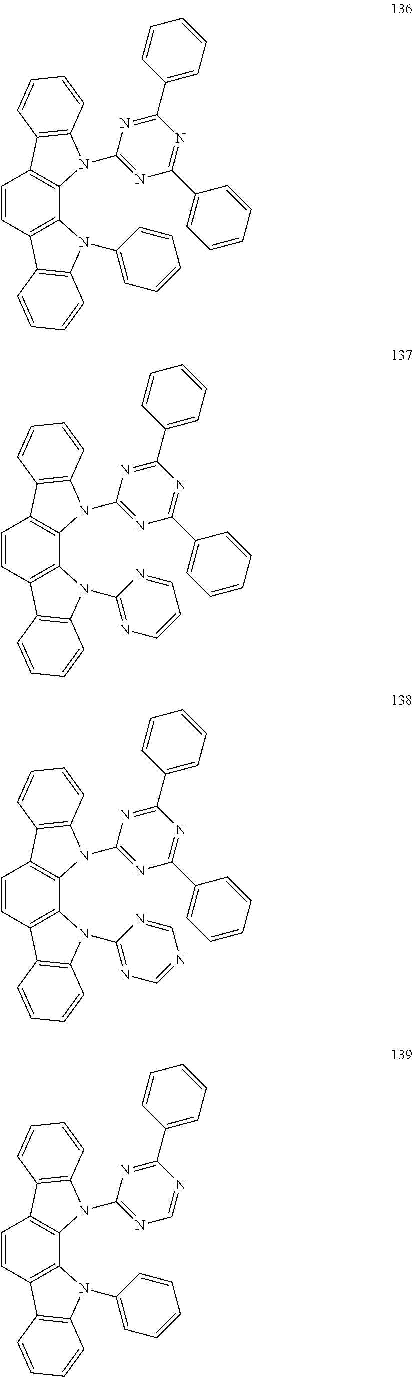 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6n(-c6ncccn6)c5c43)n2)cc1 ; c1ccc(-c2nc(-c3ccccc3)nc(-n3c4ccccc4c4ccc5c6ccccc6n(-c6ncncn6)c5c43)n2)cc1 ; c1ccc(-c2ncnc(-n3c4ccccc4c4ccc5c6ccccc6n(-c6ccccc6)c5c43)n2)cc1]

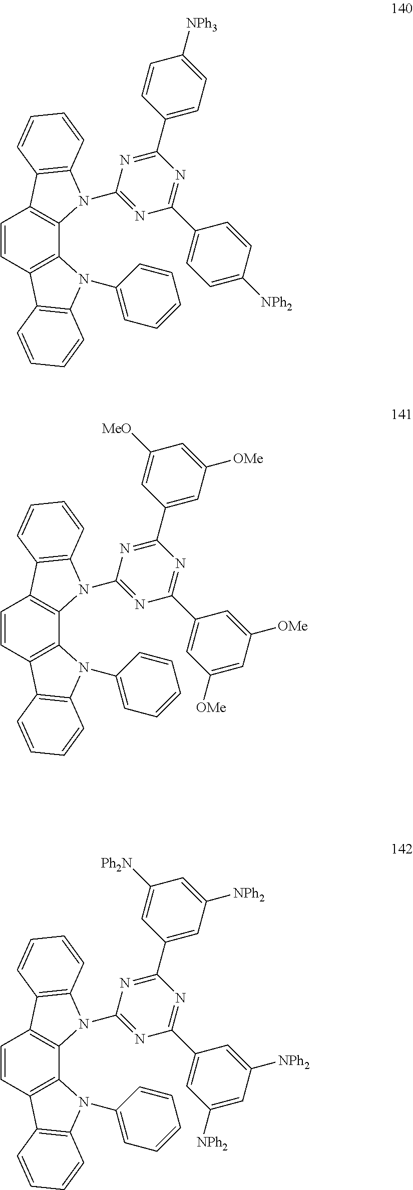

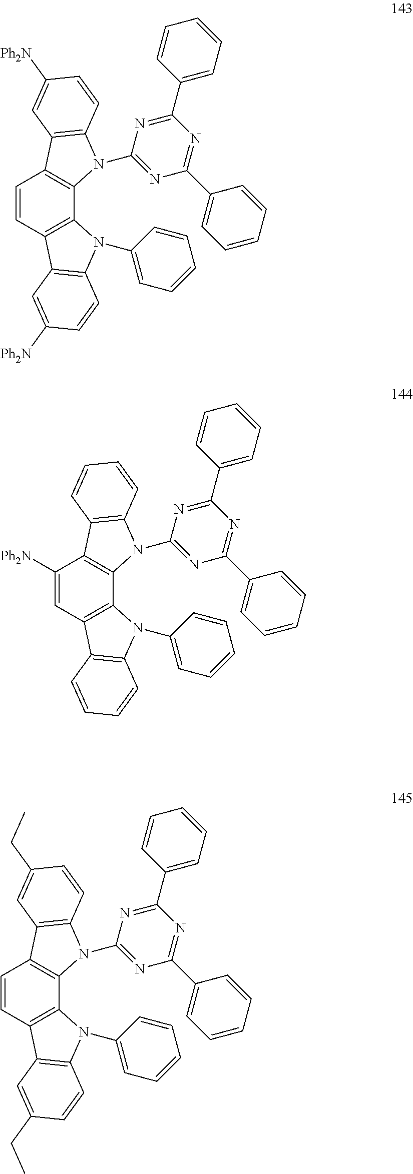

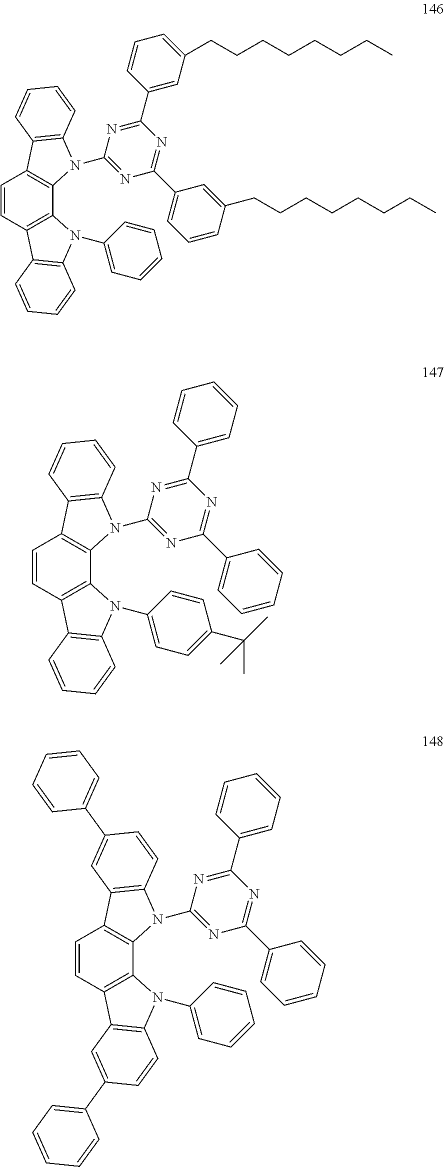 [SMILES: CCCCCCCCc1cccc(-c2nc(-c3cccc(CCCCCCCC)c3)nc(-n3c4ccccc4c4ccc5c6ccccc6n(-c6ccccc6)c5c43)n2)c1 ; CC(C)(C)c1ccc(-n2c3ccccc3c3ccc4c5ccccc5n(-c5nc(-c6ccccc6)nc(-c6ccccc6)n5)c4c32)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

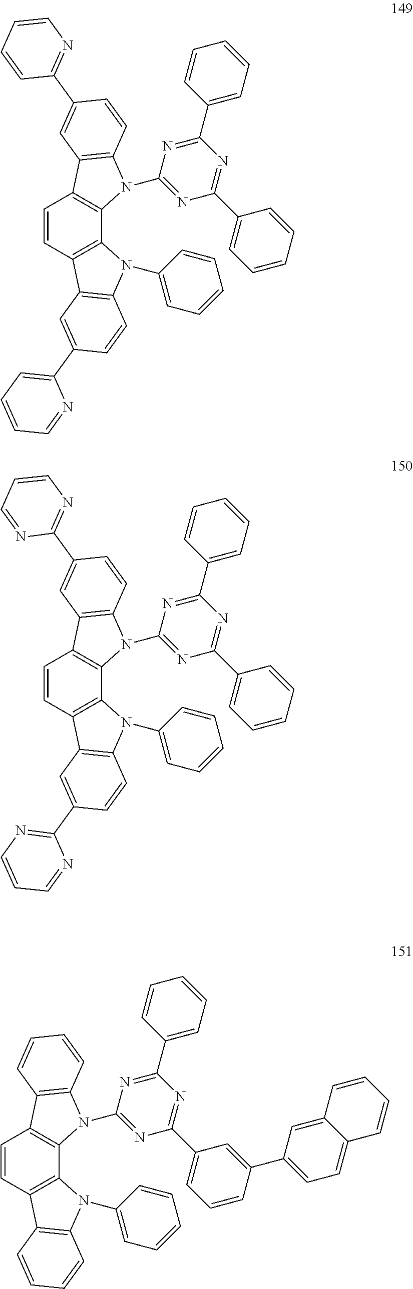

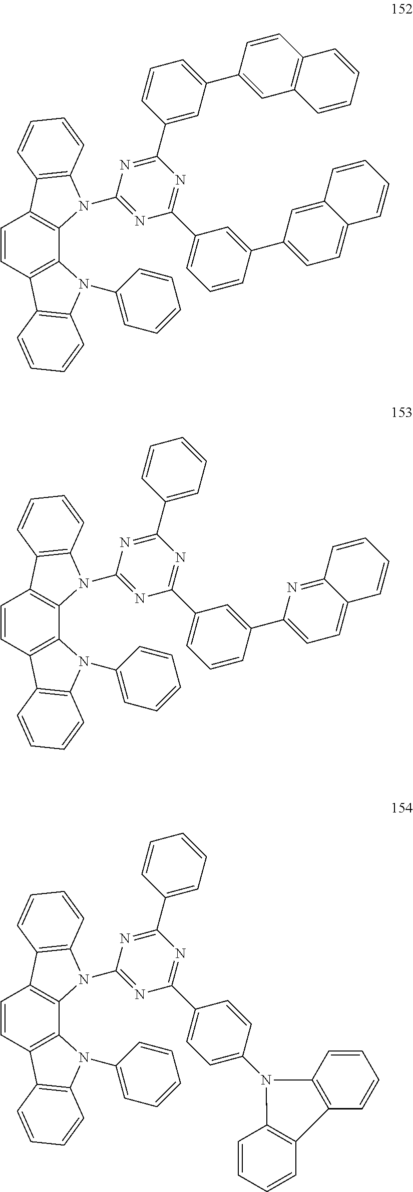 [SMILES: c1ccc(-n2c3ccccc3c3ccc4c5ccccc5n(-c5nc(-c6cccc(-c7ccc8ccccc8c7)c6)nc(-c6cccc(-c7ccc8ccccc8c7)c6)n5)c4c32)cc1 ; c1ccc(-c2nc(-c3cccc(-c4ccc5ccccc5n4)c3)nc(-n3c4ccccc4c4ccc5c6ccccc6n(-c6ccccc6)c5c43)n2)cc1 ; c1ccc(-c2nc(-c3ccc(-n4c5ccccc5c5ccccc54)cc3)nc(-n3c4ccccc4c4ccc5c6ccccc6n(-c6ccccc6)c5c43)n2)cc1]

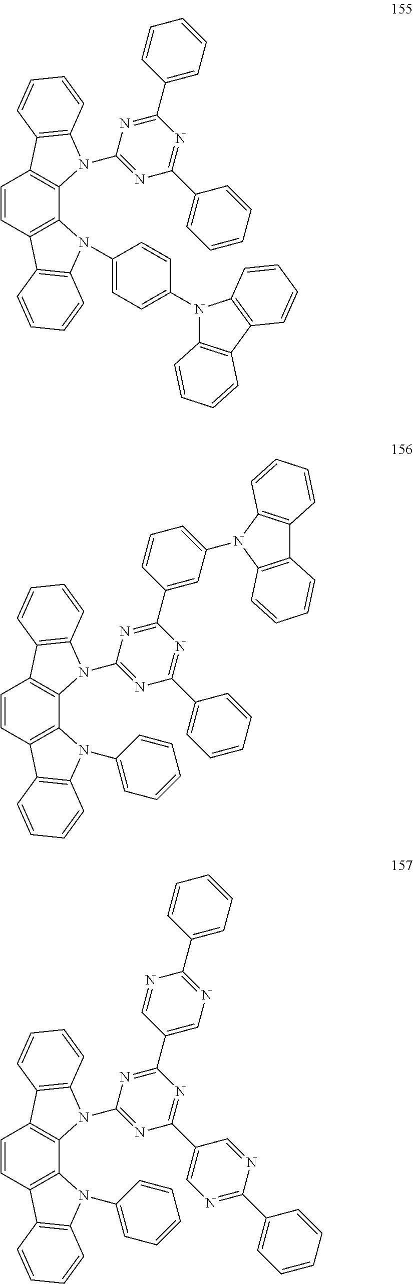 [SMILES: c1ccc(-c2nc(-c3ccccc3)nc(-n3c4ccccc4c4ccc5c6ccccc6n(-c6ccc(-n7c8ccccc8c8ccccc87)cc6)c5c43)n2)cc1 ; c1ccc(-c2nc(-c3cccc(-n4c5ccccc5c5ccccc54)c3)nc(-n3c4ccccc4c4ccc5c6ccccc6n(-c6ccccc6)c5c43)n2)cc1 ; c1ccc(-c2ncc(-c3nc(-c4cnc(-c5ccccc5)nc4)nc(-n4c5ccccc5c5ccc6c7ccccc7n(-c7ccccc7)c6c54)n3)cn2)cc1]

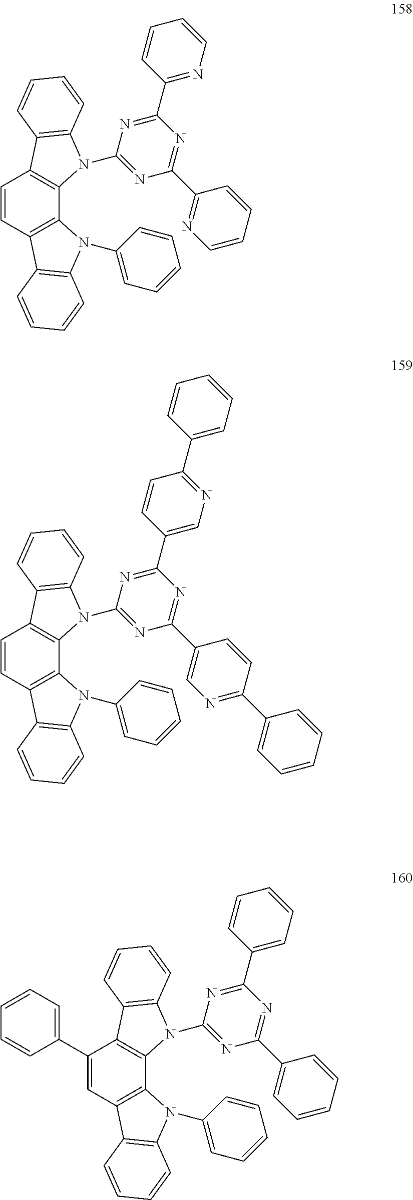 [SMILES: c1ccc(-n2c3ccccc3c3ccc4c5ccccc5n(-c5nc(-c6ccccn6)nc(-c6ccccn6)n5)c4c32)cc1 ; c1ccc(-c2ccc(-c3nc(-c4ccc(-c5ccccc5)nc4)nc(-n4c5ccccc5c5ccc6c7ccccc7n(-c7ccccc7)c6c54)n3)cn2)cc1 ; c1ccc(-c2nc(-c3ccccc3)nc(-n3c4ccccc4c4c(-c5ccccc5)cc5c6ccccc6n(-c6ccccc6)c5c43)n2)cc1]

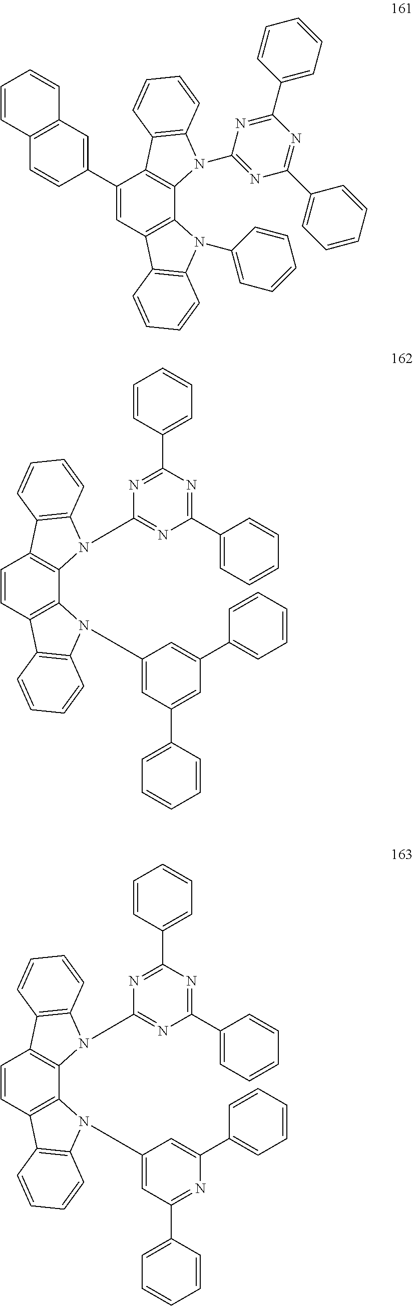

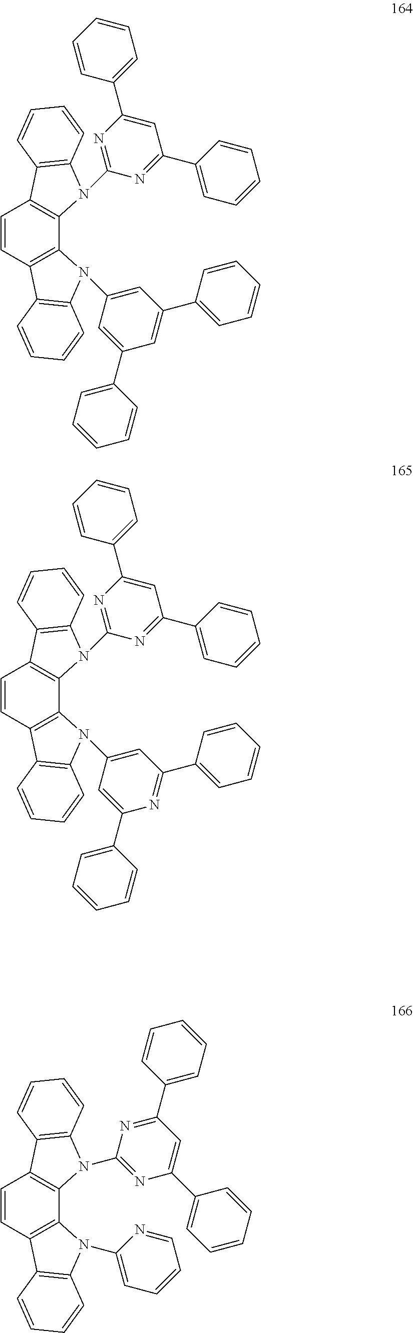

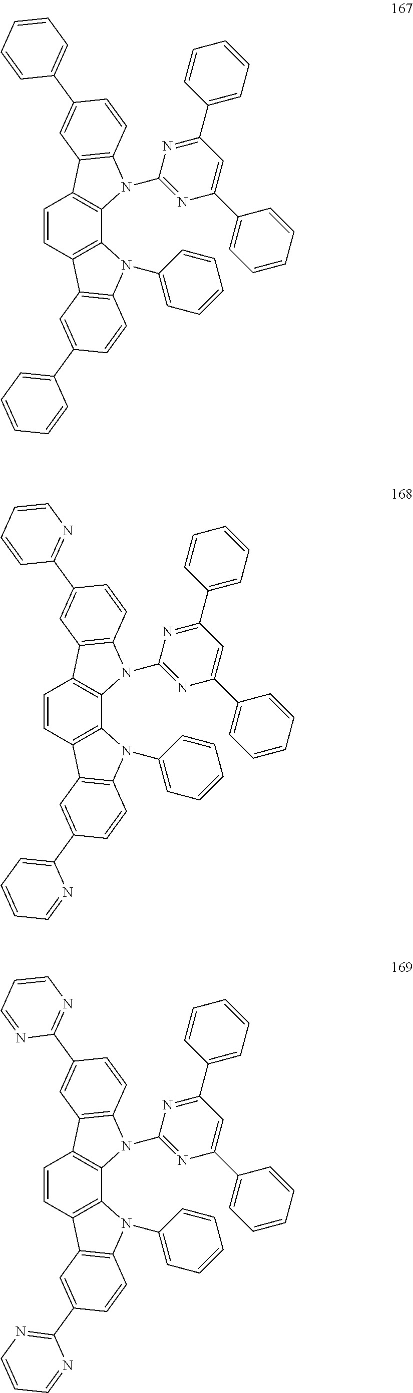 [SMILES: c1ccc(-c2ccc3c(c2)c2ccc4c5cc(-c6ccccc6)ccc5n(-c5nc(-c6ccccc6)cc(-c6ccccc6)n5)c4c2n3-c2ccccc2)cc1 ; c1ccc(-c2cc(-c3ccccc3)nc(-n3c4ccc(-c5ccccn5)cc4c4ccc5c6cc(-c7ccccn7)ccc6n(-c6ccccc6)c5c43)n2)cc1 ; c1ccc(-c2cc(-c3ccccc3)nc(-n3c4ccc(-c5ncccn5)cc4c4ccc5c6cc(-c7ncccn7)ccc6n(-c6ccccc6)c5c43)n2)cc1]

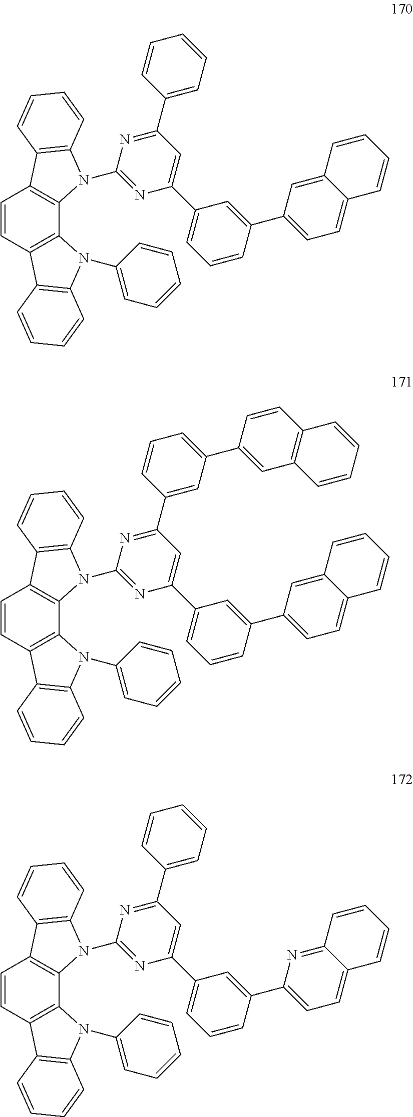 [SMILES: c1ccc(-c2cc(-c3cccc(-c4ccc5ccccc5c4)c3)nc(-n3c4ccccc4c4ccc5c6ccccc6n(-c6ccccc6)c5c43)n2)cc1 ; c1ccc(-n2c3ccccc3c3ccc4c5ccccc5n(-c5nc(-c6cccc(-c7ccc8ccccc8c7)c6)cc(-c6cccc(-c7ccc8ccccc8c7)c6)n5)c4c32)cc1 ; c1ccc(-c2cc(-c3cccc(-c4ccc5ccccc5n4)c3)nc(-n3c4ccccc4c4ccc5c6ccccc6n(-c6ccccc6)c5c43)n2)cc1]

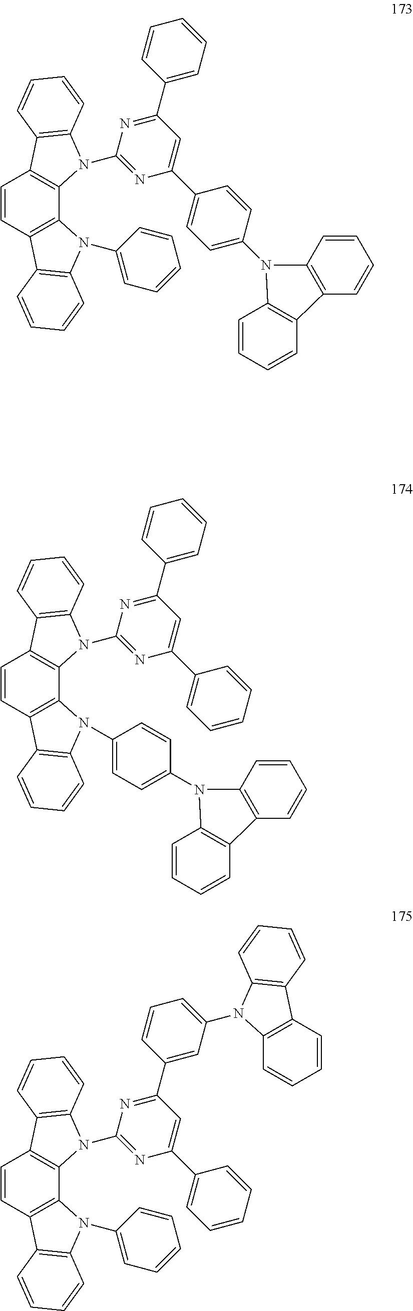 [SMILES: c1ccc(-c2cc(-c3ccc(-n4c5ccccc5c5ccccc54)cc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ccc(-n7c8ccccc8c8ccccc87)cc6)c5c43)n2)cc1 ; c1ccc(-c2cc(-c3cccc(-n4c5ccccc5c5ccccc54)c3)nc(-n3c4ccccc4c4ccc5c6ccccc6n(-c6ccccc6)c5c43)n2)cc1]

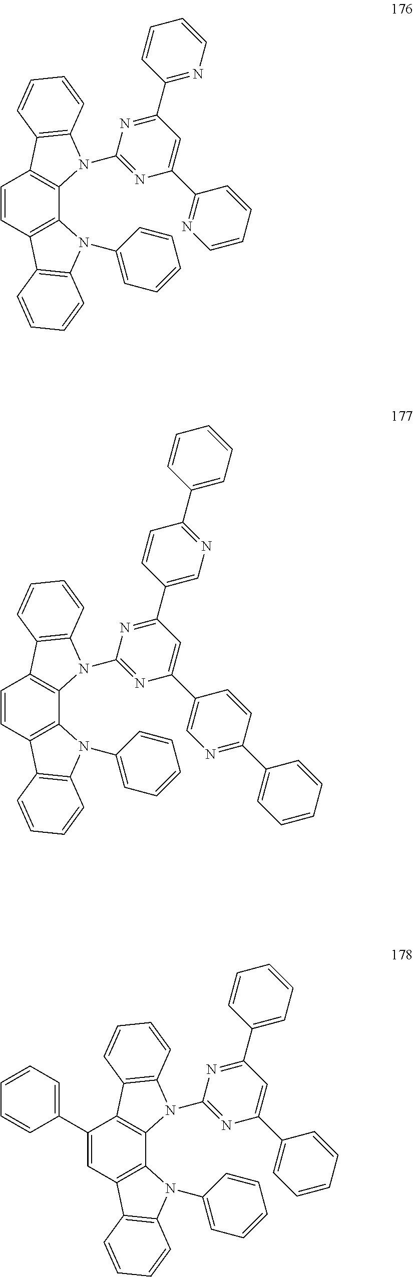 [SMILES: c1ccc(-n2c3ccccc3c3ccc4c5ccccc5n(-c5nc(-c6ccccn6)cc(-c6ccccn6)n5)c4c32)cc1 ; c1ccc(-c2ccc(-c3cc(-c4ccc(-c5ccccc5)nc4)nc(-n4c5ccccc5c5ccc6c7ccccc7n(-c7ccccc7)c6c54)n3)cn2)cc1 ; c1ccc(-c2cc(-c3ccccc3)nc(-n3c4ccccc4c4c(-c5ccccc5)cc5c6ccccc6n(-c6ccccc6)c5c43)n2)cc1]

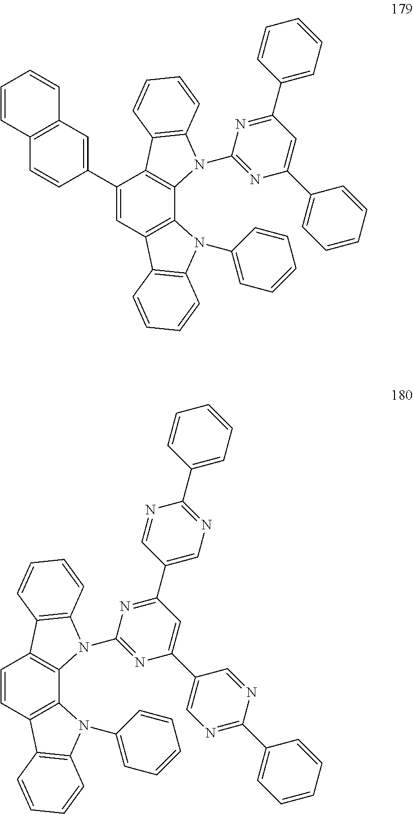 [SMILES: c1ccc(-c2cc(-c3ccccc3)nc(-n3c4ccccc4c4c(-c5ccc6ccccc6c5)cc5c6ccccc6n(-c6ccccc6)c5c43)n2)cc1 ; c1ccc(-c2ncc(-c3cc(-c4cnc(-c5ccccc5)nc4)nc(-n4c5ccccc5c5ccc6c7ccccc7n(-c7ccccc7)c6c54)n3)cn2)cc1]

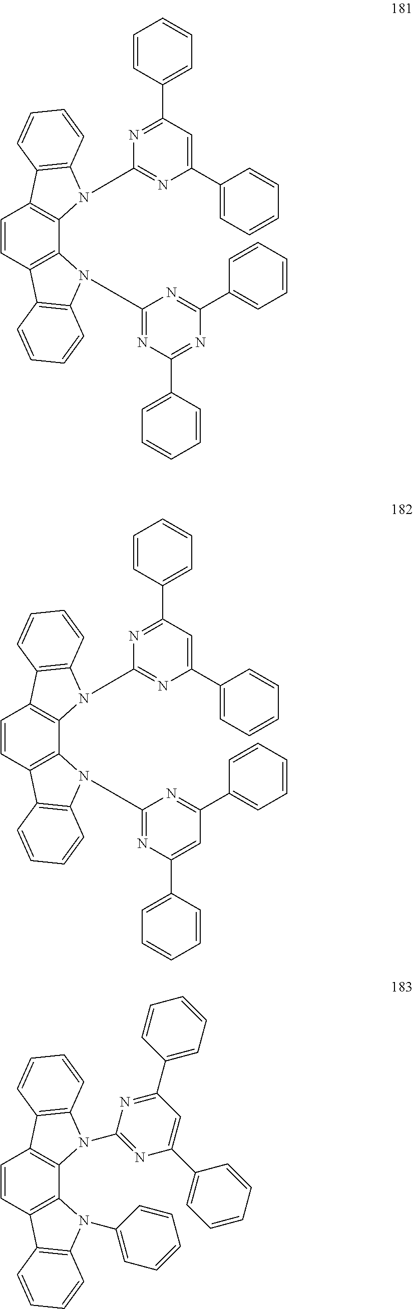

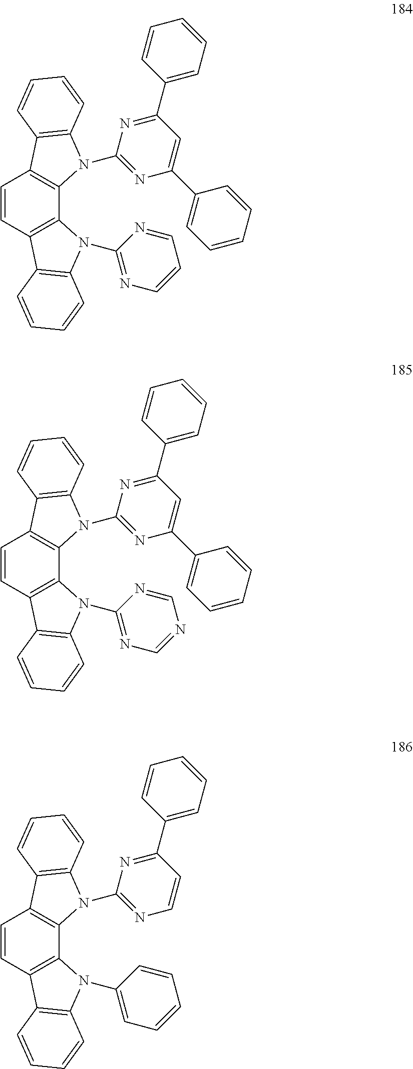 [SMILES: c1ccc(-c2cc(-c3ccccc3)nc(-n3c4ccccc4c4ccc5c6ccccc6n(-c6ncccn6)c5c43)n2)cc1 ; c1ccc(-c2cc(-c3ccccc3)nc(-n3c4ccccc4c4ccc5c6ccccc6n(-c6ncncn6)c5c43)n2)cc1 ; c1ccc(-c2ccnc(-n3c4ccccc4c4ccc5c6ccccc6n(-c6ccccc6)c5c43)n2)cc1]

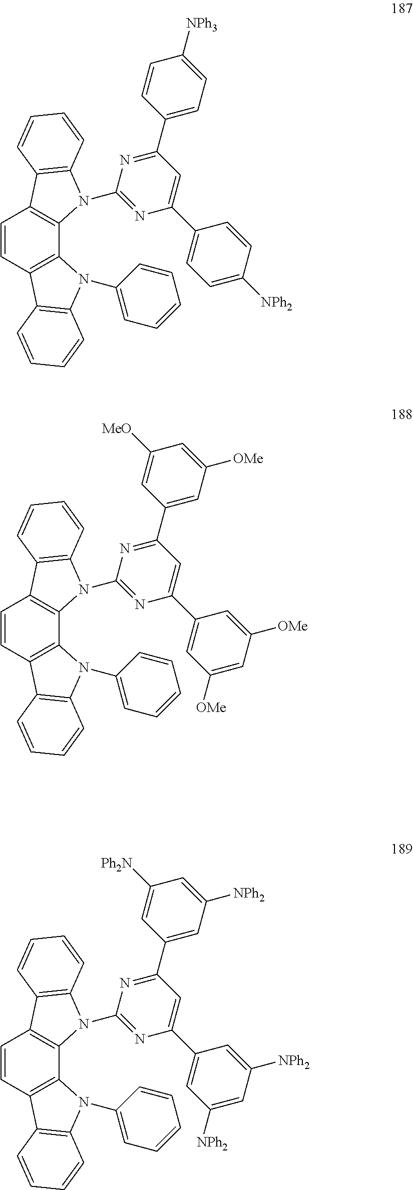

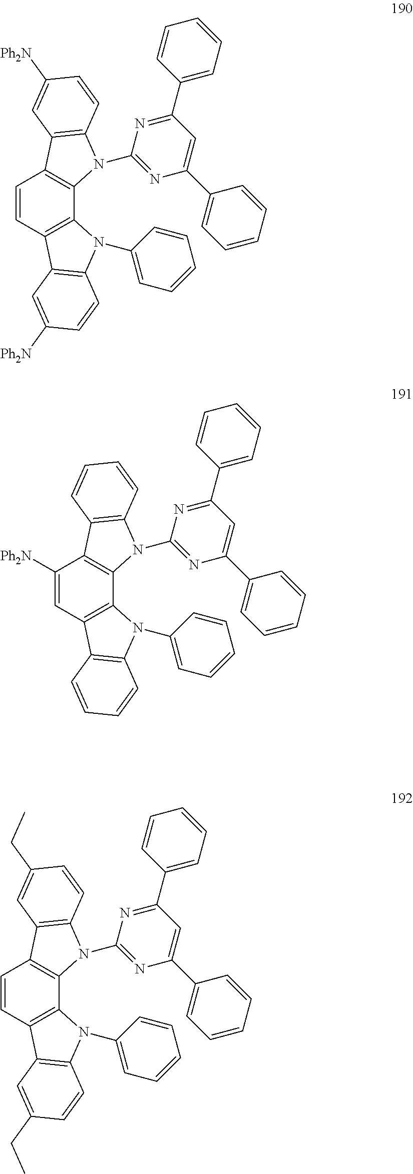

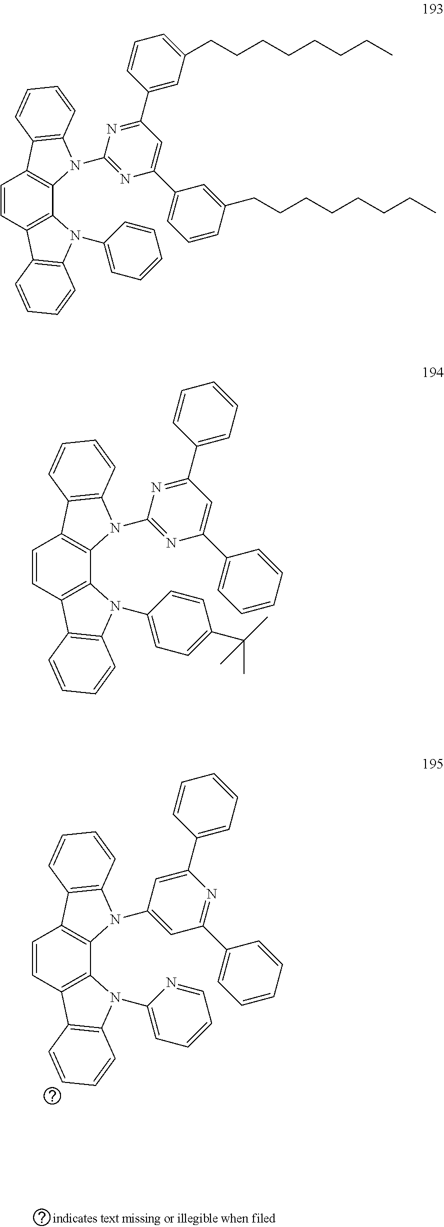 [SMILES: CCCCCCCCc1cccc(-c2cc(-c3cccc(CCCCCCCC)c3)nc(-n3c4ccccc4c4ccc5c6ccccc6n(-c6ccccc6)c5c43)n2)c1 ; CC(C)(C)c1ccc(-n2c3ccccc3c3ccc4c5ccccc5n(-c5nc(-c6ccccc6)cc(-c6ccccc6)n5)c4c32)cc1 ; c1ccc(-c2cc(-n3c4ccccc4c4ccc5c6ccccc6n(-c6ccccn6)c5c43)cc(-c3ccccc3)n2)cc1]

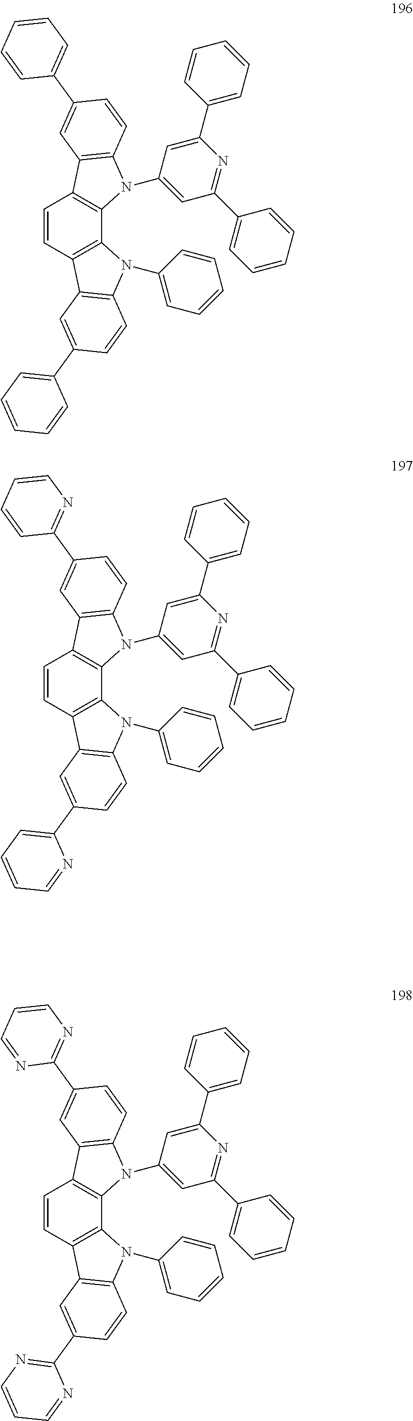

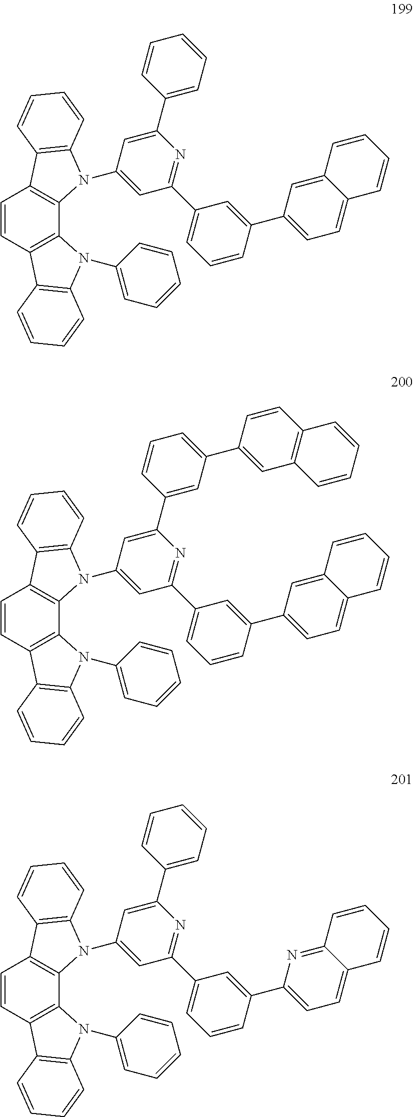 [SMILES: c1ccc(-c2cc(-n3c4ccccc4c4ccc5c6ccccc6n(-c6ccccc6)c5c43)cc(-c3cccc(-c4ccc5ccccc5c4)c3)n2)cc1 ; c1ccc(-n2c3ccccc3c3ccc4c5ccccc5n(-c5cc(-c6cccc(-c7ccc8ccccc8c7)c6)nc(-c6cccc(-c7ccc8ccccc8c7)c6)c5)c4c32)cc1 ; c1ccc(-c2cc(-n3c4ccccc4c4ccc5c6ccccc6n(-c6ccccc6)c5c43)cc(-c3cccc(-c4ccc5ccccc5n4)c3)n2)cc1]

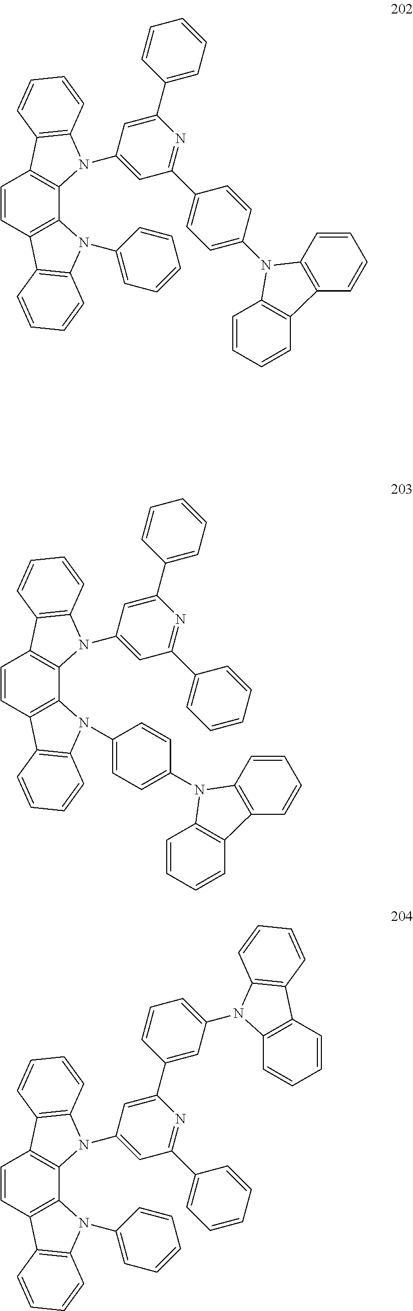 [SMILES: c1ccc(-c2cc(-n3c4ccccc4c4ccc5c6ccccc6n(-c6ccccc6)c5c43)cc(-c3ccc(-n4c5ccccc5c5ccccc54)cc3)n2)cc1 ; c1ccc(-c2cc(-n3c4ccccc4c4ccc5c6ccccc6n(-c6ccc(-n7c8ccccc8c8ccccc87)cc6)c5c43)cc(-c3ccccc3)n2)cc1 ; c1ccc(-c2cc(-n3c4ccccc4c4ccc5c6ccccc6n(-c6ccccc6)c5c43)cc(-c3cccc(-n4c5ccccc5c5ccccc54)c3)n2)cc1]

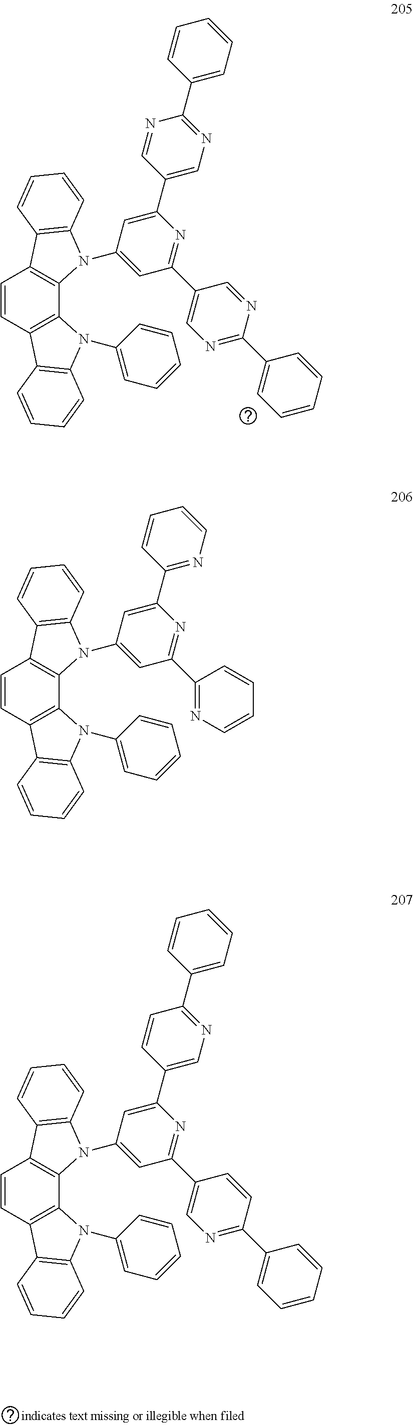 [SMILES: c1ccc(-c2ncc(-c3cc(-n4c5ccccc5c5ccc6c7ccccc7n(-c7ccccc7)c6c54)cc(-c4cnc(-c5ccccc5)nc4)n3)cn2)cc1 ; c1ccc(-n2c3ccccc3c3ccc4c5ccccc5n(-c5cc(-c6ccccn6)nc(-c6ccccn6)c5)c4c32)cc1 ; c1ccc(-c2ccc(-c3cc(-n4c5ccccc5c5ccc6c7ccccc7n(-c7ccccc7)c6c54)cc(-c4ccc(-c5ccccc5)nc4)n3)cn2)cc1]

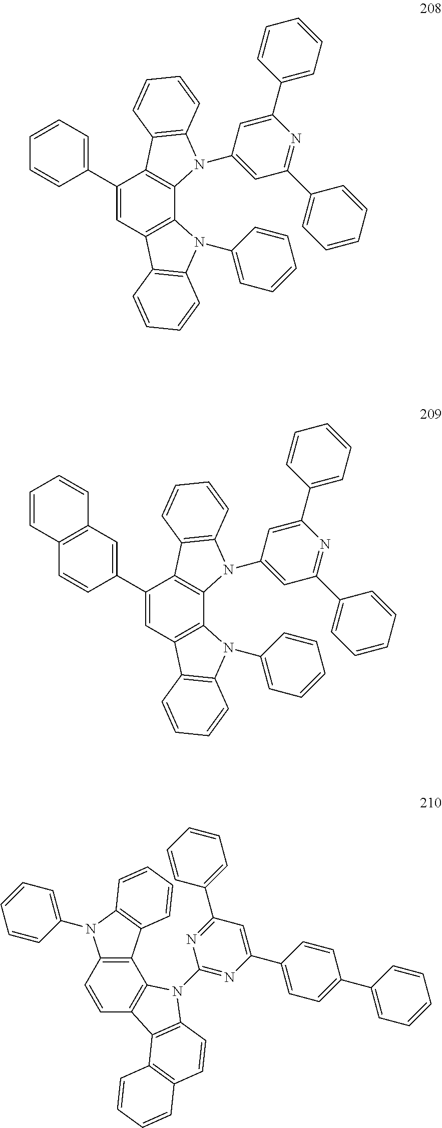 [SMILES: c1ccc(-c2cc(-n3c4ccccc4c4c(-c5ccccc5)cc5c6ccccc6n(-c6ccccc6)c5c43)cc(-c3ccccc3)n2)cc1 ; c1ccc(-c2cc(-n3c4ccccc4c4c(-c5ccc6ccccc6c5)cc5c6ccccc6n(-c6ccccc6)c5c43)cc(-c3ccccc3)n2)cc1 ; c1ccc(-c2ccc(-c3cc(-c4ccccc4)nc(-n4c5ccc6ccccc6c5c5ccc6c(c7ccccc7n6-c6ccccc6)c54)n3)cc2)cc1]

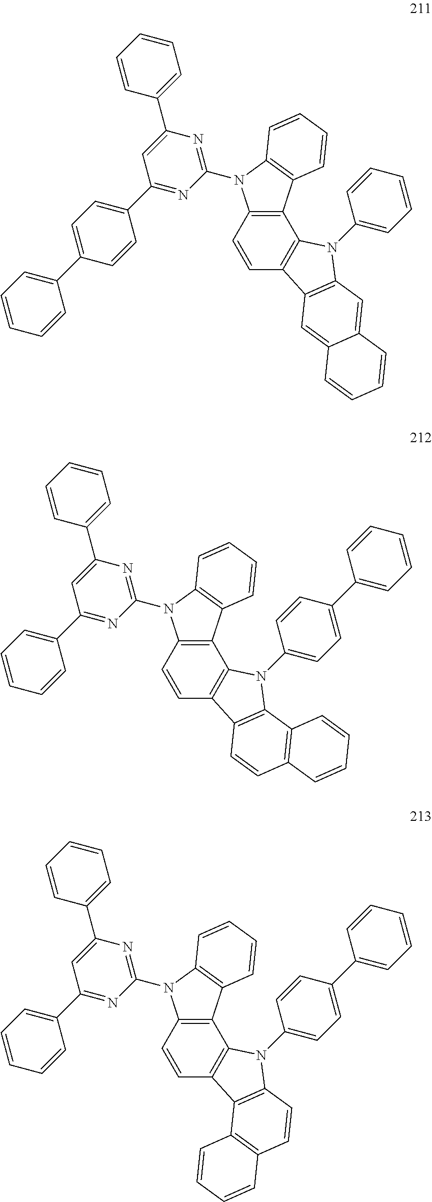 [SMILES: c1ccc(-c2ccc(-c3cc(-c4ccccc4)nc(-n4c5ccccc5c5c4ccc4c6cc7ccccc7cc6n(-c6ccccc6)c45)n3)cc2)cc1 ; c1ccc(-c2ccc(-n3c4c5ccccc5ccc4c4ccc5c(c6ccccc6n5-c5nc(-c6ccccc6)cc(-c6ccccc6)n5)c43)cc2)cc1 ; c1ccc(-c2ccc(-n3c4ccc5ccccc5c4c4ccc5c(c6ccccc6n5-c5nc(-c6ccccc6)cc(-c6ccccc6)n5)c43)cc2)cc1]

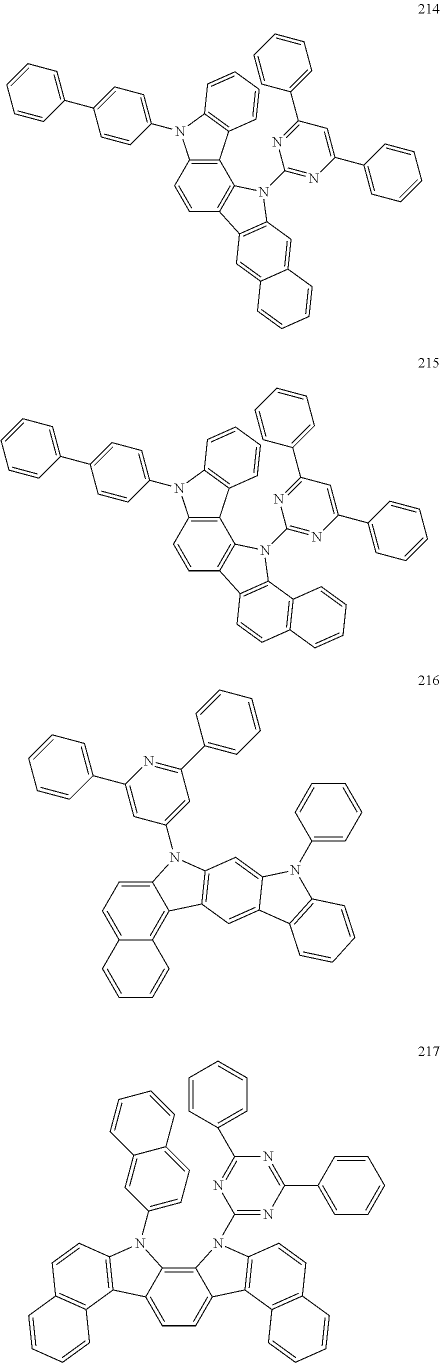 [SMILES: c1ccc(-c2ccc(-n3c4ccccc4c4c3ccc3c5cc6ccccc6cc5n(-c5nc(-c6ccccc6)cc(-c6ccccc6)n5)c34)cc2)cc1 ; c1ccc(-c2ccc(-n3c4ccccc4c4c3ccc3c5ccc6ccccc6c5n(-c5nc(-c6ccccc6)cc(-c6ccccc6)n5)c34)cc2)cc1 ; c1ccc(-c2cc(-n3c4cc5c(cc4c4c6ccccc6ccc43)c3ccccc3n5-c3ccccc3)cc(-c3ccccc3)n2)cc1 ; c1ccc(-c2nc(-c3ccccc3)nc(-n3c4ccc5ccccc5c4c4ccc5c6c7ccccc7ccc6n(-c6ccc7ccccc7c6)c5c43)n2)cc1]

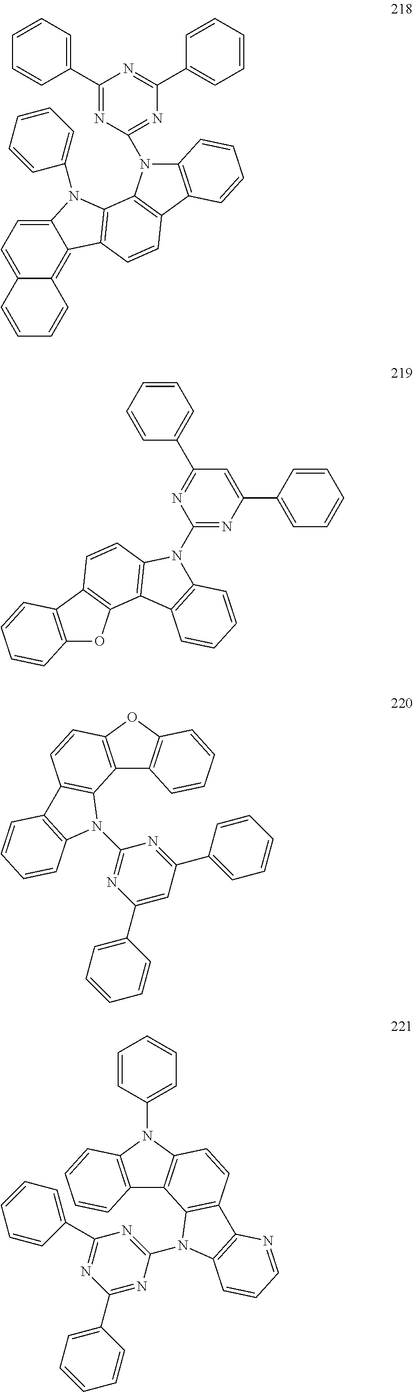

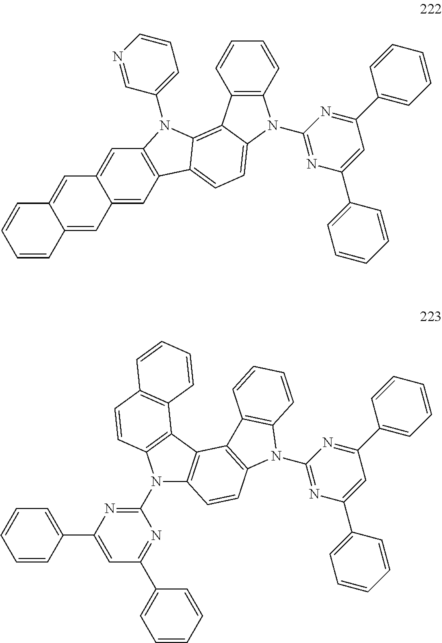 [SMILES: c1ccc(-c2cc(-c3ccccc3)nc(-n3c4ccccc4c4c3ccc3c5cc6cc7ccccc7cc6cc5n(-c5cccnc5)c34)n2)cc1 ; c1ccc(-c2cc(-c3ccccc3)nc(-n3c4ccccc4c4c5c6c7ccccc7ccc6n(-c6nc(-c7ccccc7)cc(-c7ccccc7)n6)c5ccc43)n2)cc1]

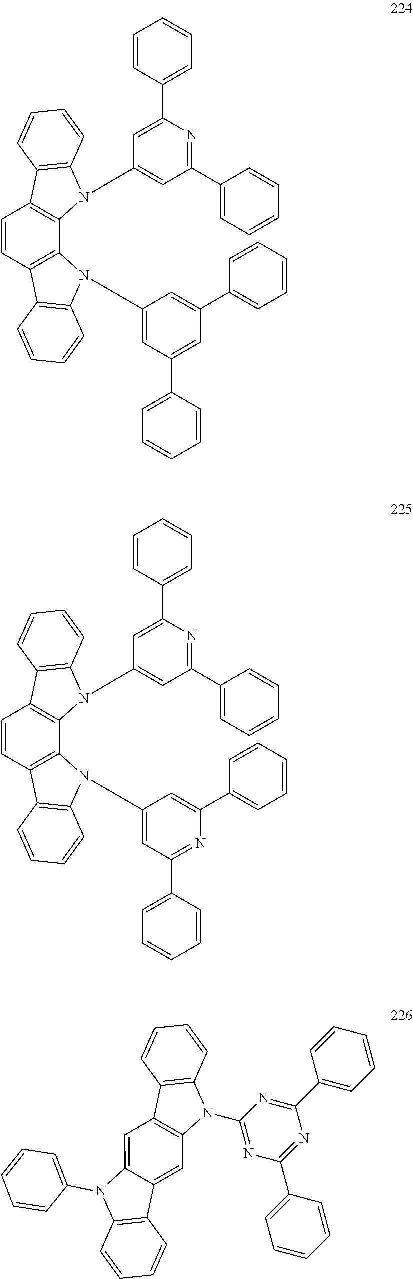 [SMILES: c1ccc(-c2cc(-c3ccccc3)cc(-n3c4ccccc4c4ccc5c6ccccc6n(-c6cc(-c7ccccc7)nc(-c7ccccc7)c6)c5c43)c2)cc1 ; c1ccc(-c2cc(-n3c4ccccc4c4ccc5c6ccccc6n(-c6cc(-c7ccccc7)nc(-c7ccccc7)c6)c5c43)cc(-c3ccccc3)n2)cc1 ; c1ccc(-c2nc(-c3ccccc3)nc(-n3c4ccccc4c4cc5c(cc43)c3ccccc3n5-c3ccccc3)n2)cc1]

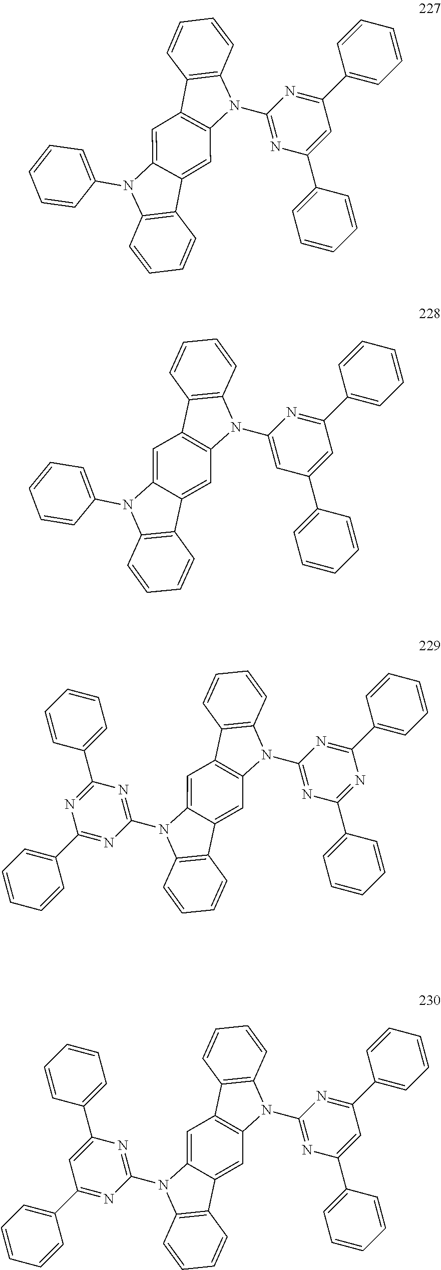 [SMILES: c1ccc(-c2cc(-c3ccccc3)nc(-n3c4ccccc4c4cc5c(cc43)c3ccccc3n5-c3ccccc3)n2)cc1 ; c1ccc(-c2cc(-c3ccccc3)nc(-n3c4ccccc4c4cc5c(cc43)c3ccccc3n5-c3ccccc3)c2)cc1 ; c1ccc(-c2nc(-c3ccccc3)nc(-n3c4ccccc4c4cc5c(cc43)c3ccccc3n5-c3nc(-c4ccccc4)nc(-c4ccccc4)n3)n2)cc1 ; c1ccc(-c2cc(-c3ccccc3)nc(-n3c4ccccc4c4cc5c(cc43)c3ccccc3n5-c3nc(-c4ccccc4)cc(-c4ccccc4)n3)n2)cc1]

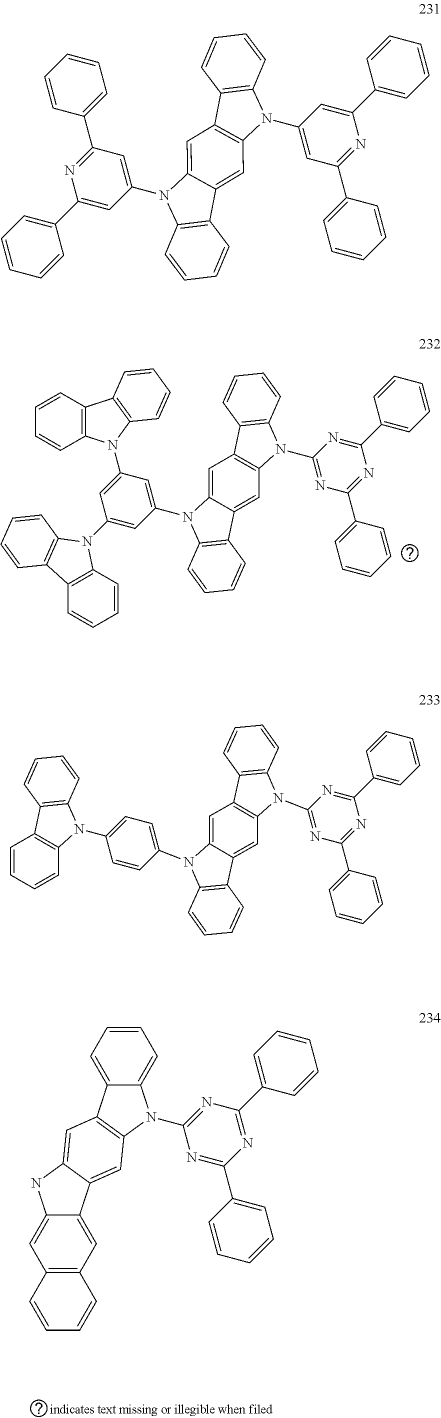 [SMILES: c1ccc(-c2cc(-n3c4ccccc4c4cc5c(cc43)c3ccccc3n5-c3cc(-c4ccccc4)nc(-c4ccccc4)c3)cc(-c3ccccc3)n2)cc1 ; c1ccc(-c2nc(-c3ccccc3)nc(-n3c4ccccc4c4cc5c(cc43)c3ccccc3n5-c3cc(-n4c5ccccc5c5ccccc54)cc(-n4c5ccccc5c5ccccc54)c3)n2)cc1 ; c1ccc(-c2nc(-c3ccccc3)nc(-n3c4ccccc4c4cc5c(cc43)c3ccccc3n5-c3ccc(-n4c5ccccc5c5ccccc54)cc3)n2)cc1 ; c1ccc(-c2nc(-c3ccccc3)nc(-n3c4ccccc4c4cc5[nH]c6cc7ccccc7cc6c5cc43)n2)cc1]

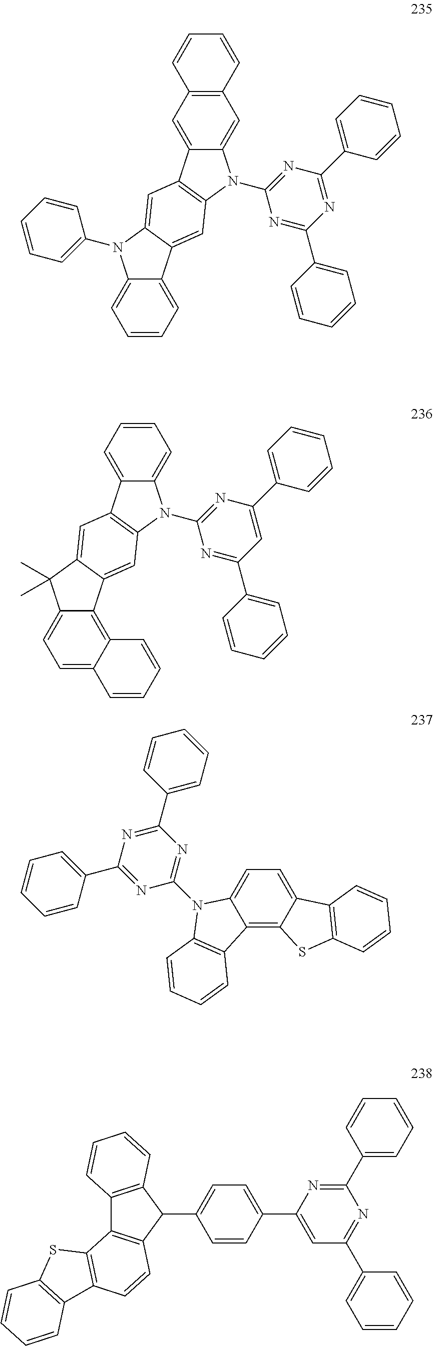

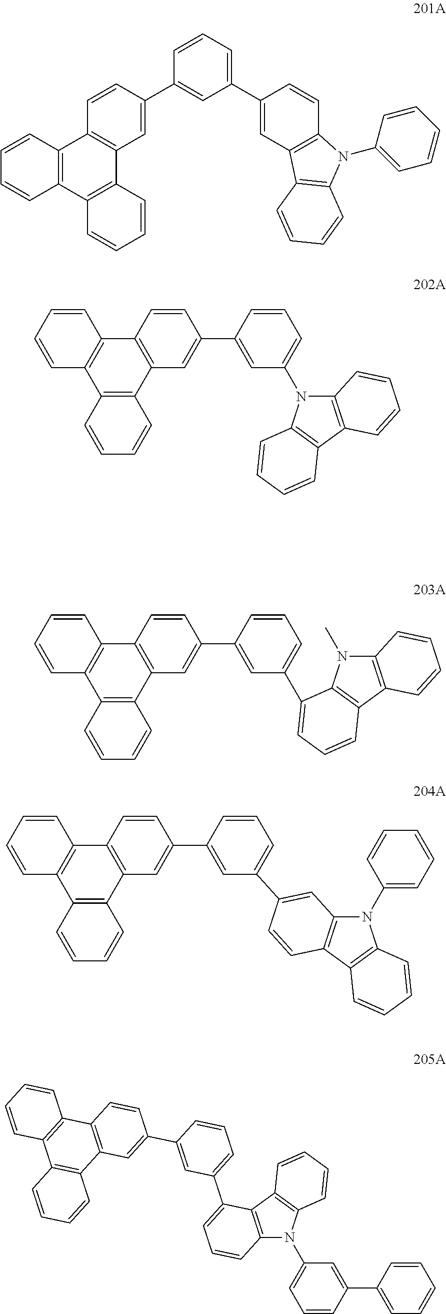 [SMILES: c1ccc(-n2c3ccccc3c3cc(-c4cccc(-c5ccc6c7ccccc7c7ccccc7c6c5)c4)ccc32)cc1 ; c1cc(-c2ccc3c4ccccc4c4ccccc4c3c2)cc(-n2c3ccccc3c3ccccc32)c1 ; Cn1c2ccccc2c2cccc(-c3cccc(-c4ccc5c6ccccc6c6ccccc6c5c4)c3)c21 ; c1ccc(-n2c3ccccc3c3ccc(-c4cccc(-c5ccc6c7ccccc7c7ccccc7c6c5)c4)cc32)cc1 ; c1ccc(-c2cccc(-n3c4ccccc4c4c(-c5cccc(-c6ccc7c8ccccc8c8ccccc8c7c6)c5)cccc43)c2)cc1]

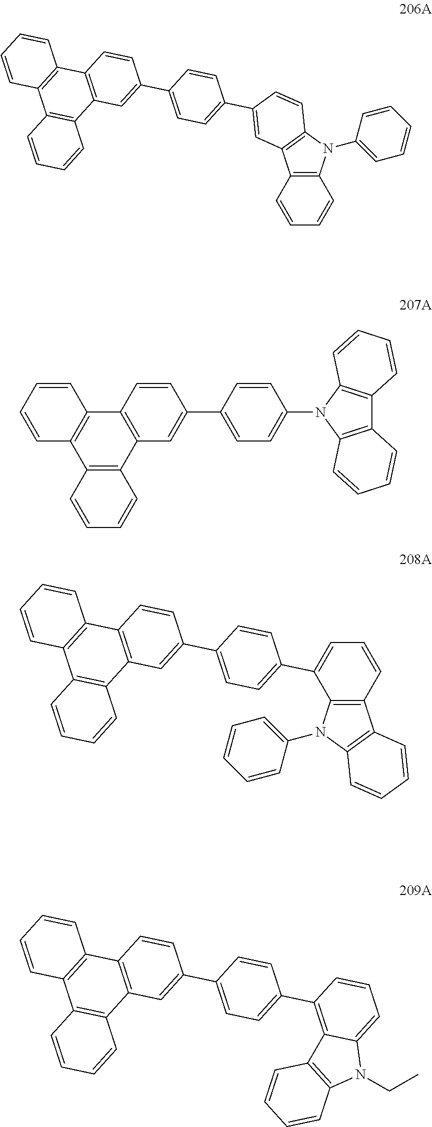 [SMILES: c1ccc(-n2c3ccccc3c3cc(-c4ccc(-c5ccc6c7ccccc7c7ccccc7c6c5)cc4)ccc32)cc1 ; c1ccc2c(c1)c1ccccc1c1cc(-c3ccc(-n4c5ccccc5c5ccccc54)cc3)ccc21 ; c1ccc(-n2c3ccccc3c3cccc(-c4ccc(-c5ccc6c7ccccc7c7ccccc7c6c5)cc4)c32)cc1 ; CCn1c2ccccc2c2c(-c3ccc(-c4ccc5c6ccccc6c6ccccc6c5c4)cc3)cccc21]

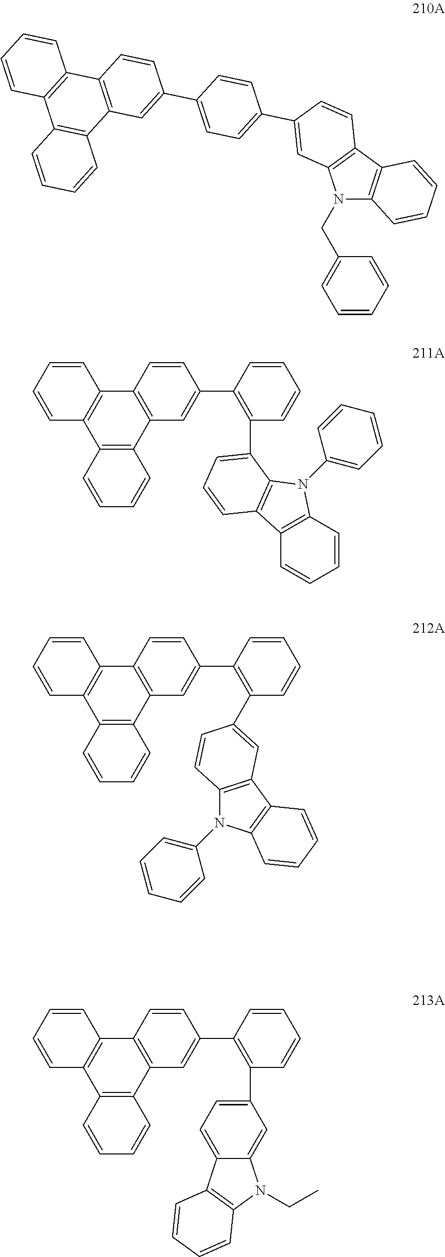 [SMILES: c1ccc(Cn2c3ccccc3c3ccc(-c4ccc(-c5ccc6c7ccccc7c7ccccc7c6c5)cc4)cc32)cc1 ; c1ccc(-n2c3ccccc3c3cccc(-c4ccccc4-c4ccc5c6ccccc6c6ccccc6c5c4)c32)cc1 ; c1ccc(-n2c3ccccc3c3cc(-c4ccccc4-c4ccc5c6ccccc6c6ccccc6c5c4)ccc32)cc1 ; CCn1c2ccccc2c2ccc(-c3ccccc3-c3ccc4c5ccccc5c5ccccc5c4c3)cc21]

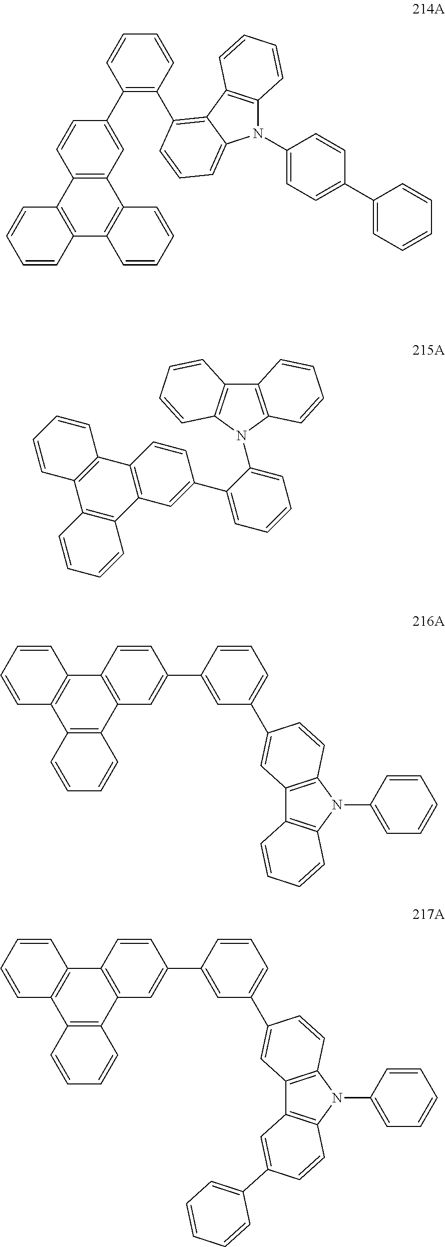 [SMILES: c1ccc(-c2ccc(-n3c4ccccc4c4c(-c5ccccc5-c5ccc6c7ccccc7c7ccccc7c6c5)cccc43)cc2)cc1 ; c1ccc(-n2c3ccccc3c3ccccc32)c(-c2ccc3c4ccccc4c4ccccc4c3c2)c1 ; c1ccc(-n2c3ccccc3c3cc(-c4cccc(-c5ccc6c7ccccc7c7ccccc7c6c5)c4)ccc32)cc1 ; c1ccc(-c2ccc3c(c2)c2cc(-c4cccc(-c5ccc6c7ccccc7c7ccccc7c6c5)c4)ccc2n3-c2ccccc2)cc1]

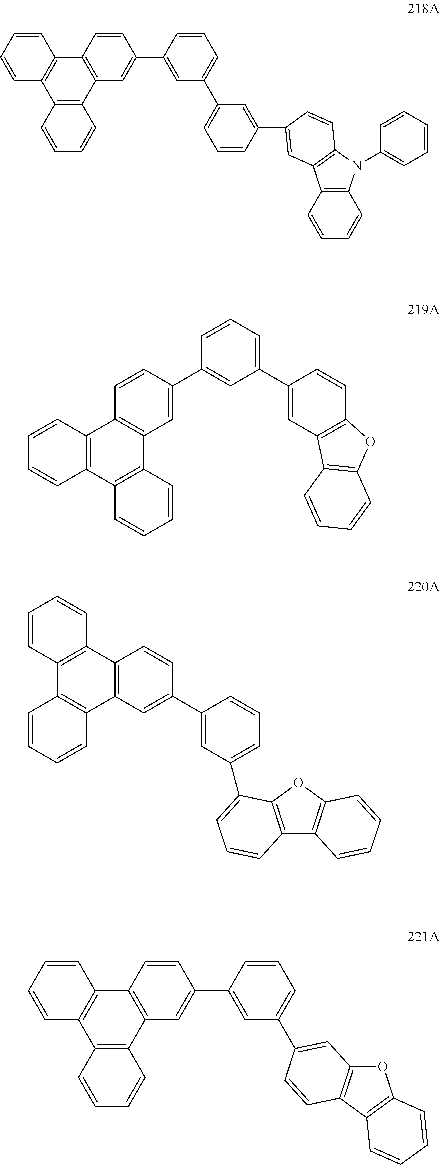 [SMILES: c1ccc(-n2c3ccccc3c3cc(-c4cccc(-c5cccc(-c6ccc7c8ccccc8c8ccccc8c7c6)c5)c4)ccc32)cc1 ; c1cc(-c2ccc3oc4ccccc4c3c2)cc(-c2ccc3c4ccccc4c4ccccc4c3c2)c1 ; c1cc(-c2ccc3c4ccccc4c4ccccc4c3c2)cc(-c2cccc3c2oc2ccccc23)c1 ; c1cc(-c2ccc3c(c2)oc2ccccc23)cc(-c2ccc3c4ccccc4c4ccccc4c3c2)c1]

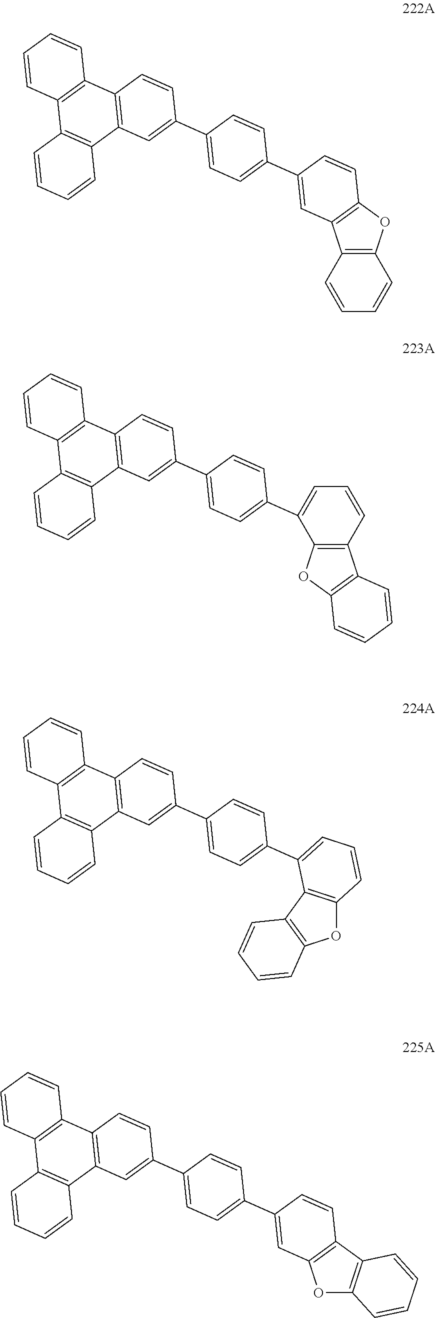 [SMILES: c1ccc2c(c1)oc1ccc(-c3ccc(-c4ccc5c6ccccc6c6ccccc6c5c4)cc3)cc12 ; c1ccc2c(c1)oc1c(-c3ccc(-c4ccc5c6ccccc6c6ccccc6c5c4)cc3)cccc12 ; c1ccc2c(c1)oc1cccc(-c3ccc(-c4ccc5c6ccccc6c6ccccc6c5c4)cc3)c12 ; c1ccc2c(c1)oc1cc(-c3ccc(-c4ccc5c6ccccc6c6ccccc6c5c4)cc3)ccc12]

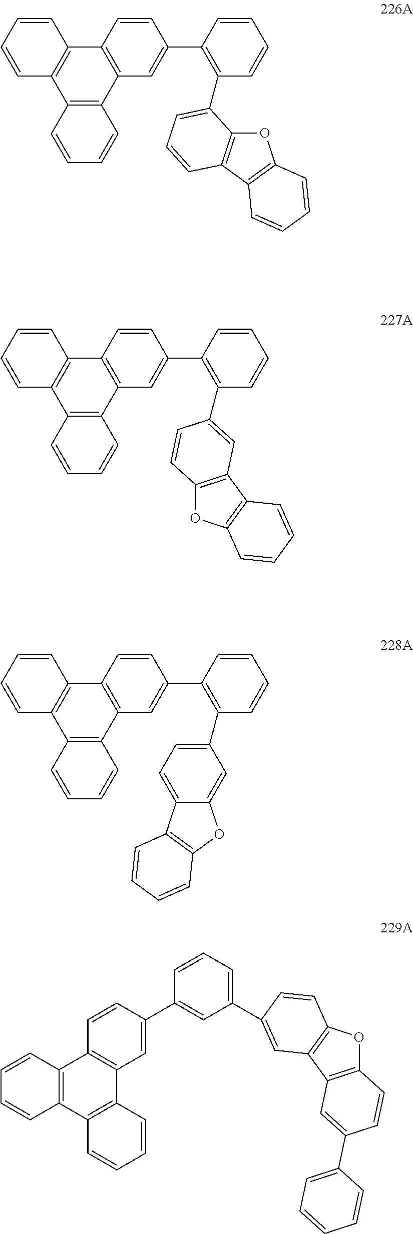 [SMILES: c1ccc(-c2cccc3c2oc2ccccc23)c(-c2ccc3c4ccccc4c4ccccc4c3c2)c1 ; c1ccc(-c2ccc3c4ccccc4c4ccccc4c3c2)c(-c2ccc3oc4ccccc4c3c2)c1 ; c1ccc(-c2ccc3c4ccccc4c4ccccc4c3c2)c(-c2ccc3c(c2)oc2ccccc23)c1 ; c1ccc(-c2ccc3oc4ccc(-c5cccc(-c6ccc7c8ccccc8c8ccccc8c7c6)c5)cc4c3c2)cc1]

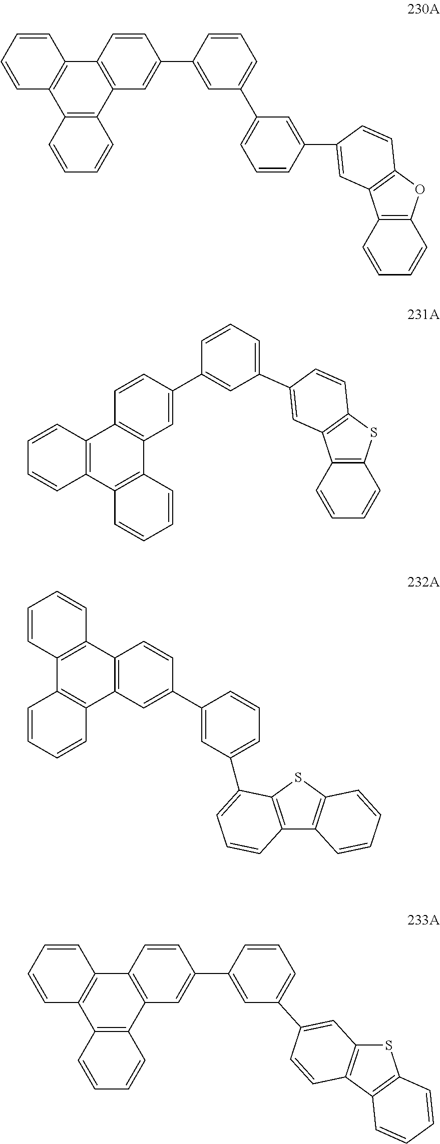 [SMILES: c1cc(-c2cccc(-c3ccc4c5ccccc5c5ccccc5c4c3)c2)cc(-c2ccc3oc4ccccc4c3c2)c1 ; c1cc(-c2ccc3sc4ccccc4c3c2)cc(-c2ccc3c4ccccc4c4ccccc4c3c2)c1 ; c1cc(-c2ccc3c4ccccc4c4ccccc4c3c2)cc(-c2cccc3c2sc2ccccc23)c1 ; c1cc(-c2ccc3c(c2)sc2ccccc23)cc(-c2ccc3c4ccccc4c4ccccc4c3c2)c1]

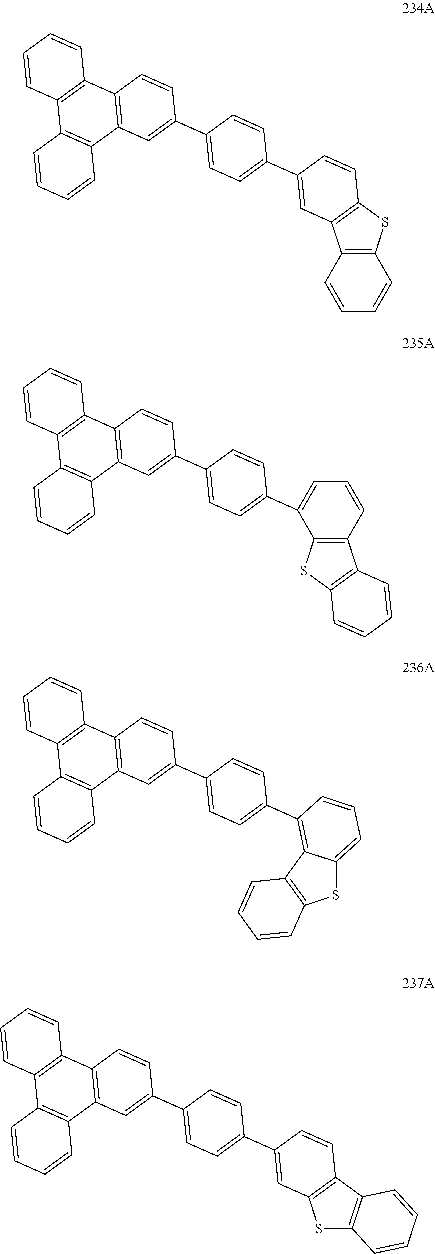 [SMILES: c1ccc2c(c1)sc1ccc(-c3ccc(-c4ccc5c6ccccc6c6ccccc6c5c4)cc3)cc12 ; c1ccc2c(c1)sc1c(-c3ccc(-c4ccc5c6ccccc6c6ccccc6c5c4)cc3)cccc12 ; c1ccc2c(c1)sc1cccc(-c3ccc(-c4ccc5c6ccccc6c6ccccc6c5c4)cc3)c12 ; c1ccc2c(c1)sc1cc(-c3ccc(-c4ccc5c6ccccc6c6ccccc6c5c4)cc3)ccc12]

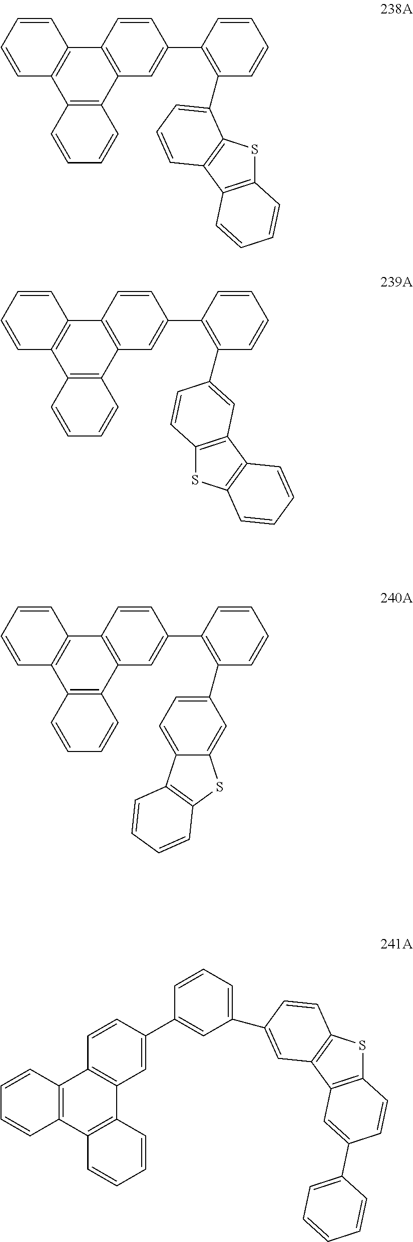

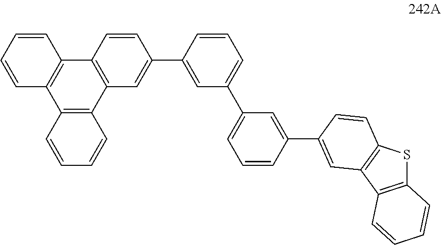 [SMILES: c1cc(-c2cccc(-c3ccc4c5ccccc5c5ccccc5c4c3)c2)cc(-c2ccc3sc4ccccc4c3c2)c1]

The heterocyclic compound and the triphenylene-based compound may act as hosts in the emission layer, but they are not limited thereto.

Among compounds represented by Formulae 1A, 1B, 1C, 1D, and 1E, a ratio of an amount of the at least one type of heterocyclic compound to an amount of the triphenylene-based compound represented by Formula 2 may be in a range of about 0.01:0.99 to about 0.99:0.01, but it is not limited thereto.

For example, among compounds represented by Formulae 1A, 1B, 1C, 1D, and 1E, a ratio of an amount of at least one type of heterocyclic compound to an amount of the triphenylene-based compound represented by Formula 2 may be in a range of about 0.30:0.70 to about 0.70:0.30, but it is not limited thereto.

In another embodiment, among compounds represented by Formulae 1A, 1B, 1C, 1D, and 1E, a ratio of an amount of at least one type of heterocyclic compound to an amount of the triphenylene-based compound represented by Formula 2 above may be 0.50:0.50, but it is not limited thereto.

The EML may further include at least one of TPBi, TBADN, ADN (also referred to as “DNA”), a CBP, a CDBP, and a TCP, in addition to the heterocyclic compound and the triphenylene-based compound described above:

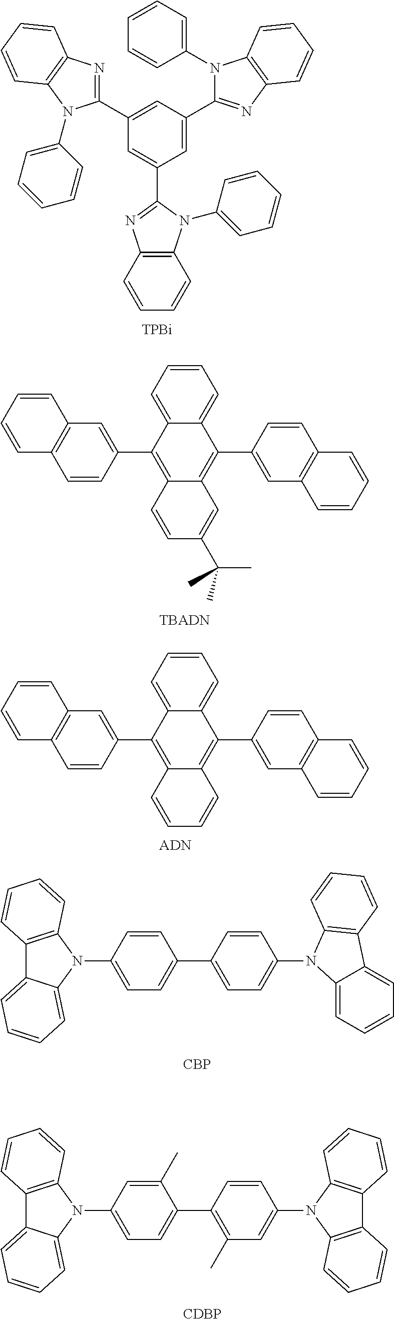

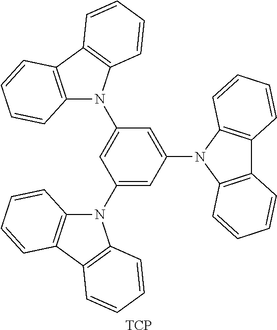

In an implementation, the EML may further include a compound represented by Formula 301, in addition to the heterocyclic compound and the triphenylene-based compound described above.

Ar₃₀₁-[(L₃₀₁)_{xb1}-R₃₀₁]_{xb2} <Formula 301>

In Formula 301,

Ar₃₀₁ may be selected from a naphthalene group, a heptalene group, a fluorene group, a spiro-fluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, and an indenoanthracene group; and

a naphthalene group, a heptalene group, a fluorene group, a spiro-fluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, and an indenoanthracene group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a non-aromatic condensed polycyclic group, and —Si(Q₃₀₁)(Q₃₀₂)(Q₃₀₃) (wherein, Q₃₀₁ to Q₃₀₃ may be each independently selected from a hydrogen, a C₁-C₆₀ alkyl group, a C₂-C₆₀ alkenyl group, a C₆-C₆₀ aryl group, and a C₂-C₆₀ heteroaryl group);

description of L₃₀₁ may be as the description of L₂₀₁ herein;

R₃₀₁ may be selected from

a C₁-C₂₀ alkyl group and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; wherein,

xb1 may be selected from 0, 1, 2, and 3; and

xb2 may be selected from 1, 2, 3, and 4.

For example, in Formula 301,

L₃₀₁ may be selected from a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, and a chrysenylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene, and a chrysenylene group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group; wherein,

R₃₀₁ may be selected from a C₁-C₂₀ alkyl group and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group, but it is not limited thereto.

For example, the EML may further include a compound represented by Formula 301A, in addition to the heterocyclic compound and the triphenylene-based compound described above:

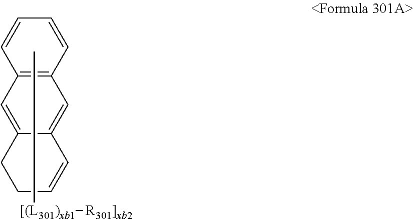

In Formula 301A, descriptions of the substituents may be as the descriptions herein.

The compound represented by Formula 301A may include at least one of Compounds H1 to H42 below, but it is not limited thereto.

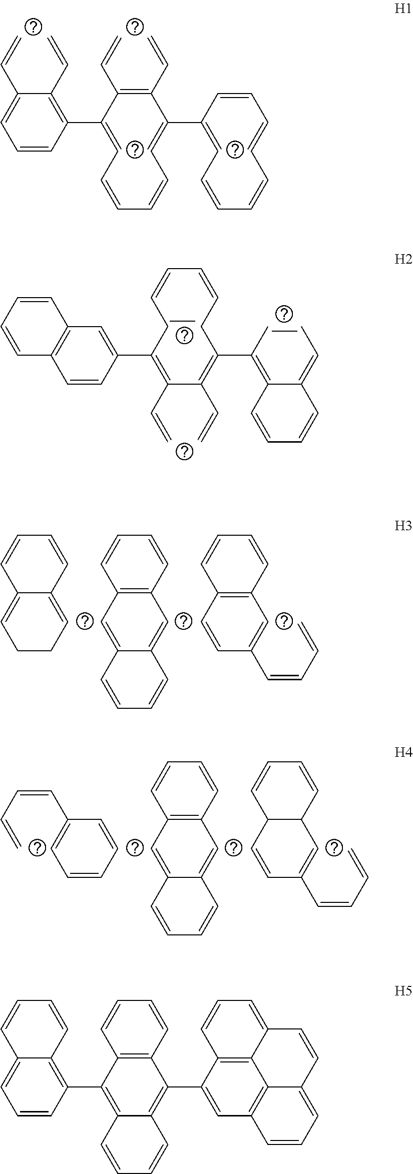

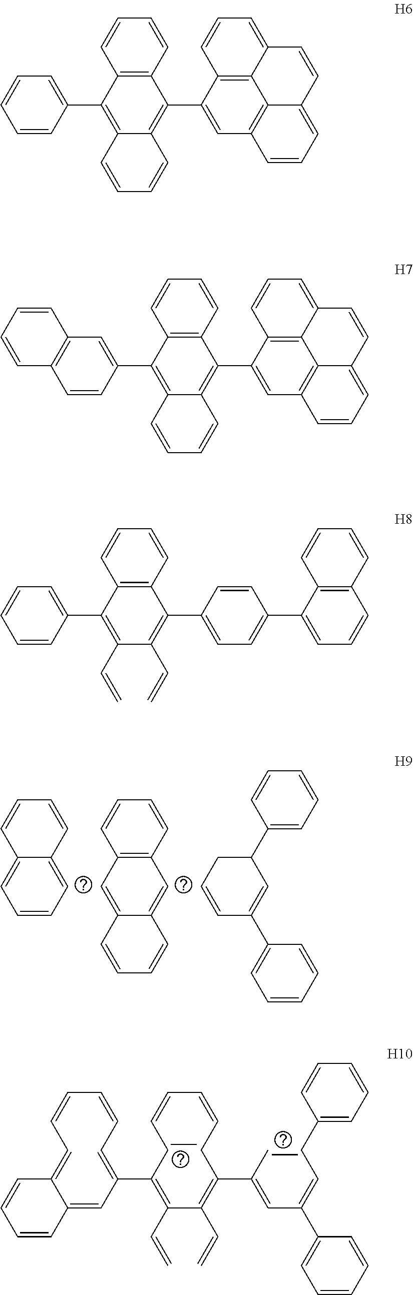

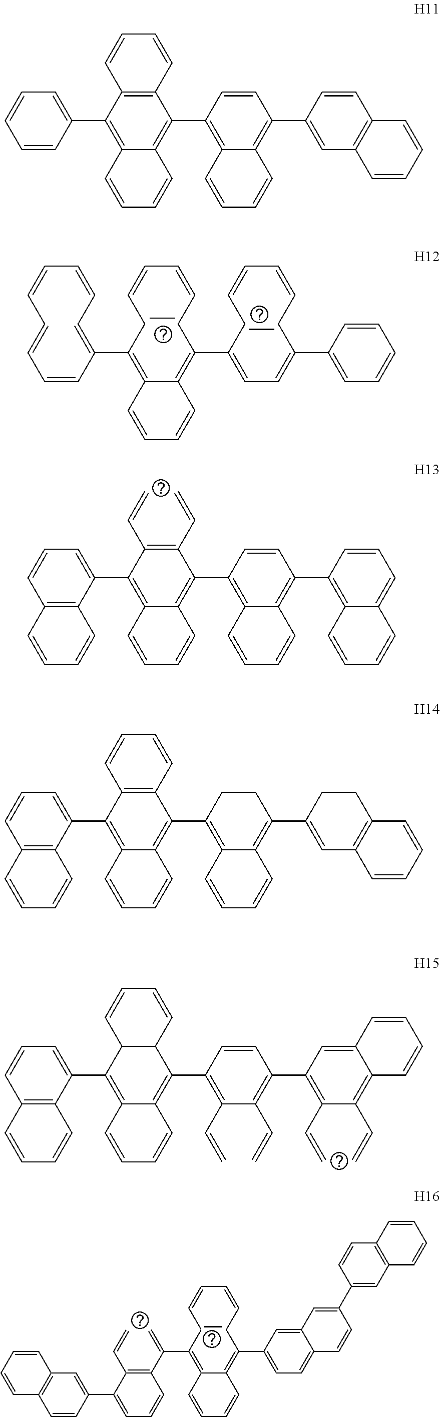

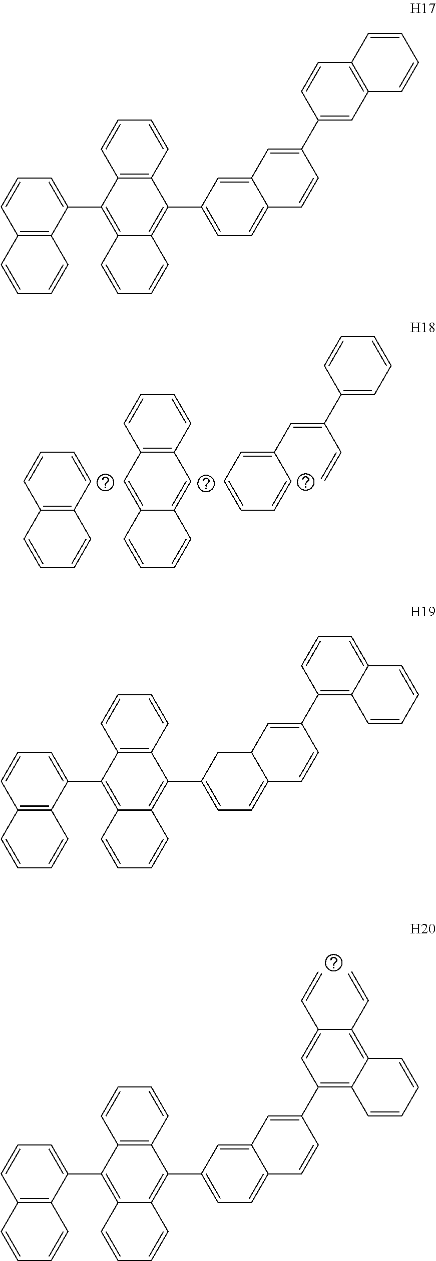

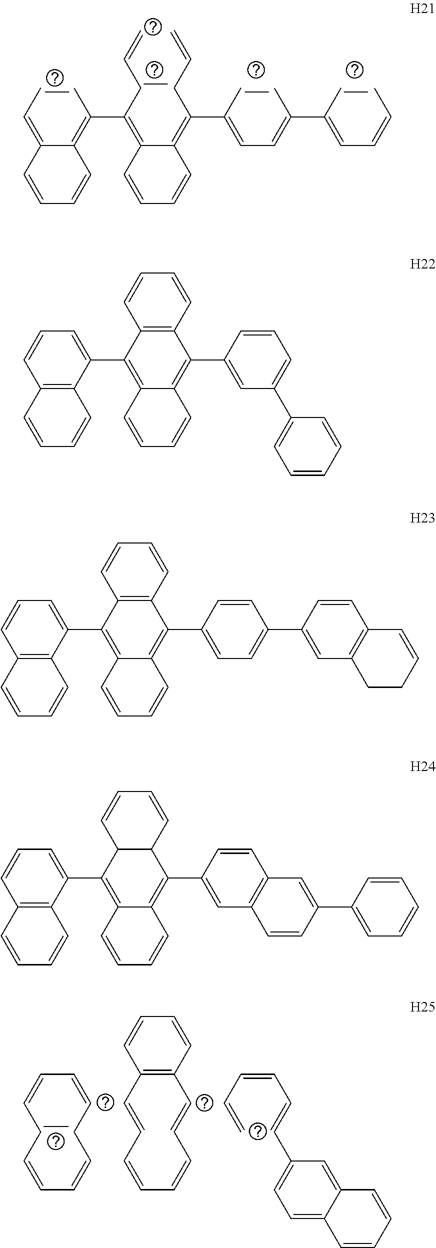

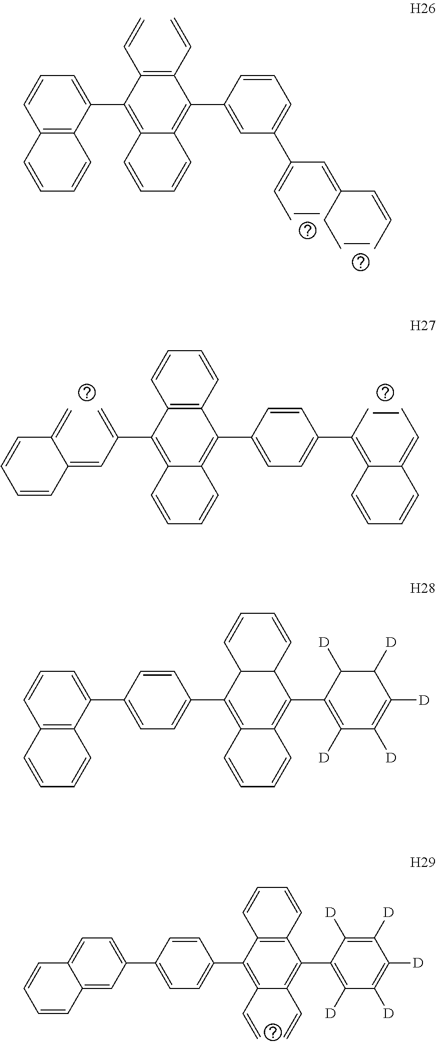

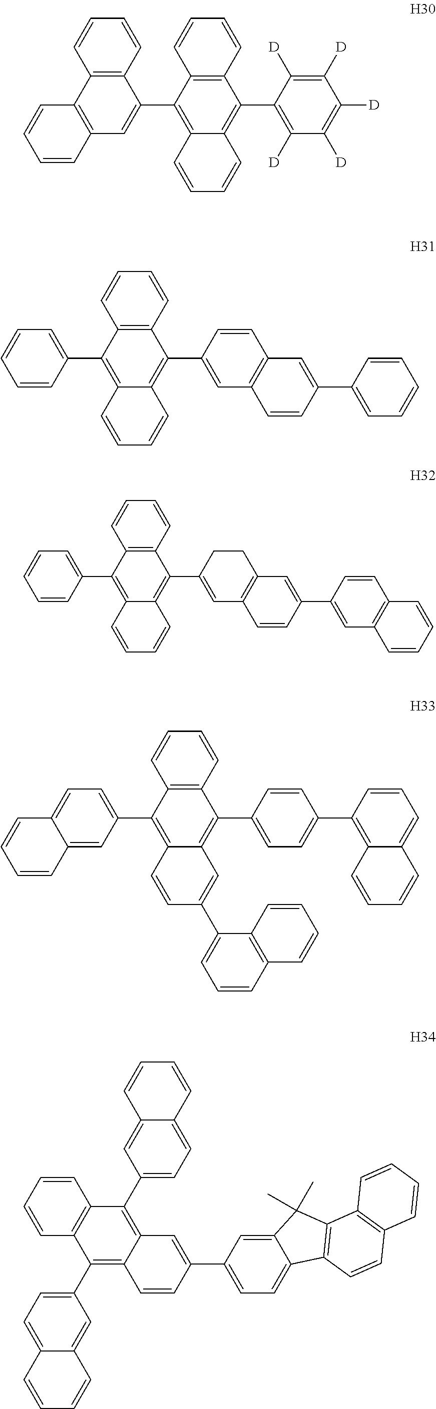

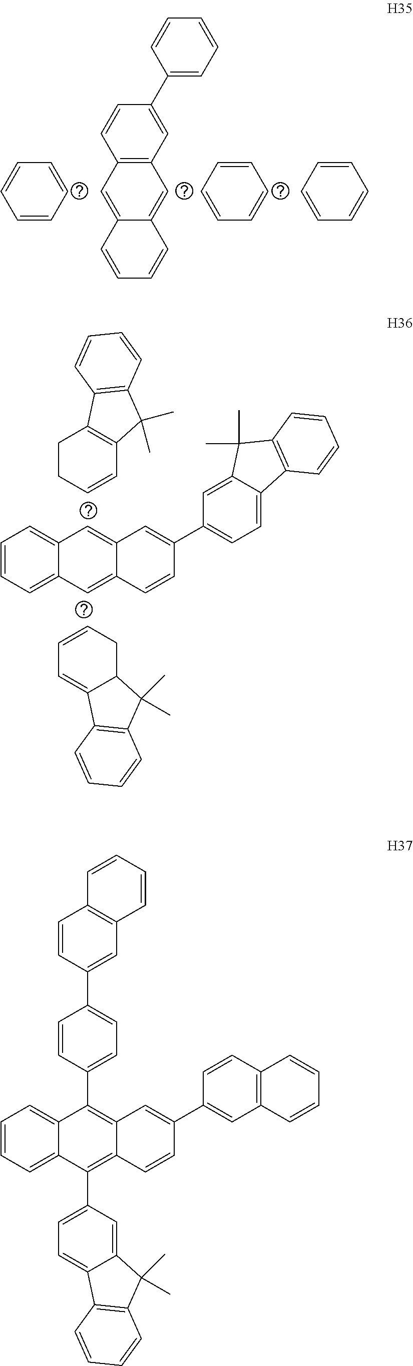

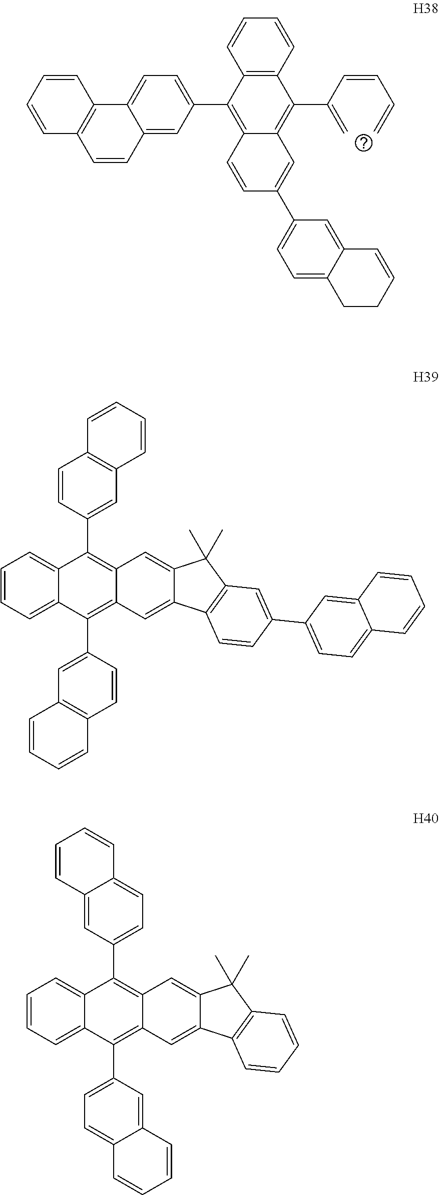

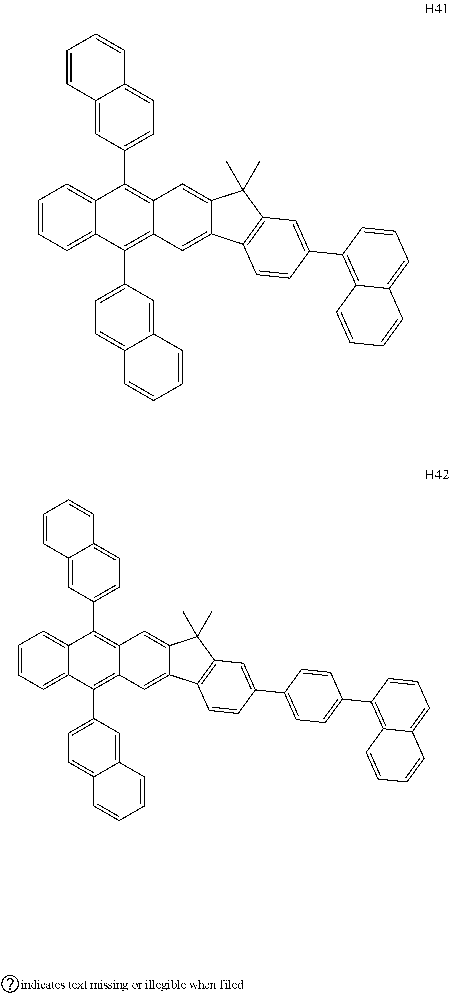

In an implementation, the EML may include at least one of Compounds H43 to H49 below, in addition to the heterocyclic compound and the triphenylene-based compound:

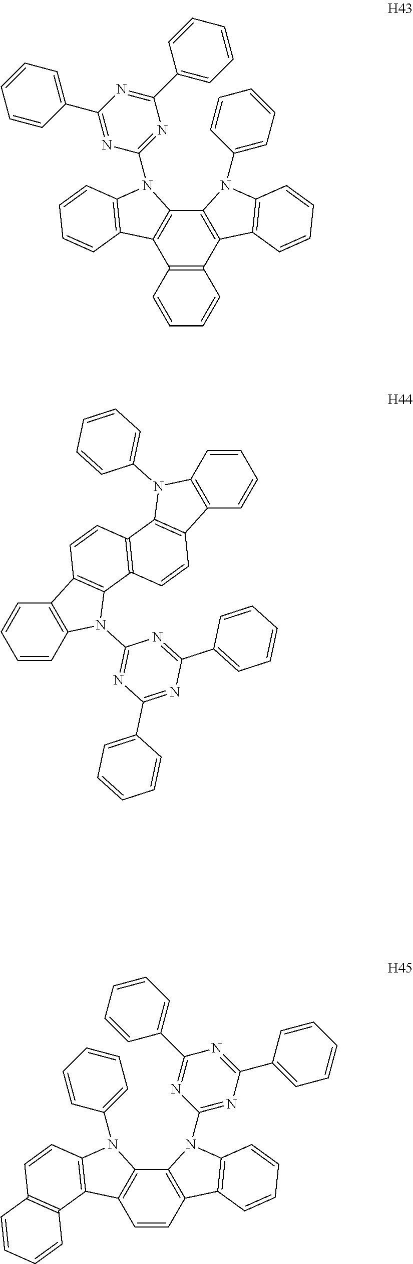 [SMILES: c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1]

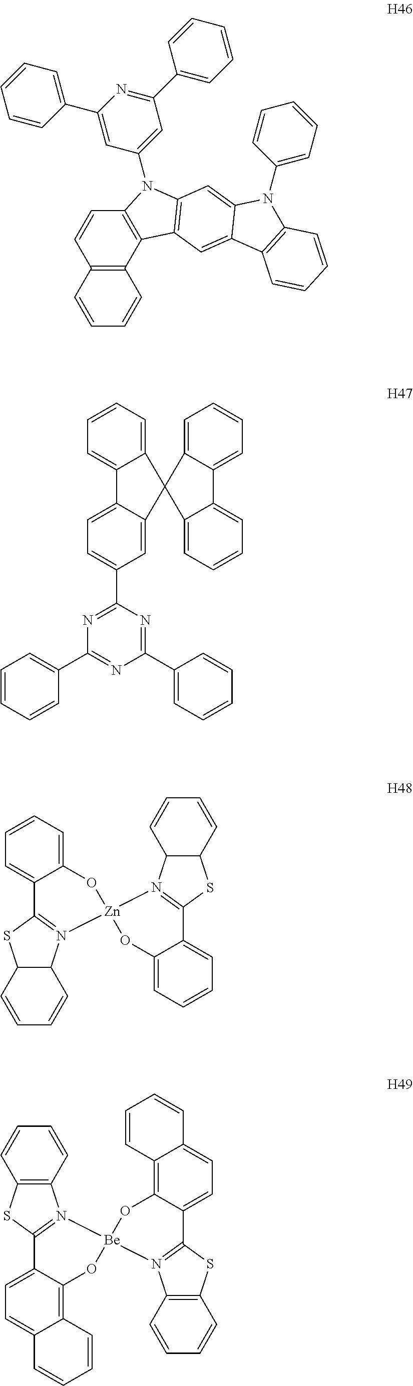

The EML may further include a dopant. The dopant may include at least one phosphorescent dopant.

The phosphorescent dopant may include at least one organic metal, e.g., organometallic, complex represented by Formula 401 below.

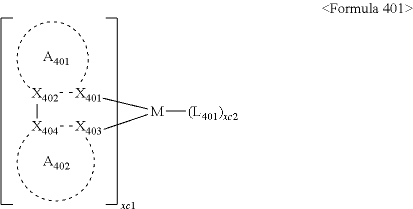

In Formula 401,

M may be selected from iridium (Ir), platinum (Pt), osmium (Os), titanium (Ti), zirconium (Zr), hafnium (Hf), europium (Eu), terbium (Tb), and thulium (Tm);

X₄₀₁ to X₄₀₄ may be each independently nitrogen or carbon;

A₄₀₁ ring and A₄₀₂ ring may be each independently selected from a substituted or unsubstituted benzene group, a substituted or unsubstituted naphthalene group, a substituted or unsubstituted fluorene group, a substituted or unsubstituted spiro-fluorene group, a substituted or unsubstituted indene group, a substituted or unsubstituted pyrrole group, a substituted or unsubstituted thiopene group, a substituted or unsubstituted furan group, a substituted or unsubstituted imidazole group, a substituted or unsubstituted pyrazole group, a substituted or unsubstituted thiazole group, a substituted or unsubstituted isothiazole group, a substituted or unsubstituted oxazole group, a substituted or unsubstituted isooxazole group, a substituted or unsubstituted pyridine group, a substituted or unsubstituted pyrazine group, a substituted or unsubstituted pyrimidine group, a substituted or unsubstituted pyridazine, a substituted or unsubstituted quinoline group, a substituted or unsubstituted isoquinoline group, a substituted or unsubstituted benzoquinoline group, a substituted or unsubstituted quinoxaline group, a substituted or unsubstituted quinazoline group, a substituted or unsubstituted carbazole group, a substituted or unsubstituted benzoimidazole group, a substituted or unsubstituted benzofuran group, a substituted or unsubstituted benzothiopene group, a substituted or unsubstituted isobenzothiopene group, a substituted or unsubstituted benzooxazole group, a substituted or unsubstituted isobenzooxazole group, a substituted or unsubstituted triazole, a substituted or unsubstituted oxadiazole, a substituted or unsubstituted triazine, a substituted or unsubstituted dibenzofuran group, and a substituted or unsubstituted dibenzothiopene;

at least one substituent of the substituted benzene group, the substituted naphthalene group, the substituted fluorene group, the substituted spiro-fluorene group, the substituted indene group, the substituted pyrrole group, the substituted thiopene group, the substituted furan group, the substituted imidazole group, the substituted pyrazole group, the substituted thiazole group, the substituted isothiazole group, the substituted oxazole group, the substituted isooxazole group, the substituted pyridine group, the substituted pyrazine group, the substituted pyrimidine group, the substituted pyridazine, the substituted quinoline group, the substituted isoquinoline group, the substituted benzoquinoline group, the substituted quinoxaline group, the substituted quinazoline group, the substituted carbazole group, the substituted benzoimidazole group, the substituted benzofuran group, the substituted benzothiopene group, the substituted isobenzothiopene group, the substituted benzooxazole group, the substituted isobenzooxazole group, the substituted triazole, the substituted oxadiazole, the substituted triazine, the substituted dibenzofuran group, and the substituted dibenzothiopene group may be selected from

deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a non-aromatic condensed polycyclic group(non-aromatic condensed polycyclic group), —N(Q₄₀₁)(Q₄₀₂), —Si(Q₄₀₃)(Q₄₀₄)(Q₄₀₅), and —B(Q₄₀₆)(Q₄₀₇);

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, and a non-aromatic condensed polycyclic group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, and a non-aromatic condensed polycyclic group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a non-aromatic condensed polycyclic group, —N(Q₄₁₁)(Q₄₁₂), —Si(Q₄₁₃)(Q₄₁₄)(Q₄₁₅), and —B(Q₄₁₆)(Q₄₁₇); and

—N(Q₄₂₁)(Q₄₂₂), —Si(Q₄₂₃)(Q₄₂₄)(Q₄₂₅), and —B(Q₄₂₆)(Q₄₂₇);

L₄₀₁ may be an organic ligand;

xc1 may be 1, 2, or 3; and

xc2 may be 0, 1, 2, or 3.

The L₄₀₁ may be any one selected from a monovalent, a divalent, or a trivalent organic ligand. For example, the L₄₀₁ may be a halogen ligand (for example, Cl or F), a diketone ligand (for example, acetylacetate, 1,3-diphenyl-1,3-propanedionate, 2,2,6,6-tetramethyl-3,5-heptanedionate, and hexafluoroacetonate), a carboxylic acid ligand (for example, picolinate, dimethyl-3-pyrazolecarboxylate, benzoate), a carbon monoxide ligand, an isonitrile ligand, a cyano ligand, and a phosphorus ligand (for example, phosphine, phosphaite, but it is not limited thereto.

In Formula 401, when A₄₀₁ includes two or more substituents, two or more substituents of A₄₀₁ may bind to each other to form a saturated or an unsaturated ring.

In Formula 401, when A₄₀₂ includes two or more substituents, the two or more substituents of A₄₀₂ may bind to each other to form a saturated ring or an unsaturated ring.

In Formula 401, when xc1 is two or greater, a plurality of ligands in Formula 401

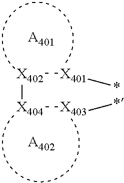

may be the same or different. When xc1 in Formula 401 is two or greater, neighboring ligands of A₄₀₁ and A₄₀₂ may be respectively connected to ligands of neighboring A₄₀₁ and A₄₀₂, directly or via a linker (for example, a C₁-C₅ alkylene group, —N(R′)-(wherein, R′ may be a C₁-C₁₀ alkyl group or a C₆-C₂₀ aryl group), or —C(═O)—) disposed therebetween.

The phosphorescent dopant may include at least one of Compounds PD1 to PD82, but it is not limited thereto.

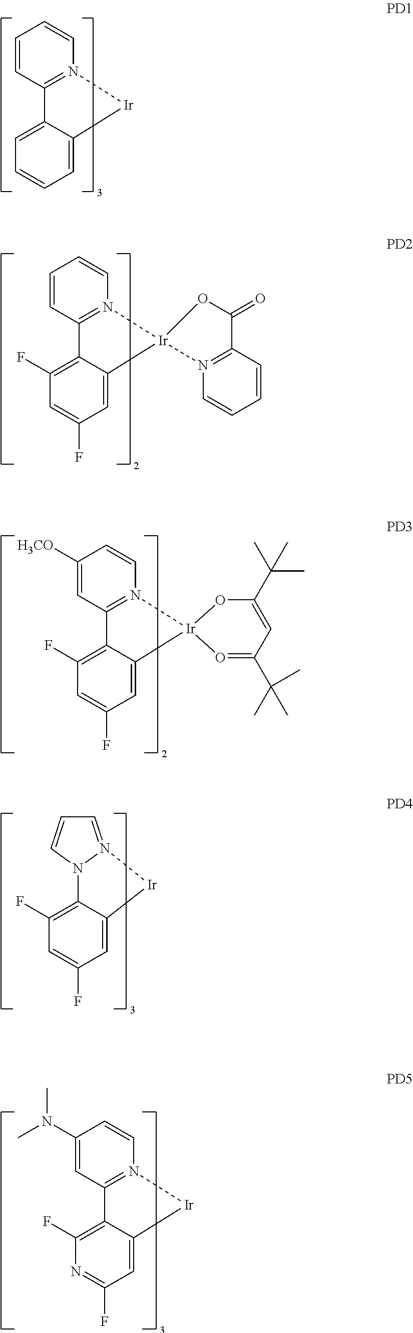

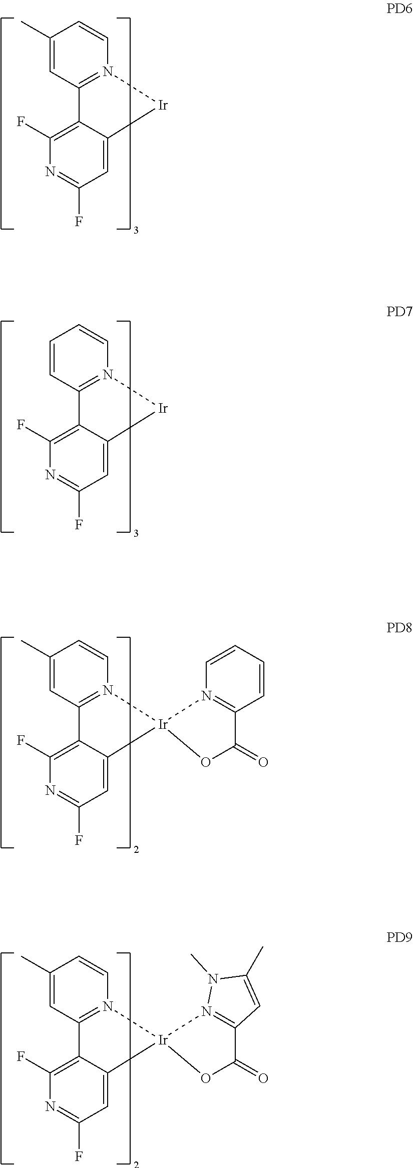

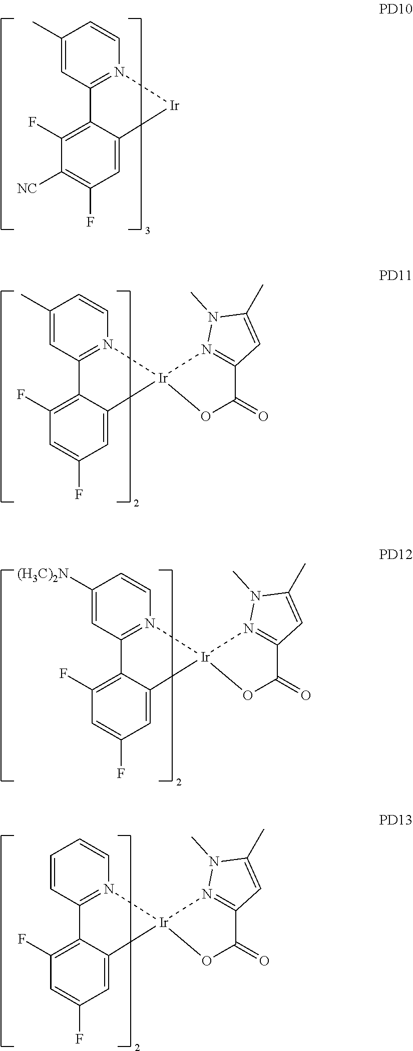

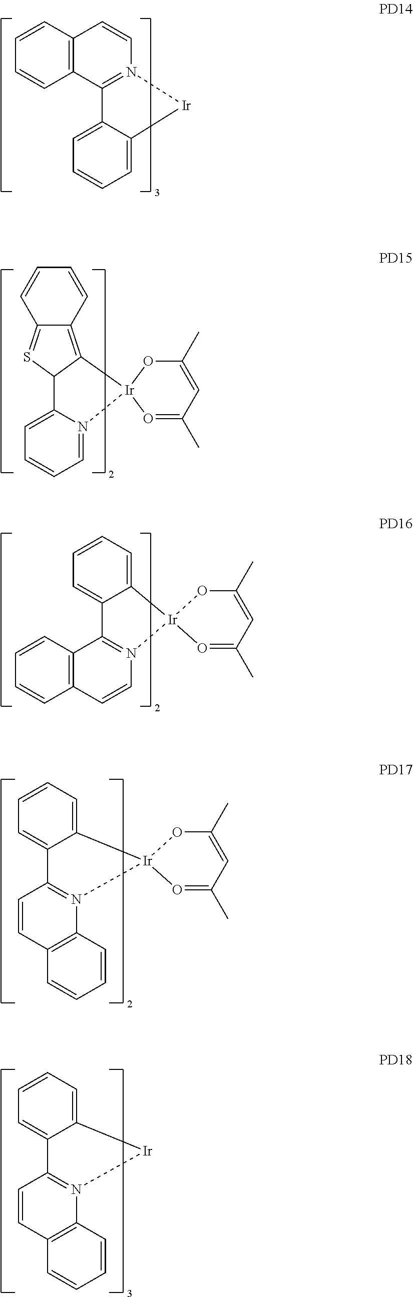

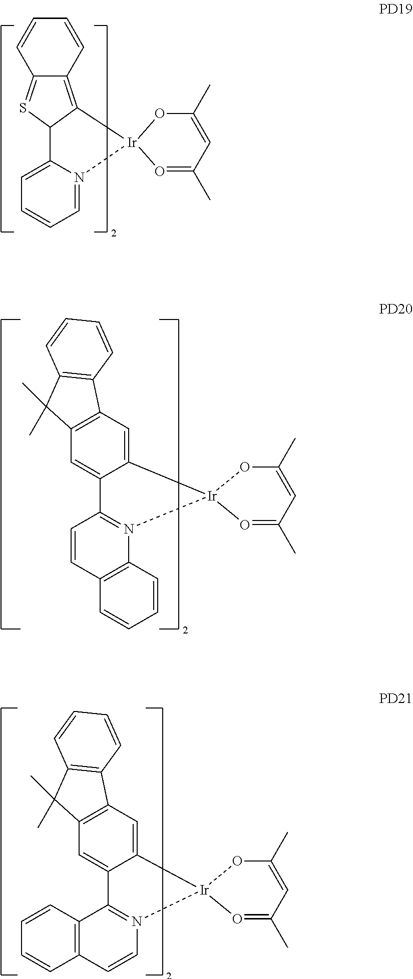

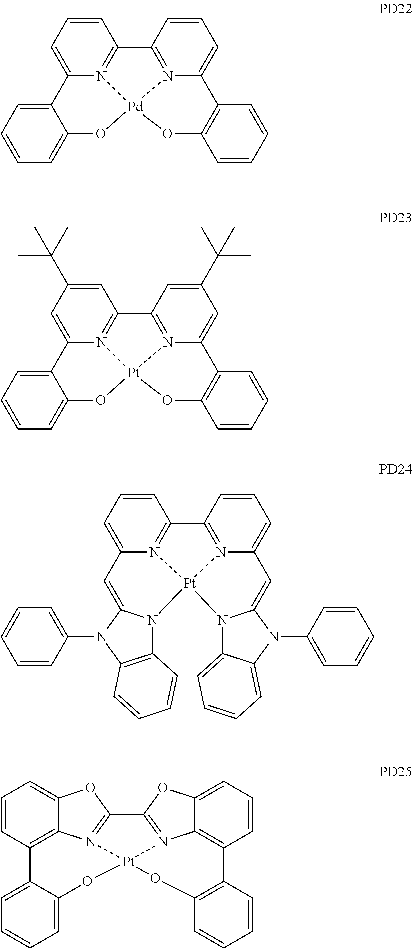

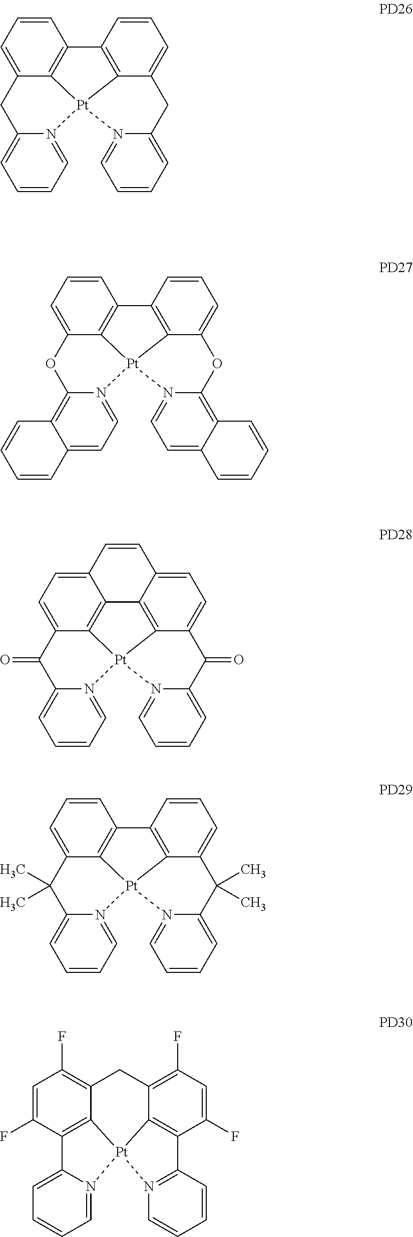

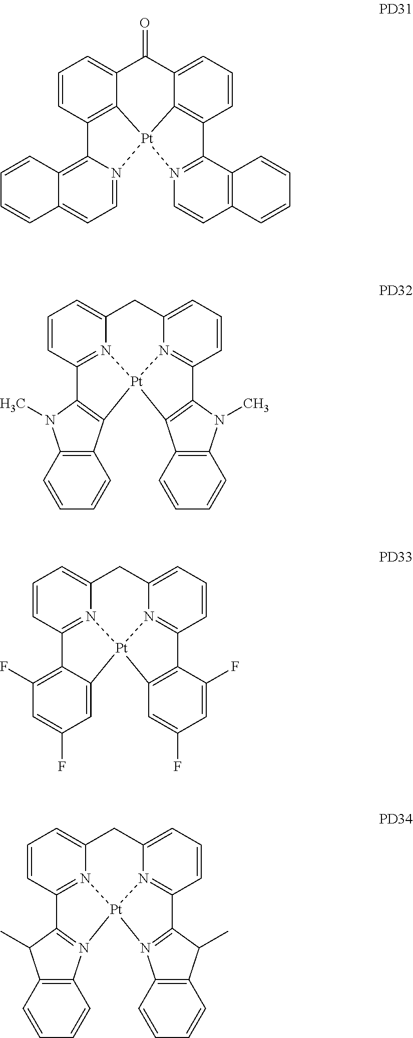

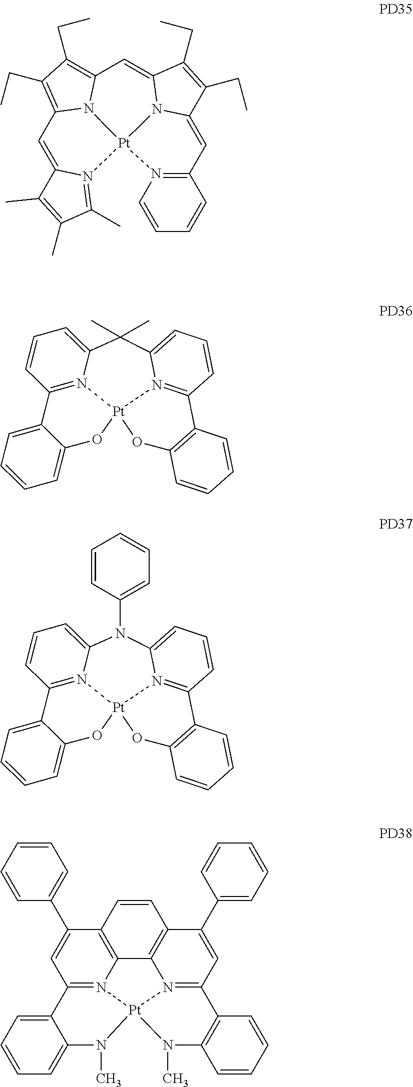

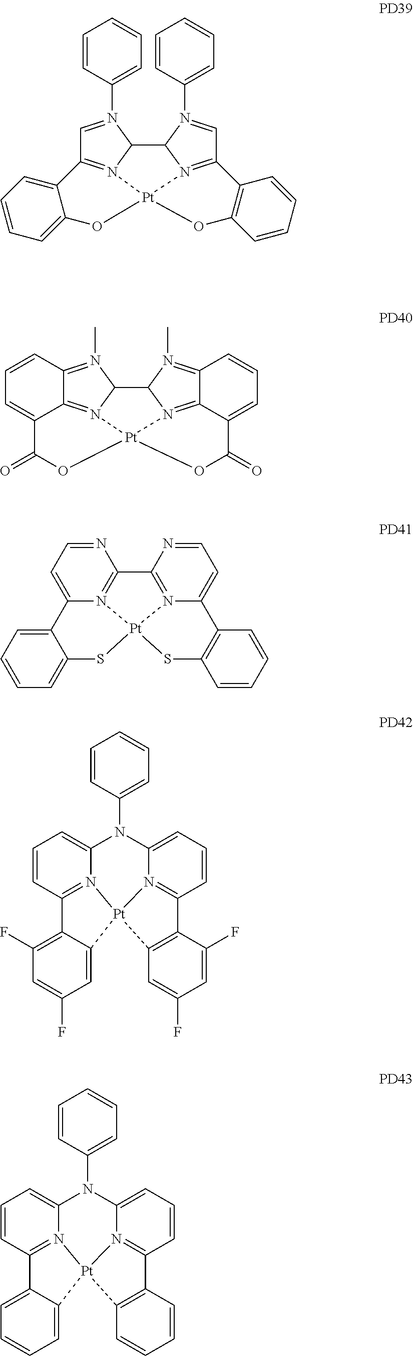

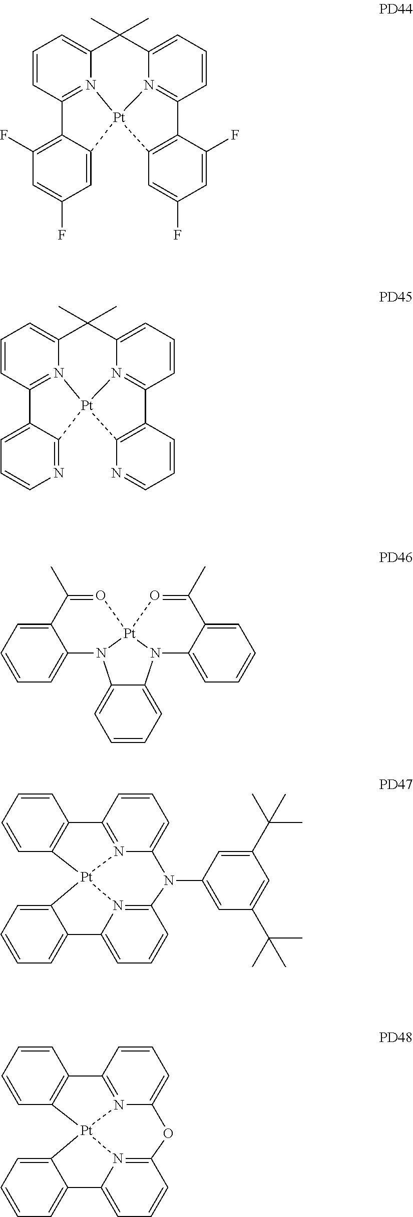

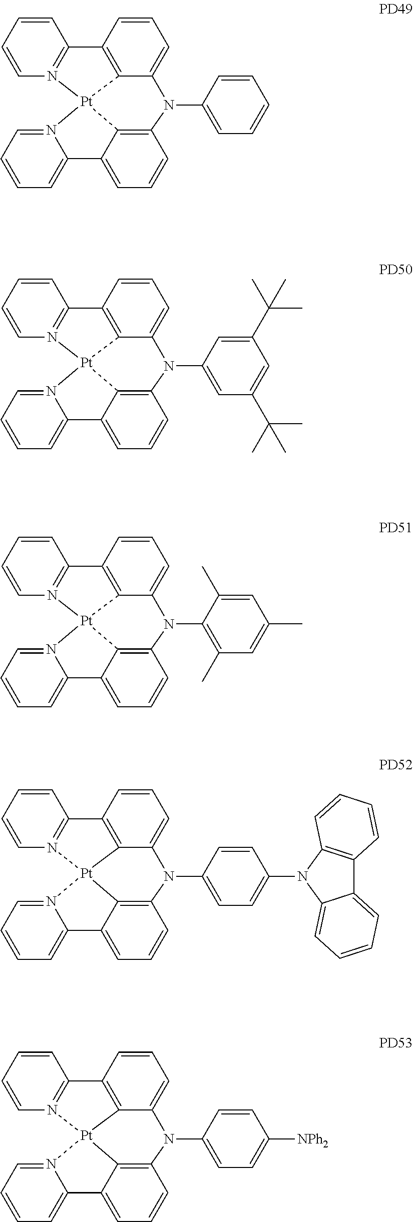

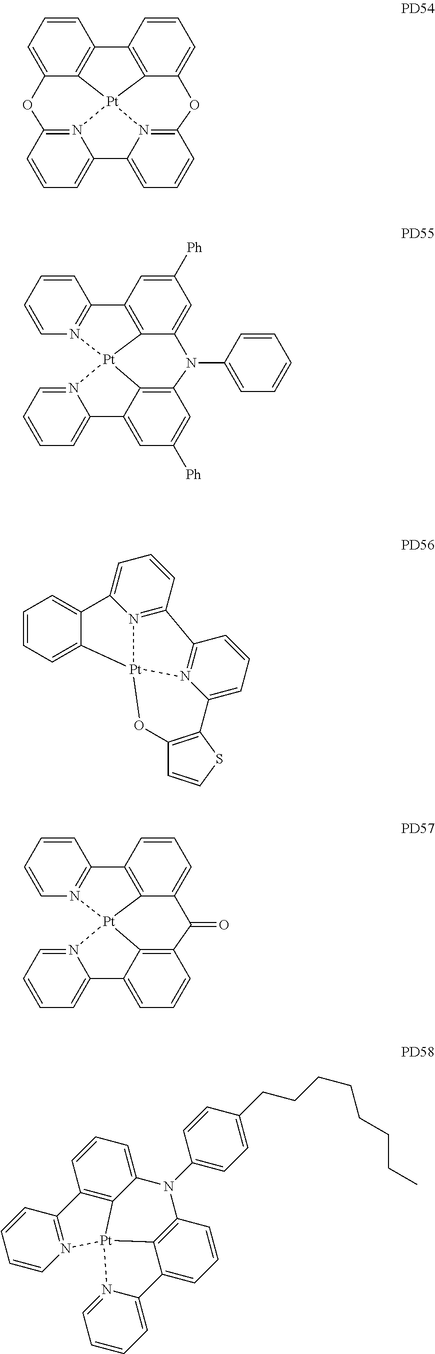

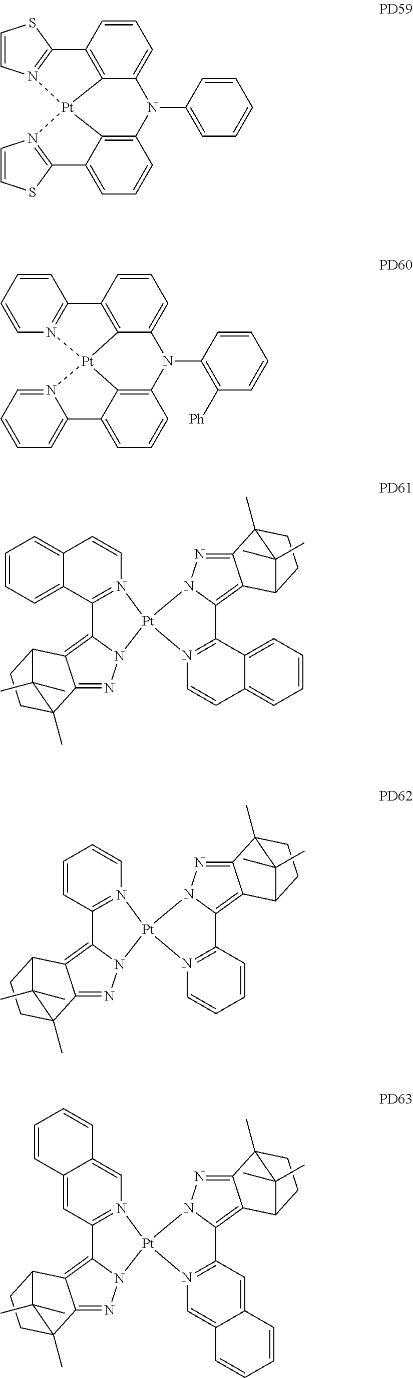

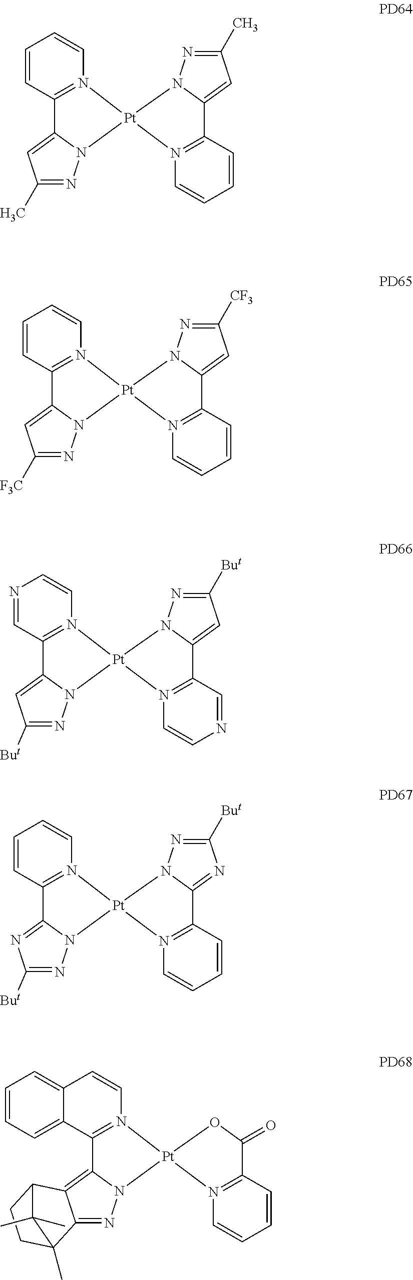

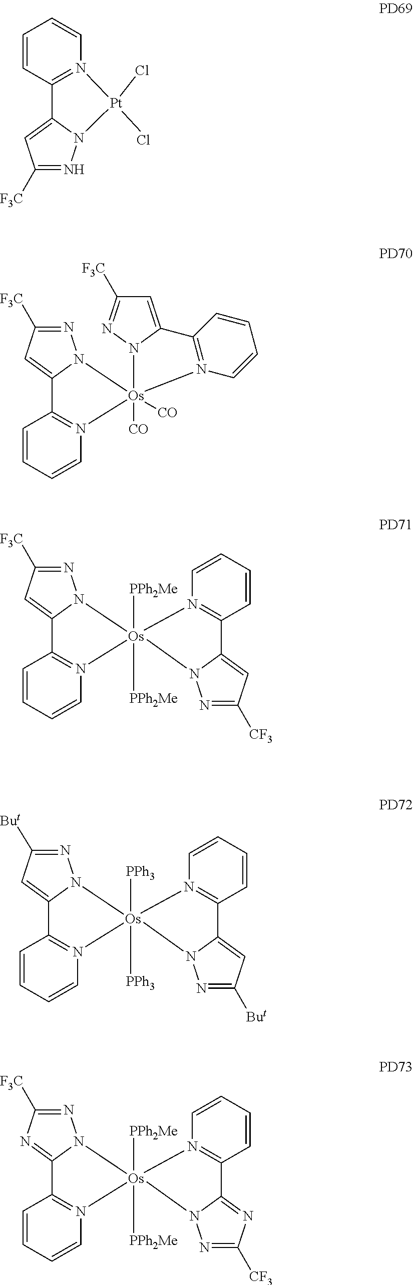

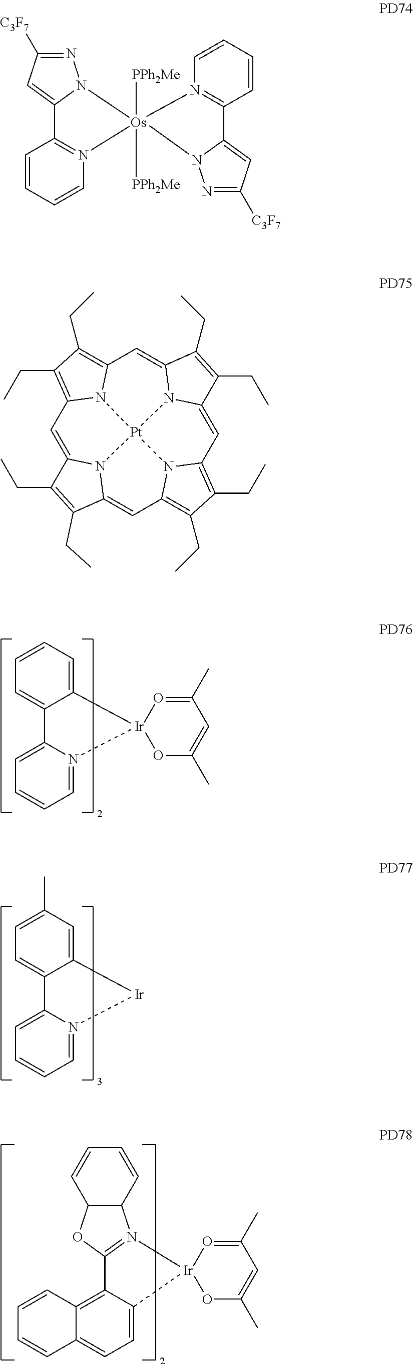

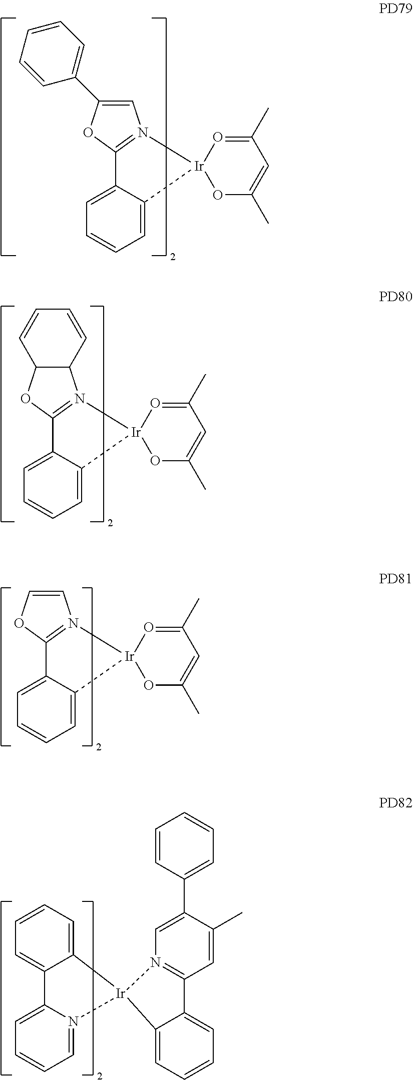

In the EML, an amount of the dopant may generally be about 0.01 parts by weight to about 15 parts by weight based on 100 parts by weight of the host, but it is not limited thereto.

A thickness of the EML may be about 100 Å to about 1000 Å, for example, about 200 Å to about 600 Å. When the thickness of the EML is in the range described above, the EML may have excellent light-emitting ability without a substantial increase in driving voltage.

The electron transport region may be disposed on the EML.

The electron transport region may include at least one of the HBL, the ETL, and EIL, but it is not limited thereto.

For example, the electron transport region may have a structure in which the ETL/EIL or HBL/ETL/EIL are sequentially layered on the EML, but it is not limited thereto.

The electron transport region may include an HBL. When the EML includes a phosphorescent dopant, the HBL may be formed to help prevent diffusion of triplet excitons or holes into the ETL.

When the electron transport region includes the HBL, the HBL may be formed on the EML by using various methods such as vacuum deposition, spin coating, casting, LB, inkjet printing, laser printing, and LITI. When the HBL is formed by vacuum deposition and spin coating, the deposition and coating conditions may be similar to those for forming the HIL, though the deposition and coating conditions may vary according to a compound that is used to form the HBL.

The HBL may include, for example, at least one of BCP and Bphen below, but it is not limited thereto.

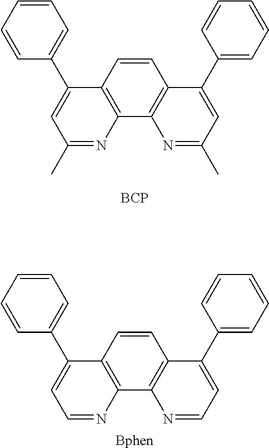

A thickness of the HBL may be from about 20 Å to about 1,000 Å, and in some embodiments, may be from about 30 Å to about 300 Å. When the thickness of the HBL is within these ranges, the HBL may have a hole blocking transporting ability without a substantial increase in driving voltage.

The electron transport region may include an ETL. The ETL may be formed on the EML or the HBL by using various methods such as vacuum deposition, spin coating, casting, LB, inkjet printing, laser printing, and LITI. When the ETL is formed by vacuum deposition and spin coating, the deposition and coating conditions may be similar to those for forming the HIL, though the deposition and coating conditions may vary according to a compound that is used to form the ETL.

The ETL may include at least one selected from the BCP, Bphen, and Alq₃, Balq, TAZ, and NTAZ illustrated below.

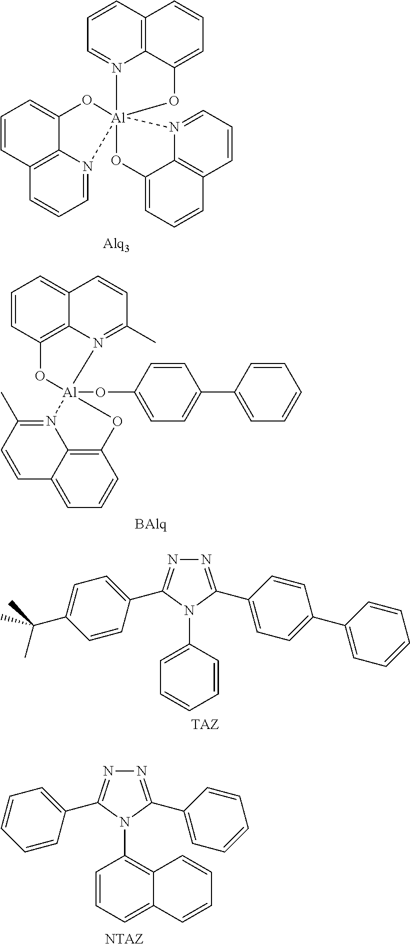

In an implementation, the ETL may include at least one compound represented by Formula 601:

Ar₆₀₁-[(L₆₀₁)ₓₑ₁-E₆₀₁]ₓₑ₂ <Formula 601>

In Formula 601,

Ar₆₀₁ may be selected from

a naphthalene group, a heptalene group, a fluorene group, a spiro-fluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, and an indenoanthracene group; and

a naphthalene group, a heptalene group, a fluorene group, a spiro-fluorene group, a benzofluorene group, a dibenzofluorene group, a phenalene group, a phenanthrene group, an anthracene group, a fluoranthene group, a triphenylene group, a pyrene group, a chrysene group a naphthacene group, a picene group, a perylene group, a pentaphene group, and an indenoanthracene group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a non-aromatic condensed polycyclic group, and —Si(Q₃₀₁)(Q₃₀₂)(Q₃₀₃) (wherein, Q₃₀₁ to Q₃₀₃ may be each independently selected from a hydrogen, a C₁-C₆₀ alkyl group, a C₂-C₆₀ alkenyl group, a C₆-C₆₀ aryl group, and a C₂-C₆₀ heteroaryl group);

description of L₆₀₁ may be as the description of L₂₀₁;

E₆₀₁ may be selected from a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group; and

a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a pentalenyl group, an indenyl, a naphthyl group, an azulenyl, a heptalenyl, an indacenyl, an acenaphthyl group, a fluorenyl group, a spiro-fluorenyl group, a benzofluorenyl group, a dibenzofluorenyl group, a phenalenyl, a phenanthrenyl group, an anthracenyl group, a fluoranthenyl, a triphenylenyl, a pyrenyl group, a chrysenyl group, a naphthacenyl, a picenyl, a perylenyl, a pentaphenyl group, a hexacenyl, a pentacenyl, a rubicenyl, a coronenyl, an ovalenyl, a pyrrolyl, a thiophenyl group, a furanyl, an imidazolyl, a pyrazolyl, a thiazolyl, an isothiazolyl, an oxazolyl, an isooxazolyl, a pyridinyl group, a pyrazinyl group, a pyrimidinyl group, a pyridazinyl group, an isoindolyl group, an indolyl, an indazolyl, a purinyl, a quinolinyl group, an isoquinolinyl group, a benzoquinolinyl group, a phthalazinyl, a naphthyridinyl, a quinoxalinyl group, a quinazolinyl group, a cinnolinyl, a carbazolyl, a phenanthridinyl, an acridinyl, a phenanthrolinyl, a phenazinyl, a benzoimidazolyl, a benzofuranyl, a benzothiophenyl group, an isobenzothiazolyl, a benzooxazolyl, an isobenzooxazolyl, a triazolyl, a tetrazolyl, an oxadiazolyl, a triazinyl, a dibenzofuranyl, a dibenzothiophenyl group, a benzocarbazolyl group, and a dibenzocarbazolyl group;

xe1 may be selected from 0, 1, 2, and 3; and

xe2 may be selected from 1, 2, 3, and 4.

Alternatively, the ETL may further include at least one compound represented by Formula 602, in addition to an amine-based compound represented by Formula 1:

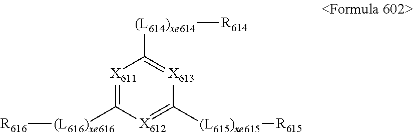

In Formula 602,

X₆₁₁ may be N or C-(L₆₁₁)ₓₑ₆₁₁-R₆₁₁, X₆₁₂ may be N or C-(L₆₁₂)ₓₑ₆₁₂-R₆₁₂, X₆₁₃ may be N or C-(L₆₁₃)ₓₑ₆₁₃-R₆₁₃, and at least one of X₆₁₁ to X₆₁₃ may be N;

descriptions of each of L₆₁₁ to L₆₁₆ may be as the description of L₂₀₁ herein;

R₆₁₁ to R₆₁₆ may be each independently selected from a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, an azulenyl, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

xe611 to xe616 may be each independently selected from 0, 1, 2, and 3.

The compound represented by Formula 601 and the compound represented by Formula 602 may include at least one of Compounds ET1 to ET15.

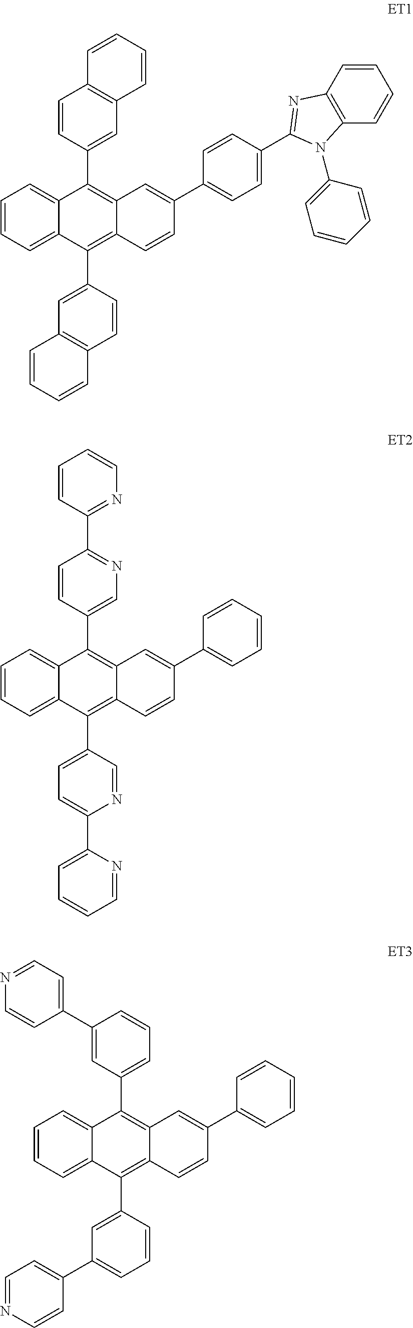 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

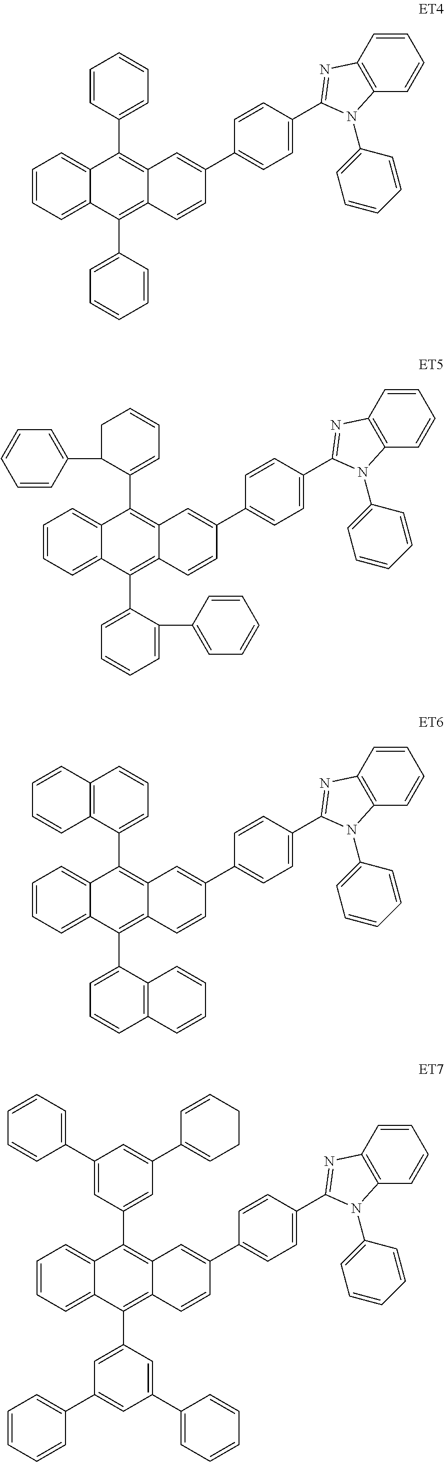 [SMILES: c1ccc(-c2c3ccccc3c(-c3ccccc3)c3cc(-c4ccc(-c5nc6ccccc6n5-c5ccccc5)cc4)ccc23)cc1 ; C1=CCC(c2ccccc2)C(c2c3ccccc3c(-c3ccccc3-c3ccccc3)c3ccc(-c4ccc(-c5nc6ccccc6n5-c5ccccc5)cc4)cc23)=C1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; C1=CC(c2cc(-c3ccccc3)cc(-c3c4ccccc4c(-c4cc(-c5ccccc5)cc(-c5ccccc5)c4)c4ccc(-c5ccc(-c6nc7ccccc7n6-c6ccccc6)cc5)cc34)c2)=CCC1]

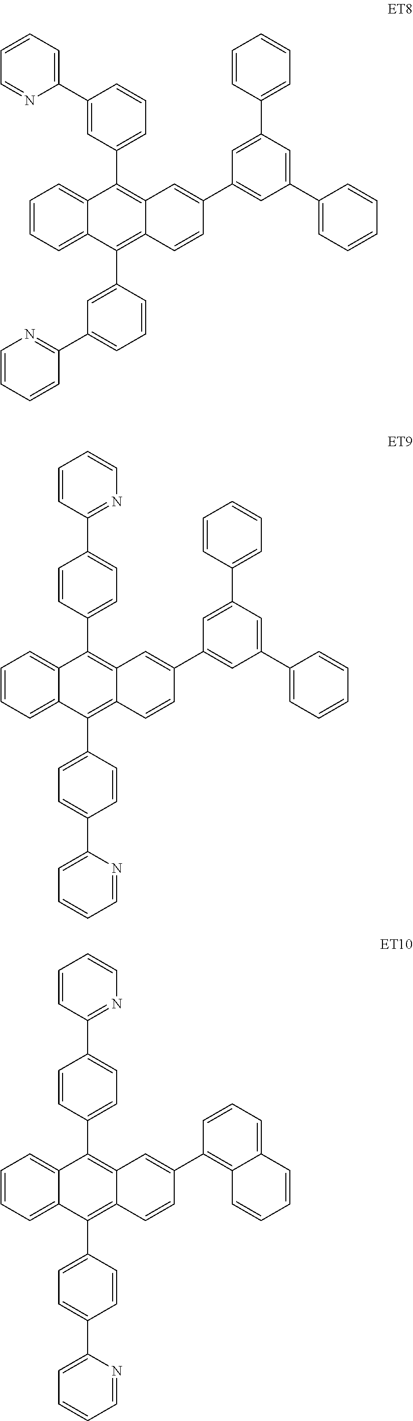

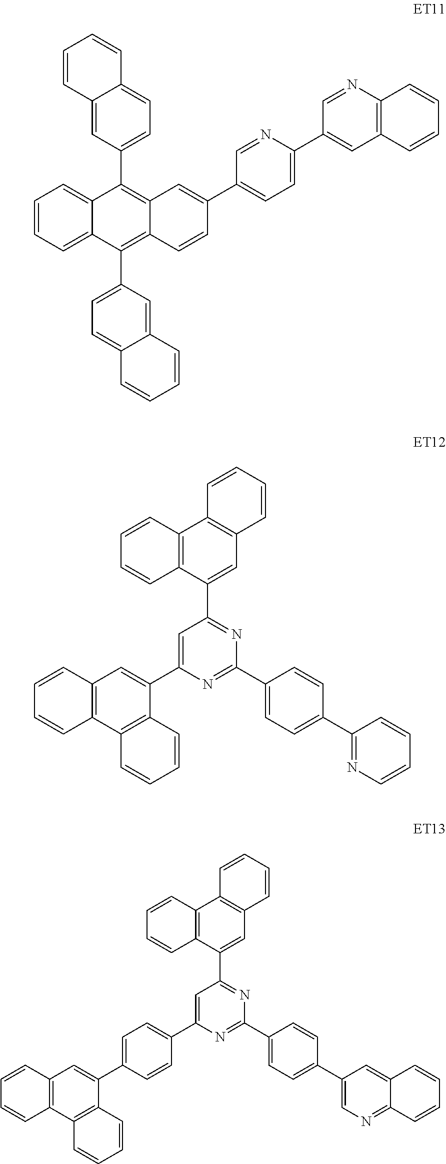 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1]

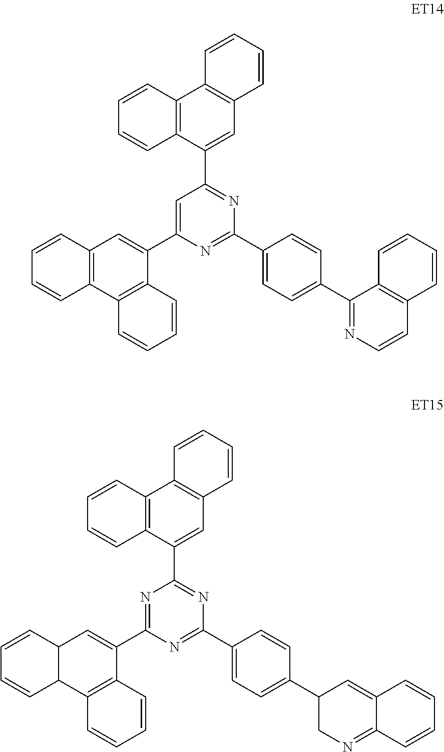 [SMILES: c1ccc2c(-c3ccc(-c4nc(-c5cc6ccccc6c6ccccc56)cc(-c5cc6ccccc6c6ccccc56)n4)cc3)nccc2c1 ; C1=CC2C=C(c3nc(-c4ccc(C5C=c6ccccc6=NC5)cc4)nc(-c4cc5ccccc5c5ccccc45)n3)c3ccccc3C2C=C1]

A thickness of the ETL may be about 100 Å to about 1000 Å, for example, about 150 Å to about 500 Å. When the thickness of the ETL is within the range described above, the ETL may have satisfactory electron transport characteristics without a substantial increase in driving voltage.

The ETL may further include a metal-containing material in addition to the material described above.

The metal-containing material may include a Li complex. The Li complex may, for example, include compounds ET-D1 (lithium quinolate: LiQ) or ET-D2 illustrated below.

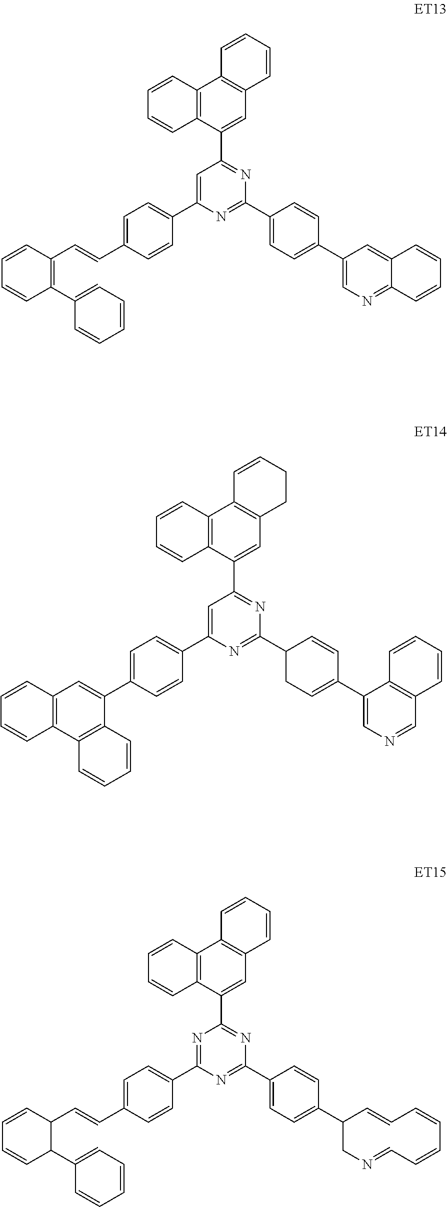 [SMILES: C(=C\c1ccccc1-c1ccccc1)/c1ccc(-c2cc(-c3cc4ccccc4c4ccccc34)nc(-c3ccc(-c4cnc5ccccc5c4)cc3)n2)cc1 ; C1=Cc2c(cc(-c3cc(-c4ccc(-c5cc6ccccc6c6ccccc56)cc4)nc(C4C=CC(c5cncc6ccccc56)=CC4)n3)c3ccccc23)CC1 ; C1=CC(/C=C/c2ccc(-c3nc(-c4ccc(C5/C=C/C=C\C=C/C=N/C5)cc4)nc(-c4cc5ccccc5c5ccccc45)n3)cc2)C(c2ccccc2)C=C1]

The electron transport region may include an EIL that facilitates electron injection from the second electrode 190.

The EIL may be formed on the ETL by using various methods such as vacuum deposition, spin coating, casting, LB, inkjet printing, laser printing, and LITI. When the EIL is formed by vacuum deposition or spin coating, the deposition and coating conditions may be similar to those for forming the HIL. When the EIL is formed using vacuum deposition or spin coating, the deposition and coating conditions may be similar to those for the formation of the HIL.

The EIL may include at least one selected from LiF, NaCl, CsF, Li₂O, BaO, and LiQ. When the thickness of the EIL is within the range described above, satisfactory electron injection characteristics may be obtained without a substantial increase in driving voltage.

A thickness of the EIL may be about 1 Å to about 100 Å or about 3 Å to about 90 Å.

The second electrode 190 is disposed on the organic layer 150 described above. The second electrode 190 may be a cathode, which is an electron injection electrode, in which a material of the second electrode 190 may be a metal, an alloy, an electroconductive compound, or a mixture thereof having a low work function. Detailed examples of the material of the second electrode 190 include lithium (Li), magnesium (Mg), aluminum (Al), aluminum-lithium (Al—Li), calcium (Ca), magnesium-indium (Mg—In), and magnesium-silver (Mg—Ag). Alternatively, ITO, IZO, or the like may be used as the material of the second electrode 190. The second electrode 190 may be a reflective electrode, a semi-transmission electrode, or a transmission electrode.

Hereinabove, the organic light-emitting device is described with reference to FIG. 1, but it is not limited thereto.

As used herein, the C₁-C₆₀ alkyl group refers to a linear or aliphatic C₁-C₆₀ hydrocarbon monovalent group and detailed examples thereof include a methyl group, an ethyl group, a propyl group, an isobutyl group, a sec-butyl group, a tert-butyl group, a pentyl group, an iso-amyl group, and a hexyl group. As used herein, the C₁-C₆₀ alkylene group refers to a divalent group having the same structure as the C₁-C₆₀ alkyl group.

As used herein, the C₁-C₆₀ alkoxy group is a monovalent group having a formula of -OA₁₀₁ (wherein, A₁₀₁ is the C₁-C₆₀ alkyl group) and detailed examples thereof include a methoxy group, an ethoxy group, and an isopropyloxy group.

As used herein, the C₂-C₆₀ alkenyl group (or C₂-C₆₀ alkenyl group) refers to a C₂-C₆₀ alkyl group having one or more carbon-carbon double bonds at a center or end thereof. Examples of the unsubstituted C₂-C₆₀ alkenyl group are an ethenyl group, a propenyl group, and a butenyl group. As used herein, the C₂-C₆₀ alkenylene group refers to a divalent group having the same structure as the C₂-C₆₀ alkenyl group.

As used herein, the C₂-C₆₀ alkynyl group refers to an unsubstituted C₂-C₆₀ alkyl group having one or more carbon-carbon triple bonds at a center or end thereof. Examples of the C₂-C₆₀ alkynyl group are an ethynyl group, a propynyl group, and the like. As used herein, the C₂-C₆₀ alkynylene group refers to a divalent group having the same structure as the C₂-C₆₀ alkynyl group.

As used herein, the C₃-C₁₀ cycloalkyl group refers to a C₃-C₁₀ monovalent hydrocarbon monocyclic group and detailed examples thereof include a cyclopropyl group, a cyclobutyl group, a cyclopentyl group, a cyclohexyl group, and a cycloheptyl group. As used herein, the C₃-C₁₀ cycloalkylene group refers to a divalent group having the same structure as the C₃-C₁₀ cycloalkyl group.

As used herein, the C₃-C₁₀ heterocycloalkyl group refers to a C₃-C₁₀ monovalent monocyclic group including at least one selected from N, O, P, and S as a ring-forming atom and detailed examples thereof include a tetrahydrofuranyl group and a tetrahydrothiophenyl group. As used herein, the C₃-C₁₀ heterocycloalkylene group refers to a divalent group having the same structure as the C₃-C₁₀ heterocycloalkyl group.

As used herein, the C₃-C₁₀ cycloalkenyl group refers to a C₃-C₁₀ monovalent monocyclic group having at least one double bond in a ring but without aromaticity, and detailed examples thereof include a cyclopentenyl group, a cyclohexenyl group, and a cycloheptenyl group. As used herein, the C₃-C₁₀ cycloalkenylene group refers to a divalent group having the same structure as the C₃-C₁₀ cycloalkenyl group.

As used herein, the C₃-C₁₀ heterocycloalkenyl group is a C₃-C₁₀ monovalent monocyclic group including at least one selected from N, O, P, and S as a ring-forming atom, and includes at least one double bond in a ring. Detailed examples of the C₃-C₁₀ heterocycloalkenyl group include a 2,3-hydrofuranyl group and a 2,3-hydrothiophenyl group. As used herein, the C₃-C₁₀ heterocycloalkenylene group is a divalent group having the same structure as the C₃-C₁₀ heterocycloalkenyl group.

As used herein, the C₆-C₆₀ aryl group is a C₆-C₆₀ monovalent group having a carbocyclic aromatic system and the C₆-C₆₀ arylene group refers to a divalent group having a C₆-C₆₀ carbocyclic aromatic system. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group include two or more rings, the two or more rings may be fused to each other.

As used herein, the C₂-C₆₀ heteroaryl group refers to a monovalent group having a C₂-C₆₀ carbocyclic aromatic system including at least one heteroatom selected from N, O, P, and S as a ring-forming atom and the C₂-C₆₀ heteroarylene group refers to a divalent group having a C₂-C₆₀ carbocyclic aromatic system including at least one heteroatom selected from N, O, P, and S. Examples of the C₂-C₆₀ heteroaryl group include a pyridinyl group, a pyrimidinyl group, a pyrazinyl group, a pyridazinyl group, a triazinyl group, a quinolinyl group, and an isoquinolinyl group. When the C₂-C₆₀ heteroaryl group and the C₂-C₆₀ heteroarylene group include two or more rings, the two or more rings may be fused to each other.

As used herein, the C₆-C₆₀ aryloxy group refers to -OA₁₀₂ (wherein, A₁₀₂ is the C₆-C₆₀ aryl group) and the C₆-C₆₀ arythio group refers to -SA₁₀₃ (wherein, A₁₀₃ is the C₆-C₆₀ aryl group).

As used herein, the monovalent non-aromatic condensed polycyclic group refers to a monovalent group having two or more rings that are fused to each other, including only carbon as a ring forming atom, wherein the entire molecule does not have aromacity. Examples of the non-aromatic condensed polycyclic group include a fluorenyl group or the like. As used herein, the divalent non-aromatic condensed polycyclic group may refer to a divalent group having the same structure as the monovalent non-aromatic condensed polycyclic group.

As used herein, the monovalent non-aromatic hetero-condensed polycyclic group refers to a monovalent group having two or more rings that are fused to each other, including a heteroatom selected from N, O, P, and S as a ring-forming atom, in addition to carbon, wherein the entire molecule does not have aromaticity. The monovalent non-aromatic hetero-condensed polycyclic group includes a carbazolyl group or the like. As used herein, the divalent non-aromatic hetero-condensed polycyclic group refers to a divalent group having the same structure as the monovalent non-aromatic hetero-condensed polycyclic group.

As used herein, the term “Ph” refers to a phenyl group, the term “Me” refers to a methyl group, the term “Et” refers to an ethyl group, and the term “ter-Bu” or “Bu^{t}” refers to a tert-butyl group.

Hereinafter, an organic light-emitting device according to an embodiment will be described in detail with reference to Synthesis Examples and Examples. Hereinafter, the expression “A was used instead of B” in the Synthesis Examples refers to the fact that a molar amount of A is the same as a molar amount of B.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE

### Example 1

As an anode, a glass substrate in which ITO/Ag/ITO was deposited in a thickness of 70 Å/1000 Å/70 Å was cut into a size of about 50 mm×50 mm×0.4 mm, ultrasonically washed with isopropyl alcohol and pure water for 10 minutes each, irradiated with UV for 10 minutes, exposed to ozone, and then loaded onto a vacuum deposition device.

HT13 was deposited on the anode to form an HIL having a thickness of 700 Å, HT3 was deposited thereon to form an HTL having a thickness of 800 Å, and then Compound 201A (host), Compound 103 (host), and Compound PD82 (dopant) were co-deposited on the HTL at a weight ratio of 50:50:15 to form an EML. Thereafter, ET1 and LiQ were vacuum-deposited at a weight ratio of 100:100 to form an ETL having a thickness of 360 Å, Liq was deposited on the ETL to form an EIL having a thickness of 10 Å, and then Mg:Ag were deposited on the EIL at a weight ratio of 90:10 to form a cathode having a thickness of 120 Å, to thereby manufacture an organic light-emitting device.

### Example 2

An organic light-emitting device was manufactured in the same manner as in Example 1, except that Compound 218A was used instead of Compound 201A and Compound 237 was used instead of Compound 103 for forming the EML.

### Example 3

An organic light-emitting device was manufactured in the same manner as in Example 1, except that Compound 201A and Compound 103 were deposited at a weight ratio of 70:30 for forming the EML.

### Example 4

An organic light-emitting device was manufactured in the same manner as in Example 2, except that Compound 218A and Compound 237 were deposited at a weight ratio of 70:30 for forming the EML.

### Comparative Example 1

An organic light-emitting device was manufactured in the same manner as in Example 1, except that Compound 103 was not used and Compound 201A and Compound PD82 were co-deposited at a weight ratio of 100:15.

### Comparative Example 2

An organic light-emitting device was manufactured in the same manner as in Example 1, except that Compound 201A was not used and Compound 103 and Compound PD82 were co-deposited at a weight ratio of 100:15.

### Comparative Example 3

An organic light-emitting device was manufactured in the same manner as in Example 1, except that Compound A and Compound B were used for forming the EML.

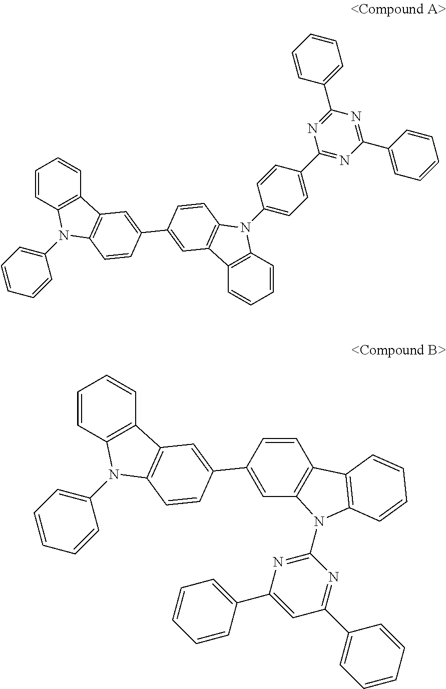 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1]

### Evaluation Example 1

Driving voltages, current densities, brightness, emission colors, efficiencies, color coordinates, and lifespans (@10 mA/cm²) of the organic light-emitting devices manufactured in Examples 1 to 4 and Comparative Examples 1 to 3 were evaluated by using a PR650 Spectroscan Source Measurement Unit (a product of PhotoResearch).

The results are as shown in Table 1. Lifespan refers to the time taken until the brightness reached 97% of the initial brightness.

TABLE 1

| | | Driv- | | | | | | |
|---|---|---|---|---|---|---|---|---|
| | | ing | Current | | | | | |
| | | volt- | density | Bright- | Power | | | Life- |
| | | age | (mA/ | ness | (Im/ | CIE_ | CIE_ | span |
| | Host | (V) | cm²) | (cd/A) | W) | x | y | (hr) |
| Exam- | Compound | 4.2 | 10.7 | 84.3 | 63.1 | 0.266 | 0.705 | 165 |
| ple 1 | 201A | | | | | | | |
| | Compound | | | | | | | |
| | 103 | | | | | | | |
| Exam- | Compound | 4.4 | 9.8 | 92.3 | 65.6 | 0.315 | 0.666 | 176 |
| ple 2 | 218A | | | | | | | |
| | Compound | | | | | | | |
| | 237 | | | | | | | |
| Exam- | Compound | 4.7 | 9.3 | 96.9 | 64.1 | 0.268 | 0.704 | 182 |
| ple 3 | 201A | | | | | | | |
| | Compound | | | | | | | |
| | 103 | | | | | | | |
| Exam- | Compound | 5.3 | 9.6 | 93.6 | 55.7 | 0.315 | 0.666 | 203 |
| ple 4 | 218A | | | | | | | |
| | Compound | | | | | | | |
| | 237 | | | | | | | |
| Com- | Compound | 8.0 | 24.4 | 36.8 | 14.5 | 0.269 | 0.701 | 5 |
| par- | 201A | | | | | | | |
| ative | | | | | | | | |
| Exam- | | | | | | | | |
| ple 1 | | | | | | | | |
| Com- | Compound | 3.8 | 12.6 | 71.3 | 59.2 | 0.281 | 0.690 | 23 |
| par- | 103 | | | | | | | |
| ative | | | | | | | | |
| Exam- | | | | | | | | |
| ple 2 | | | | | | | | |
| Com- | Compound | 4.1 | 12.8 | 70.3 | 53.4 | 0.277 | 0.697 | 64 |
| par- | A | | | | | | | |
| ative | Compound | | | | | | | |
| Exam- | B | | | | | | | |
| ple 3 | | | | | | | | |

From Table 1, it may be seen that the organic light-emitting devices manufactured in Examples 1 to 4 had better driving voltages, brightness, efficiencies, color purity, and lifespan properties, compared with the organic light-emitting devices manufactured in Comparative Examples 1 to 3.

By way of summation and review, one of the major factors that may greatly affect the lifespan of an organic light-emitting device is a balance between holes and electrons in the EML. In addition, it may be important to distribute an emission region in the EML without being biased to the HTL or the ETL. However, it may be difficult to satisfy this with only one material. In this regard, good results may be obtained when substituent properties of two materials are different.

According to an embodiment, when the heterocyclic compound includes an electron-transporting cyclic group, the triphenylene-based compound may not include an electron-transporting cyclic group. For example, when the heterocyclic compound includes a triazine group, which is a strong electron-transporting cyclic group, the triphenylene-based compound may have improved efficiency and lifespan properties when it does not include the electron-transporting cyclic group. Also, when the heterocyclic compound includes a triazine group, an amount of the triphenylene-based compound may be greater than an amount of the triphenylene-based compound than when the heterocyclic compound includes a pyridine group or a pyrimidine group, which is a weak electron-transporting cyclic group. As such, an optimal ratio of the two hosts may vary depending on electrical properties of the host.

For example, the triphenylene-based compound may have a wide energy gap when the triphenylene-based compound does not include an electron-transporting cyclic group. Accordingly, the triphenylene-based compound may help effectively adjust electron-transporting properties of the heterocyclic compound including the electron-transporting cyclic group, which has a relatively narrow energy gap. This may help reduce and/or prevent a phenomenon in which the emission region is concentrated at an interface between the hole transport layer and the emission layer, which may greatly improve efficiency and lifespan. Such properties may be identified through the embodiments.

As described above, according to the one or more of the above embodiments, organic light-emitting devices have high efficiencies and long lifespans.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode facing the first electrode; and
an emission layer between the first electrode and the second electrode, wherein:
the emission layer includes a triphenylene-based compound represented by Formula 2, below, and at least one heterocyclic compound selected from compounds represented by Formulae 1A, 1B, 1C, 1D, and 1E, below: 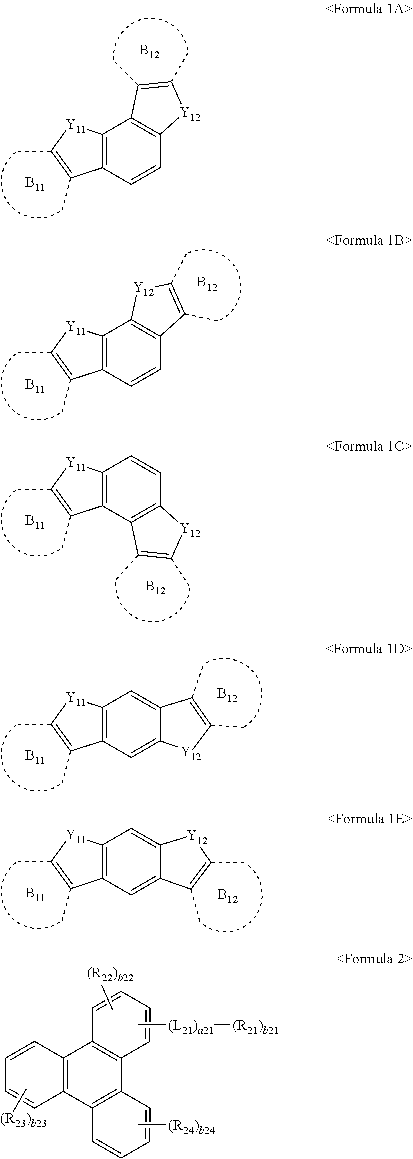
in Formulae 1A, 1B, 1C, 1D, 1E, and 2,
B₁₁ and B₁₂ are each independently selected from:
a benzene group, a naphthalene group, an anthracene group, a pyridine group, a pyrimidine group, a quinoline group, an isoquinoline group, 2,6-naphthyridine group, 1,8-naphthyridine group, 1,5-naphthyridine group, 1,6-naphthyridine group, 1,7-naphthyridine group, 2,7-naphthyridine group, a quinoxaline group, a phthalazine group, and a quinazoline group; and
a benzene group, a naphthalene group, an anthracene group, a pyridine group, a pyrimidine group, a quinoline group, an isoquinoline group, 2,6-naphthyridine group(naphthyridine), 1,8-naphthyridine group, 1,5-naphthyridine group, 1,6-naphthyridine group, 1,7-naphthyridine group, 2,7-naphthyridine group, a quinoxaline group, a phthalazine group, and a quinazoline group, each substituted with at least one selected from deuterium, —F, —Cl, —Br, —I, a C₁-C₆₀ alkyl group, a C₆-C₆₀ aryl group, a C₂-C₆₀ heteroaryl group, and —N(Q₁)(Q₂);
Y₁₁ is N-(L₁₁)ₐ₁₁-R₁₁;
Y₁₂ is N-(L₁₂)ₐ₁₂-R₁₂, an oxygen atom, a sulfur atom, C(R₁₃)(R₁₄), or Si(R₁₃)(R₁₄);
L₁₁, L₁₂, and L₂₁ are each independently selected from:
a C₃-C₁₀ cycloalkylene group, a C₃-C₁₀ heterocycloalkylene group, a C₃-C₁₀ cycloalkenylene group, a C₃-C₁₀ heterocycloalkenylene group, a C₆-C₆₀ arylene group, a C₂-C₆₀ heteroarylene group, a divalent non-aromatic condensed polycyclic group, and a divalent non-aromatic hetero-condensed polycyclic group; and
a C₃-C₁₀ cycloalkylene group, a C₃-C₁₀ heterocycloalkylene group, a C₃-C₁₀ cycloalkenylene group, a C₃-C₁₀ heterocycloalkenylene group, a C₆-C₆₀ arylene group, a C₂-C₆₀ heteroarylene group, a divalent non-aromatic condensed polycyclic group, and a divalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group;
a11, a12, and a21 are each independently selected from 0, 1, 2, 3, 4, and 5;
R₁₁ to R₁₄ and R₂₁ are each independently selected from a substituted or unsubstituted C₃-C₁₀ cycloalkyl group, a substituted or unsubstituted C₃-C₁₀ heterocycloalkyl group, a substituted or unsubstituted C₃-C₁₀ cycloalkenyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, and a substituted or unsubstituted monovalent non-aromatic hetero-condensed polycyclic group; at least one substituent of the substituted C₃-C₁₀ cycloalkyl group, the substituted C₃-C₁₀ heterocycloalkyl group, the substituted C₃-C₁₀ cycloalkenyl group, the substituted C₃-C₁₀ heterocycloalkenyl group, the substituted C₆-C₆₀ aryl group, the substituted C₂-C₆₀ heteroaryl group, the substituted monovalent non-aromatic condensed polycyclic group, and the substituted monovalent non-aromatic hetero-condensed polycyclic group is selected from:
deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₁₁)(Q₁₂), —Si(Q₁₃)(Q₁₄)(Q₁₅), and —B(Q₁₆)(Q₁₇);
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group;
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₂₁)(Q₂₂), —Si(Q₂₃)(Q₂₄)(Q₂₅), and —B(Q₂₆)(Q₂₇); and
—N(Q₃₁)(Q₃₂), —Si(Q₃₃)(Q₃₄)(Q₃₅), and —B(Q₃₆)(Q₃₇);
R₂₂ to R₂₄, Q₁, Q₂, Q₁₁ to Q₁₇, Q₂₁ to Q₂₇ and Q₃₁ to Q₃₇ are each independently selected from hydrogen, deuterium, a C₁-C₆₀ alkyl group, a C₆-C₆₀ aryl group, a C₂-C₆₀ heteroaryl group, a monovalent non-aromatic condensed polycyclic group, and a monovalent non-aromatic hetero-condensed polycyclic group;
b22 is selected from 1, 2, and 3; and
b23 and b24 are each independently selected from 1, 2, 3, and 4.

2. The organic light-emitting device as claimed in claim 1, wherein:
in Formulae 1A, 1B, 1C, 1D, and 1E, B₁₁ and B₁₂ are each independently selected from:
a benzene group, a naphthalene group, an anthracene group, a pyridine group, a pyrimidine group, a quinoline group, and an isoquinoline group; and
a benzene group, a naphthalene group, an anthracene group, a pyridine group, a pyrimidine group, a quinoline group, and an isoquinoline group, each substituted with at least one selected from deuterium, a methyl group, an ethyl group, a tert-butyl group, an octyl group, a phenyl group, a naphthyl group, a pyridyl group, a pyrimidyl group, and —N(Q₁)(Q₂);
Q₁ and Q₂ are each independently selected from:
a phenyl group, a naphthyl group, an anthracenyl group, a triphenylenyl group, a phenanthrenyl group, a pyrenyl group, and a chrysenyl group; and
a phenyl group, a naphthyl group, an anthracenyl group, a triphenylenyl group, a phenanthrenyl group, a pyrenyl group, and a chrysenyl group, each substituted with at least one selected from a phenyl group, a naphthyl group, an anthracenyl group, a triphenylenyl group, a pyrenyl group, and a chrysenyl group.

3. The organic light-emitting device as claimed in claim 1, wherein, in Formulae 1A, 1B, 1C, 1D, and 1E, B₁₁ and B₁₂ are each independently selected from:
a benzene group, a naphthalene group, a pyridine group, and a pyrimidine group; and
a benzene group, a naphthalene group, a pyridine group, and a pyrimidine group, each substituted with at least one selected from deuterium, a methyl group, an ethyl group, a phenyl group, a naphthyl group, a pyridyl group, a pyrimidyl group, and —N(Ph)₂.

4. The organic light-emitting device as claimed in claim 1, wherein, in Formulae 1A, 1B, 1C, 1D, and 1E, at least one of R₁₁ to R₁₄ is a group selected from substituted or unsubstituted electron transporting-cyclic groups including at least one nitrogen atom N as a ring-forming atom.

5. The organic light-emitting device as claimed in claim 1, wherein
in Formulae 1A, 1B, 1C, 1D, and 1E, R₁₁ to R₁₄ are each independently selected from groups represented by Formulae H1 to H81 below; provided that at least one of R₁₁ to R₁₄ is selected from groups represented by Formulae H1 to H28, H37 to H41, H68 to H76, and H80 below: 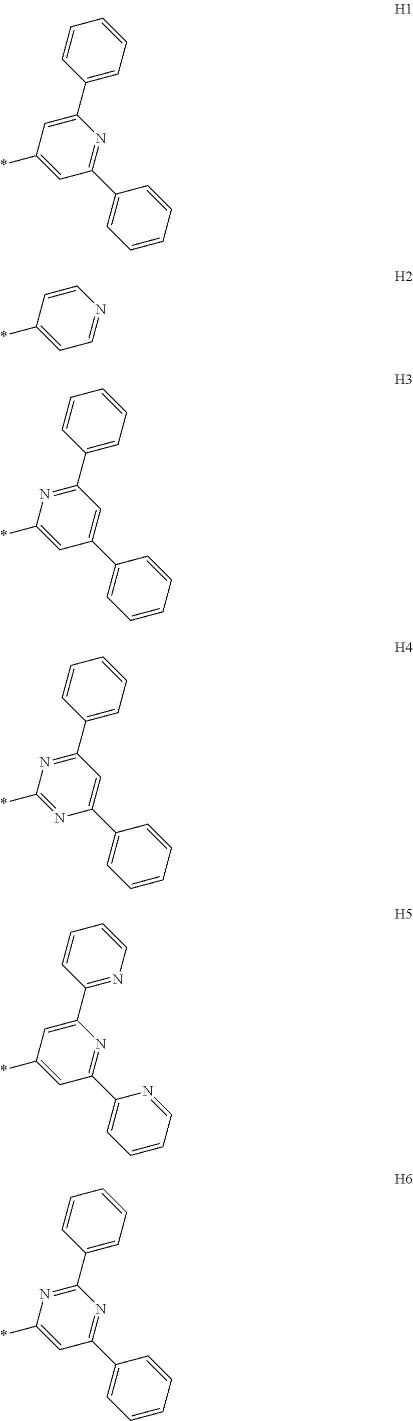 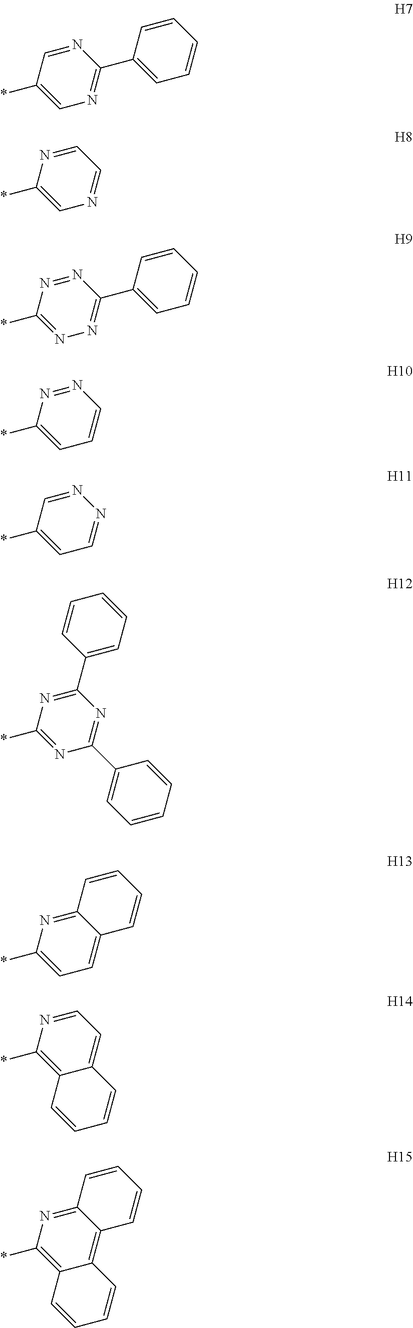 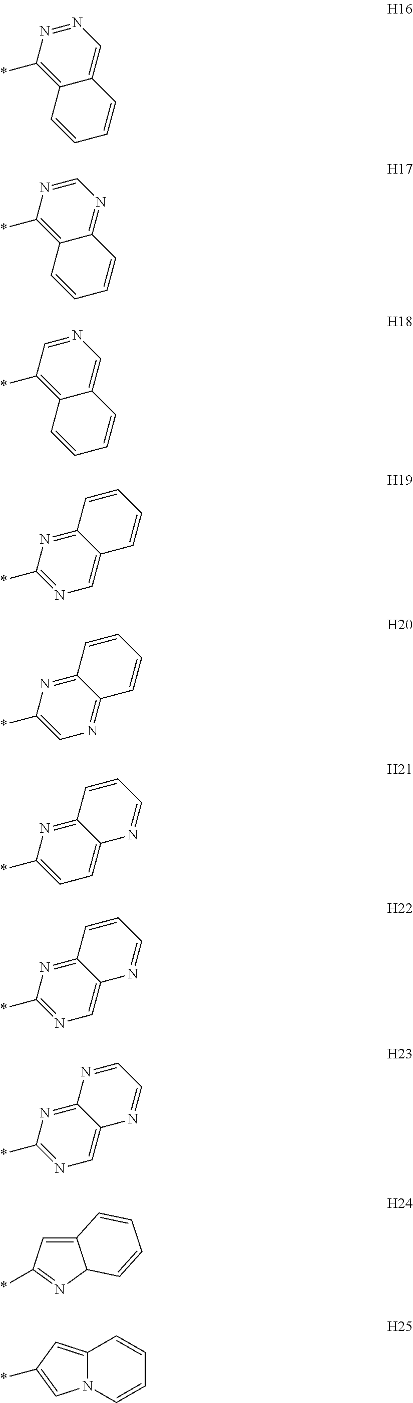 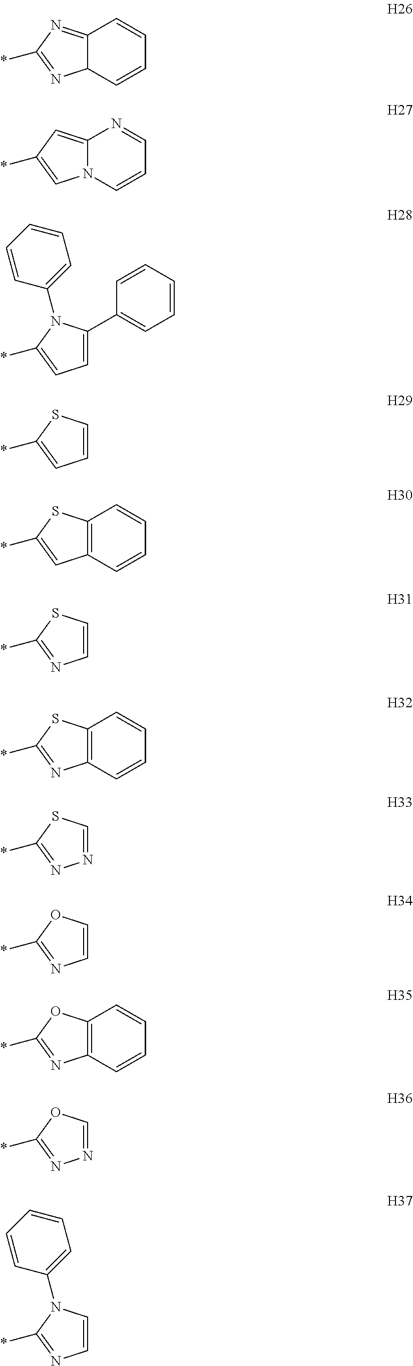 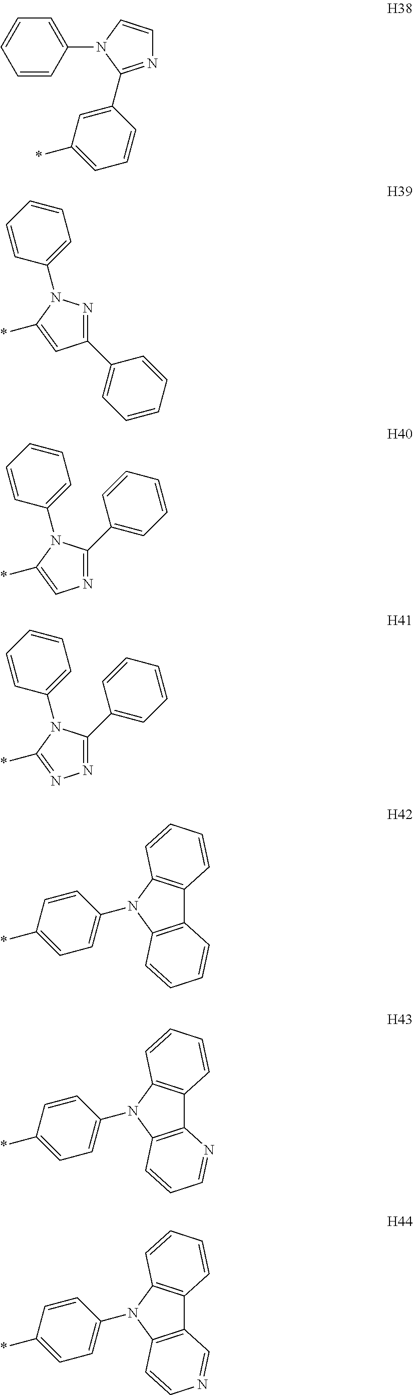 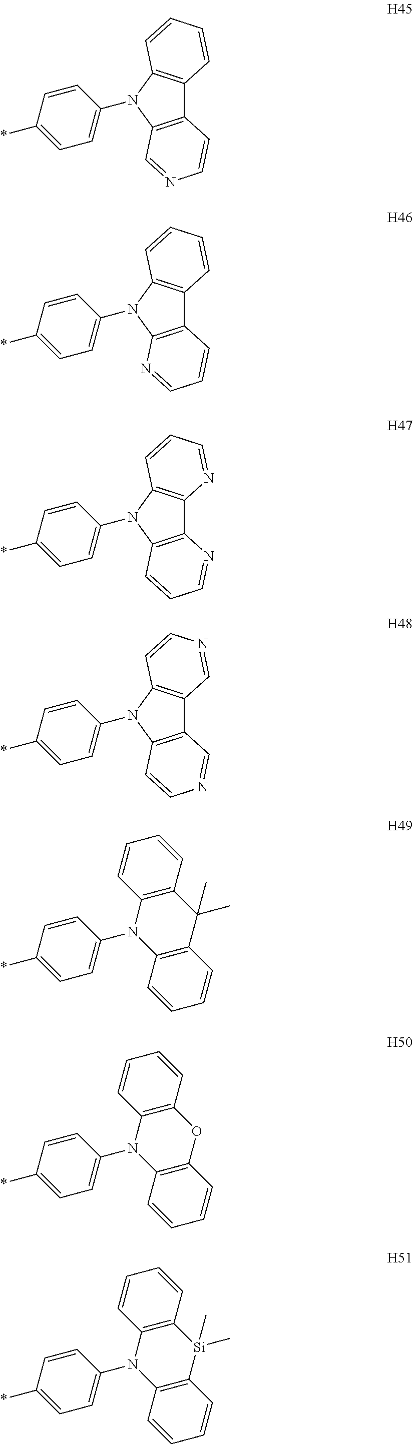 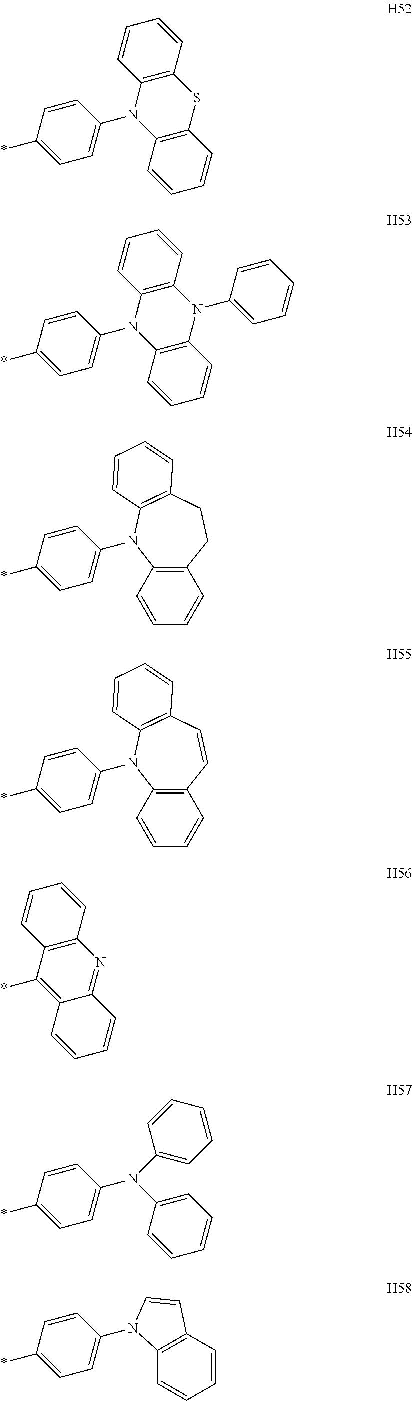 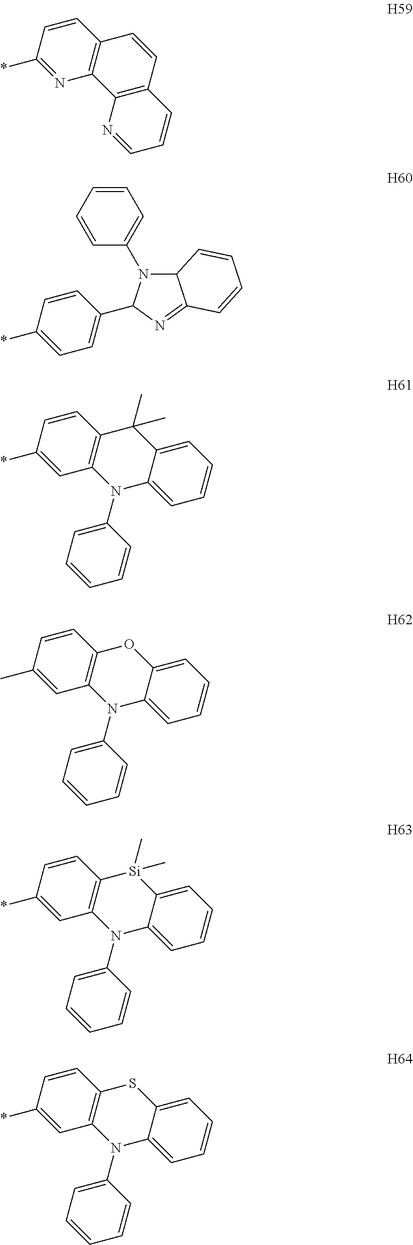 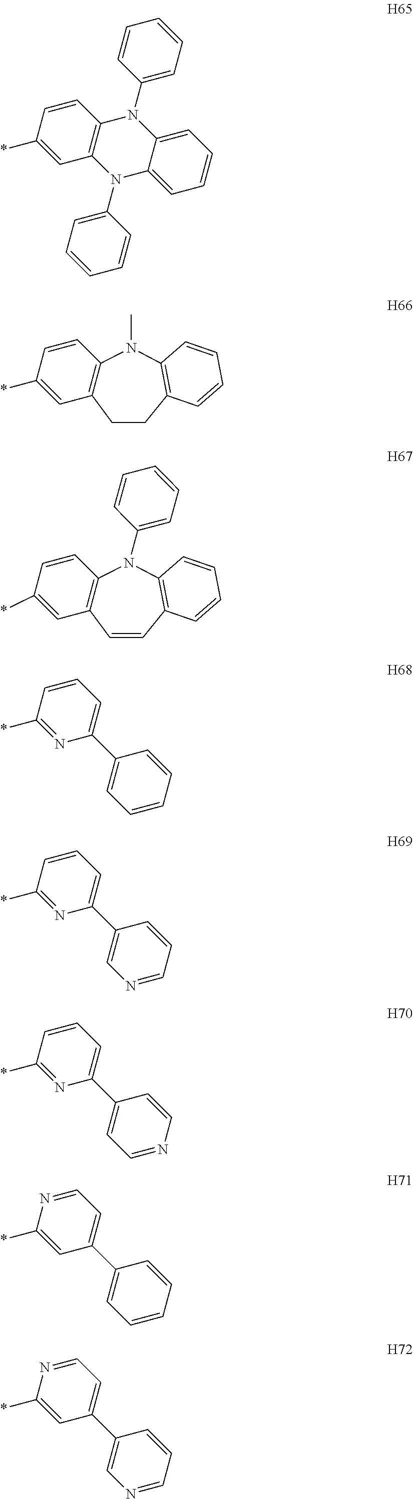 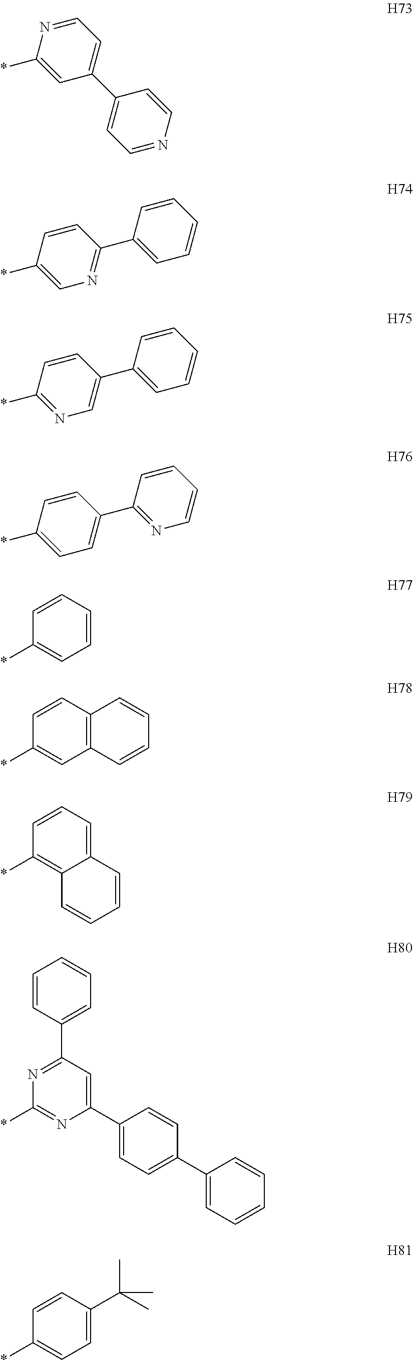
in Formulae H1 to H81, * is a binding site to a neighboring atom.

6. The organic light-emitting device as claimed in claim 1, wherein in Formulae 1A, 1B, 1C, 1D, 1E, and 2, L₁₁, L₁₂, and L₂₁ are each independently selected from:
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thienylene group, a furanylene group, a silolylene group, an imidazolylene group, a pyrazolylene group, a thiazolylene group, an isothiazolylene group, an oxazolylene group, an isooxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothienylene group, a benzosilolylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, and a dibenzosilolylene group; and
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thienylene group, a furanylene group, a silolylene group, an imidazolylene group, a pyrazolylene group, a thiazolylene group, an isothiazolylene group, an oxazolylene group, an isooxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothienylene group, a benzosilolylene group, an isobenzothiazolylene group, a benzooxazolylene group, an isobenzooxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, and a dibenzosilolylene group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thienyl group, a furanyl group, a silolyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothienyl group, a benzosilolyl group, an isobenzothiazolyl group, a benzooxazolyl group, an isobenzooxazolyl group, a triazolyl group, a tetrazole group, an oxadiazolyl group, a triazinyl group, a dibenzofuranyl group, a diabenzothienyl group, a benzocarbazolyl group, a dibenzocarbazolyl group, and a dibenzosilolyl group.

7. The organic light-emitting device as claimed in claim 1, wherein
in Formulae 1A, 1B, 1C, 1D, 1E, and 2, L₁₁, L₁₂, and L₂₁ are each independently selected from groups represented by Formulae 3-1 to 3-30: 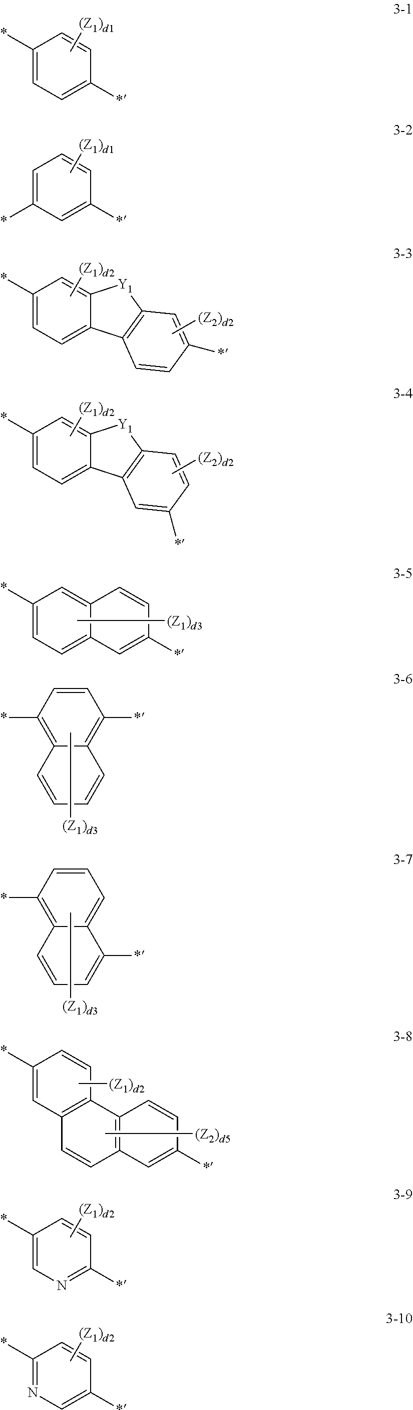 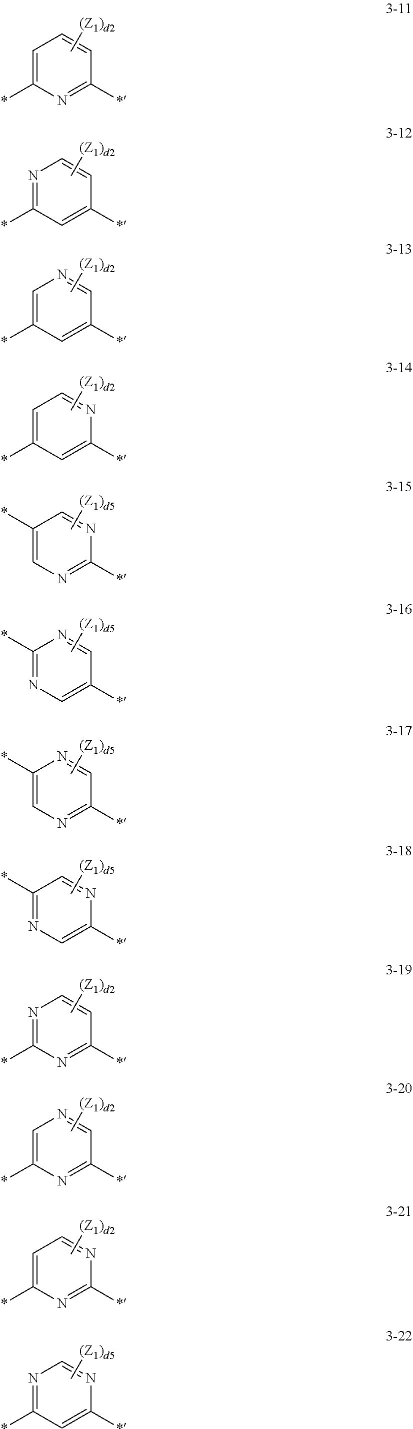 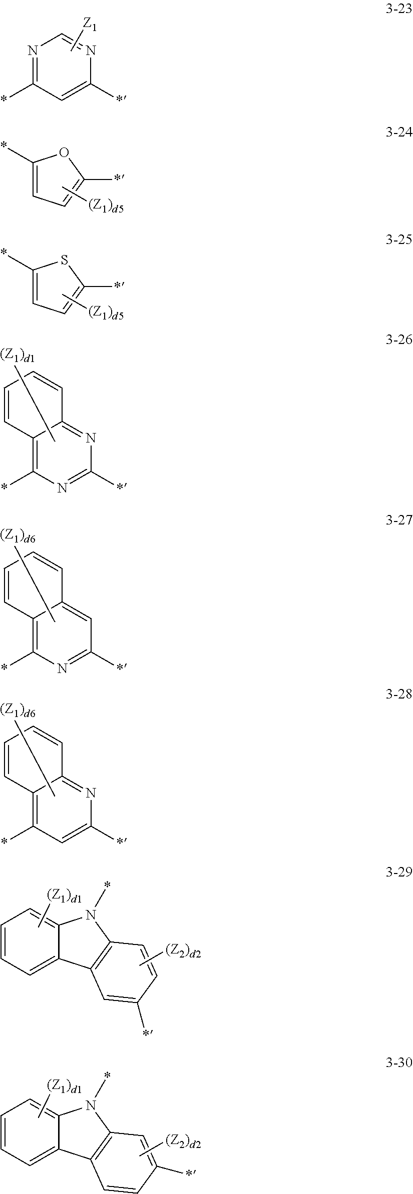
in Formulae 3-1 to 3-30,
Y₁ is O, S, C(Z₃)(Z₄), N(Z₅), or Si(Z₆)(Z₇);
Z₁ to Z₇ are each independently selected from hydrogen, deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,
d1 is an integer of 1 to 4;
d2 is an integer of 1 to 3;
d3 is an integer of 1 to 6;
d4 is an integer of 1 to 8;
d5 is 1 or 2;
d6 is an integer of 1 to 5; and
* and *′ are binding sites to neighboring atoms.

8. The organic light-emitting device as claimed in claim 1, wherein:
in Formulae 1A, 1B, 1C, 1D, 1E, and 2, L₁₁, L₁₂, and L₂₁ are each independently selected from groups represented by Formulae 4-1 to 4-21 below: 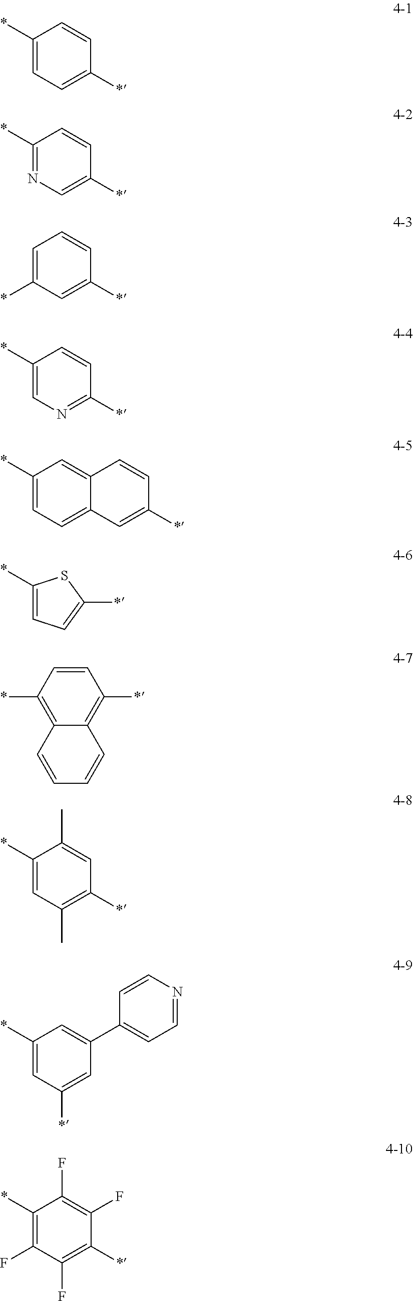 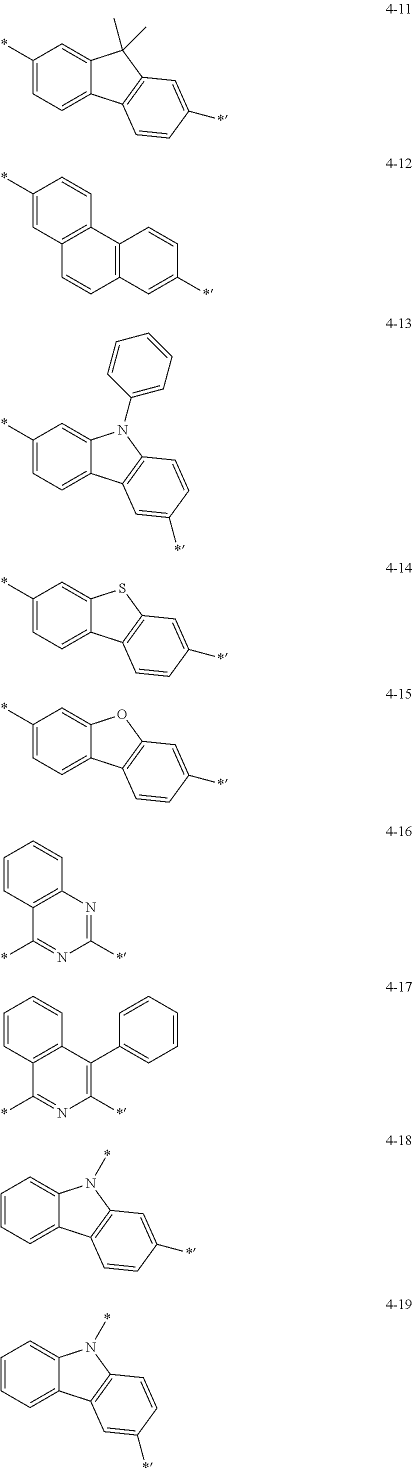 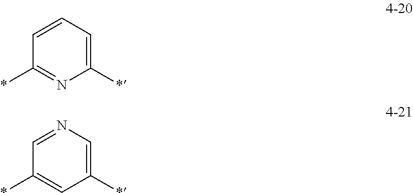
in Formulae 4-1 to 4-21, * and *′ are binding sites to neighboring atoms.

9. The organic light-emitting device as claimed in claim 1, wherein in Formulae 1A, 1B, 1C, 1D, and 1E, a11 and a12 are each independently 0 or 1.

10. The organic light-emitting device as claimed in claim 1, wherein in Formula 2, a21 is 1.

11. The organic light-emitting device as claimed in claim 1, wherein in Formula 2, R₂₁ excludes a substituted or unsubstituted electron transporting-cyclic group including at least one nitrogen atom N as a ring-forming atom.

12. The organic light-emitting device as claimed in claim 1, wherein in Formula 2, R₂₁ is selected from:
a phenyl group, a naphthyl group, a fluorenyl group, a spiro-fluorenyl group, a phenanthrenyl group, an anthracenyl group, a fluoranthenyl group, a triphenylenyl group, a pyrenyl group, a chrysenyl group, a carbazolyl group, a furanyl group, a thienyl group, a thianthrenyl group, a phnoxathiinyl group, and an oxanthrenyl group; and
a phenyl group, a naphthyl group, a fluorenyl group, a spiro-fluorenyl group, a phenanthrenyl group, an anthracenyl group, a fluoranthenyl group, a triphenylenyl group, a pyrenyl group, a chrysenyl group, a carbazolyl group, a furanyl, a thienyl, a thianthrenyl group, a phnoxathiinyl group, and an oxanthrenyl group, each substituted with at least one selected from deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, phosphoric acid or a salt thereof, a C₁-C₂₀ alkyl group, a C₁-C₂₀ alkoxy group, a phenyl group, a naphthyl group, a fluorenyl group, a spiro-fluorenyl group, a phenanthrenyl group, an anthracenyl group, a fluoranthenyl group, a triphenylenyl group, a pyrenyl group, a chrysenyl group, a pyridinyl group, a pyrazinyl group, a pyrimidinyl group, a pyridazinyl group, an isoindolyl group, an indolyl group, a quinolinyl group, a benzoquinolinyl group, a quinoxalinyl group, a quinazolinyl group, a cinnolinylene group, a carbazolyl group, a triazinyl group, and —Si(Q₃₃)(Q₃₄)(Q₃₅); in which Q₃₃ to Q₃₅ are each independently selected from a C₁-C₂₀ alkyl group, a phenyl group, and a naphthyl group.

13. The organic light-emitting device as claimed in claim 1, wherein:
in Formula 2, R₂₁ is selected from groups represented by Formulae 13-1 to 13-13: 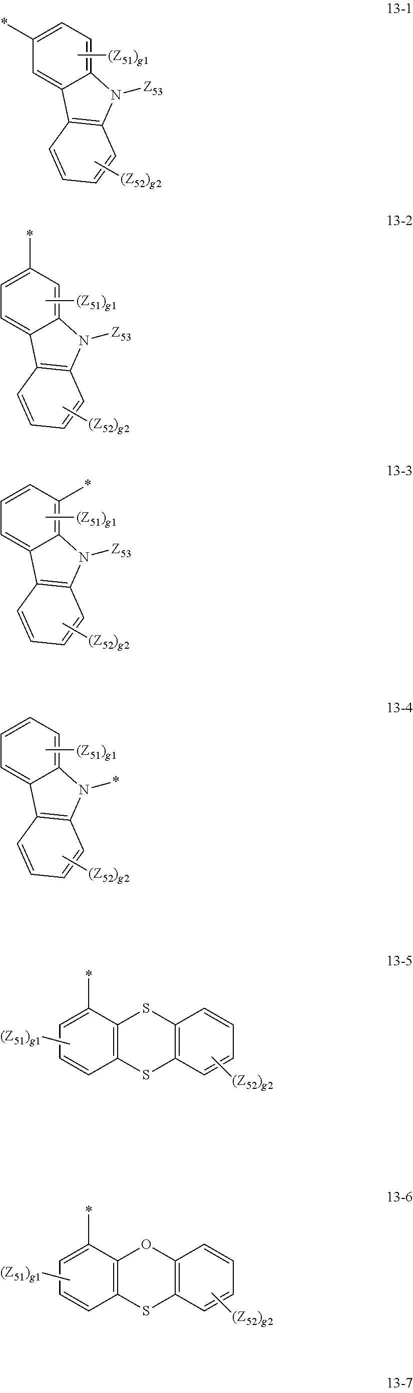 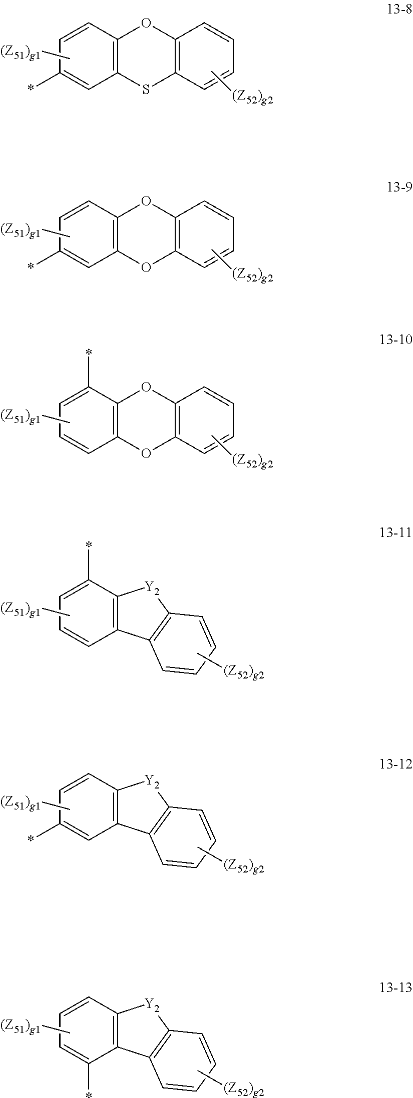
in Formulae 13-1 to 13-13,
Y₂ is an oxygen atom or a sulfur atom;
Z₅₁ to Z₅₃ are each independently selected from hydrogen, deuterium, —F, —Cl, —Br, —I, a hydroxyl group, a cyano group, a nitro group, an amino group, an amidino group, a hydrazine group, a hydrazone group, a carboxyl group or a salt thereof, sulfonic acid or a salt thereof, and phosphoric acid or a salt thereof, a C₁-C₂₀ alkyl group, a C₂-C₂₀ alkenyl group, a C₂-C₂₀ alkynyl group, a C₁-C₂₀ alkoxy group, a phenyl group, a naphthyl group, an anthryl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a quinoxalinyl group, a quinazolinyl group, a cinnolinyl group, a quinazolinyl group, and —Si(Q₃₃)(Q₃₄)(Q₃₅); in which Q₃₃ to Q₃₅ are each independently selected from a C₁-C₂₀ alkyl group, a phenyl group, and a naphthyl group;
g1 is an integer of 1 to 3;
g2 is an integer of 1 to 4; and
* is a binding site to a neighboring atom.

14. The organic light-emitting device as claimed in claim 1, wherein
in Formula 2, R₂₁ is selected from Formulae 14-1 to 14-13 below. 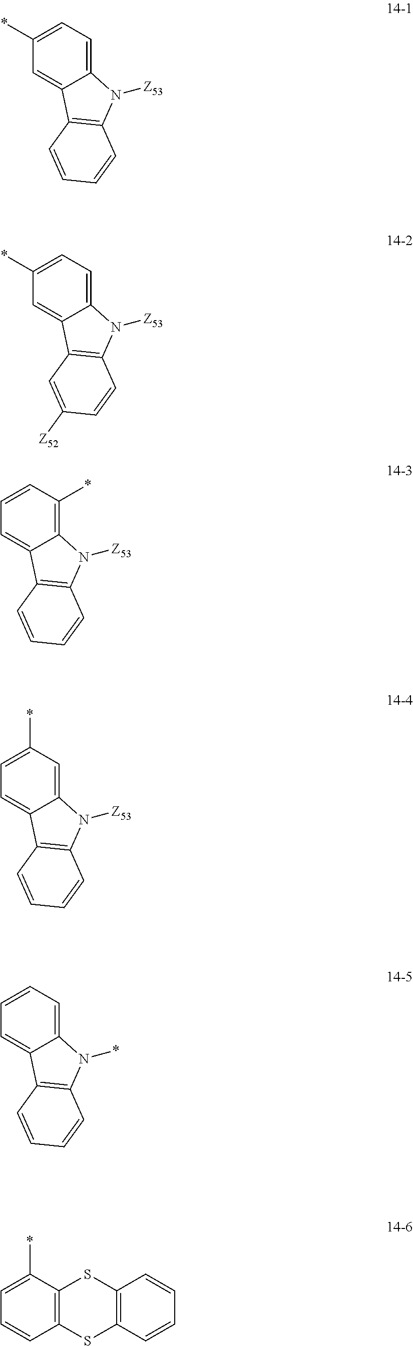 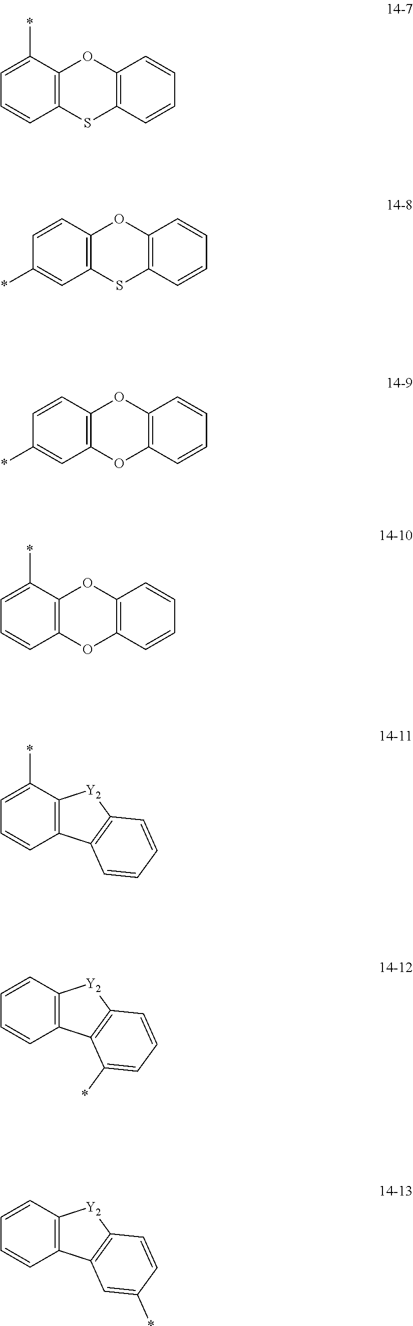
in Formulae 14-1 to 14-13,
Y₂ is an oxygen atom or a sulfur atom;
Z₅₃ is selected from hydrogen, deuterium, —F, —Cl, —Br, —I, a cyano group, a nitro group, a phenyl group, a naphthyl group, an anthryl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a quinoxalinyl group, a quinazolinyl group, a cinnolinyl group, a quinazolinyl group, and —Si(Q₃₃)(Q₃₄)(Q₃₅); in which Q₃₃ to Q₃₅ are each independently selected from a C₁-C₂₀ alkyl group, a phenyl group, and a naphthyl group; and
* is a binding site to a neighboring atom.

15. The organic light-emitting device as claimed in claim 1, wherein in Formula 2, R₂₂ to R₂₄ are hydrogen.

16. The organic light-emitting device as claimed in claim 1, wherein the triphenylene-based compound represented by Formula 2 is selected from compounds represented by Formulae 2A and 2B below. 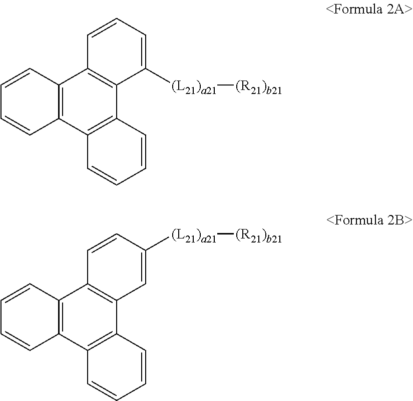
in Formulae 2A and 2B, L₂₁, a21, R₂₁, and b21 are the same as described with respect to Formula 2.

17. The organic light-emitting device as claimed in claim 1, wherein:
the at least one compound represented by Formulae 1A, 1B, 1C, 1D, or 1E, above, include at least one heterocyclic compound selected from Compounds 100 to 238, below, and
the triphenylene-based compound represented by Formula 2, above, is selected from Compounds 201A to 242A below:

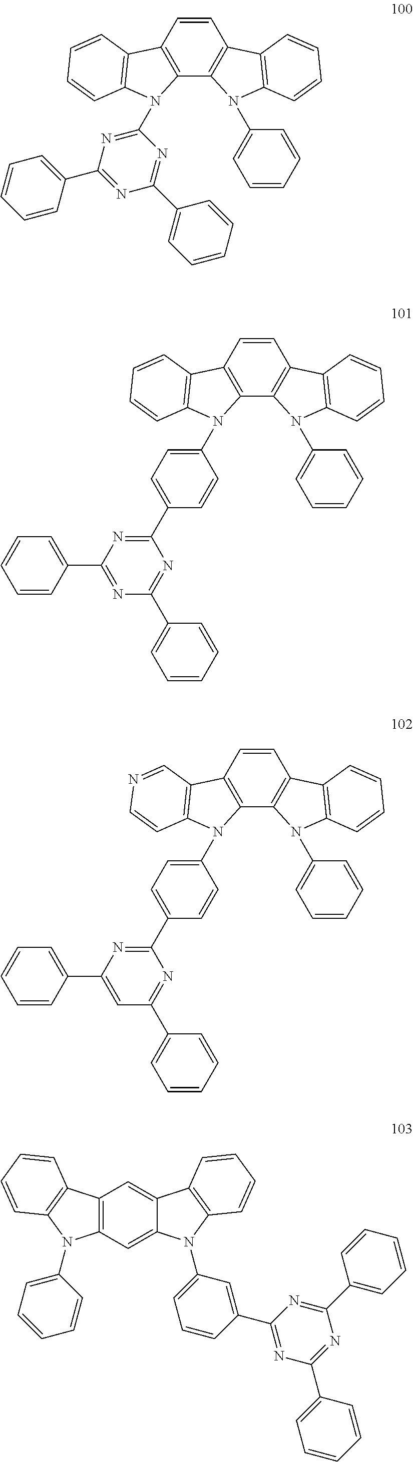 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-c3ccc(-n4c5ccccc5c5ccc6c7ccccc7n(-c7ccccc7)c6c54)cc3)n2)cc1 ; c1ccc(-c2cc(-c3ccccc3)nc(-c3ccc(-n4c5ccncc5c5ccc6c7ccccc7n(-c7ccccc7)c6c54)cc3)n2)cc1 ; c1ccc(-c2nc(-c3ccccc3)nc(-c3cccc(-n4c5ccccc5c5cc6c7ccccc7n(-c7ccccc7)c6cc54)c3)n2)cc1]

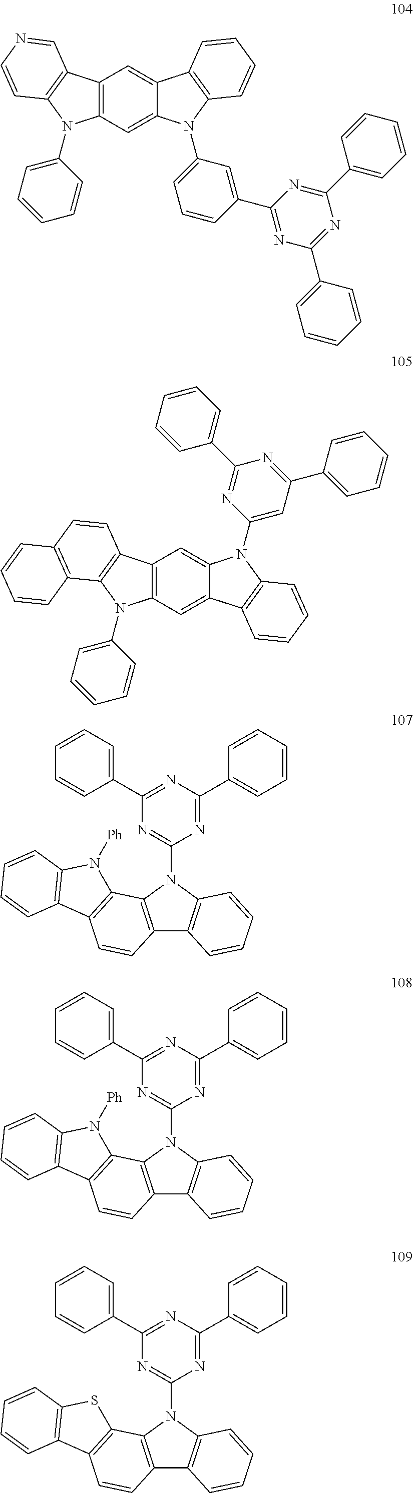

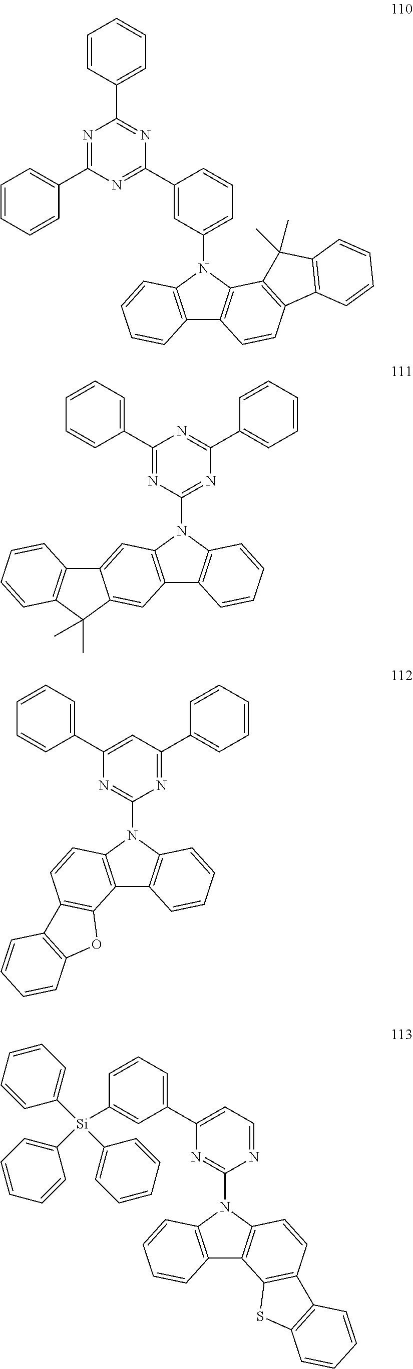

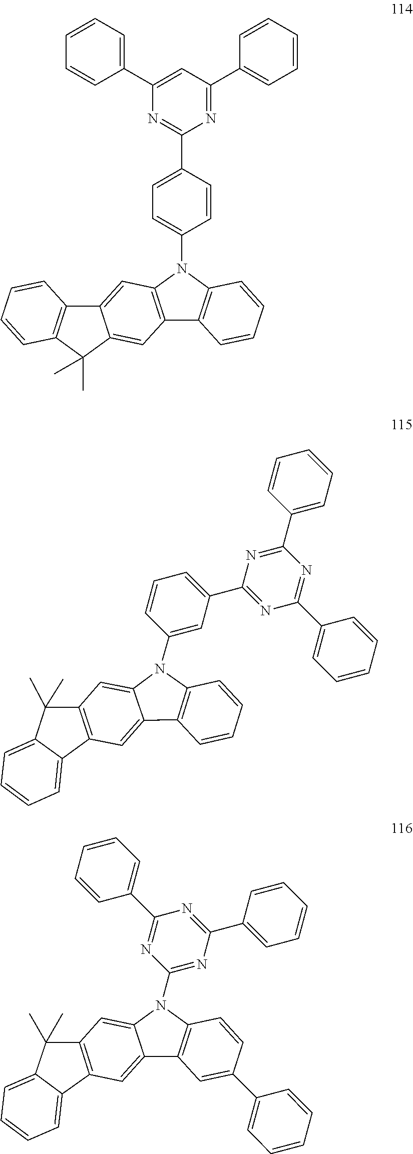 [SMILES: CC1(C)c2ccccc2-c2cc3c(cc21)c1ccccc1n3-c1ccc(-c2nc(-c3ccccc3)cc(-c3ccccc3)n2)cc1 ; CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2cc3c4cc(-c5ccccc5)ccc4n(-c4nc(-c5ccccc5)nc(-c5ccccc5)n4)c3cc21]

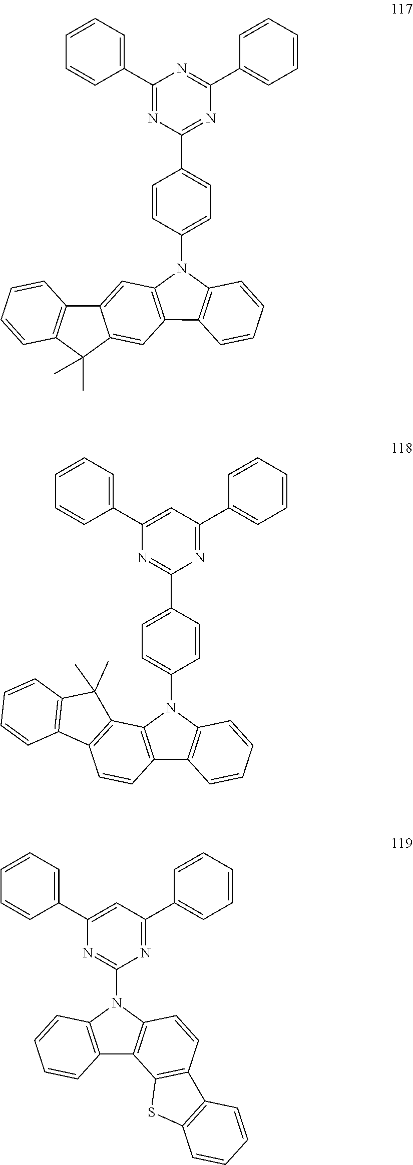 [SMILES: CC1(C)c2ccccc2-c2cc3c(cc21)c1ccccc1n3-c1ccc(-c2nc(-c3ccccc3)nc(-c3ccccc3)n2)cc1 ; CC1(C)c2ccccc2-c2ccc3c4ccccc4n(-c4ccc(-c5nc(-c6ccccc6)cc(-c6ccccc6)n5)cc4)c3c21 ; c1ccc(-c2cc(-c3ccccc3)nc(-n3c4ccccc4c4c5sc6ccccc6c5ccc43)n2)cc1]

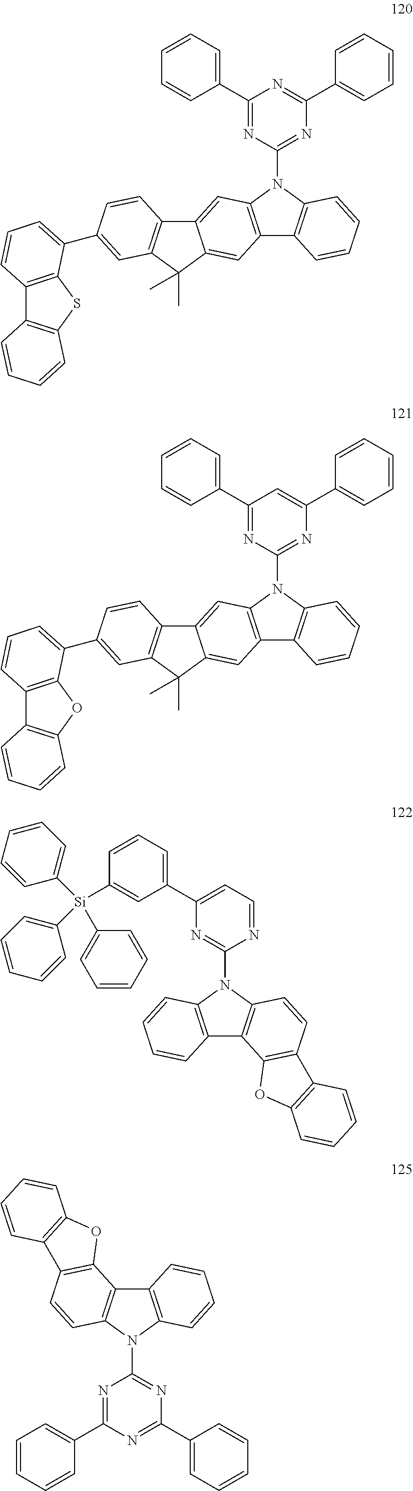

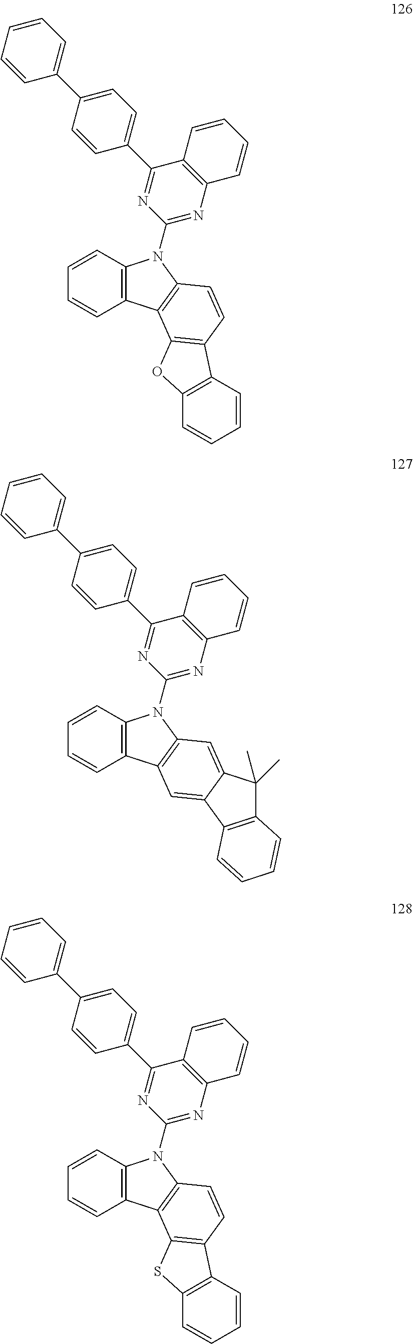 [SMILES: c1ccc(-c2ccc(-c3nc(-n4c5ccccc5c5c6oc7ccccc7c6ccc54)nc4ccccc34)cc2)cc1 ; CC1(C)c2ccccc2-c2cc3c4ccccc4n(-c4nc(-c5ccc(-c6ccccc6)cc5)c5ccccc5n4)c3cc21 ; c1ccc(-c2ccc(-c3nc(-n4c5ccccc5c5c6sc7ccccc7c6ccc54)nc4ccccc34)cc2)cc1]

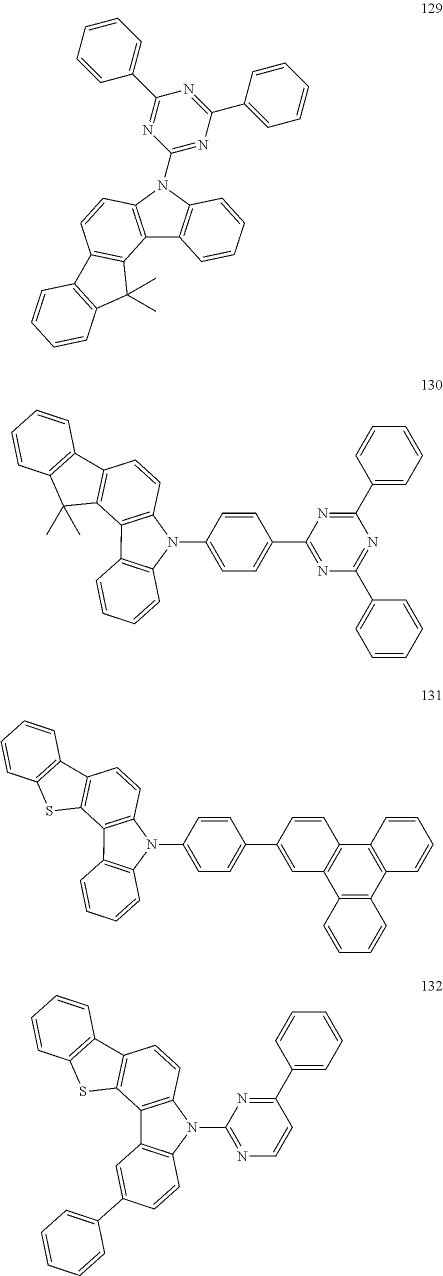 [SMILES: CC1(C)c2ccccc2-c2ccc3c(c21)c1ccccc1n3-c1nc(-c2ccccc2)nc(-c2ccccc2)n1 ; CC1(C)c2ccccc2-c2ccc3c(c21)c1ccccc1n3-c1ccc(-c2nc(-c3ccccc3)nc(-c3ccccc3)n2)cc1 ; c1ccc2c(c1)sc1c2ccc2c1c1ccccc1n2-c1ccc(-c2ccc3c4ccccc4c4ccccc4c3c2)cc1 ; c1ccc(-c2ccc3c(c2)c2c4sc5ccccc5c4ccc2n3-c2nccc(-c3ccccc3)n2)cc1]

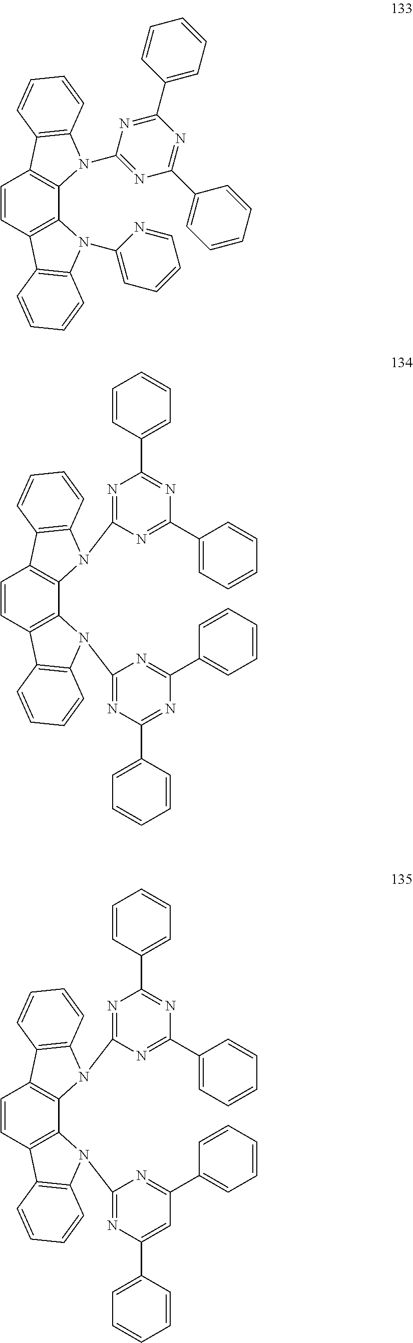 [SMILES: c1ccc(-c2nc(-c3ccccc3)nc(-n3c4ccccc4c4ccc5c6ccccc6n(-c6ccccn6)c5c43)n2)cc1 ; c1ccc(-c2nc(-c3ccccc3)nc(-n3c4ccccc4c4ccc5c6ccccc6n(-c6nc(-c7ccccc7)nc(-c7ccccc7)n6)c5c43)n2)cc1 ; c1ccc(-c2cc(-c3ccccc3)nc(-n3c4ccccc4c4ccc5c6ccccc6n(-c6nc(-c7ccccc7)nc(-c7ccccc7)n6)c5c43)n2)cc1]

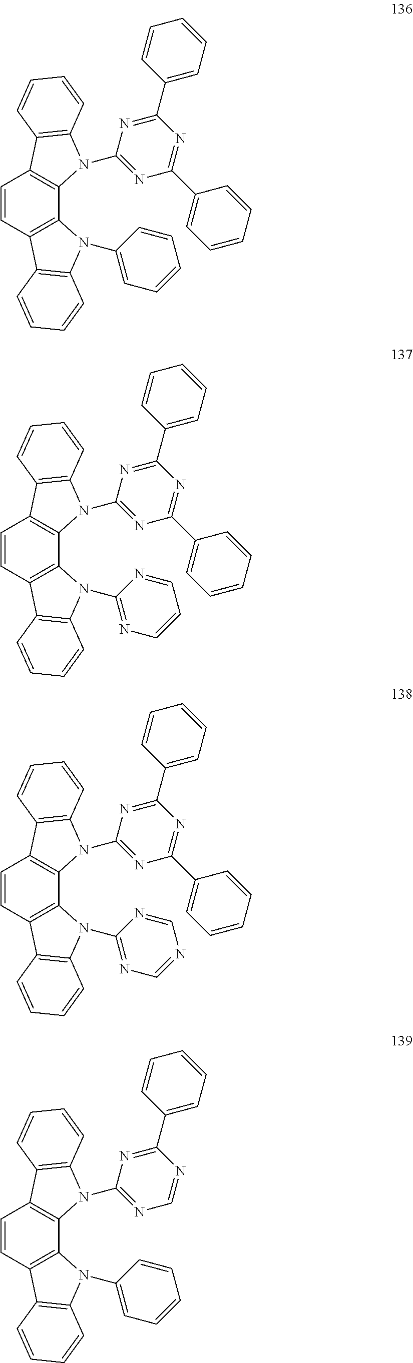 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6n(-c6ncccn6)c5c43)n2)cc1 ; c1ccc(-c2nc(-c3ccccc3)nc(-n3c4ccccc4c4ccc5c6ccccc6n(-c6ncncn6)c5c43)n2)cc1 ; c1ccc(-c2ncnc(-n3c4ccccc4c4ccc5c6ccccc6n(-c6ccccc6)c5c43)n2)cc1]

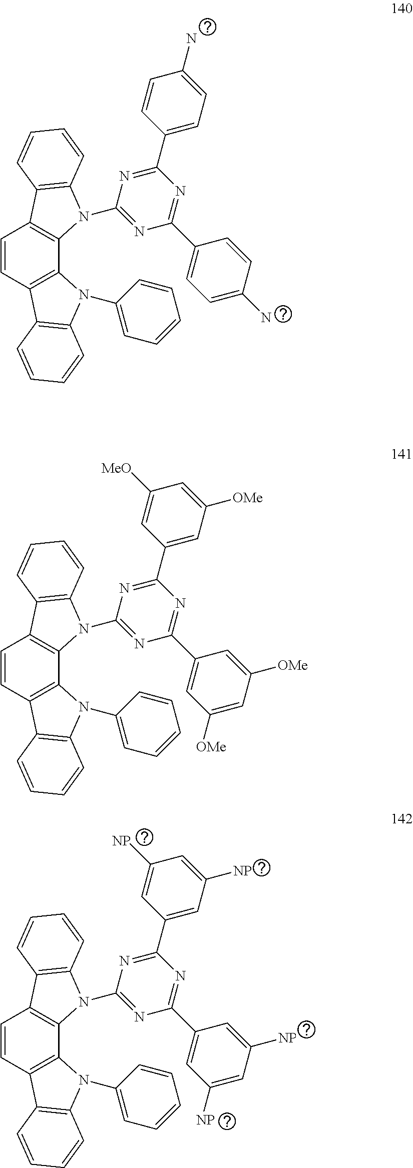

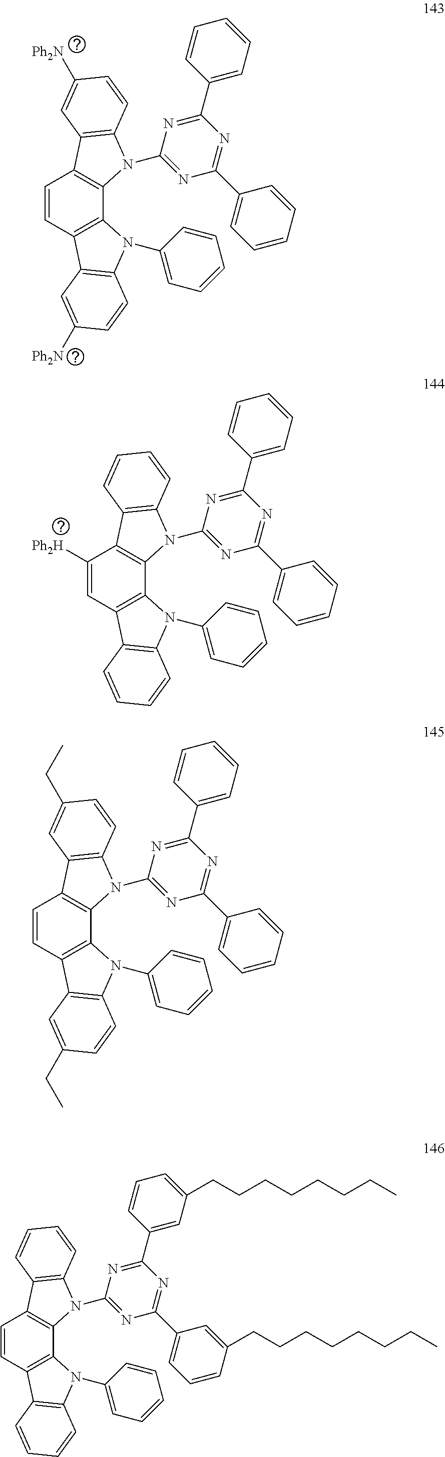

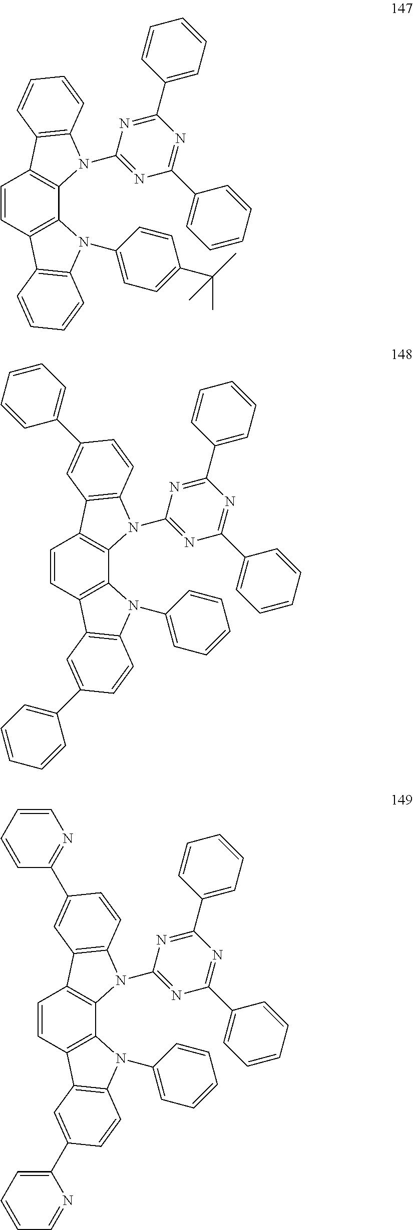

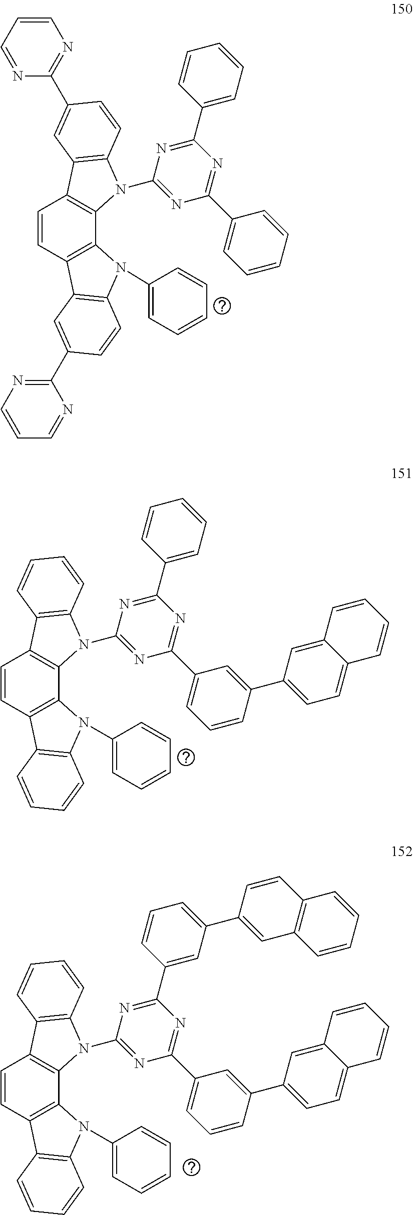 [SMILES: c1ccc(-c2nc(-c3ccccc3)nc(-n3c4ccc(-c5ncccn5)cc4c4ccc5c6cc(-c7ncccn7)ccc6n(-c6ccccc6)c5c43)n2)cc1 ; c1ccc(-c2nc(-c3cccc(-c4ccc5ccccc5c4)c3)nc(-n3c4ccccc4c4ccc5c6ccccc6n(-c6ccccc6)c5c43)n2)cc1 ; c1ccc(-n2c3ccccc3c3ccc4c5ccccc5n(-c5nc(-c6cccc(-c7ccc8ccccc8c7)c6)nc(-c6cccc(-c7ccc8ccccc8c7)c6)n5)c4c32)cc1]

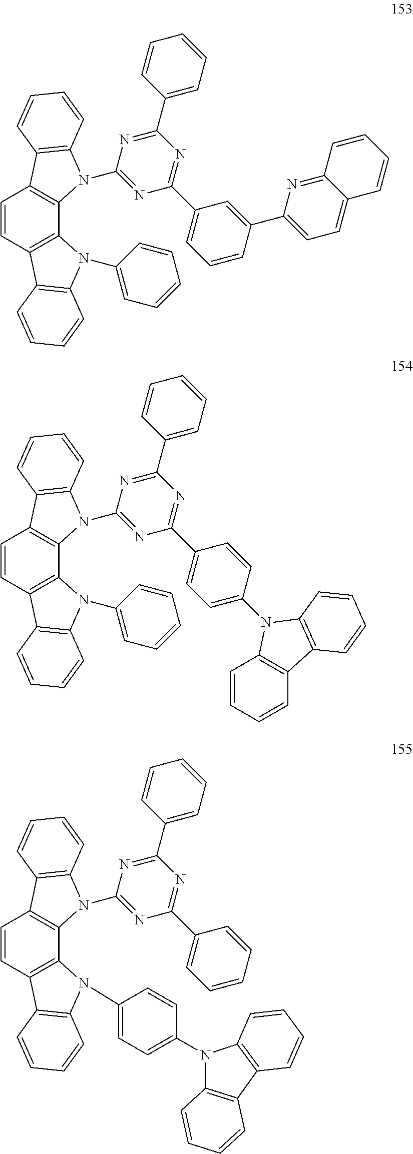 [SMILES: c1ccc(-c2nc(-c3cccc(-c4ccc5ccccc5n4)c3)nc(-n3c4ccccc4c4ccc5c6ccccc6n(-c6ccccc6)c5c43)n2)cc1 ; c1ccc(-c2nc(-c3ccc(-n4c5ccccc5c5ccccc54)cc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6n(-c6ccc(-n7c8ccccc8c8ccccc87)cc6)c5c43)n2)cc1]

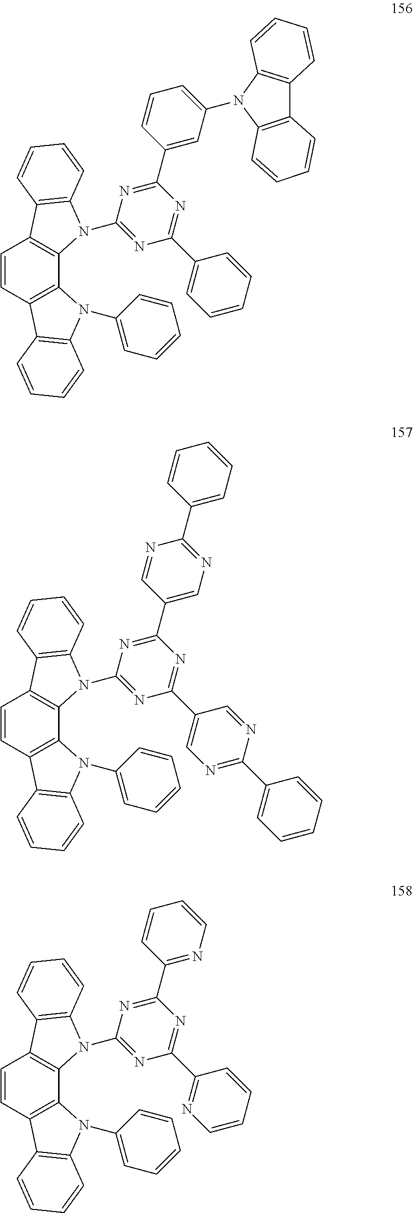 [SMILES: c1ccc(-c2nc(-c3cccc(-n4c5ccccc5c5ccccc54)c3)nc(-n3c4ccccc4c4ccc5c6ccccc6n(-c6ccccc6)c5c43)n2)cc1 ; c1ccc(-c2ncc(-c3nc(-c4cnc(-c5ccccc5)nc4)nc(-n4c5ccccc5c5ccc6c7ccccc7n(-c7ccccc7)c6c54)n3)cn2)cc1 ; c1ccc(-n2c3ccccc3c3ccc4c5ccccc5n(-c5nc(-c6ccccn6)nc(-c6ccccn6)n5)c4c32)cc1]

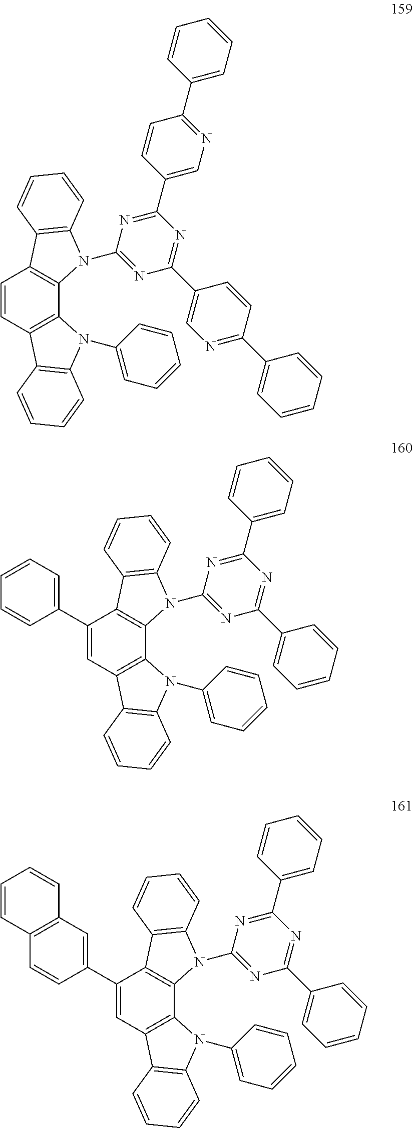

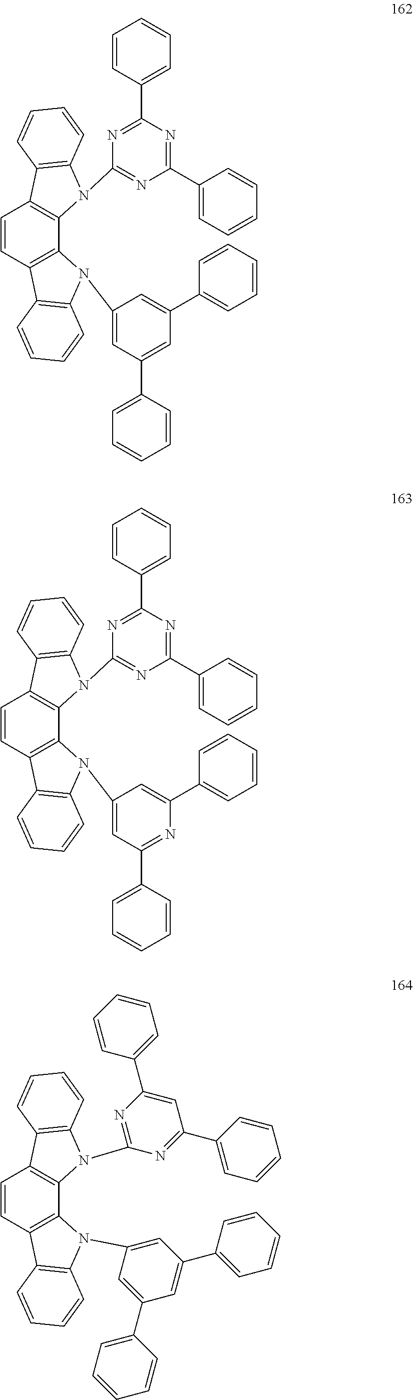 [SMILES: c1ccc(-c2cc(-c3ccccc3)cc(-n3c4ccccc4c4ccc5c6ccccc6n(-c6nc(-c7ccccc7)nc(-c7ccccc7)n6)c5c43)c2)cc1 ; c1ccc(-c2cc(-n3c4ccccc4c4ccc5c6ccccc6n(-c6nc(-c7ccccc7)nc(-c7ccccc7)n6)c5c43)cc(-c3ccccc3)n2)cc1 ; c1ccc(-c2cc(-c3ccccc3)cc(-n3c4ccccc4c4ccc5c6ccccc6n(-c6nc(-c7ccccc7)cc(-c7ccccc7)n6)c5c43)c2)cc1]

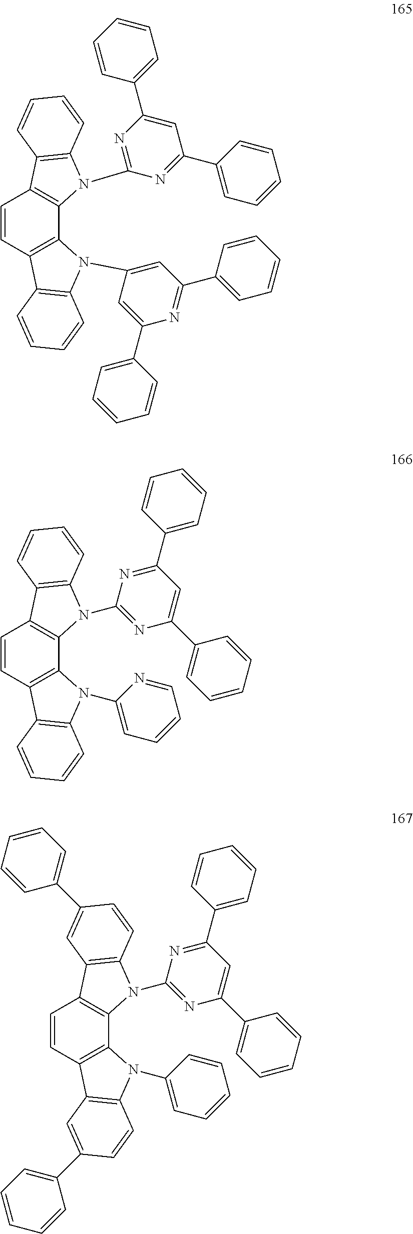 [SMILES: c1ccc(-c2cc(-n3c4ccccc4c4ccc5c6ccccc6n(-c6nc(-c7ccccc7)cc(-c7ccccc7)n6)c5c43)cc(-c3ccccc3)n2)cc1 ; c1ccc(-c2cc(-c3ccccc3)nc(-n3c4ccccc4c4ccc5c6ccccc6n(-c6ccccn6)c5c43)n2)cc1 ; c1ccc(-c2ccc3c(c2)c2ccc4c5cc(-c6ccccc6)ccc5n(-c5nc(-c6ccccc6)cc(-c6ccccc6)n5)c4c2n3-c2ccccc2)cc1]

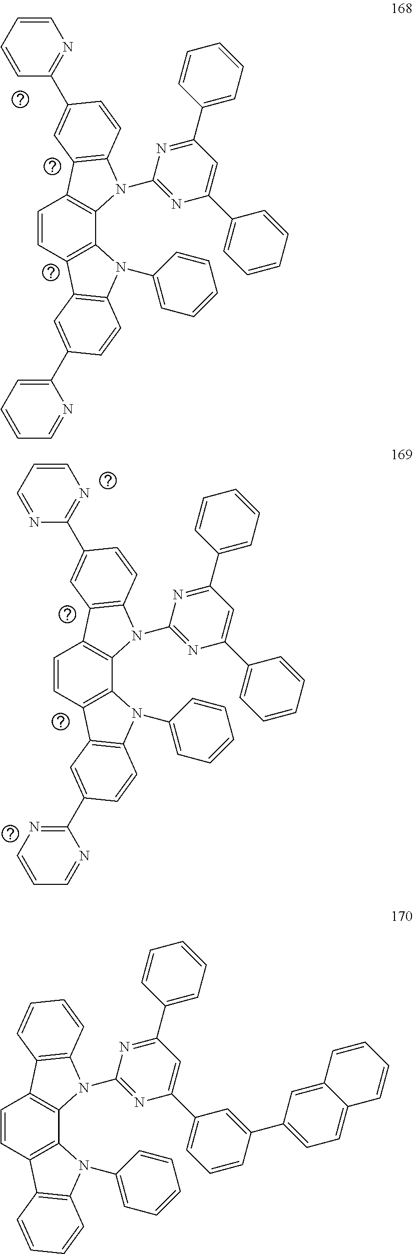

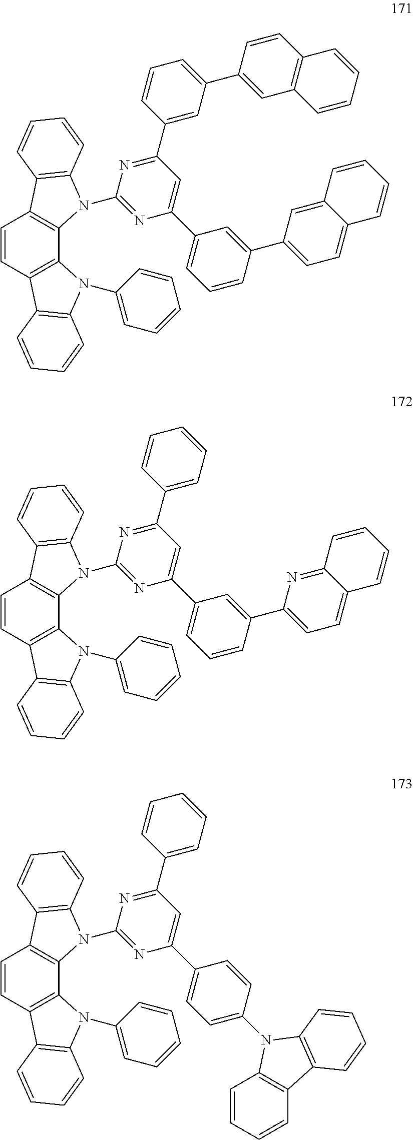 [SMILES: c1ccc(-n2c3ccccc3c3ccc4c5ccccc5n(-c5nc(-c6cccc(-c7ccc8ccccc8c7)c6)cc(-c6cccc(-c7ccc8ccccc8c7)c6)n5)c4c32)cc1 ; c1ccc(-c2cc(-c3cccc(-c4ccc5ccccc5n4)c3)nc(-n3c4ccccc4c4ccc5c6ccccc6n(-c6ccccc6)c5c43)n2)cc1 ; c1ccc(-c2cc(-c3ccc(-n4c5ccccc5c5ccccc54)cc3)nc(-n3c4ccccc4c4ccc5c6ccccc6n(-c6ccccc6)c5c43)n2)cc1]

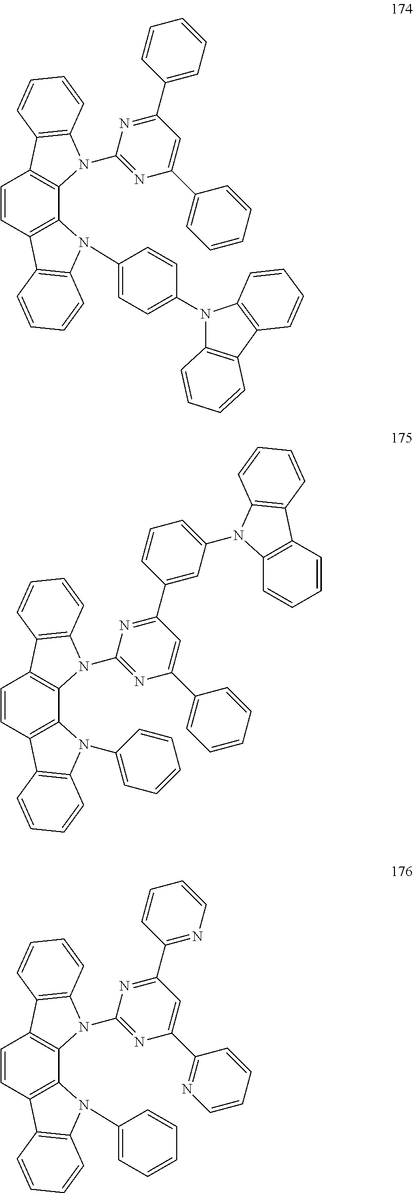 [SMILES: c1ccc(-c2cc(-c3ccccc3)nc(-n3c4ccccc4c4ccc5c6ccccc6n(-c6ccc(-n7c8ccccc8c8ccccc87)cc6)c5c43)n2)cc1 ; c1ccc(-c2cc(-c3cccc(-n4c5ccccc5c5ccccc54)c3)nc(-n3c4ccccc4c4ccc5c6ccccc6n(-c6ccccc6)c5c43)n2)cc1 ; c1ccc(-n2c3ccccc3c3ccc4c5ccccc5n(-c5nc(-c6ccccn6)cc(-c6ccccn6)n5)c4c32)cc1]

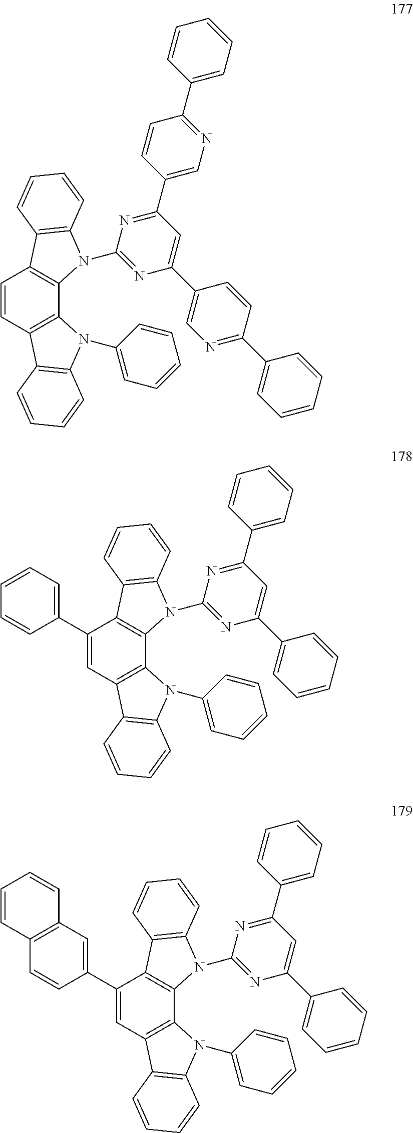 [SMILES: c1ccc(-c2ccc(-c3cc(-c4ccc(-c5ccccc5)nc4)nc(-n4c5ccccc5c5ccc6c7ccccc7n(-c7ccccc7)c6c54)n3)cn2)cc1 ; c1ccc(-c2cc(-c3ccccc3)nc(-n3c4ccccc4c4c(-c5ccccc5)cc5c6ccccc6n(-c6ccccc6)c5c43)n2)cc1 ; c1ccc(-c2cc(-c3ccccc3)nc(-n3c4ccccc4c4c(-c5ccc6ccccc6c5)cc5c6ccccc6n(-c6ccccc6)c5c43)n2)cc1]

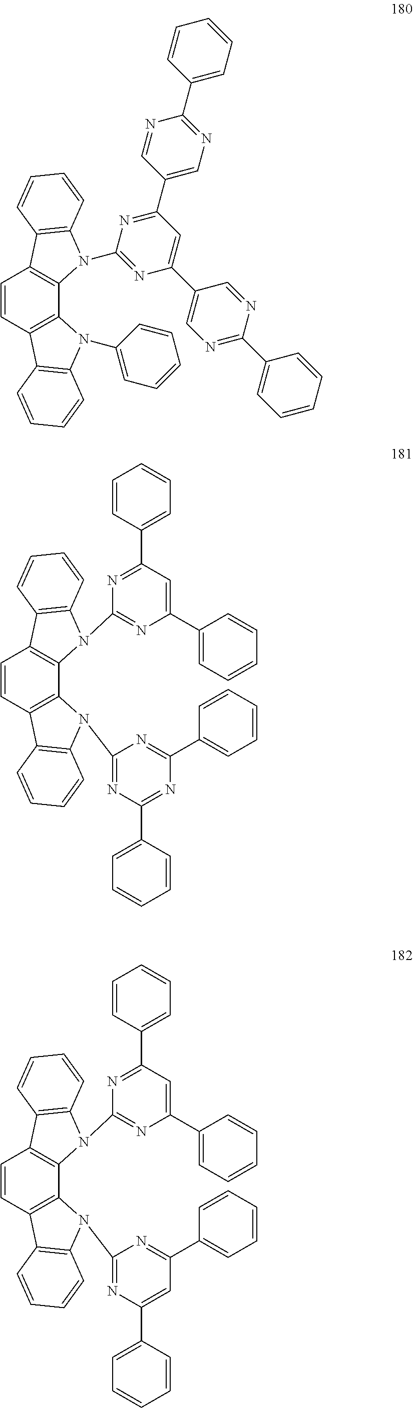 [SMILES: c1ccc(-c2ncc(-c3cc(-c4cnc(-c5ccccc5)nc4)nc(-n4c5ccccc5c5ccc6c7ccccc7n(-c7ccccc7)c6c54)n3)cn2)cc1 ; c1ccc(-c2cc(-c3ccccc3)nc(-n3c4ccccc4c4ccc5c6ccccc6n(-c6nc(-c7ccccc7)nc(-c7ccccc7)n6)c5c43)n2)cc1 ; c1ccc(-c2cc(-c3ccccc3)nc(-n3c4ccccc4c4ccc5c6ccccc6n(-c6nc(-c7ccccc7)cc(-c7ccccc7)n6)c5c43)n2)cc1]

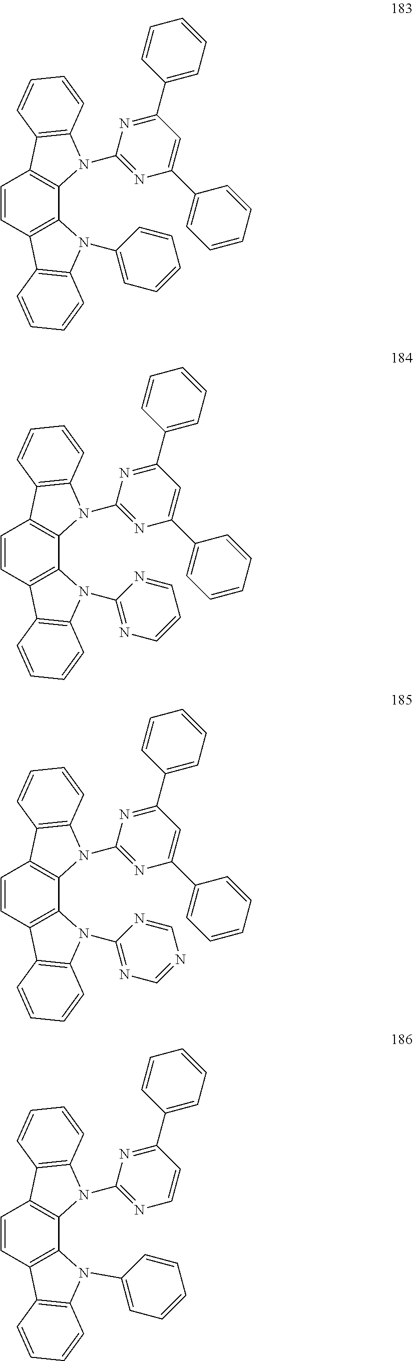 [SMILES: c1ccc(-c2cc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ncccn6)c5c43)n2)cc1 ; c1ccc(-c2cc(-c3ccccc3)nc(-n3c4ccccc4c4ccc5c6ccccc6n(-c6ncncn6)c5c43)n2)cc1 ; c1ccc(-c2ccnc(-n3c4ccccc4c4ccc5c6ccccc6n(-c6ccccc6)c5c43)n2)cc1]

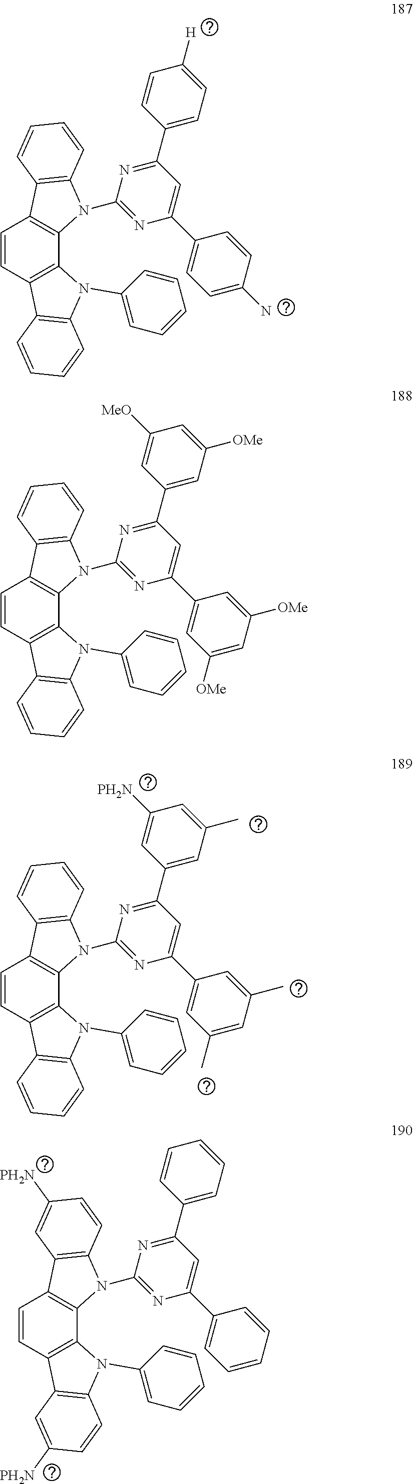

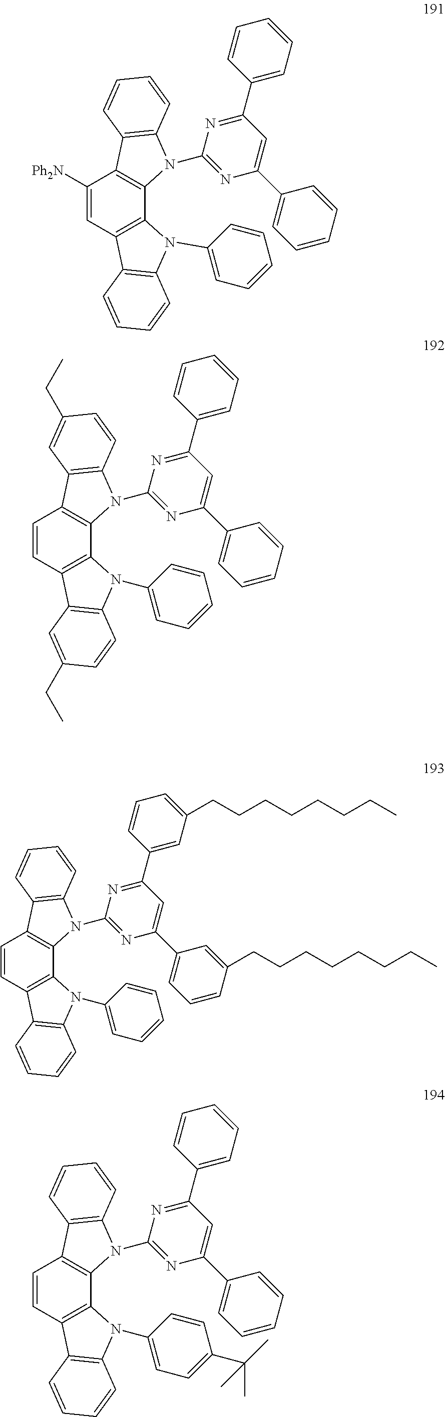

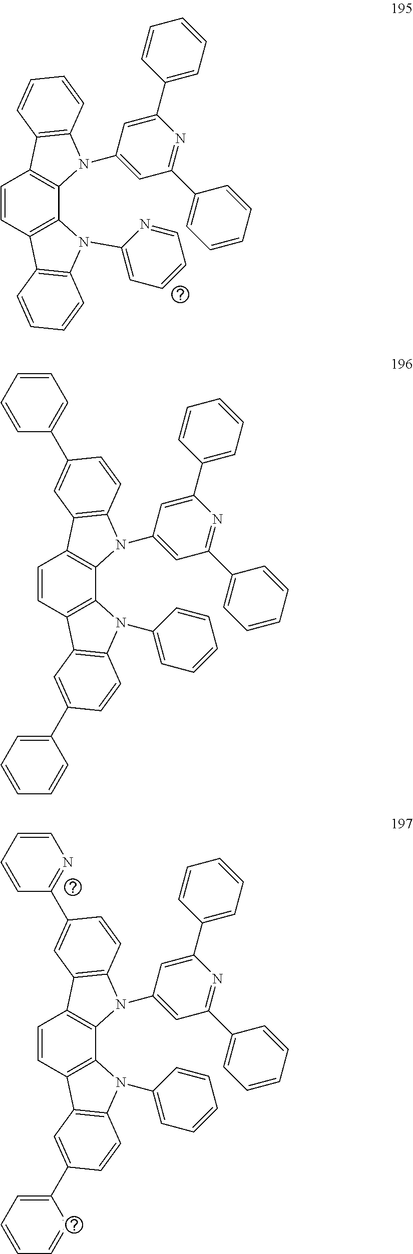

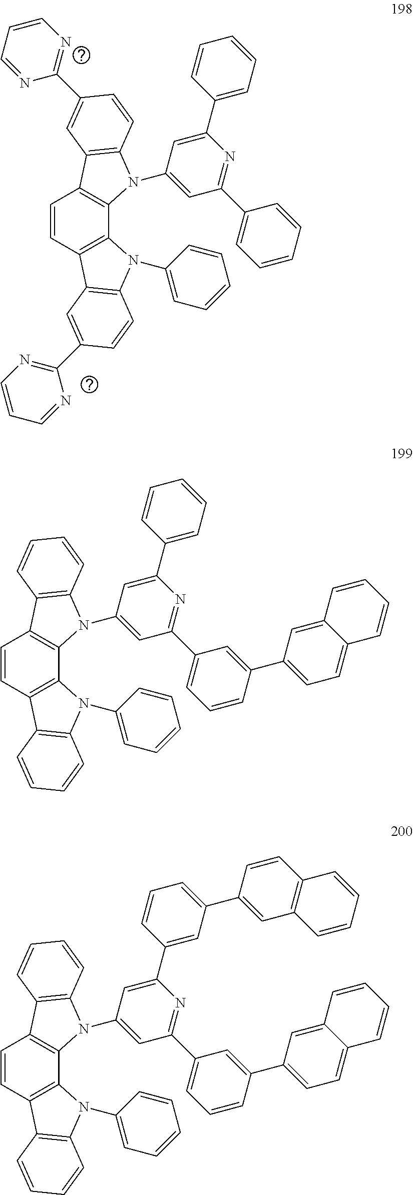 [SMILES: c1ccc(-c2cc(-n3c4ccc(-c5ncccn5)cc4c4ccc5c6cc(-c7ncccn7)ccc6n(-c6ccccc6)c5c43)cc(-c3ccccc3)n2)cc1 ; c1ccc(-c2cc(-n3c4ccccc4c4ccc5c6ccccc6n(-c6ccccc6)c5c43)cc(-c3cccc(-c4ccc5ccccc5c4)c3)n2)cc1 ; c1ccc(-n2c3ccccc3c3ccc4c5ccccc5n(-c5cc(-c6cccc(-c7ccc8ccccc8c7)c6)nc(-c6cccc(-c7ccc8ccccc8c7)c6)c5)c4c32)cc1]

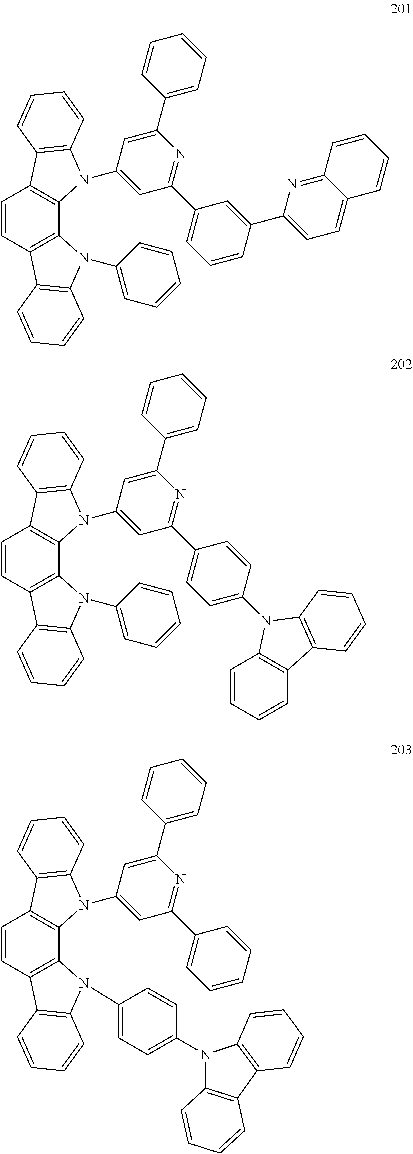 [SMILES: c1ccc(-c2cc(-n3c4ccccc4c4ccc5c6ccccc6n(-c6ccccc6)c5c43)cc(-c3cccc(-c4ccc5ccccc5n4)c3)n2)cc1 ; c1ccc(-c2cc(-n3c4ccccc4c4ccc5c6ccccc6n(-c6ccccc6)c5c43)cc(-c3ccc(-n4c5ccccc5c5ccccc54)cc3)n2)cc1 ; c1ccc(-c2cc(-n3c4ccccc4c4ccc5c6ccccc6n(-c6ccc(-n7c8ccccc8c8ccccc87)cc6)c5c43)cc(-c3ccccc3)n2)cc1]

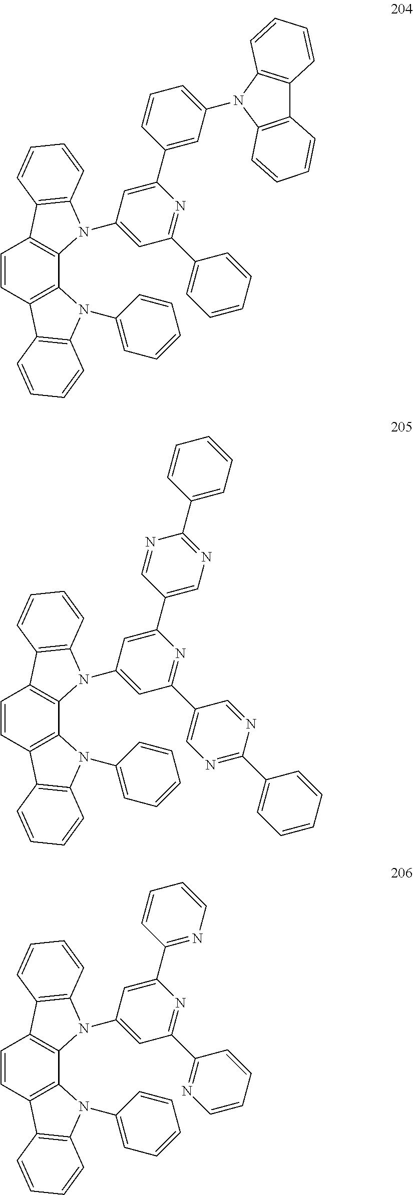 [SMILES: c1ccc(-c2cc(-n3c4ccccc4c4ccc5c6ccccc6n(-c6ccccc6)c5c43)cc(-c3cccc(-n4c5ccccc5c5ccccc54)c3)n2)cc1 ; c1ccc(-c2ncc(-c3cc(-n4c5ccccc5c5ccc6c7ccccc7n(-c7ccccc7)c6c54)cc(-c4cnc(-c5ccccc5)nc4)n3)cn2)cc1 ; c1ccc(-n2c3ccccc3c3ccc4c5ccccc5n(-c5cc(-c6ccccn6)nc(-c6ccccn6)c5)c4c32)cc1]

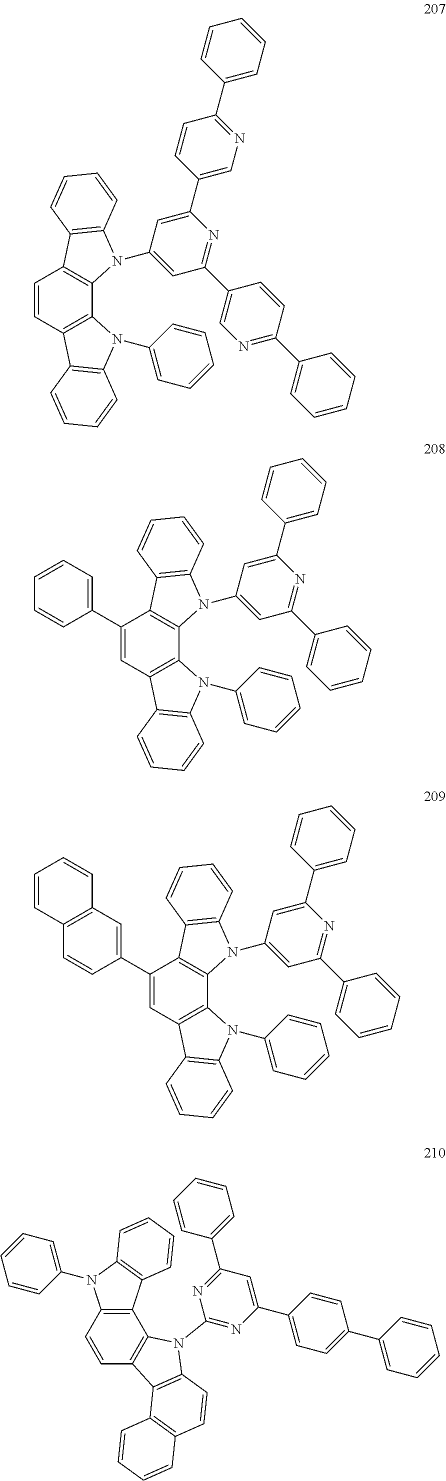

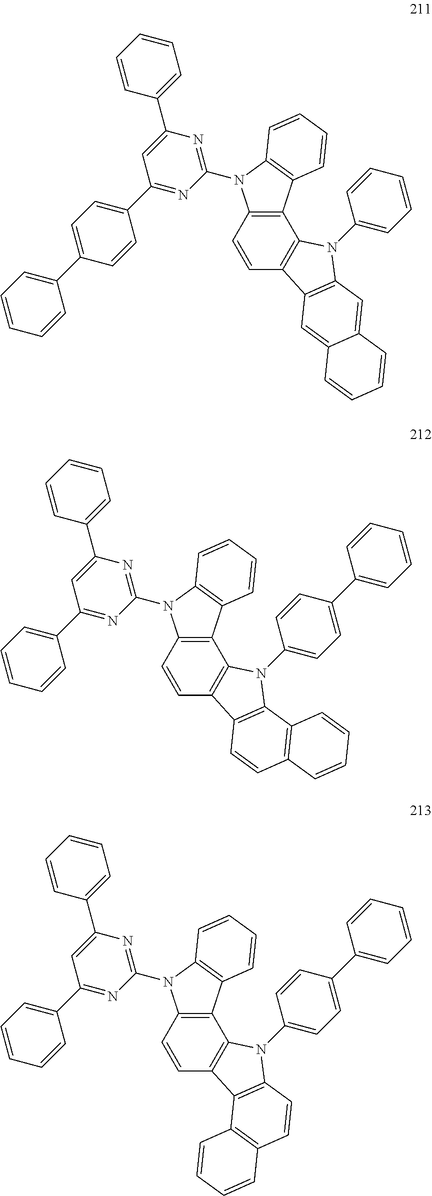 [SMILES: c1ccc(-c2ccc(-c3cc(-c4ccccc4)nc(-n4c5ccccc5c5c4ccc4c6cc7ccccc7cc6n(-c6ccccc6)c45)n3)cc2)cc1 ; c1ccc(-c2ccc(-n3c4c5ccccc5ccc4c4ccc5c(c6ccccc6n5-c5nc(-c6ccccc6)cc(-c6ccccc6)n5)c43)cc2)cc1 ; c1ccc(-c2ccc(-n3c4ccc5ccccc5c4c4ccc5c(c6ccccc6n5-c5nc(-c6ccccc6)cc(-c6ccccc6)n5)c43)cc2)cc1]

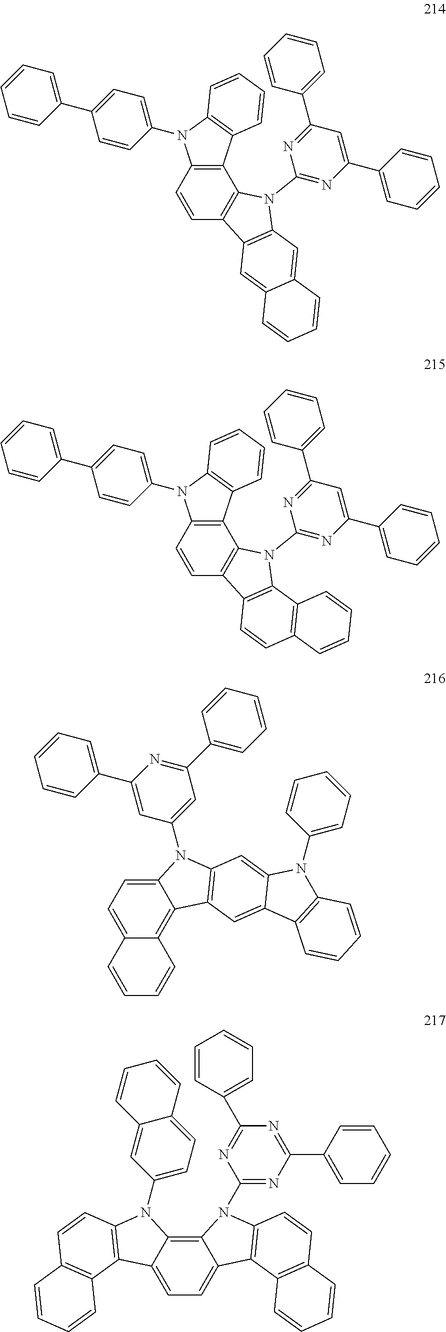 [SMILES: c1ccc(-c2ccc(-n3c4ccccc4c4c3ccc3c5cc6ccccc6cc5n(-c5nc(-c6ccccc6)cc(-c6ccccc6)n5)c34)cc2)cc1 ; c1ccc(-c2ccc(-n3c4ccccc4c4c3ccc3c5ccc6ccccc6c5n(-c5nc(-c6ccccc6)cc(-c6ccccc6)n5)c34)cc2)cc1 ; c1ccc(-c2cc(-n3c4cc5c(cc4c4c6ccccc6ccc43)c3ccccc3n5-c3ccccc3)cc(-c3ccccc3)n2)cc1 ; c1ccc(-c2nc(-c3ccccc3)nc(-n3c4ccc5ccccc5c4c4ccc5c6c7ccccc7ccc6n(-c6ccc7ccccc7c6)c5c43)n2)cc1]

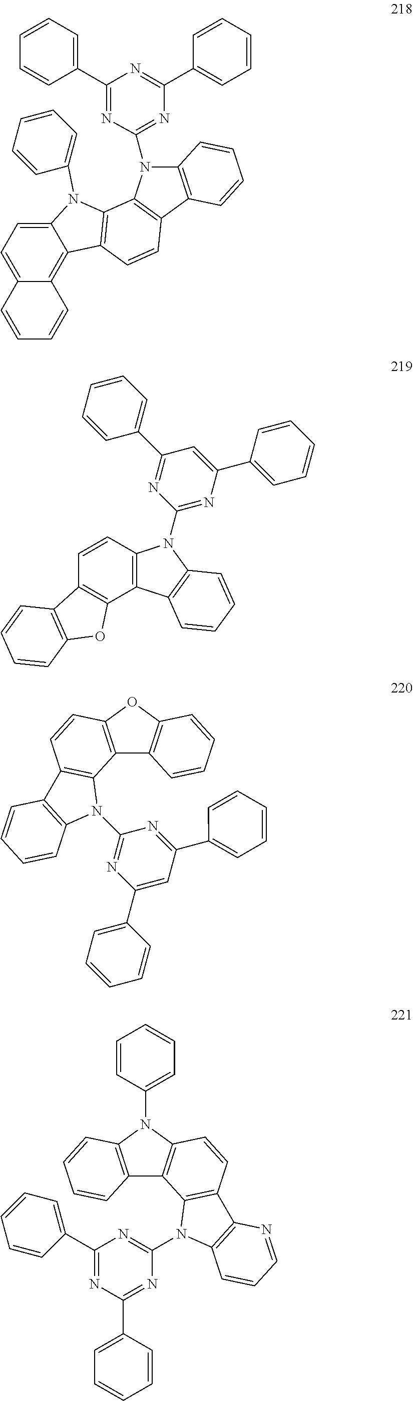

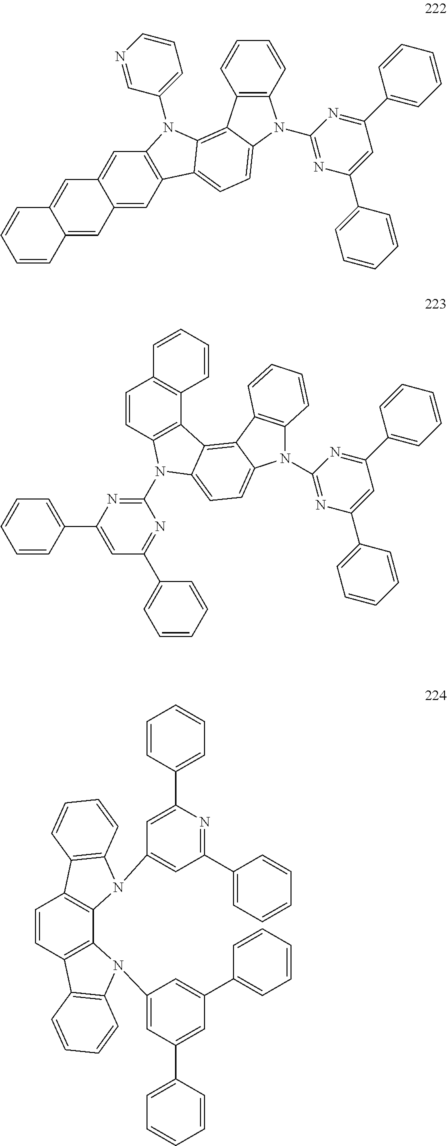 [SMILES: c1ccc(-c2cc(-c3ccccc3)nc(-n3c4ccccc4c4c3ccc3c5cc6cc7ccccc7cc6cc5n(-c5cccnc5)c34)n2)cc1 ; c1ccc(-c2cc(-c3ccccc3)nc(-n3c4ccccc4c4c5c6c7ccccc7ccc6n(-c6nc(-c7ccccc7)cc(-c7ccccc7)n6)c5ccc43)n2)cc1 ; c1ccc(-c2cc(-c3ccccc3)cc(-n3c4ccccc4c4ccc5c6ccccc6n(-c6cc(-c7ccccc7)nc(-c7ccccc7)c6)c5c43)c2)cc1]

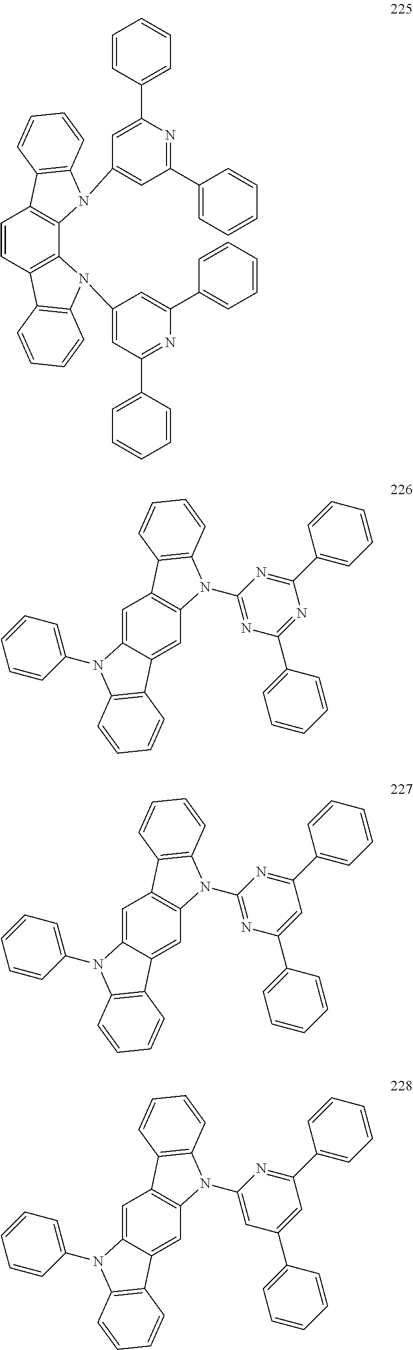

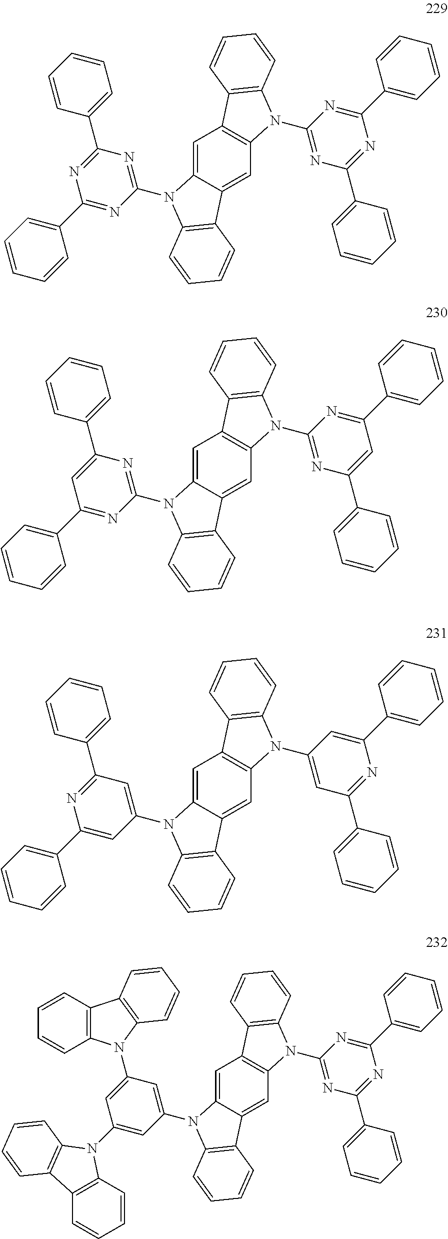 [SMILES: c1ccc(-c2nc(-c3ccccc3)nc(-n3c4ccccc4c4cc5c(cc43)c3ccccc3n5-c3nc(-c4ccccc4)nc(-c4ccccc4)n3)n2)cc1 ; c1ccc(-c2cc(-c3ccccc3)nc(-n3c4ccccc4c4cc5c(cc43)c3ccccc3n5-c3nc(-c4ccccc4)cc(-c4ccccc4)n3)n2)cc1 ; c1ccc(-c2cc(-n3c4ccccc4c4cc5c(cc43)c3ccccc3n5-c3cc(-c4ccccc4)nc(-c4ccccc4)c3)cc(-c3ccccc3)n2)cc1 ; c1ccc(-c2nc(-c3ccccc3)nc(-n3c4ccccc4c4cc5c(cc43)c3ccccc3n5-c3cc(-n4c5ccccc5c5ccccc54)cc(-n4c5ccccc5c5ccccc54)c3)n2)cc1]

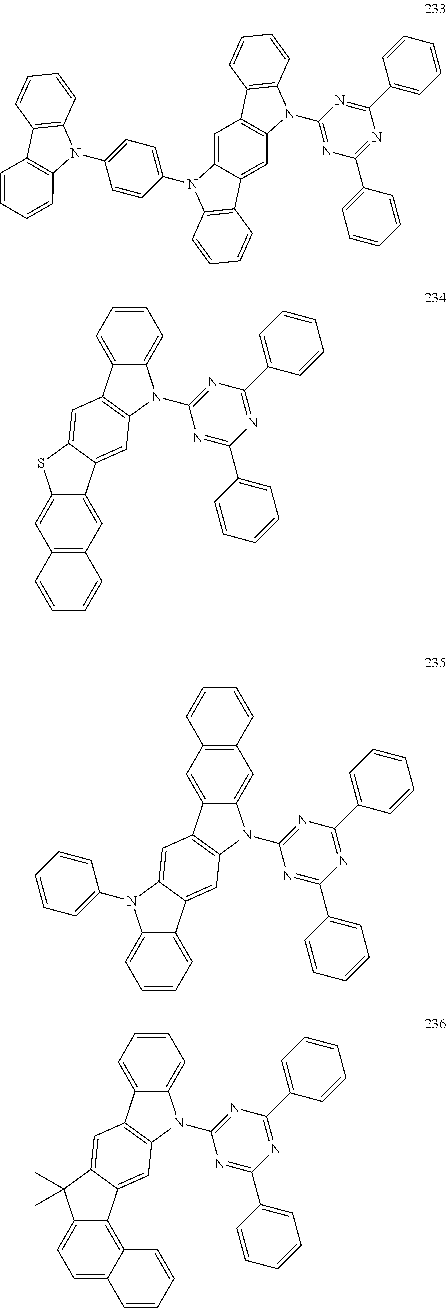

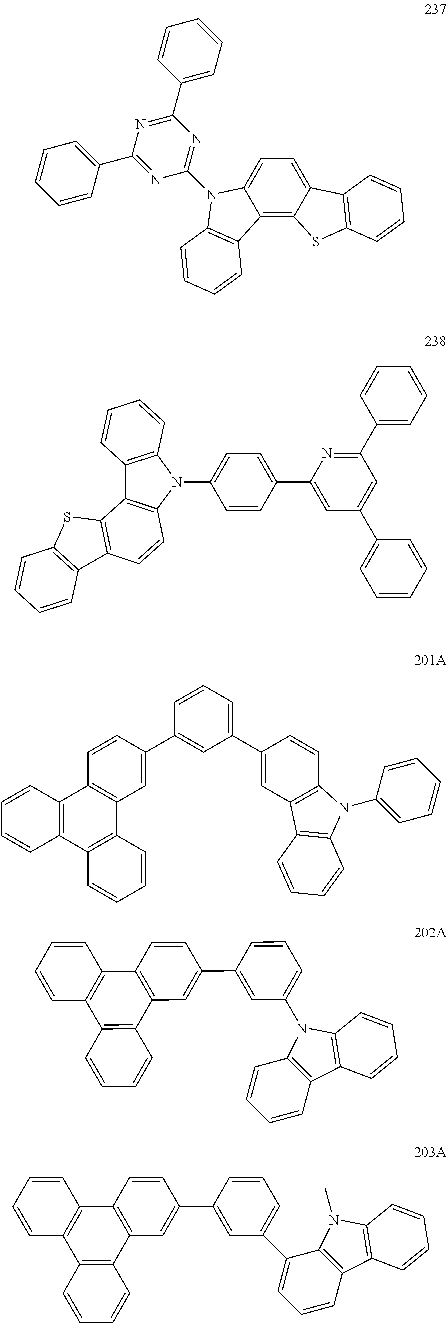 [SMILES: c1ccc(-c2nc(-c3ccccc3)nc(-n3c4ccccc4c4c5sc6ccccc6c5ccc43)n2)cc1 ; c1ccc(-c2cc(-c3ccccc3)nc(-c3ccc(-n4c5ccccc5c5c6sc7ccccc7c6ccc54)cc3)c2)cc1 ; c1ccc(-n2c3ccccc3c3cc(-c4cccc(-c5ccc6c7ccccc7c7ccccc7c6c5)c4)ccc32)cc1 ; c1cc(-c2ccc3c4ccccc4c4ccccc4c3c2)cc(-n2c3ccccc3c3ccccc32)c1 ; Cn1c2ccccc2c2cccc(-c3cccc(-c4ccc5c6ccccc6c6ccccc6c5c4)c3)c21]

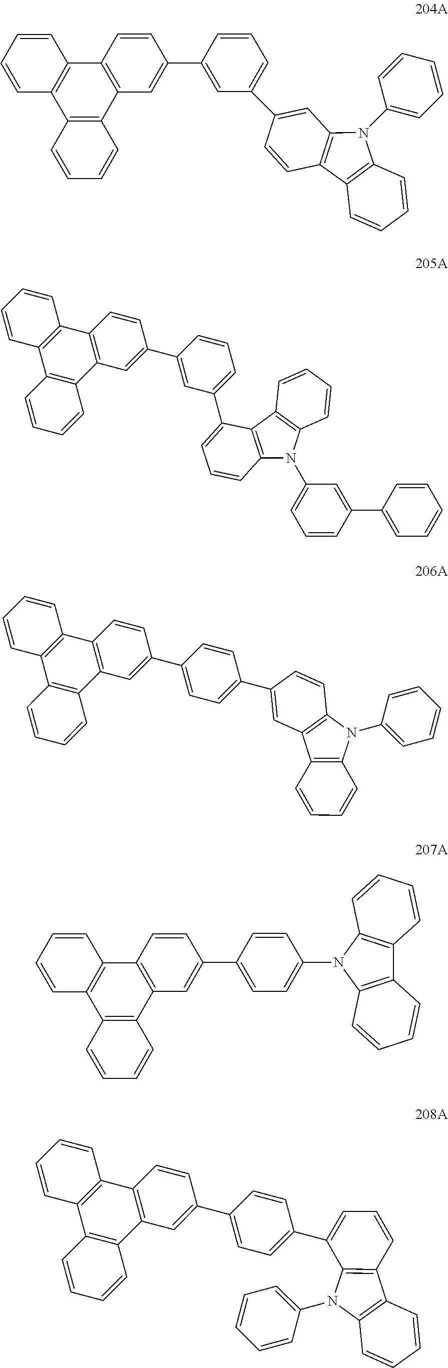 [SMILES: c1ccc(-n2c3ccccc3c3ccc(-c4cccc(-c5ccc6c7ccccc7c7ccccc7c6c5)c4)cc32)cc1 ; c1ccc(-c2cccc(-n3c4ccccc4c4c(-c5cccc(-c6ccc7c8ccccc8c8ccccc8c7c6)c5)cccc43)c2)cc1 ; c1ccc(-n2c3ccccc3c3cc(-c4ccc(-c5ccc6c7ccccc7c7ccccc7c6c5)cc4)ccc32)cc1 ; c1ccc2c(c1)c1ccccc1c1cc(-c3ccc(-n4c5ccccc5c5ccccc54)cc3)ccc21 ; c1ccc(-n2c3ccccc3c3cccc(-c4ccc(-c5ccc6c7ccccc7c7ccccc7c6c5)cc4)c32)cc1]

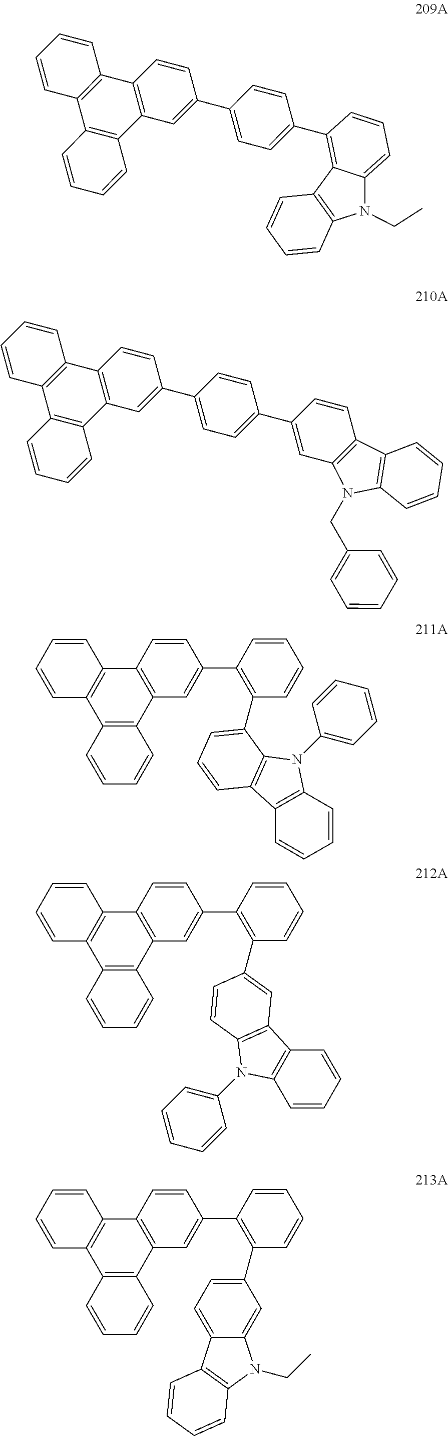

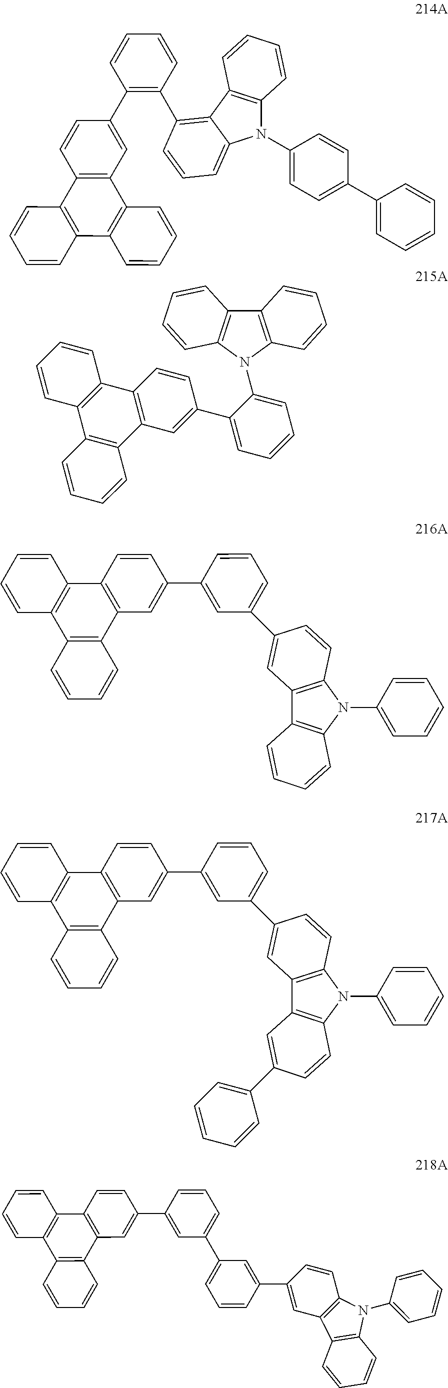

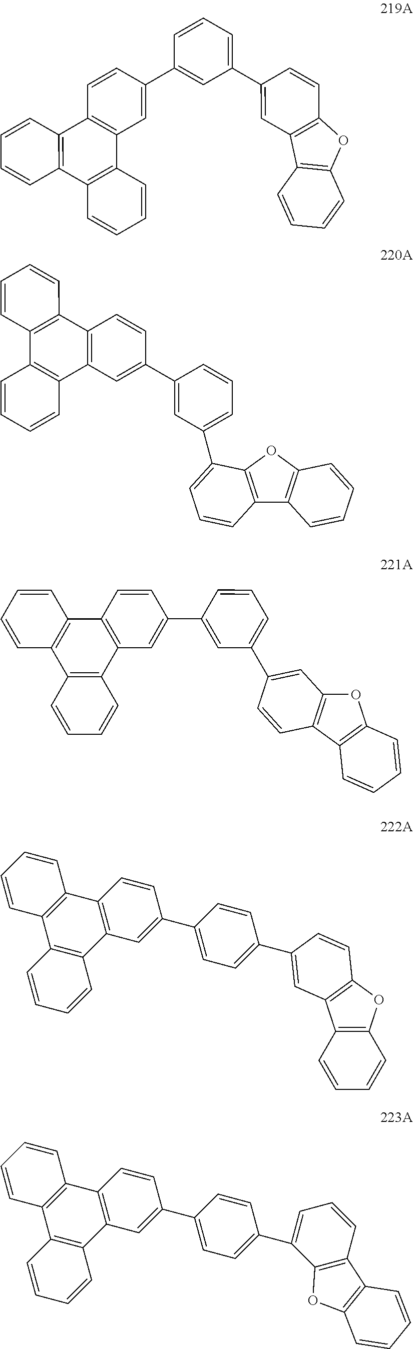 [SMILES: c1cc(-c2ccc3oc4ccccc4c3c2)cc(-c2ccc3c4ccccc4c4ccccc4c3c2)c1 ; c1cc(-c2ccc3c4ccccc4c4ccccc4c3c2)cc(-c2cccc3c2oc2ccccc23)c1 ; c1cc(-c2ccc3c(c2)oc2ccccc23)cc(-c2ccc3c4ccccc4c4ccccc4c3c2)c1 ; c1ccc2c(c1)oc1ccc(-c3ccc(-c4ccc5c6ccccc6c6ccccc6c5c4)cc3)cc12 ; c1ccc2c(c1)oc1c(-c3ccc(-c4ccc5c6ccccc6c6ccccc6c5c4)cc3)cccc12]

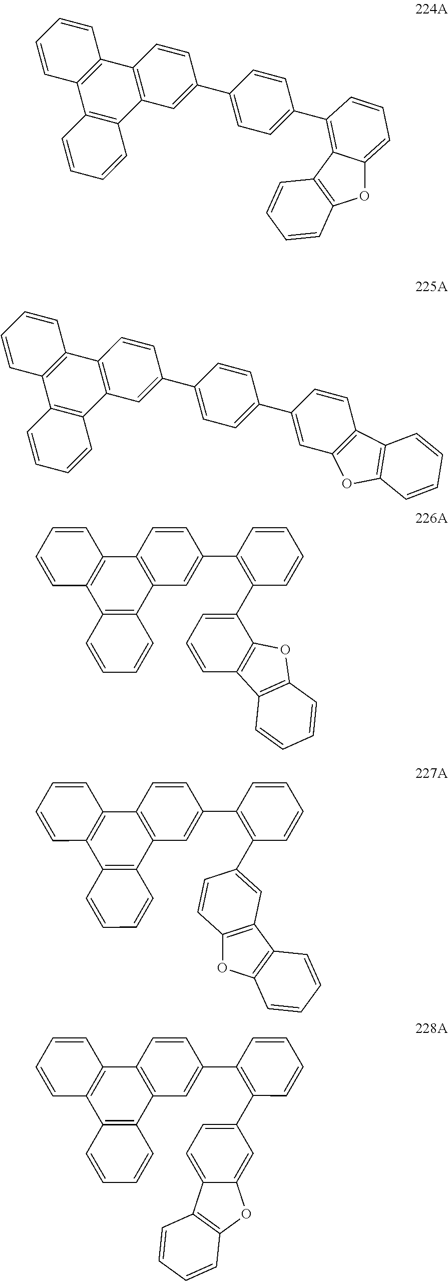

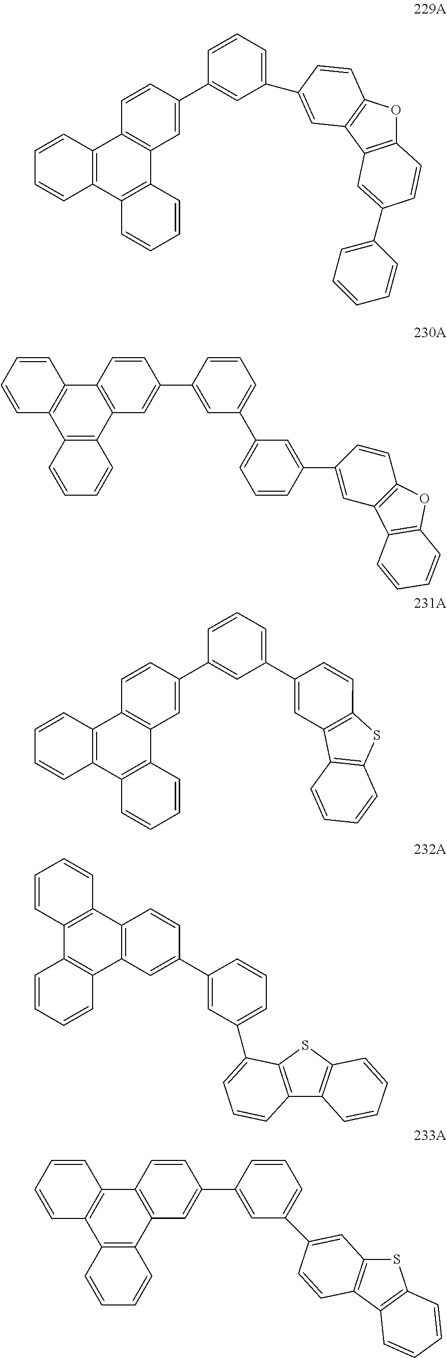

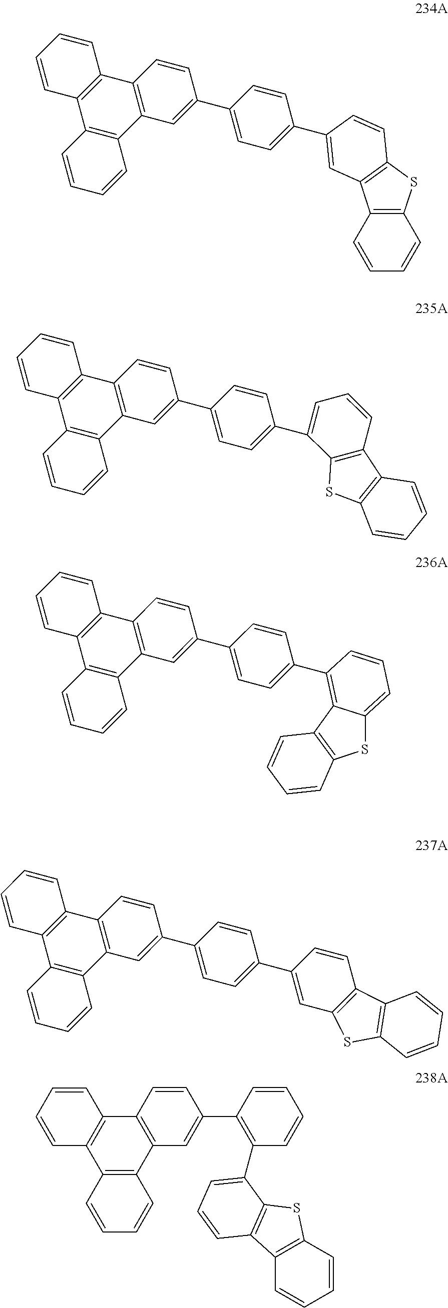 [SMILES: c1ccc2c(c1)sc1ccc(-c3ccc(-c4ccc5c6ccccc6c6ccccc6c5c4)cc3)cc12 ; c1ccc2c(c1)sc1c(-c3ccc(-c4ccc5c6ccccc6c6ccccc6c5c4)cc3)cccc12 ; c1ccc2c(c1)sc1cccc(-c3ccc(-c4ccc5c6ccccc6c6ccccc6c5c4)cc3)c12 ; c1ccc2c(c1)sc1cc(-c3ccc(-c4ccc5c6ccccc6c6ccccc6c5c4)cc3)ccc12 ; c1ccc(-c2cccc3c2sc2ccccc23)c(-c2ccc3c4ccccc4c4ccccc4c3c2)c1]

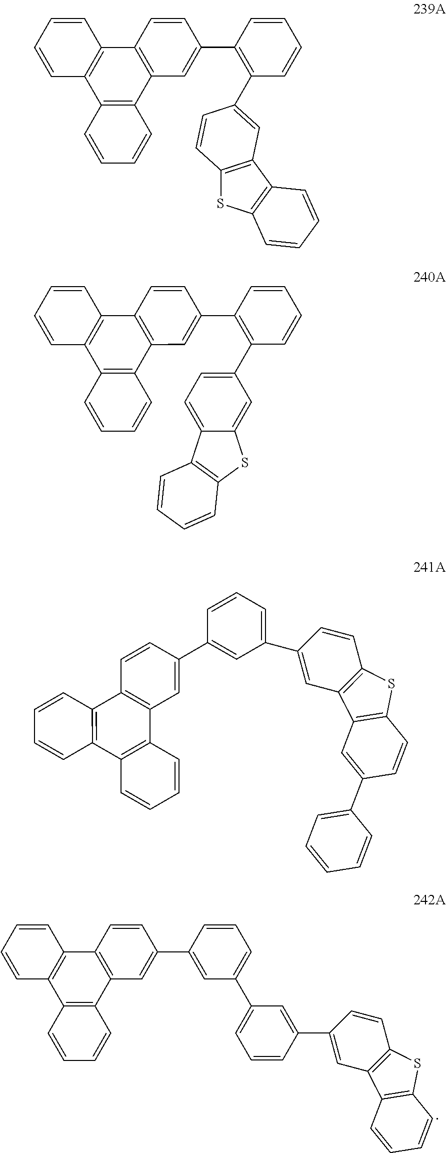

18. The organic light-emitting device as claimed in claim 1, wherein the emission layer further includes a phosphorescent dopant.

19. The organic light-emitting device as claimed in claim 18, wherein the phosphorescent dopant is an organometallic complex represented by Formula 401, below: 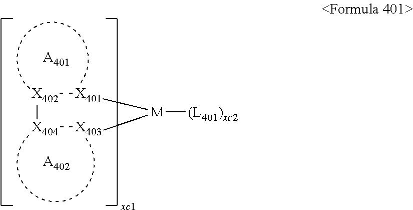
in Formula 401,
M is selected from iridium (Ir), platinum (Pt), osmium (Os), titanium (Ti), zirconium (Zr), hafnium (Hf), europium (Eu), terbium (Tb), and thulium (Tm);
X₄₀₁ to X₄₀₄ are each independently a nitrogen atom or a carbon atom;
ring A₄₀₁ and ring A₄₀₂ are each independently selected from a substituted or unsubstituted benzene group, a substituted or unsubstituted naphthalene group, a substituted or unsubstituted fluorene group, a substituted or unsubstituted spiro-fluorene group, a substituted or unsubstituted indene group, a substituted or unsubstituted pyrrole group, a substituted or unsubstituted thiopene group, a substituted or unsubstituted furan group, a substituted or unsubstituted imidazole group, a substituted or unsubstituted pyrazole group, a substituted or unsubstituted thiazole group, a substituted or unsubstituted isothiazole group, a substituted or unsubstituted oxazole group, a substituted or unsubstituted isooxazole group, a substituted or unsubstituted pyridine group, a substituted or unsubstituted pyrazine group, a substituted or unsubstituted pyrimidine group, a substituted or unsubstituted pyridazine, a substituted or unsubstituted quinoline group, a substituted or unsubstituted isoquinoline group, a substituted or unsubstituted benzoquinoline group, a substituted or unsubstituted quinoxaline group, a substituted or unsubstituted quinazoline group, a substituted or unsubstituted carbazole group, a substituted or unsubstituted benzoimidazole group, a substituted or unsubstituted benzofuran(benzofuran), a substituted or unsubstituted benzothiopene group, a substituted or unsubstituted isobenzothiopene group, a substituted or unsubstituted benzooxazole group, a substituted or unsubstituted isobenzooxazole group, a substituted or unsubstituted triazole, a substituted or unsubstituted oxadiazole, a substituted or unsubstituted triazine, a substituted or unsubstituted dibenzofuran group, and a substituted or unsubstituted dibenzothiopene group;
at least one substituent of the substituted benzene group, the substituted naphthalene group, the substituted fluorene group, the substituted spiro-fluorene group, the substituted indene group, the substituted pyrrole group, the substituted thiopene group, the substituted furan group, the substituted imidazole group, the substituted pyrazole group, the substituted thiazole group, the substituted isothiazole group, the substituted oxazole group, the substituted isooxazole group, the substituted pyridine group, the substituted pyrazine group, the substituted pyrimidine group, the substituted pyridazine, the substituted quinoline group, the substituted isoquinoline group, the substituted benzoquinoline group, the substituted quinoxaline group, the substituted quinazoline group, the substituted carbazole group, the substituted benzoimidazole group, the substituted benzofuran group, the substituted benzothiopene group, the substituted isobenzothiopene group, the substituted benzooxazole group, the substituted isobenzooxazole group, the substituted triazole, the substituted oxadiazole, the substituted triazine, the substituted dibenzofuran, and the substituted dibenzothiopene is selected from
deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a non-aromatic condensed polycyclic group(non-aromatic condensed polycyclic group), —N(Q₄₀₁)(Q₄₀₂), —Si(Q₄₀₃)(Q₄₀₄)(Q₄₀₅), and —B(Q₄₀₆)(Q₄₀₇);
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, and a non-aromatic condensed polycyclic group;
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, and a non-aromatic condensed polycyclic group, each substituted with at least one selected from deuterium, —F, —Cl, —Br, —I, a hydroxyl group, a cyano group, a nitro group, an amino group, an amidino group, a hydrazine group, a hydrazone group, carboxylic acid and a salt thereof, sulfonic acid and a salt thereof, phosphoric acid and a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a non-aromatic condensed polycyclic group, —N(Q₄₁₁)(Q₄₁₂), —Si(Q₄₁₃)(Q₄₁₄)(Q₄₁₅), and —B(Q₄₁₆)(Q₄₁₇); and
—N(Q₄₂₁)(Q₄₂₂), —Si(Q₄₂₃)(Q₄₂₄)(Q₄₂₅), and —B(Q₄₂₆)(Q₄₂₇);
L₄₀₁ is an organic ligand;
xc1 is 1, 2, or 3; and
xc2 is 0, 1, 2, or 3.

20. The organic light-emitting device as claimed in claim 18, wherein the phosphorescent dopant is selected from Compounds PD1 to PD82 below: 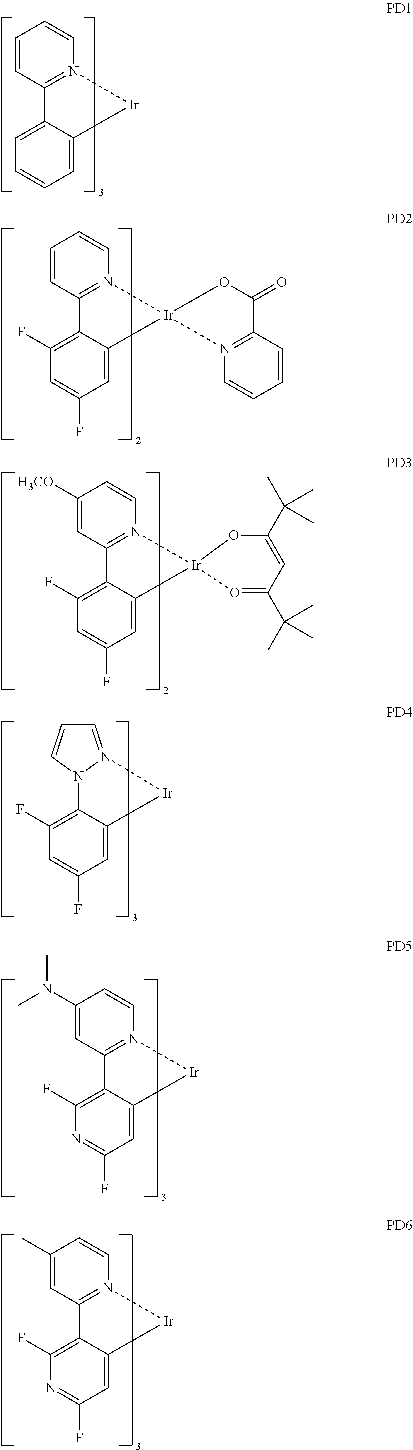 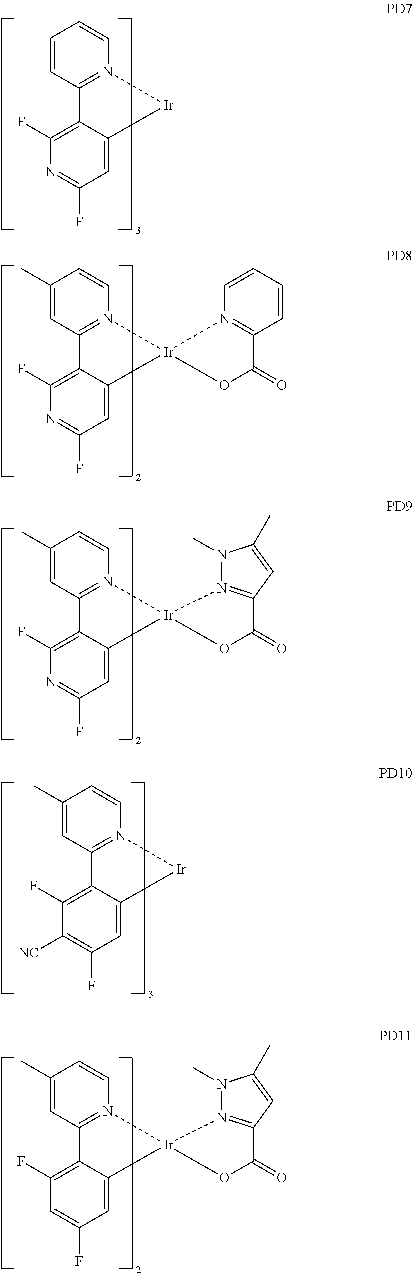 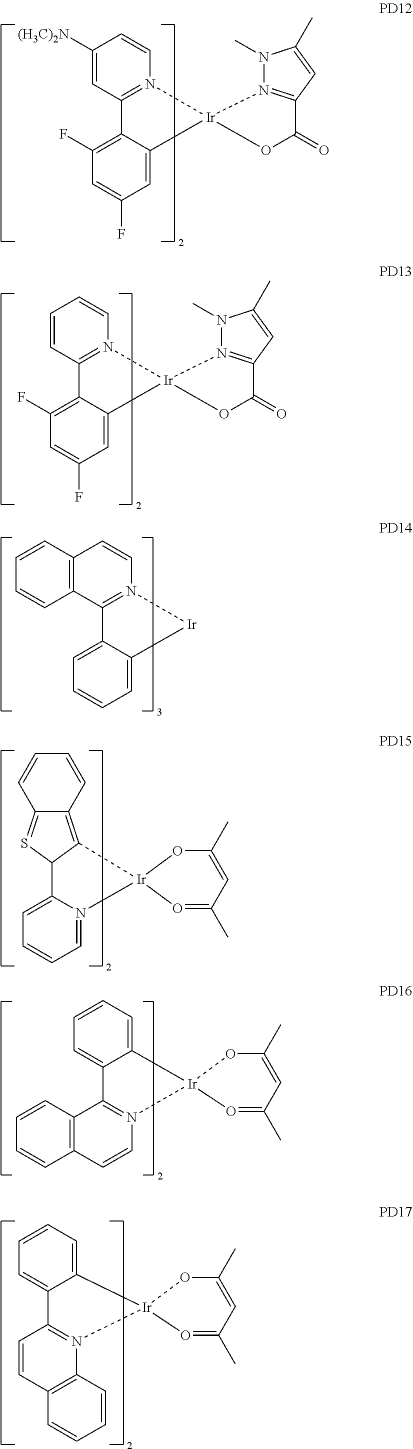 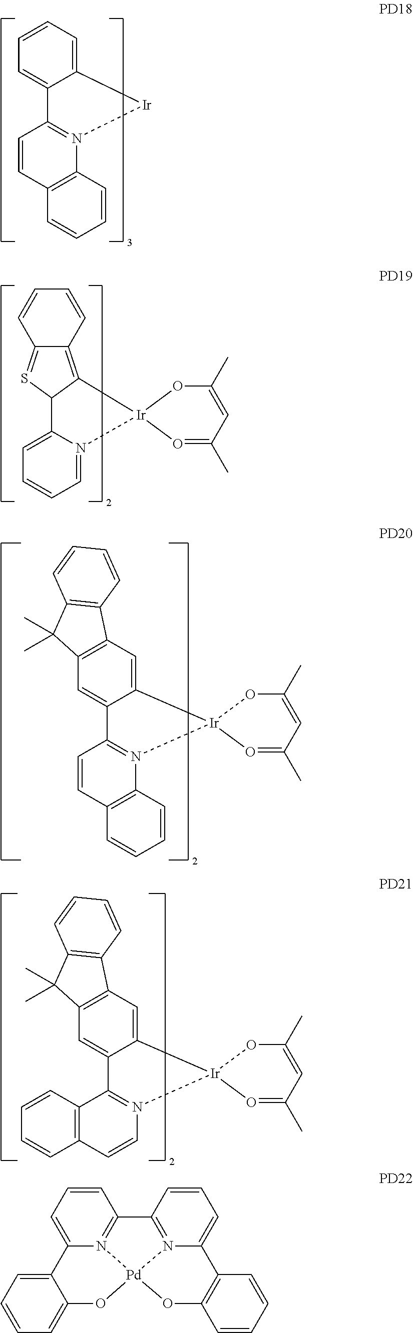 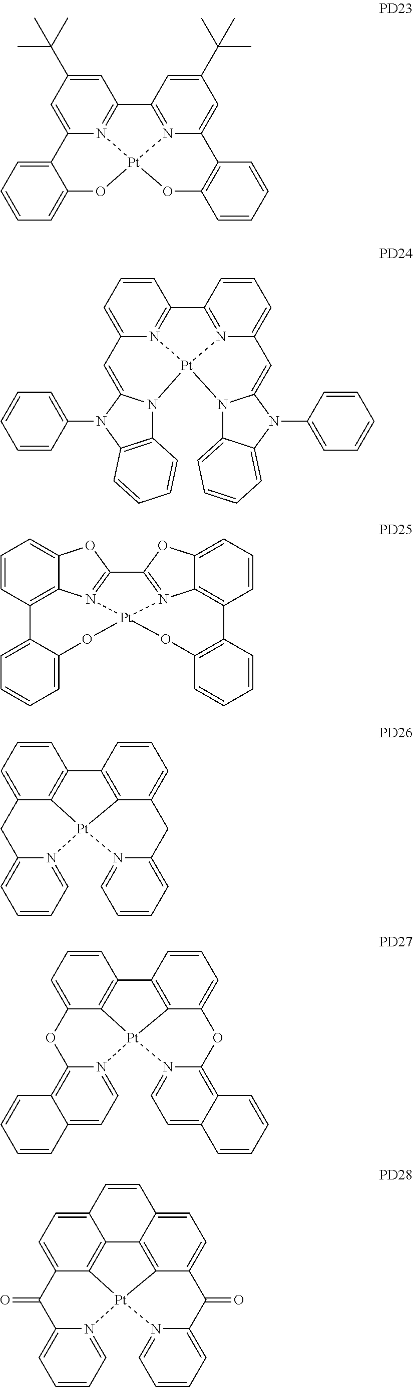 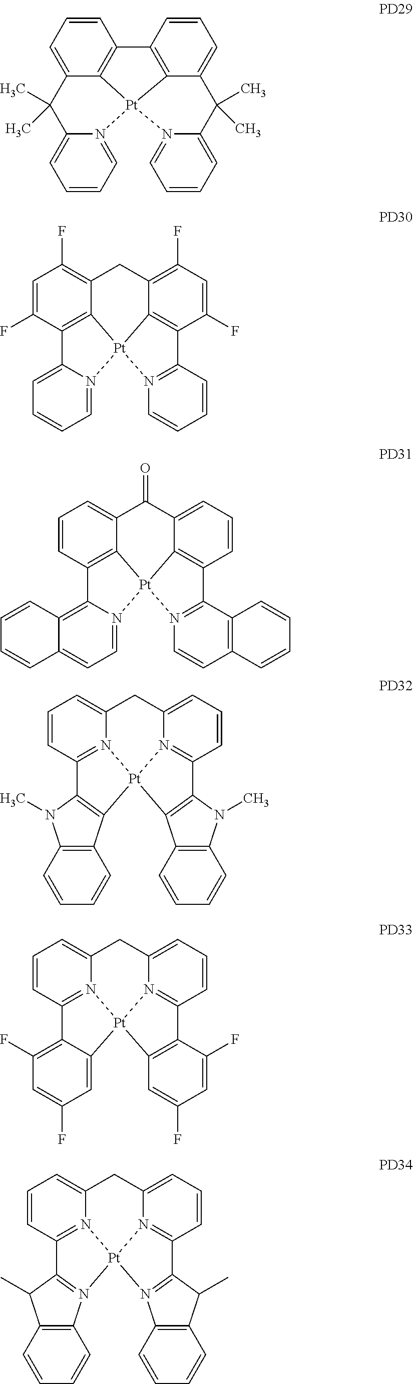 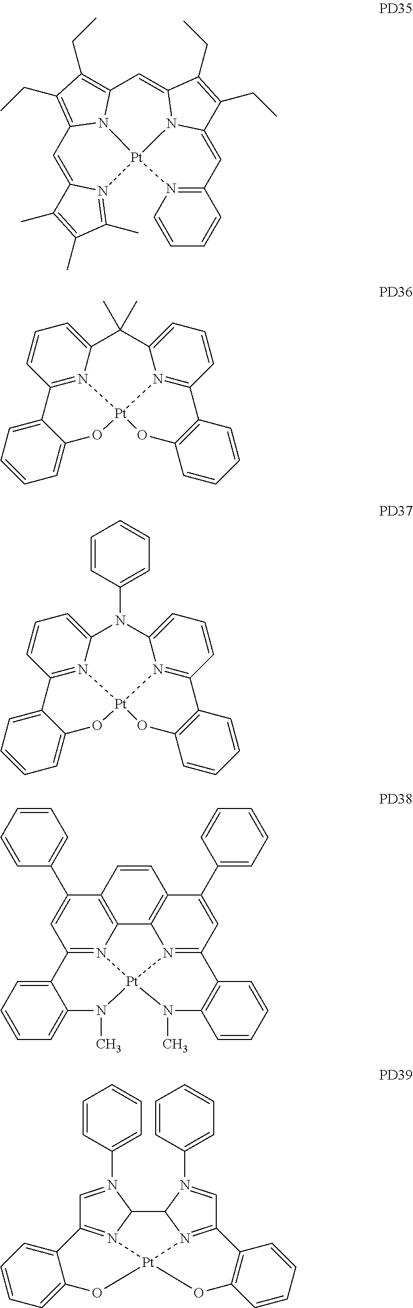 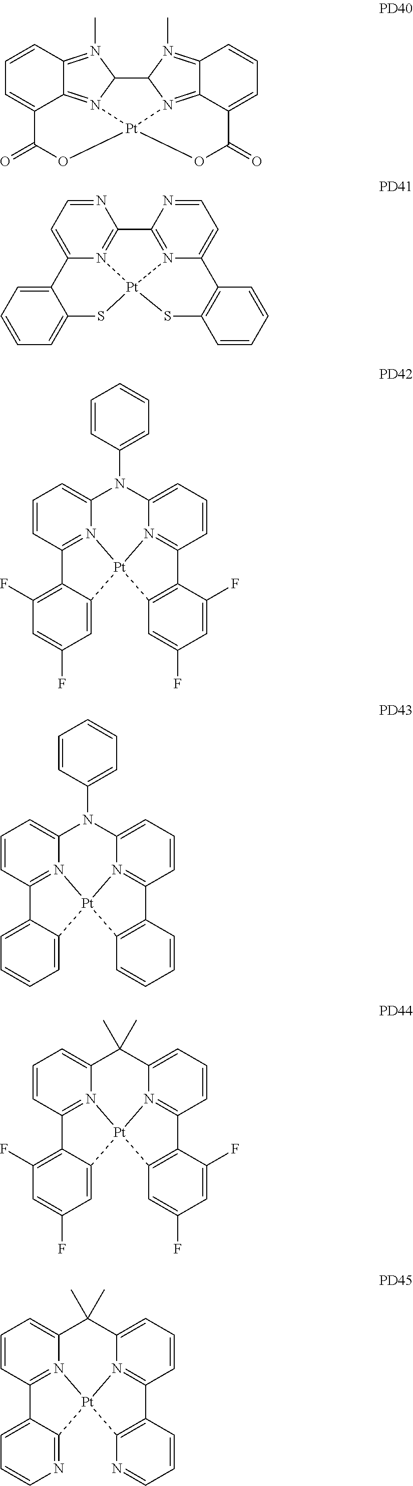 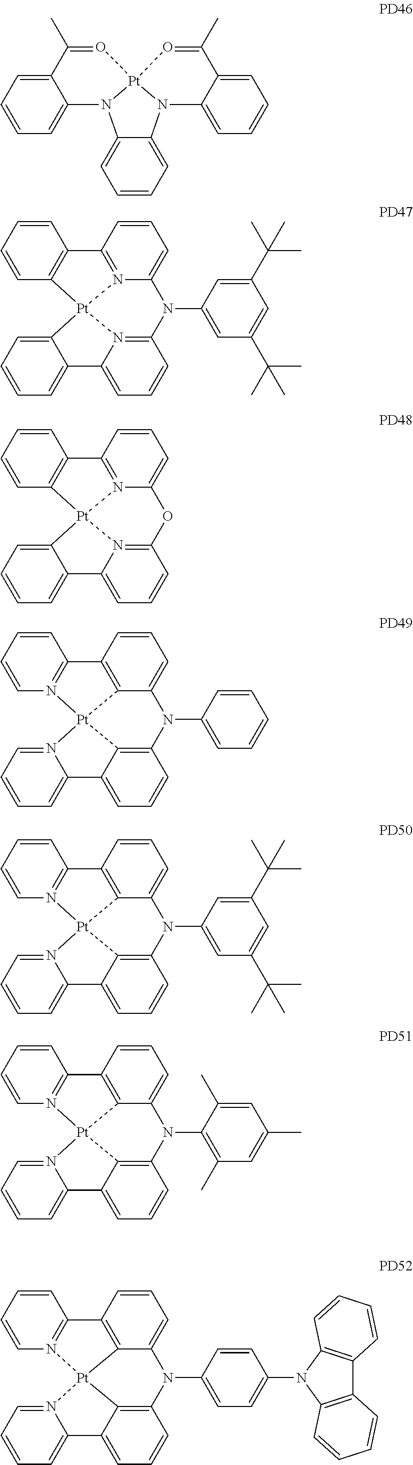 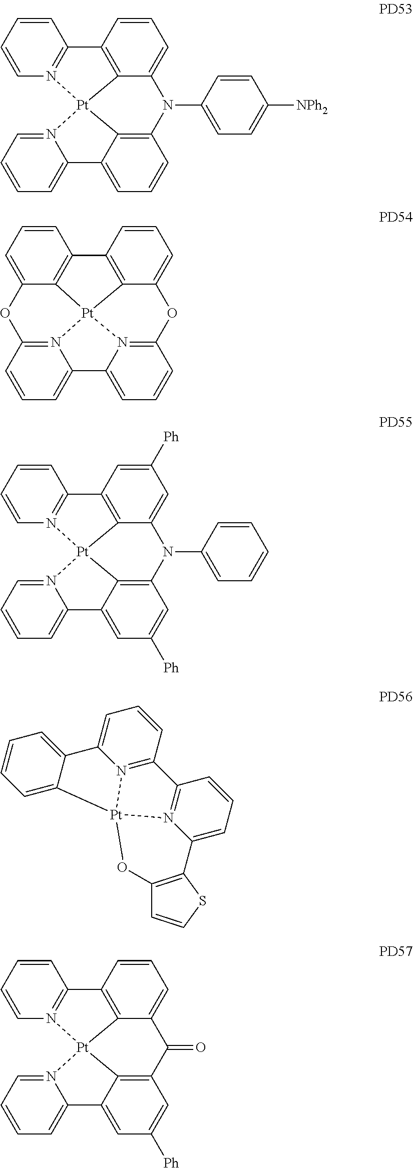 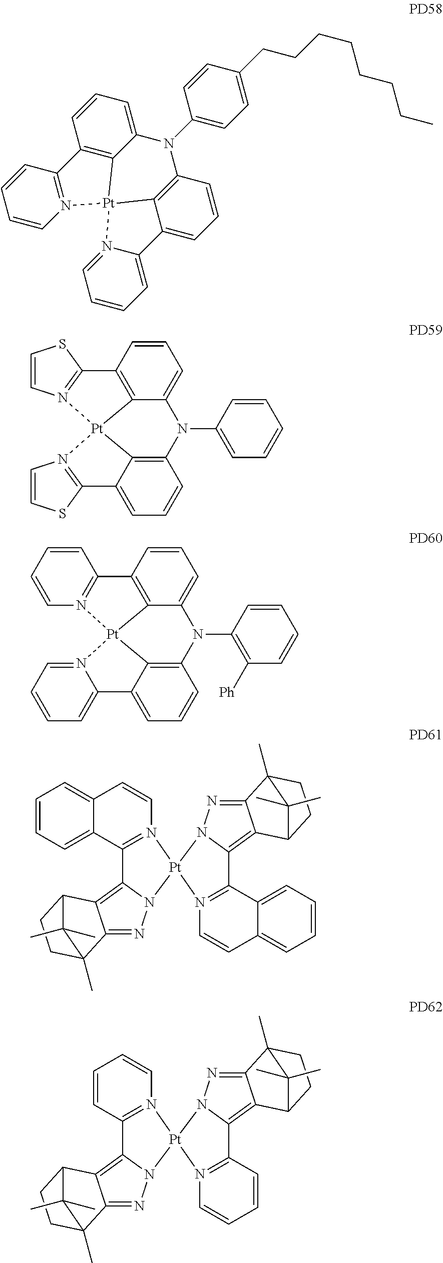 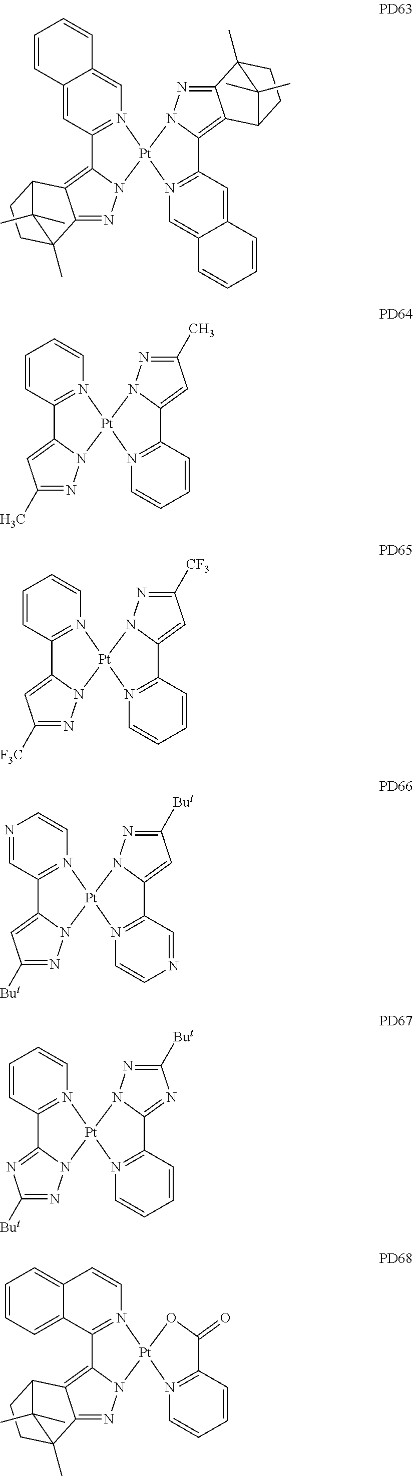 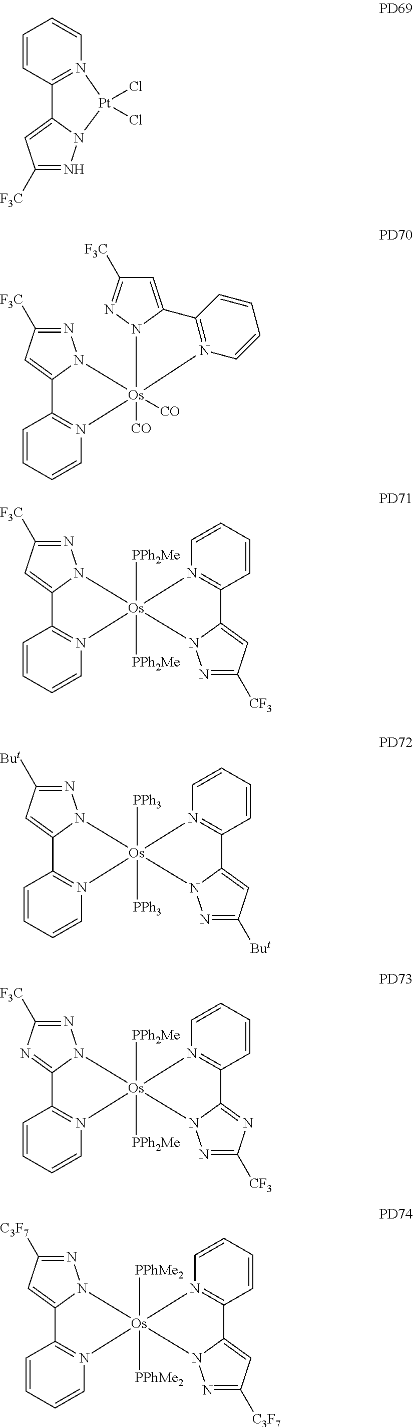 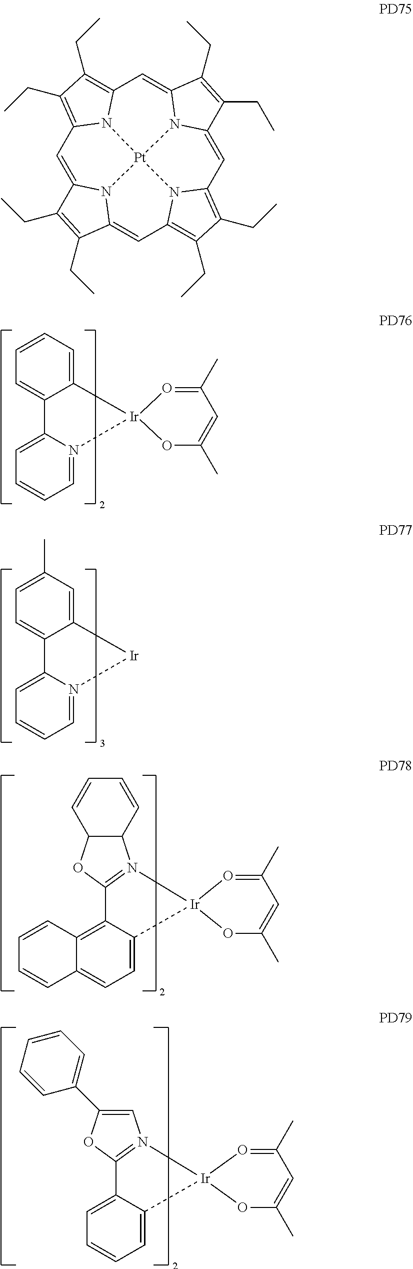 [chemical structure]
